(19) United States
(12) Patent Application Publication
(10) Pub. No.: US 2025/0255182 A1
(43) Pub. Date: Aug. 7, 2025

(54) ORGANIC ELECTROLUMINESCENT MATERIAL, DEVICE, AND PREPARATION METHOD

(71) Applicant: BEIJING SUMMER SPROUT TECHNOLOGY CO., LTD., Beijing (CN)

(72) Inventors: Chunliang ZHAO, Beijing (CN); Ming SANG, Beijing (CN); Xuechao TIAN, Beijing (CN); Liuhuan CAI, Beijing (CN); Chi Yuen Raymond KWONG, Beijing (CN); Chuanjun XIA, Beijing (CN)

(21) Appl. No.: 19/039,193

(22) Filed: Jan. 28, 2025

(30) Foreign Application Priority Data
Feb. 5, 2024 (CN) 202410164735.1
Jul. 10, 2024 (CN) 202410921058.3

(51) Int. Cl. H10K 85/60; C09K 11/02; C09K 11/06; H10K 50/12; H10K 71/16; H10K 85/30

(52) U.S. Cl. CPC H10K 85/658; C09K 11/02; C09K 11/06; H10K 85/342; H10K 85/346; H10K 85/654; H10K 85/657; H10K 85/6572; H10K 85/6574; C09K 2211/1007; C09K 2211/1018; H10K 50/121; H10K 71/16

(57) ABSTRACT

Provided are a composition, a device, and a preparation method. The composition includes a premix and a phosphorescent sensitizer, and the premix includes a first host compound, a second host compound, and a fluorescent compound. The first host compound has an evaporation temperature T1, and the second host compound has an evaporation temperature T2. Both T1 and T2 range from 100° C. to 400° C., and the absolute value therebetween is less than or equal to 20° C. The premix of the present disclosure can be used as a single evaporation source in the preparation process of a device, thereby reducing the cost and complexity of the evaporation process. Moreover, the premix included in the composition of the present disclosure shows high evaporation stability and can obtain stable and more excellent device performance when the premix is applied to continuous evaporation of an organic electroluminescent device.

### CROSS-REFERENCE TO RELATED APPLICATION(S)

This application claims priority to Chinese Patent Application No. 202410164735.1 filed on Feb. 5, 2024 and Chinese Patent Application No. 202410921058.3 filed on Jul. 10, 2024, the disclosure of which are incorporated herein by reference in their entireties.

### TECHNICAL FIELD

The present disclosure relates to organic electronic devices, for example, organic electroluminescent devices. In particular, the present disclosure relates to organic electroluminescent materials used in the devices. More particularly, the present disclosure relates to a premix including three materials, a composition including the premix and a phosphorescent sensitizer, a device including the composition in a light-emitting layer, and a preparation method of the device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

A device with a phosphorescent sensitizer and a light-emitting material co-doped in a host material in an organic emitting layer (EML) and use thereof are disclosed in the related art. However, in practical applications, with the introduction of another material into the organic emitting layer, an additional evaporation source is generally required, and the evaporation process is very complex and expensive. The desired approach is to pre-mix multiple materials in the emissive layer to form a premix with high evaporation stability and then put the premix into a single evaporation source to reduce the use of the evaporation source, thereby reducing the cost and complexity of the evaporation process. However, the co-evaporation of the premix that can serve as a single evaporation source must be stable so that it can be ensured that the device prepared by evaporating the premix has stable device performance. However, when multiple compounds are mixed to form the premix, it is difficult to achieve a stable co-evaporated premix since possible interactions between the multiple compounds affect the stability of evaporation film forming of the multiple compounds.

In the research of phosphor-sensitized fluorescent devices, it has been reported that a fluorescent emissive material and a single host material are pre-mixed (a two-component premix) and then placed in a single evaporation source. For example, CN116814246A discloses an organic luminescent material including a fluorescent guest, a phosphorescent sensitizer and/or a host material and further discloses an organic electroluminescent device and a display device including the organic luminescent material. In the device embodiments of the present application, a fluorescent guest and a single host material are pre-mixed and then placed in a single evaporation source, and a phosphorescent sensitizer is placed in another evaporation source to solve the problem that three evaporation sources are required for preparing a three-component emissive layer, thereby reducing the difficulty and cost of the evaporation process. However, to achieve better device performance, two different host materials generally need to be introduced into the emissive layer in practical applications of the phosphor-sensitized fluorescent device. Especially for a phosphor-sensitized TADF device, four component materials are present in the emissive layer of such a phosphor-sensitized fluorescent device. At this point, to reduce the cost and complexity of the evaporation process, the desired approach is to pre-mix three component materials to form a premix with high evaporation stability. However, if three component materials are pre-mixed, the possible interactions between the three component materials are more complex, and it is more difficult to form a premix with high evaporation stability. Therefore, when four component materials are present in the emissive layer, it is challenging to simplify the evaporation process while ensuring the device performance.

### SUMMARY

The present disclosure aims to provide a new premix and a composition including the premix and a phosphorescent sensitizer to solve at least part of the above problems. The premix includes a first host compound, a second host compound, and a fluorescent compound. The first host compound has an evaporation temperature T1, and the second host compound has an evaporation temperature T2. Both T1 and T2 range from 100° C. to 400° C., and the absolute value of the difference between T1 and T2 is less than or equal to 20° C. The premix of the present disclosure shows high evaporation stability and can obtain stable device performance when the premix is applied to continuous evaporation of an organic electroluminescent device in industrial mass production. Meanwhile, the premix of the present disclosure can be used as a single evaporation source in the preparation process of a device, thereby reducing the cost and complexity of the evaporation process. Moreover, the composition of the present disclosure can be used in the emissive layer of a device, and compared with an ordinary device, can obtain more excellent device performance with a narrow full width at half maximum, high external quantum efficiency and/or a long device lifetime.

According to an embodiment of the present disclosure, a premix is disclosed, which includes a first host compound, a second host compound, and a fluorescent compound;
wherein the triplet energy level of the first host compound and the triplet energy level of the second host compound are higher than the triplet energy level of the fluorescent compound;
the first host compound has an evaporation temperature T1, wherein T1 ranges from 100° C. to 400° C.;
the second host compound has an evaporation temperature T2, wherein T2 ranges from 100° C. to 400° C.;
the absolute value of the difference between T1 and T2 is less than or equal to 20° C.

According to an embodiment of the present disclosure, the use of a premix in a sensitized device is disclosed, wherein the premix is as described in the above embodiment, and the premix and a phosphorescent sensitizer are co-evaporated to prepare the sensitized device.

According to an embodiment of the present disclosure, a composition is disclosed, which includes:
a premix and a phosphorescent sensitizer, wherein the premix includes a first host compound, a second host compound, and a fluorescent compound;
the triplet energy level of the first host compound, the triplet energy level of the second host compound, and the triplet energy level of the phosphorescent sensitizer are higher than the triplet energy level of the fluorescent compound;
the first host compound has an evaporation temperature T1, wherein T1 ranges from 100° C. to 400° C.;
the second host compound has an evaporation temperature T2, wherein T2 ranges from 100° C. to 400° C.;
the absolute value of the difference between T1 and T2 is less than or equal to 20° C.

According to an embodiment of the present disclosure, the use of the composition in an organic electroluminescent device is disclosed.

According to an embodiment of the present disclosure, an organic electroluminescent device is disclosed, which includes:
an anode,
a cathode, and
an organic layer disposed between the anode and the cathode, wherein the organic layer includes the composition described in the above embodiments.

According to an embodiment of the present disclosure, a preparation method of an organic electroluminescent device is disclosed, wherein the organic electroluminescent device includes an anode, a cathode, and an organic layer disposed between the anode and the cathode, wherein the organic layer includes the composition described in the above embodiments, wherein the preparation method includes:
step 1: providing a substrate and disposing the anode thereon;
step 2: pre-mixing a first host compound, a second host compound, and a fluorescent compound to form a premix, and placing the premix in an evaporation source 1 in a high vacuum evaporation tool; placing a phosphorescent sensitizer in an evaporation source 2 in the high vacuum evaporation tool; in the high vacuum evaporation tool with a vacuum degree of 106 Torr or lower, co-evaporating the premix in the evaporation source 1 and the phosphorescent sensitizer in the evaporation source 2 at a rate of 0.2 angstroms (Å)/second(s) to 2 Å/s, and co-evaporating the premix in the evaporation source 1 and the phosphorescent sensitizer in the evaporation source 2 on a surface positioned at a certain distance away from the evaporated premix and the evaporated phosphorescent sensitizer to form the organic layer;
wherein the triplet energy level of the first host compound, the triplet energy level of the second host compound, and the triplet energy level of the phosphorescent sensitizer are higher than the triplet energy level of the fluorescent compound;
the first host compound has an evaporation temperature T1, wherein T1 ranges from 100° C. to 400° C.;
the second host compound has an evaporation temperature T2, wherein T2 ranges from 100° C. to 400° C.;
the absolute value of the difference between T1 and T2 is less than or equal to 20° C.; and
step 3: evaporating the cathode on the organic layer.

The present disclosure aims to provide a new premix and a composition including the premix. The new composition includes the premix and a phosphorescent sensitizer, and the premix includes a first host compound, a second host compound, and a fluorescent compound. The first host compound has an evaporation temperature T1, and the second host compound has an evaporation temperature T2. Both T1 and T2 range from 100° C. to 400° C., and the absolute value of the difference between T1 and T2 is less than or equal to 20° C. The premix of the present disclosure shows high evaporation stability and can obtain stable device performance when the premix is applied to continuous evaporation of an organic electroluminescent device. Meanwhile, the premix of the present disclosure can be used as a single evaporation source in the preparation process of a device, thereby reducing the cost and complexity of the evaporation process. Moreover, the composition of the present disclosure can be used in the emissive layer of a device, and compared with an ordinary device, can obtain more excellent device performance with a narrow full width at half maximum, high external quantum efficiency and/or a long device lifetime. In particular, when the fluorescent compound included in the premix of the present disclosure is an E-type delayed fluorescent compound, the premix shows high evaporation stability, can obtain stable device performance when the premix is applied to continuous evaporation of an organic electroluminescent device in industrial mass production, and has great potential application value in industrial mass production. Compared with an ordinary device, the premix can obtain more excellent device performance with a narrow full width at half maximum, high external quantum efficiency and/or a long device lifetime.

### BRIEF DESCRIPTION OF DRAWINGS

FIG. 1 is a schematic diagram of an organic light-emitting apparatus that may include an organic electroluminescent device disclosed herein.

FIG. 2 is a schematic diagram of another organic light-emitting apparatus that may include an organic electroluminescent device disclosed herein.

FIG. 3 is a schematic diagram of device emission spectra of Example 1, Comparative Example 1, and Comparative Example 2 after normalization treatment.

### DETAILED DESCRIPTION

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

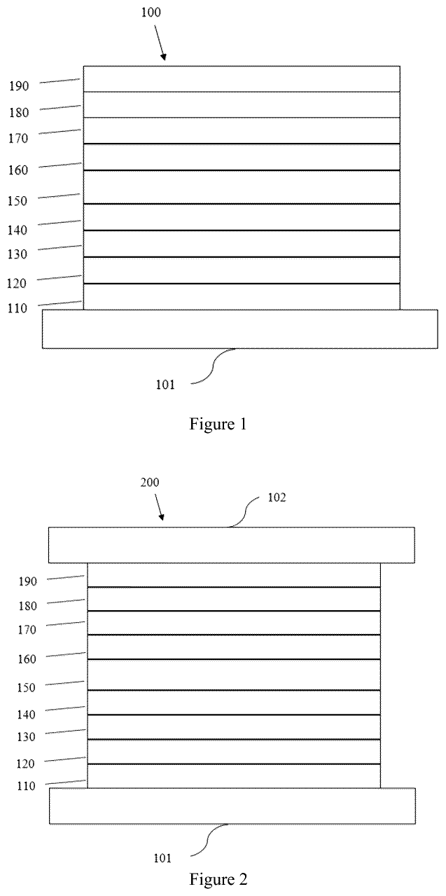

An OLED can be encapsulated by a barrier layer. FIG. 2 schematically shows an organic light emitting device 200 without limitation. FIG. 2 differs from FIG. 1 in that the organic light emitting device includes a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptatrienyl, cycloheptenyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

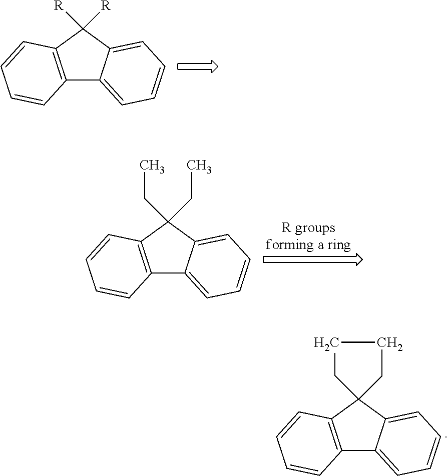

The expression that adjacent substituents can be optionally joined to form a ring is also intended to mean that two substituents bonded to carbon atoms which are directly bonded to each other are joined to each other via a chemical bond to form a ring, which can be exemplified by the following formula:

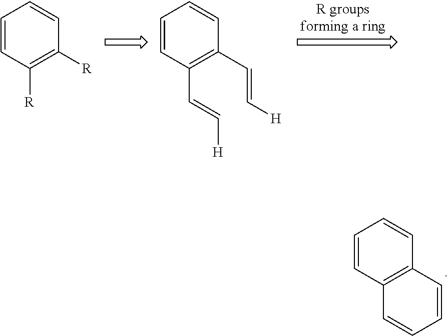

The expression that adjacent substituents can be optionally joined to form a ring is also intended to mean that two substituents bonded to further distant carbon atoms are joined to each other via a chemical bond to form a ring, which can be exemplified by the following formula:

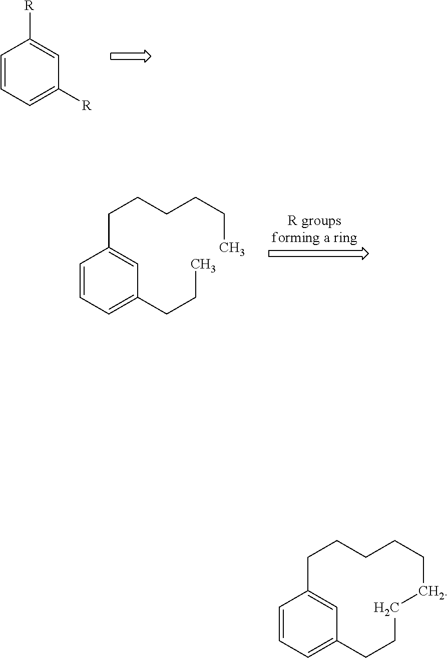

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

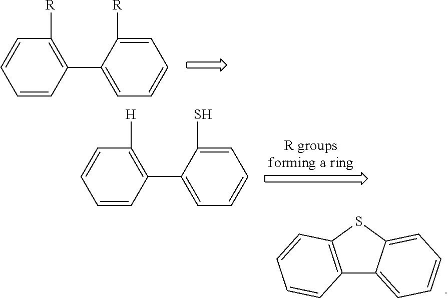

According to an embodiment of the present disclosure, a premix is disclosed, which includes a first host compound, a second host compound, and a fluorescent compound;
wherein the triplet energy level of the first host compound and the triplet energy level of the second host compound are higher than the triplet energy level of the fluorescent compound;
the first host compound has an evaporation temperature T1, wherein T1 ranges from 100° C. to 400° C.;
the second host compound has an evaporation temperature T2, wherein T2 ranges from 100° C. to 400° C.;
the absolute value of the difference between T1 and T2 is less than or equal to 20° C.

According to an embodiment of the present disclosure, a composition is disclosed, which includes:
a premix and a phosphorescent sensitizer, wherein the premix includes a first host compound, a second host compound, and a fluorescent compound;
the triplet energy level of the first host compound, the triplet energy level of the second host compound, and the triplet energy level of the phosphorescent sensitizer are higher than the triplet energy level of the fluorescent compound;
the first host compound has an evaporation temperature T1, wherein T1 ranges from 100° C. to 400° C.;
the second host compound has an evaporation temperature T2, wherein T2 ranges from 100° C. to 400° C.;
the absolute value of the difference between T1 and T2 is less than or equal to 20° C.

According to an embodiment of the present disclosure, T1 ranges from 150° C. to 350° C., and T2 ranges from 150° C. to 350° C.

According to an embodiment of the present disclosure, T1 ranges from 200° C. to 350° C., and T2 ranges from 200° C. to 350° C.

According to an embodiment of the present disclosure, the fluorescent compound has an evaporation temperature T3, wherein T3 ranges from 150° C. to 400° C.

According to an embodiment of the present disclosure, the fluorescent compound is a P-type delayed fluorescent compound.

According to an embodiment of the present disclosure, the fluorescent compound is an E-type delayed fluorescent compound.

According to an embodiment of the present disclosure, the fluorescent compound has an evaporation temperature T3, wherein T3 ranges from 150° C. to 350° C.

According to an embodiment of the present disclosure, the fluorescent compound has an evaporation temperature T3, wherein T3 ranges from 180° C. to 350° C.

According to an embodiment of the present disclosure, the absolute value of the difference between T1 and T2 is less than or equal to 10° C.

According to an embodiment of the present disclosure, the absolute value of the difference between T1 and T2 is less than or equal to 5° C.

According to an embodiment of the present disclosure, the absolute value of the difference between T3 and T1 or the absolute value of the difference between T3 and T2 is less than or equal to 80° C.

According to an embodiment of the present disclosure, the absolute value of the difference between T3 and T1 or the absolute value of the difference between T3 and T2 is less than or equal to 70° C.

According to an embodiment of the present disclosure, the absolute value of the difference between T3 and T1 or the absolute value of the difference between T3 and T2 is less than or equal to 60° C.

According to an embodiment of the present disclosure, the absolute value of the difference between T3 and T1 or the absolute value of the difference between T3 and T2 is less than or equal to 50° C.

According to an embodiment of the present disclosure, the absolute value of the difference between T3 and T1 or the absolute value of the difference between T3 and T2 is less than or equal to 40° C.

According to an embodiment of the present disclosure, the absolute value of the difference between T3 and T1 or the absolute value of the difference between T3 and T2 is less than or equal to 30° C.

According to an embodiment of the present disclosure, the absolute value of the difference between T3 and T1 or the absolute value of the difference between T3 and T2 is less than or equal to 20° C.

According to an embodiment of the present disclosure, the thermally activated delayed fluorescent compound (E-type delayed fluorescent compound) has a structure represented by Formula 1:

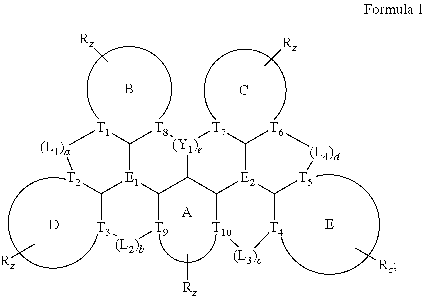

wherein in Formula 1,
the ring A, the ring B, the ring C, the ring D, and the ring E are each independently selected from an unsaturated carbocyclic ring having 5 to 30 carbon atoms or an unsaturated heterocyclic ring having 3 to 30 carbon atoms;
Y₁, E₁, and E₂ are each independently selected from B, N, P, P═S, As, As═O, As═S, SiR′ or GeR′;
T₁ to T₁₀ are each independently selected from C, CR_{z} or N;
L₁, L₂, L₃, and L₄ are, at each occurrence identically or differently, selected from a single bond, O, S, Se, BRᵥ or NRᵥ;
a, b, c, d, and e are each independently selected from 0 or 1;
R_{z} represents, at each occurrence identically or differently, mono-substitution, multiple substitutions or non-substitution;
Rᵥ, R_{z}, and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rᵥ, R_{z}, R′, and R″ can be optionally joined to form a ring.

In the present embodiment, “a, b, c, d, and e are each independently selected from 0 or 1” is intended to mean the presence or absence of L₁, L₂, L₃, L₄, and Y₁ corresponding to a, b, c, d, and e. For example, when a is 1, L₁ exists, and T1 and T2 are joined through L₁; when a is 0, L₁ does not exist, and T₁ is not joined to T₂; and when b, c, and d are each independently selected from 0 or 1, the situation is similar to the situation of a. When e is 1, Y₁ exists, and the ring A is joined to T₈ on the ring B and T₇ on the ring C through Y₁; when e is 0, Y₁ does not exist, and the ring A, the ring B, and the ring C are not joined.

Herein, “adjacent substituents Rᵥ, R_{z}, R′, and R″ can be optionally joined to form a ring” is intended to mean that any one or more of groups of adjacent substituents, such as two substituents R_{z}, two substituents R″, substituents R_{z} and Rᵥ, substituents R_{z} and R′, and substituents R_{z} and R″, can be joined to form a ring. Obviously, it is also possible that none of these groups of adjacent substituents are joined to form a ring.

Herein, an “unsaturated carbocyclic ring” includes an aromatic unsaturated carbocyclic ring (aromatic ring) and a non-aromatic unsaturated carbocyclic ring, and an “unsaturated heterocyclic ring” includes an aromatic unsaturated heterocyclic ring (heteroaromatic ring) and a non-aromatic unsaturated heterocyclic ring.

According to an embodiment of the present disclosure, the ring A, the ring B, the ring C, the ring D, and the ring E are each independently selected from a five-membered unsaturated carbocyclic ring, an aromatic ring having 6 to 30 carbon atoms or a heteroaromatic ring having 3 to 30 carbon atoms.

According to an embodiment of the present disclosure, the ring A, the ring B, the ring C, the ring D, and the ring E are each independently selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadiene ring, a furan ring, a thiophene ring or a silole ring.

According to an embodiment of the present disclosure, the ring A, the ring B, the ring C, the ring D, and the ring E are selected from a benzene ring.

According to an embodiment of the present disclosure, in Formula 1, e is 1, Y₁ is each independently selected from B, P═O or P═S, and E₁ and E₂ are each independently selected from N or P.

According to an embodiment of the present disclosure, in Formula 1, e is 1, Y₁ is selected from B, and E₁ and E₂ are selected from N.

According to an embodiment of the present disclosure, in Formula 1, e is 1, a is 0, b is 0, c is 0, and d is 0.

According to an embodiment of the present disclosure, in Formula 1, e is 1, a is 1, b is 0, c is 0, and d is 1.

According to an embodiment of the present disclosure, in Formula 1, e is 1, a is 0, b is 1, c is 0, and d is 1.

According to an embodiment of the present disclosure, in Formula 1, e is 0, and E₁ and E₂ are each independently selected from B or N.

According to an embodiment of the present disclosure, in Formula 1, e is 0, and E₁ and E₂ are selected from B.

According to an embodiment of the present disclosure, in Formula 1, e is 0, a is 1, b is 1, c is 1, and d is 1.

According to an embodiment of the present disclosure, the thermally activated delayed fluorescent compound has a structure represented by one of Formula 1-1 to Formula 1-4:

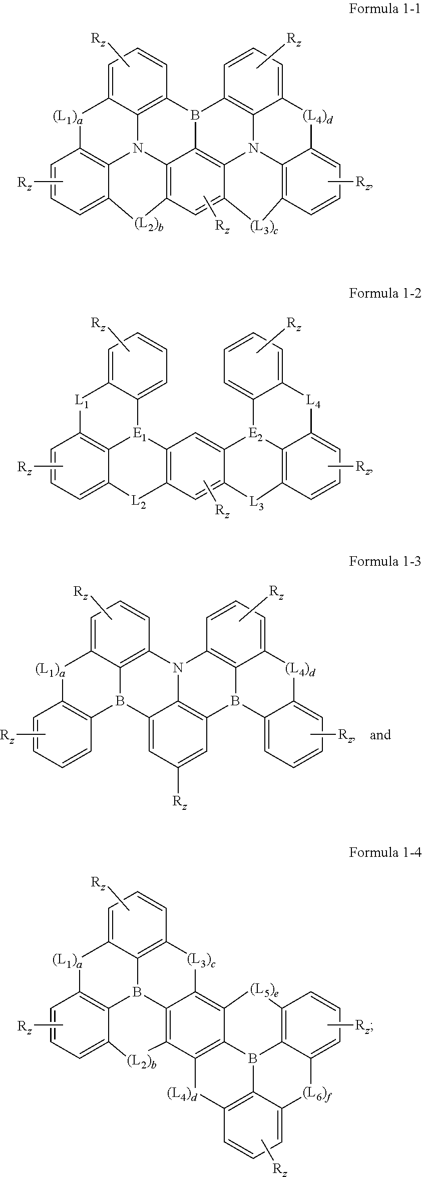

wherein
a, b, c, d, e, and f are each independently selected from 0 or 1;
E₁ and E₂ are each independently selected from B or N;
L₁, L₂, L₃, and L₄ are, at each occurrence identically or differently, selected from a single bond, O, S, BRᵥ or NRᵥ;
L₅ and L₆ are, at each occurrence identically or differently, selected from a single bond, O, S or NRᵥ;
R_{z} represents, at each occurrence identically or differently, mono-substitution, multiple substitutions or non-substitution;
Rᵥ and R_{z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rᵥ, R_{z}, and R″ can be optionally joined to form a ring.

Herein, “adjacent substituents Rᵥ, R_{z}, and R″ can be optionally joined to form a ring” is intended to mean that on the same ring, two adjacent substituents R_{z} can be joined to form an unsaturated carbocyclic ring or an unsaturated heterocyclic ring including one or more of O, S, Se, Si, Ge or P, two substituents R″ can be joined to form a ring, substituents R_{z} and Rᵥ can be joined to form a ring, and substituents R_{z} and R″ can be joined to form a ring. Obviously, on the same ring, two adjacent substituents R_{z} may not be joined to form a ring, two substituents R″ may not be joined to form a ring, substituents R_{z} and Rᵥ may not be joined to form a ring, and substituents R_{z} and R″ may not be joined to form a ring.

According to an embodiment of the present disclosure, in Formula 1-1, a is 0, b is 0, c is 0, and d is 0.

According to an embodiment of the present disclosure, in Formula 1-1, a+b+c+d is greater than or equal to 1.

According to an embodiment of the present disclosure, in Formula 1-1, a is 1, b is 0, c is 0, and d is 1.

According to an embodiment of the present disclosure, in Formula 1-1, a is 0, b is 1, c is 0, and d is 1.

According to an embodiment of the present disclosure, in Formula 1, Formula 1-1, and Formula 1-2, L₁, L₂, L₃, and L₄ are, at each occurrence identically or differently, selected from a single bond, O, BRᵥ or NRᵥ.

According to an embodiment of the present disclosure, in Formula 1-1, L₁, L₂, L₃, and L₄ are selected from a single bond.

According to an embodiment of the present disclosure, in Formula 1-2, L₁, L₂, L₃, and L₄ are, at each occurrence identically or differently, selected from O or NRᵥ.

According to an embodiment of the present disclosure, in Formula 1-2, E₁ and E₂ are each independently selected from B.

According to an embodiment of the present disclosure, in Formula 1-3, a is 1, and b is 1.

According to an embodiment of the present disclosure, in Formula 1-3, L₁ and L₄ are, at each occurrence identically or differently, selected from NRᵥ.

According to an embodiment of the present disclosure, in Formula 1-4, a is 1, b is 1, c is 0, d is 0, e is 1, and f is 1.

According to an embodiment of the present disclosure, in Formula 1-4, a is 0, b is 1, c is 1, d is 1, e is 1, and f is 0.

According to an embodiment of the present disclosure, in Formula 1-4, L₁, L₂, L₃, L₄, L₅, and L₆ are, at each occurrence identically or differently, selected from a single bond, O or NRᵥ.

According to an embodiment of the present disclosure, the thermally activated delayed fluorescent compound has a structure represented by Formula 1-1-1, Formula 1-1-2, Formula 1-1-3, Formula 1-1-4, Formula 1-1-5, Formula 1-1-6 or Formula 1-1-7:

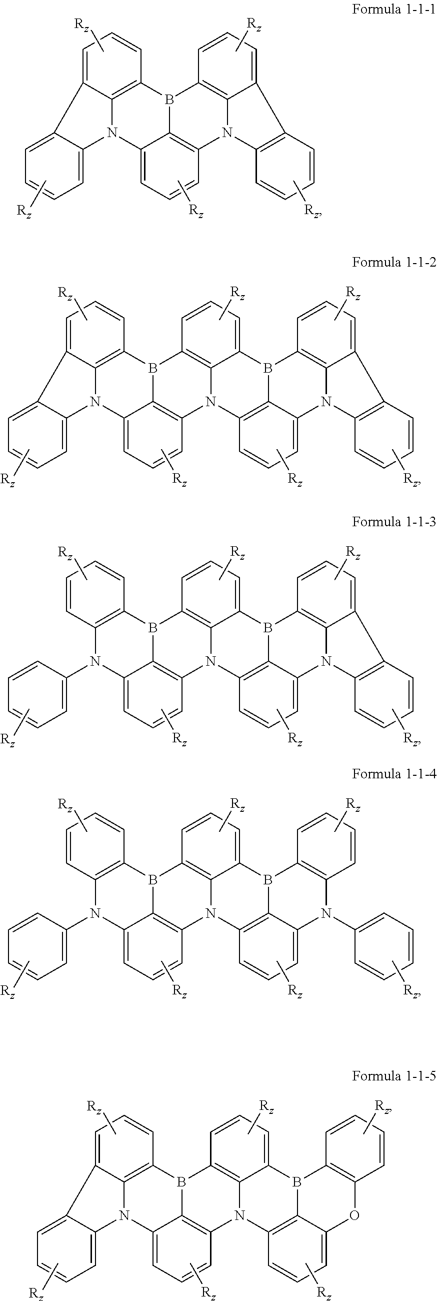

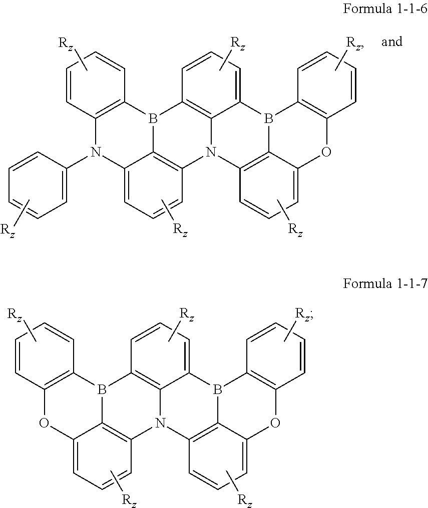

wherein R_{z} represents, at each occurrence identically or differently, mono-substitution, multiple substitutions or non-substitution;
R_{z} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{z} can be optionally joined to form a ring.

According to an embodiment of the present disclosure, R_{z} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, and combinations thereof.

According to an embodiment of the present disclosure, R_{z} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, a cyano group, and combinations thereof.

According to an embodiment of the present disclosure, R_{z} is, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, deuterated t-butyl, cyclopentyl, cyclohexyl, phenyl, trimethylsilyl, carbazolyl, indolyl, benzofuryl, dibenzofuryl, benzosilolyl, dibenzosilolyl, benzothienyl, dibenzothienyl, dibenzoselenophenyl, and combinations thereof.

According to an embodiment of the present disclosure, multiple R_{z} are present in the thermally activated delayed fluorescent compound, and at least one (for example, one, two, three or four) of the multiple R_{z} is selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, and combinations thereof.

According to an embodiment of the present disclosure, the substituent R_{z} on the ring A, the ring B, the ring C, the ring D, and the ring E is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, and combinations thereof.

According to an embodiment of the present disclosure, the fluorescent compound is selected from the group consisting of Compound BN-BD-1 to Compound BN-BD-53, Compound BN-RD-1 to Compound BN-RD-22, Compound BN-GD-1 to Compound BN-GD-63, and Compound FD-1-1 to Compound FD-1-53, wherein the specific structures of Compound BN-BD-1 to Compound BN-BD-53, Compound BN-RD-1 to Compound BN-RD-22, Compound BN-GD-1 to Compound BN-GD-51, Compound BN-GD-53 to Compound BN-GD-63, and Compound FD-1-1 to Compound FD-1-53 are referred to claim 9.

According to an embodiment of the present disclosure, hydrogens in Compound BN-BD-1 to Compound BN-BD-53, Compound BN-RD-1 to Compound BN-RD-22, Compound BN-GD-1 to Compound BN-GD-51, Compound BN-GD-53 to Compound BN-GD-63, and Compound FD-1-1 to Compound FD-1-53 can be partially or fully substituted with deuterium.

According to an embodiment of the present disclosure, the maximum emission wavelength λ_{max-PL} of a photoluminescence spectrum of the fluorescent compound ranges from 450 nm to 500 nm.

According to an embodiment of the present disclosure, the maximum emission wavelength λ_{max-PL} of the photoluminescence spectrum of the fluorescent compound ranges from 450 nm to 470 nm.

According to an embodiment of the present disclosure, the maximum emission wavelength Amax-PL of the photoluminescence spectrum of the fluorescent compound ranges from 455 nm to 465 nm.

According to an embodiment of the present disclosure, the maximum emission wavelength λ_{max-PL} of the photoluminescence spectrum of the fluorescent compound ranges from 520 nm to 650 nm.

According to an embodiment of the present disclosure, the maximum emission wavelength λ_{max-PL} of the photoluminescence spectrum of the fluorescent compound ranges from 520 nm to 630 nm.

According to an embodiment of the present disclosure, the maximum emission wavelength λ_{max-PL} of the photoluminescence spectrum of the fluorescent compound ranges from 520 nm to 580 nm.

According to an embodiment of the present disclosure, the full width at half maximum FWHM-_{PL} of the photoluminescence spectrum of the fluorescent compound is less than or equal to 45 nm.

According to an embodiment of the present disclosure, the full width at half maximum FWHM-_{PL} of the photoluminescence spectrum of the fluorescent compound is less than or equal to 35 nm.

According to an embodiment of the present disclosure, the full width at half maximum FWHM-_{PL} of the photoluminescence spectrum of the fluorescent compound is less than or equal to 30 nm.

According to an embodiment of the present disclosure, the full width at half maximum FWHM-_{PL} of the photoluminescence spectrum of the fluorescent compound is less than or equal to 25 nm.

According to an embodiment of the present disclosure, the full width at half maximum FWHM-_{PL} of the photoluminescence spectrum of the fluorescent compound is less than or equal to 20 nm.

According to an embodiment of the present disclosure, the absolute value of the difference between the triplet energy level of the phosphorescent sensitizer and the triplet energy level of the fluorescent compound is less than or equal to 20 nm.

In the present disclosure, the maximum emission wavelength λ_{max-PL} and the full width at half maximum FWHM-_{PL} of the photoluminescence spectrum are measured in the following method.

The photoluminescence (PL) spectrum data of a compound to be measured were measured using a fluorescence spectrophotometer F98 produced by SHANGHAI LENGGUANG TECHNOLOGY CO., LTD. The compound to be measured was dissolved in a toluene solvent to prepare a solution with a concentration of 1×10⁻⁶ mol/L, nitrogen was introduced into the prepared solution to be measured to remove oxygen for 5 minutes, and the solution to be measured was loaded into a quartz sample tube and excited at room temperature (298 K) by light with the maximum absorption wavelength of the compound to be measured to measure the emission spectrum of the compound to be measured. The emission spectrum has a maximum emission wavelength λ_{max-PL} and a full width at half maximum FWHM-PL (that is, a peak width at half the maximum emission peak height, the distance between two points where a straight line parallel to the horizontal axis through the middle point of the peak height intersects both sides of the peak).

For example, maximum emission wavelengths λ_{max-PL} and full widths at half maximum FWHM-PL of the photoluminescence spectra of the following thermally activated delayed fluorescent compounds were measured by the above method, and the specific results are shown in Table 1.

TABLE 1
Maximum emission wavelengths and full widths at half
maximum of the photoluminescence spectra of compounds

| Compound ID | λ_{max-PL} (nm) | FWHM-_{PL} (nm) |
|---|---|---|
| BN-BD-1 | 453 | 25.8 |
| BN-BD-2 | 459 | 25.3 |
| BN-BD-20 | 465 | 24.4 |
| BN-BD-34 | 460 | 27.4 |
| BN-GD-12 | 545 | 30.31 |

### Measurement of Triplet Energy Levels

Herein, the triplet energy levels (T₁) of the first host compound, the second host compound, the fluorescent compound, and a blue phosphorescent sensitizer were measured at an ultra-low temperature using the properties of long-lived triplet excitons. Specifically, a compound to be measured was dissolved in a 2-methyltetrahydrofuran solvent to prepare a solution with a concentration of 10⁻⁵ M, the solution was loaded into a quartz tube, placed in a Dewar flask and cooled to 77 K, and the solution of the compound to be measured was irradiated by a light source with the maximum absorption wavelength of the compound to be measured to measure a phosphorescence spectrum. The spectrum was measured using a spectrophotometer F98 produced by SHANGHAI LENGGUANG TECHNOLOGY CO., LTD.

In the phosphorescence spectrum, the longitudinal axis represents a phosphorescence intensity, and the horizontal axis represents a wavelength. The minimum value λ₁ (nm) of a peak on the shorter wavelength side of the phosphorescence spectrum was taken, and the wavelength value was substituted into the following conversion formula F1 to calculate the triplet energy of the compound to be measured.

The conversion formula F₁ is as follows: T₁ (eV)=1240/λ₁.

Herein, the triplet energy levels (T₁) of a red phosphorescent sensitizer and a green phosphorescent sensitizer were measured in the following method. A compound to be measured was dissolved in a toluene solvent to prepare a solution with a concentration of 1×10⁻⁶ mol/L, nitrogen was introduced into the prepared solution to be measured to remove oxygen for 5 minutes, and the solution to be measured was loaded into a quartz sample tube and excited at room temperature (298 K) by light with the maximum absorption wavelength of the compound to be measured to measure the emission spectrum of the compound to be measured. The spectrum was measured using a spectrophotometer F98 produced by SHANGHAI LENGGUANG TECHNOLOGY CO., LTD. The maximum emission wavelength λₘₐₓ (nm) of the measured spectrum is substituted into the above conversion formula F₁ to calculate the triplet energy of the compound to be measured.

The triplet energy levels T₁ (eV) of the following compounds were measured through the above method, and the specific results are shown in Table 2-1 and Table 2-2.

TABLE 2-1
Triplet energy levels of compounds

| Compound ID | T₁ (eV) |
|---|---|
| P-22 | 2.96 |
| N-1-15 | 2.89 |
| Pt27 | 2.70 |
| Pt11 | 2.69 |
| BN-BD-1 | 2.66 |
| BN-BD-2 | 2.49 |
| BN-BD-20 | 2.46 |
| BN-BD-34 | 2.62 |

As can be seen from the above results in Table 2-1, for a blue light material, the triplet energy levels of the first host compound, the second host compound, and the phosphorescent sensitizer are all higher than the triplet energy level of the fluorescent compound, so the first host compound, the second host compound, the phosphorescent sensitizer, and the fluorescent compound can be well matched to achieve the luminescence of the fluorescent compound.

TABLE 2-2
Triplet energy levels of compounds

| Compound ID | T₁ (eV) |
|---|---|
| PH-24 | 2.70 |
| NH-144 | 2.53 |
| PH-1 | 2.71 |
| NH-45 | 2.60 |
| PH-51 | 2.70 |
| NH-147 | 2.54 |
| GD100 | 2.34 |
| BN-GD-12 | 2.30 |

As can be seen from the above results in Table 2-2, for a green light material, the triplet energy levels of the first host compound, the second host compound, and the phosphorescent sensitizer are all higher than the triplet energy level of the fluorescent compound, so the first host compound, the second host compound, the phosphorescent sensitizer, and the fluorescent compound can be well matched to achieve the luminescence of the fluorescent compound.

According to an embodiment of the present disclosure, the phosphorescent sensitizer has a general formula of M(Lₐ)ₘ(L_{b})ₙ(L_{c})_{q};
wherein M is selected from a metal with a relative atomic mass greater than 40; preferably, the metal M is selected from the group consisting of Cu, Ag, Au, Zn, Ru, Rh, Pd, Os, Ir, and Pt;
the ligands Lₐ, L_{b}, and L_{c} are a first ligand, a second ligand, and a third ligand coordinated to the metal M, respectively, and the ligands Lₐ, L_{b}, and L_{c} may be the same or different;
the ligands Lₐ, L_{b}, and L_{c} can be optionally joined to form a multidentate ligand; for example, any two of Lₐ, L_{b}, and L_{c} may be joined to form a tetradentate ligand; in another example, Lₐ, L_{b}, and L_{c} may be joined to each other to form a hexadentate ligand; in another example, none of Lₐ, L_{b}, and L_{c} are joined so that no multidentate ligand is formed;
m is 1, 2 or 3; n is 0, 1 or 2; q is 0, 1 or 2; the sum of m, n, and q is equal to an oxidation state of the metal M; when m is greater than or equal to 2, multiple Lₐ may be the same or different; when n is 2, two L_{b} may be the same or different; when q is 2, two L_{c} may be the same or different;
the ligand Lₐ has a structure represented by Formula 2:

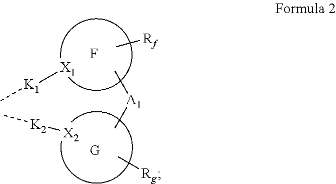

wherein the ring F and the ring G are each independently selected from an unsaturated carbocyclic ring having 5 to 30 carbon atoms, an unsaturated heterocyclic ring having 1 to 30 carbon atoms or a combination thereof;
X₁ and X₂ are, at each occurrence identically or differently, selected from C or N;
K₁ and K₂ are each independently selected from a single bond, O or S;
A₁ is selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof; y is, at each occurrence identically or differently, selected from 1, 2, 3, 4 or 5;
R_{f} and R_{g} represent, at each occurrence identically or differently, mono-substitution, multiple substitutions or non-substitution;
R_{f} and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{f} and R_{g} can be optionally joined to form a ring;
the ligands L_{b} and L_{c} are, at each occurrence identically or differently, selected from a monoanionic bidentate ligand.

In the present embodiment, “adjacent substituents R_{f} and R_{g} can be optionally joined to form a ring” is intended to mean that any one or more of groups of adjacent substituents, such as two substituents R_{f}, two substituents R_{g}, and R_{f} and R_{g}, can be joined to form a ring. Obviously, it is also possible that none of these groups of adjacent substituents are joined to form a ring.

According to an embodiment of the present disclosure, L_{b} and L_{c} are, at each occurrence identically or differently, selected from the group consisting of the following structures:

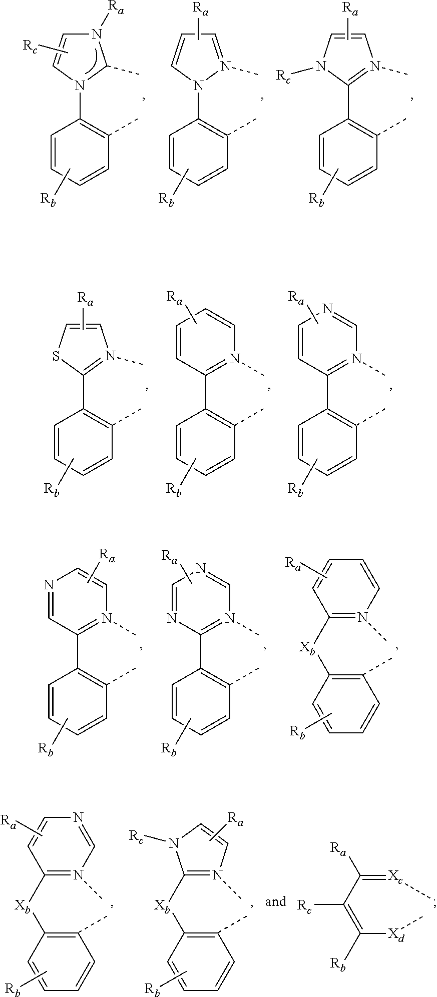

wherein
Rₐ and R_{b} represent, at each occurrence identically or differently, mono-substitution, multiple substitutions or non-substitution;
X_{b} is, at each occurrence identically or differently, selected from the group consisting of O, S, Se, NR_{N1}, and CR_{C1}R_{C2};
X_{c} and X_{d} are, at each occurrence identically or differently, selected from the group consisting of O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ, R_{b}, R_{c}, R_{N1}, R_{N2}, R_{C1}, and R_{C2} can be optionally joined to form a ring.

In the present embodiment, “adjacent substituents Rₐ, R_{b}, R_{c}, R_{N1}, R_{N2}, R_{C1}, and R_{C2} can be optionally joined to form a ring” is intended to mean that any one or more of groups of adjacent substituents, such as two substituents Rₐ, two substituents R_{b}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents Rp and R_{C2}, substituents R_{C1} and R_{C2}, substituents Rₐ and R_{N2}, and substituents R_{b} and R_{N2}, can be joined to form a ring. For example, adjacent substituents Rₐ and R_{b} in

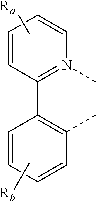

can optionally be joined to form a ring, which can form one or more of the following structures, including, but not limited to:

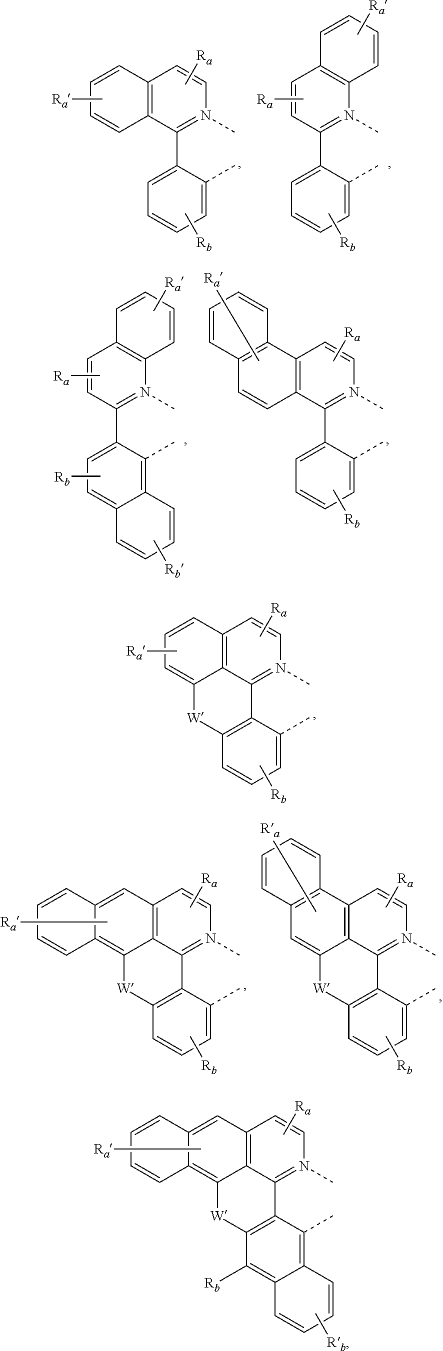

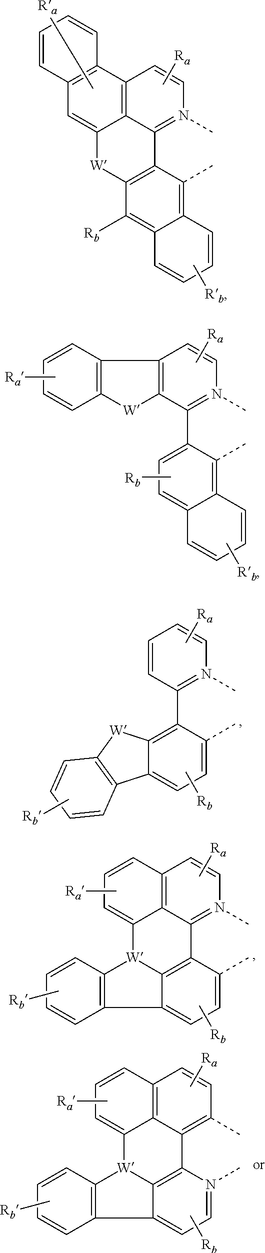

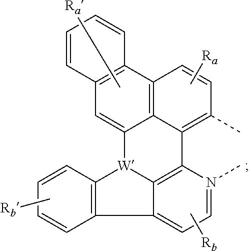

wherein W′ is selected from O,

S, Se, NR_{w}′ or CR_{w}′R_{w}′, and R_{w}′, Rₐ′, and R_{b}′ are defined the same as Rₐ. Obviously, it is also possible that none of these groups of adjacent substituents are joined to form a ring.

According to an embodiment of the present disclosure, the ligand Lₐ has a structure represented by Formula 2-1 or Formula 2-2:

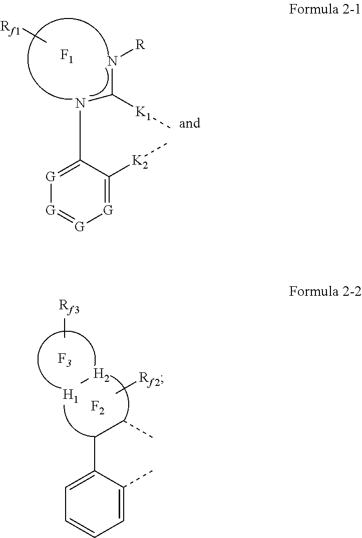

wherein in Formula 2-1, the ring F1 is selected from an unsaturated heterocyclic ring having 1 to 30 carbon atoms;
in Formula 2-2, the ring F2 and the ring F3 are each independently selected from an unsaturated carbocyclic ring having 5 to 30 carbon atoms, an unsaturated heterocyclic ring having 3 to 30 carbon atoms or a combination thereof;
the ring F2 and the ring F3 are fused via H₁ and H₂;
X₁ and X₂ are each independently selected from C or N, and X₁ is different from X₂; H₁ and H₂ are, at each occurrence identically or differently, selected from C or N;
K₁ and K₂ are each independently selected from a single bond, O or S;
G is, at each occurrence identically or differently, selected from CR_{g} or N;
R_{f1}, R_{f2}, and R_{f3} represent, at each occurrence identically or differently, mono-substitution, multiple substitutions or non-substitution;
R, R_{g}, R_{f1}, R_{f2}, and R_{f3} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
adjacent substituents R, R_{g}, R_{f1}, R_{f2}, and R_{f3} can be optionally joined to form a ring.

In the present embodiment, “adjacent substituents R, R_{g}, R_{f1}, R_{f2}, and R_{f3} can be optionally joined to form a ring” is intended to mean that any one or more of groups of adjacent substituents, such as two substituents R_{g}, two substituents R_{f1}, two substituents R_{f2}, two substituents R_{f3}, substituents R and R_{f1}, and substituents R_{f2} and R_{f3}, can be joined to form a ring. Obviously, it is also possible that none of these groups of adjacent substituents are joined to form a ring.

According to an embodiment of the present disclosure, the phosphorescent sensitizer has a structure represented by Formula 21:

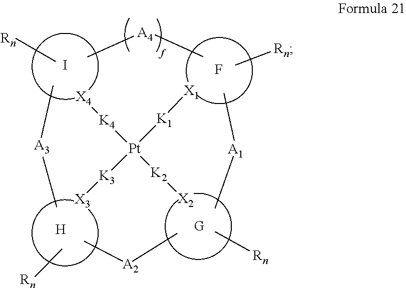

wherein in Formula 21,
the ring F, the ring G, the ring H, and the ring I are each independently selected from an unsaturated carbocyclic ring having 5 to 30 carbon atoms, an unsaturated heterocyclic ring having 1 to 30 carbon atoms or a combination thereof;
f is selected from 0 or 1;
A₁ to A₄ are, at each occurrence identically or differently, selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof; y is, at each occurrence identically or differently, selected from 1, 2, 3, 4 or 5;
X₁ to X₄ are each independently selected from C or N;
K₁ to K₄ are each independently selected from a single bond, O or S;
Rₙ represents, at each occurrence identically or differently, mono-substitution, multiple substitutions or non-substitution;
R_{q} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{q} and Rₙ can be optionally joined to form a ring.

In the present embodiment, “adjacent substituents R_{q} and Rₙ can be optionally joined to form a ring” is intended to mean that any one or more of groups of adjacent substituents, such as two substituents R_{q}, two substituents Rₙ, and substituents R_{q} and Rₙ, can be joined to form a ring. Obviously, it is also possible that none of these groups of adjacent substituents are joined to form a ring.

According to an embodiment of the present disclosure, the phosphorescent sensitizer has a structure represented by Formula 21-1:

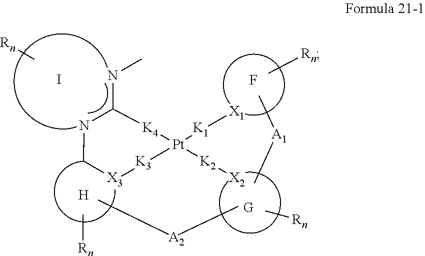

wherein in Formula 21-1,
the ring F, the ring G, and the ring H are each independently selected from an unsaturated carbocyclic ring having 5 to 30 carbon atoms, an unsaturated heterocyclic ring having 3 to 30 carbon atoms or a combination thereof; the ring I is selected from an unsaturated heterocyclic ring having 1 to 30 carbon atoms;
A₁ and A₂ are each independently selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof; y is, at each occurrence identically or differently, selected from 1, 2, 3, 4 or 5;
K₁ to K₄ are each independently selected from a single bond, O or S;
X₁ to X₃ are each independently selected from C or N;
Rₙ represents, at each occurrence identically or differently, mono-substitution, multiple substitutions or non-substitution;
R, R_{q}, and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R, R_{q}, and Rₙ can be optionally joined to form a ring.

In the present embodiment, “adjacent substituents R, R_{q}, and Rₙ can be optionally joined to form a ring” is intended to mean that any one or more of groups of adjacent substituents, such as two substituents R_{q}, two substituents Rₙ, substituents R_{q} and Rₙ, and substituents R and Rₙ, can be joined to form a ring. Obviously, it is also possible that none of these groups of adjacent substituents are joined to form a ring.

According to an embodiment of the present disclosure, in Formula 21 or Formula 21-1, the ring F, the ring G, and the ring H are each independently selected from a five-membered unsaturated carbocyclic ring, an aromatic ring having 6 to 30 carbon atoms or a heteroaromatic ring having 3 to 30 carbon atoms; the ring I is, at each occurrence identically or differently, selected from an unsaturated heterocyclic ring having 3 to 30 carbon atoms.

According to an embodiment of the present disclosure, in Formula 21 or Formula 21-1, the ring F, the ring G, and the ring H are each independently selected from a five-membered unsaturated carbocyclic ring, an aromatic ring having 6 to 18 carbon atoms or a heteroaromatic ring having 3 to 18 carbon atoms; the ring I is, at each occurrence identically or differently, selected from an unsaturated heterocyclic ring having 3 to 18 carbon atoms.

According to an embodiment of the present disclosure, in Formula 21 or Formula 21-1, the ring F, the ring G, and the ring H are each independently selected from a benzene ring, a pyridine ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadiene ring, a furan ring, a thiophene ring or a silole ring; the ring I is, at each occurrence identically or differently, selected from an imidazolecarbene ring or a benzimidazolecarbene ring.

According to an embodiment of the present disclosure, K₁ to K₄ ar selected from a single bond.

According to an embodiment of the present disclosure, the phosphorescent sensitizer has a structure represented by one of Formula 3-1 to Formula 3-24:

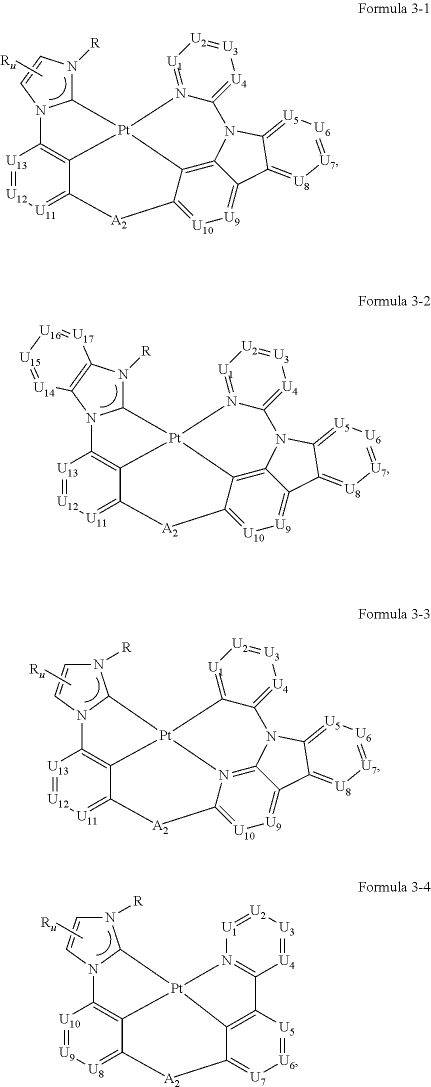

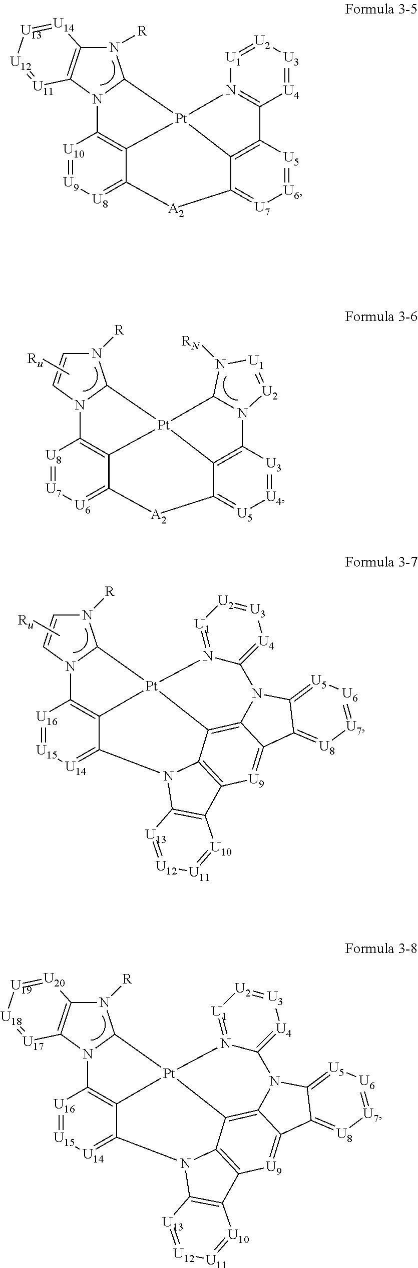

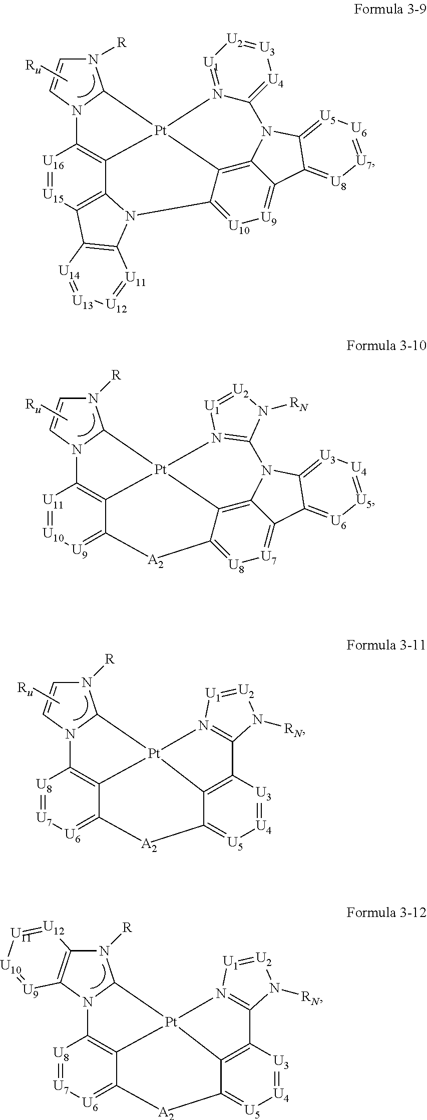

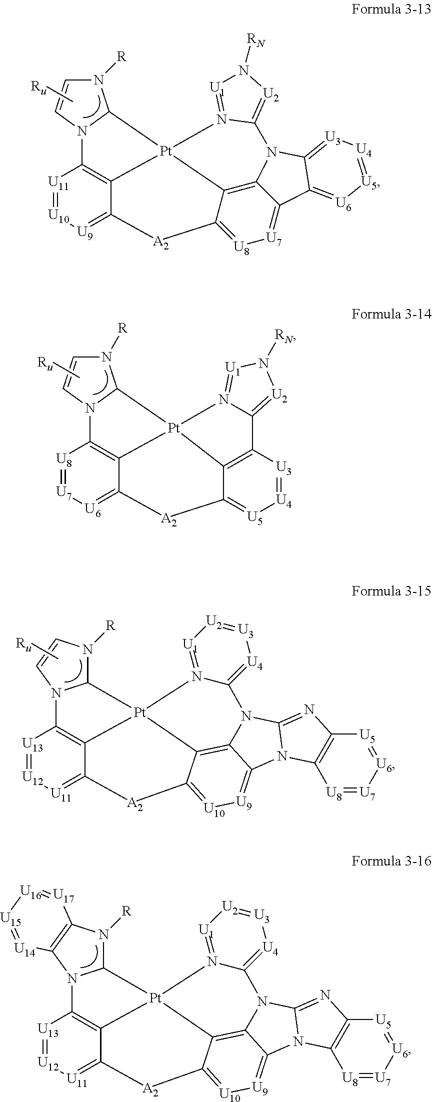

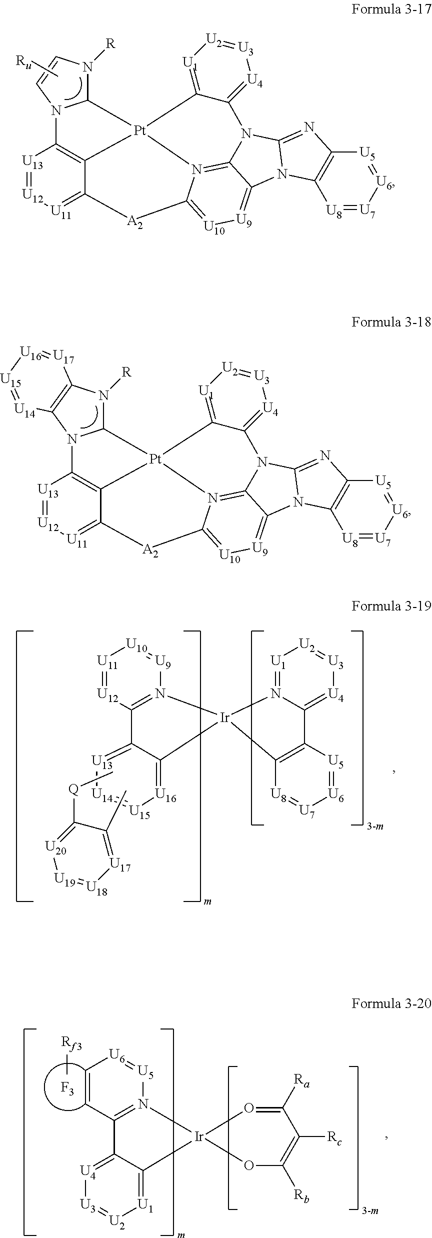

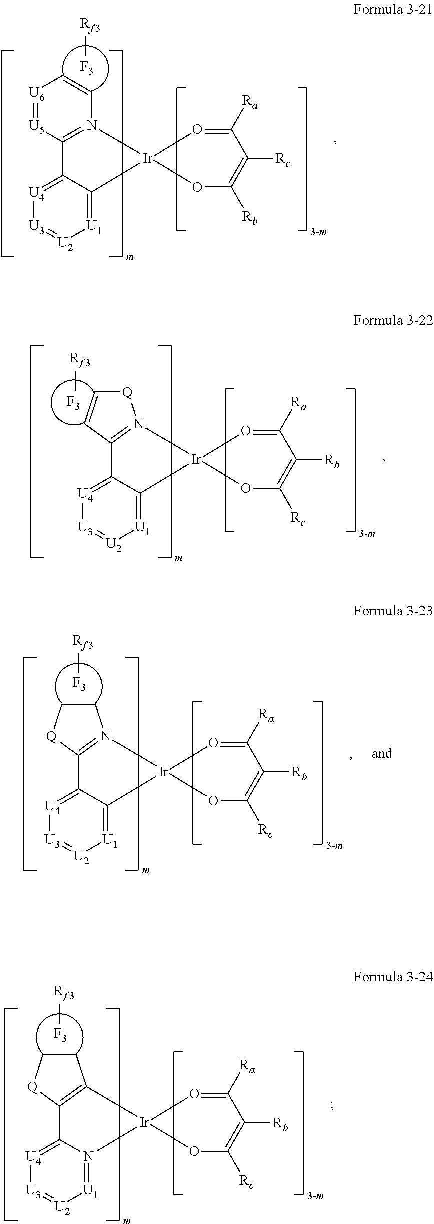

wherein
A₂ is, at each occurrence identically or differently, selected from a single bond, O, S, Se, (SiR_{q}R_{q})_{y}, PR_{q}, NR_{q}, substituted or unsubstituted arylene having 6 to 30 carbon atoms, substituted or unsubstituted heteroarylene having 3 to 30 carbon atoms or a combination thereof; y is, at each occurrence identically or differently, selected from 1, 2 or 3;
U₁ to U₂₀ are, at each occurrence identically or differently, selected from CRₙ or N;
the ring F3 is, at each occurrence identically or differently, selected from an unsaturated carbocyclic ring having 5 to 30 carbon atoms, an unsaturated heterocyclic ring having 3 to 30 carbon atoms or a combination thereof;
Q is, at each occurrence identically or differently, selected from O, S or Se;
m is, at each occurrence identically or differently, selected from 0, 1, 2 or 3;
Rᵤ and R_{f3} represent, at each occurrence identically or differently, mono-substitution, multiple substitutions or non-substitution;
R, R_{N}, R_{q}, Rᵤ, Rₙ, R_{f3}, Rₐ, R_{b}, and R_{c} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R, R_{N}, R_{q}, Rᵤ, Rₙ, and R_{f3} can be optionally joined to form a ring.

In the present embodiment, “adjacent substituents R, R_{N}, R_{q}, Rᵤ, Rₙ, and R_{f3} can be optionally joined to form a ring” is intended to mean that any one or more of groups of adjacent substituents, such as two substituents R_{q}, two substituents Rᵤ, two substituents Rₙ, two substituents R_{f3}, substituents R and Rᵤ, substituents R and Rₙ, substituents R_{N} and Rₙ, substituents R_{f3} and Rₙ, and substituents R_{q} and Rₙ, can be joined to form a ring. Obviously, it is also possible that none of these groups of adjacent substituents are joined to form a ring.

According to an embodiment of the present disclosure, the phosphorescent sensitizer has a structure represented by Formula 3-1 or Formula 3-2.

According to an embodiment of the present disclosure, A₂ is selected from a single bond, O or S.

According to an embodiment of the present disclosure, A₂ is selected from O.

According to an embodiment of the present disclosure, U₁ to U₂₀ are, at each occurrence identically or differently, selected from CRₙ, and Rₙ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, Rₙ is, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, cyclopentyl, cyclohexyl, phenyl, trimethylsilyl, carbazolyl, indolyl, benzofuryl, dibenzofuryl, benzosilolyl, dibenzosilolyl, benzothienyl, dibenzothienyl, dibenzoselenophenyl, and combinations thereof.

According to an embodiment of the present disclosure, the substituent R has a structure represented by Formula 4:

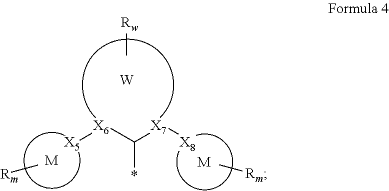

wherein in Formula 4,
the ring M and the ring W are, at each occurrence identically or differently, selected from an unsaturated carbocyclic ring having 5 to 30 carbon atoms, an unsaturated heterocyclic ring having 3 to 30 carbon atoms or a combination thereof,
X₅ to X₈ are, at each occurrence identically or differently, selected from C or N;
“*” represents a position where Formula 4 is joined;
Rₘ represents, at each occurrence identically or differently, mono-substitution, multiple substitutions or non-substitution;
R_{w} represents, at each occurrence identically or differently, mono-substitution or multiple substitutions;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₘ and R_{w} can be optionally joined to form a ring.

Herein, “adjacent substituents Rₘ and R_{w} can be optionally joined to form a ring” is intended to mean that any one or more of groups of adjacent substituents, such as two substituents Rₘ, two substituents R_{w}, and substituents Rₘ and R_{w}, can be joined to form a ring. Obviously, it is also possible that none of these groups of adjacent substituents are joined to form a ring.

According to an embodiment of the present disclosure, the substituent R has a structure represented by Formula 4-1:

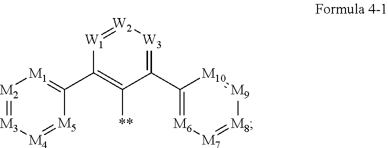

wherein in Formula 4-1,
M₁ to M₁₀ are each independently selected from CRₘ or N;
W₁ to W₃ are each independently selected from CR_{w} or N;
“**” represents a position where Formula 4-1 is joined;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₘ and R_{w} can be optionally joined to form a ring.

According to an embodiment of the present disclosure, at least one R_{w} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, M₁ to M₁₀ are each independently selected from CRₘ.

According to an embodiment of the present disclosure, W₁ to W₃ are each independently selected from CR_{w}.

According to an embodiment of the present disclosure, Rₘ and R_{w} are, at each occurrence identically or differently, selected from the group consisting of: hydrogen, deuterium, halogen, a cyano group, a hydroxyl group, a sulfanyl group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, M₁ to M₁₀ are selected from CH or CD.

According to an embodiment of the present disclosure, W₂ is selected from CR_{w}, and R_{w} is selected from the group consisting of: deuterium, halogen, a cyano group, a hydroxyl group, a sulfanyl group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, the phosphorescent sensitizer has a structure represented by a general formula of Pt(Lₐ) (L_{b}), wherein Lₐ and L_{b} are a first ligand and a second ligand coordinated to the metal Pt, respectively. For example, for

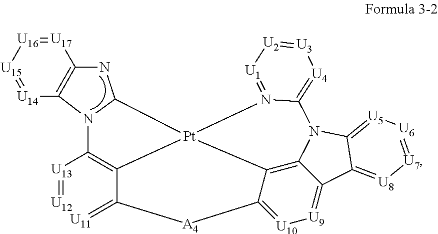

Lₐ has a structure represented by Formula A:

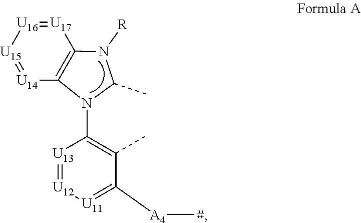

wherein “#” in Formula A represents a position joined to L_{b}; and L_{b} has a structure represented by Formula B:

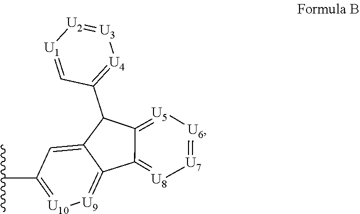

wherein “ [symbol] ” in Formula B represents a position joined to Lₐ.

According to an embodiment of the present disclosure, the phosphorescent sensitizer has a general structure of Ir(Lₐ)ₘ(L_{b})₃₋ₘ and has a structure represented by Formula M-a:

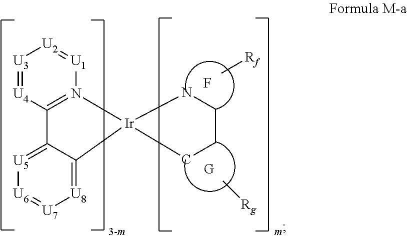

wherein
m is selected from 1, 2 or 3; when m is selected from 1, two L_{b} are the same or different;
when m is selected from 2 or 3, multiple Lₐ are the same or different;
the ring F is selected from a heteroaromatic ring having 5 to 30 ring atoms;
the ring G is selected from an aromatic ring having 6 to 30 ring atoms, a heteroaromatic ring having 5 to 30 ring atoms or a combination thereof;
U₁ to U₈ are, at each occurrence identically or differently, selected from CRₙ or N;
R_{f} and R_{g} represent, at each occurrence identically or differently, mono-substitution, multiple substitutions or non-substitution;
R_{f}, R_{g}, and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{f}, R_{g}, and Rₙ can be optionally joined to form a ring.

According to an embodiment of the present disclosure, the ring F is selected from any one of the following structures:

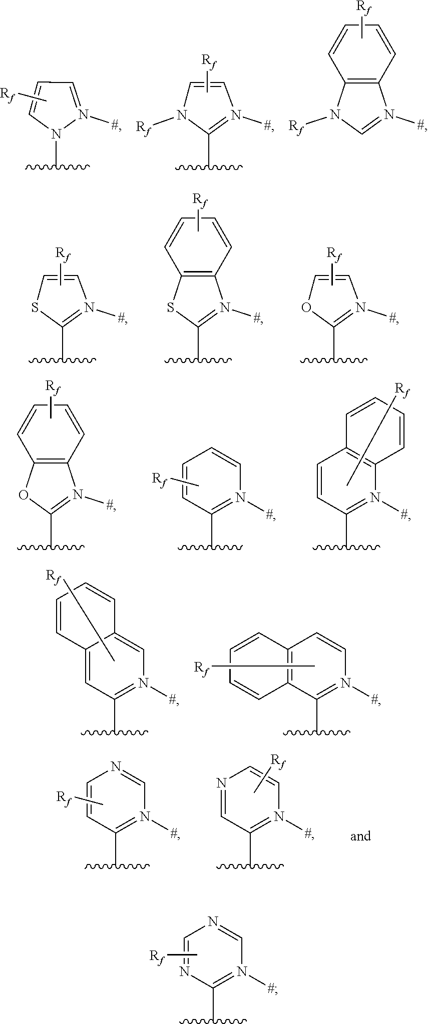

the ring G is selected from any one of the following structures:

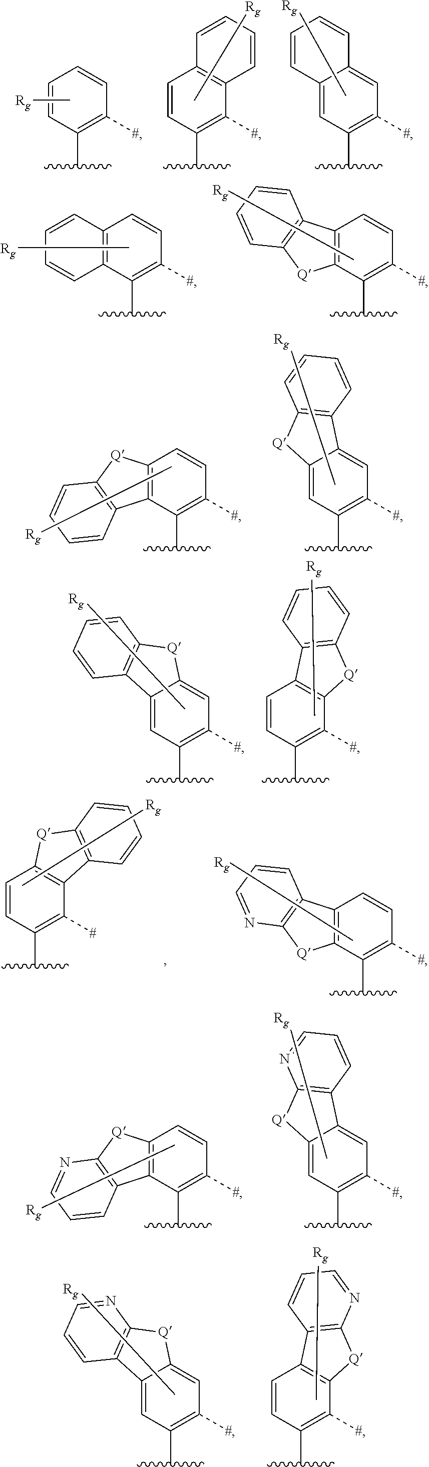

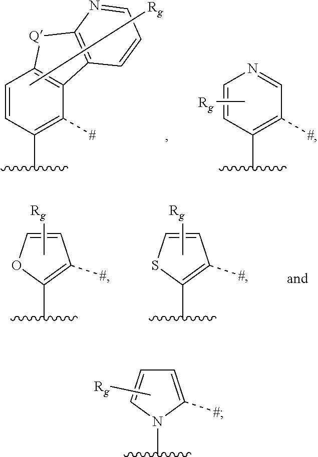

wherein
Q′ is selected from the group consisting of O, S, Se, NR_{Q}, CR_{Q}R_{Q}, SiR_{Q}R_{Q}, and GeR_{Q}R_{Q};
when multiple R_{Q} are present, the multiple R_{Q} are the same or different;
R_{f} and R_{g} represent, at each occurrence identically or differently, mono-substitution, multiple substitutions or non-substitution; when multiple R_{f} or R_{g} are present in any structure, the multiple R_{f} or R_{g} are the same or different;
R_{f}, R_{g}, and R_{Q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{f}, R_{g}, and R_{Q} can be optionally joined to form a ring;
“#” represents a position joined to the metal Ir, and

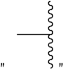

represents a position joined to the ring G.

According to an embodiment of the present disclosure, the ring F is selected from

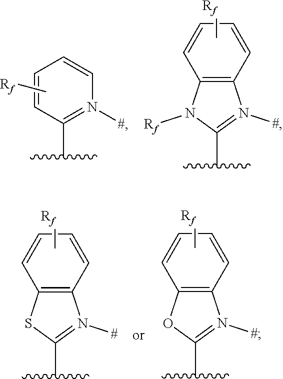

the ring G is selected from

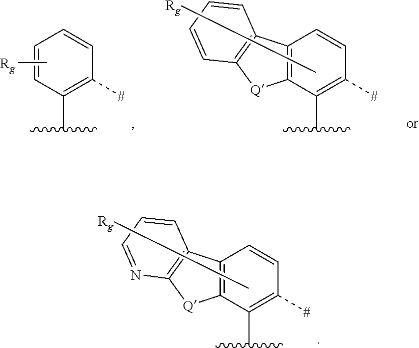

According to an embodiment of the present disclosure, the phosphorescent sensitizer has a general structure of Ir(Lₐ)ₘ(L_{b})₃₋ₘ and has a structure represented by Formula M-a-0:

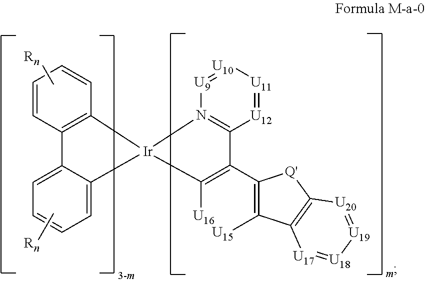

wherein
m is selected from 1, 2 or 3; when m is selected from 1, two L_{b} are the same or different;
when m is selected from 2 or 3, two or three Lₐ are the same or different;
Q′ is selected from the group consisting of O, S, Se, NR_{Q}, CR_{Q}R_{Q}, SiR_{Q}R_{Q}, and GeR_{Q}R_{Q};
when multiple R_{Q} are present, the multiple R_{Q} are the same or different;
U₁₅ to U₂₀ are, at each occurrence identically or differently, selected from CRₙ₁ or N; U₉ to U₁₂ are, at each occurrence identically or differently, selected from CRₙ₂ or N;
Rₙ represents, at each occurrence identically or differently, mono-substitution, multiple substitutions or non-substitution;
Rₙ₁, Rₙ₂, R_{Q}, and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₙ₁, Rₙ₂, R_{Q}, and Rₙ can be optionally joined to form a ring.

According to an embodiment of the present disclosure, Q′ is selected from O, S, Se, NR_{Q} or CR_{Q}R_{Q}.

According to an embodiment of the present disclosure, Q′ is selected from O or S.

According to an embodiment of the present disclosure, U₉ to U₁₂ are, at each occurrence identically or differently, selected from CRₙ₂, U₁₅ to U₁₉ are, at each occurrence identically or differently, selected from CRₙ, and U₂₀ is selected from CRₙ₁ or N; Rₙ₁ and Rₙ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group, and combinations thereof.

According to an embodiment of the present disclosure, at least two of U₁₅ to U₂₀ are selected from CRₙ₁, wherein one Rₙ₁ is a cyano group or fluorine, and another Rₙ₁ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least two of U₁₅ to U₂₀ are selected from CRₙ₁, wherein one Rₙ₁ is a cyano group or fluorine, and another Rₙ₁ is selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, U₁₉ is selected from CRₙ₁, wherein Rₙ₁ is a cyano group or fluorine; U₂₀ is selected from CRₙ₁, wherein Rₙ₁ is selected from deuterium, substituted or unsubstituted aryl having 6 to 18 carbon atoms, substituted or unsubstituted heteroaryl having 3 to 18 carbon atoms or a combination thereof.

According to an embodiment of the present disclosure, Rₙ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, a cyano group, and combinations thereof.

According to an embodiment of the present disclosure, Rₙ is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, and combinations thereof.

According to an embodiment of the present disclosure, the phosphorescent sensitizer is selected from the group consisting of BD1 to BD18, RD1 to RD209, and GD1 to GD177, wherein the specific structures of BD1 to BD18, RD1 to RD209, and GD1 to GD177 are referred to claim 17.

According to an embodiment of the present disclosure, the phosphorescent sensitizer has a structure represented by Pt(Lₐ) (L_{b}), wherein Lₐ and L_{b} are a first ligand and a second ligand coordinated to the metal Pt, respectively, Lₐ is selected from the group consisting of Lₐ1-1 to Lₐ1-25 and Lₐ2-1 to Lₐ2-10, and L_{b} is selected from the group consisting of L_{b}1-1 to L_{b}1-8 and L_{b}2-1 to L_{b}2-24, wherein the specific structures of Lₐ1-1 to Lₐ1-25, Lₐ2-1 to Lₐ2-10, L_{b}1-1 to L_{b}1-8, and L_{b}2-1 to L_{b}2-24 are referred to claim 17.

According to an embodiment of the present disclosure, the phosphorescent sensitizer is selected from the group consisting of Pt1 to Pt96, wherein Pt1 to Pt96 have a structure represented by Pt(Lₐ) (L_{b}), and the specific structures of Pt1 to Pt96 are referred to claim 17.

According to an embodiment of the present disclosure, the first host compound has a structure represented by one of Formula 5 to Formula 7:

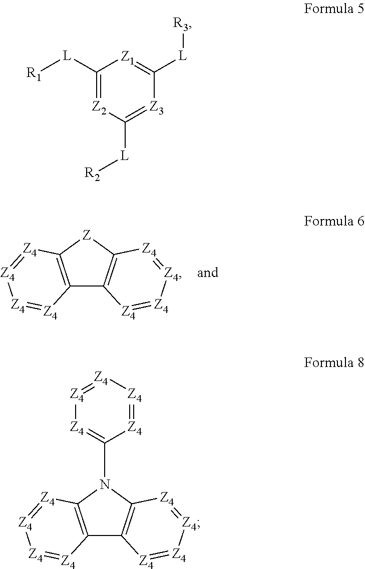

wherein in Formula 5, Z₁ to Z₃ are, at each occurrence identically or differently, selected from CR₄ or N, and at least one of Z₁ to Z₃ is N;
L is, at each occurrence identically or differently, selected from the group consisting of: a single bond, substituted or unsubstituted arylene having 6 to 30 carbon atoms, substituted or unsubstituted heteroarylene having 3 to 30 carbon atoms, and combinations thereof;
in Formula 6 and Formula 7, Z₄ is, at each occurrence identically or differently, selected from CR₄ or N, and at least one Z₄ is N;
Z is, at each occurrence identically or differently, selected from O or S;
R₁ to R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, adjacent substituents R₄ can be optionally joined to form a ring.

Herein, “adjacent substituents R₄ can be optionally joined to form a ring” is intended to mean that any two adjacent substituents R₄ can be joined to form a ring. Obviously, it is also possible that two adjacent substituents R₄ are not joined to form a ring.

According to an embodiment of the present disclosure, the first host compound has a structure represented by Formula 5-1 or Formula 6-1:

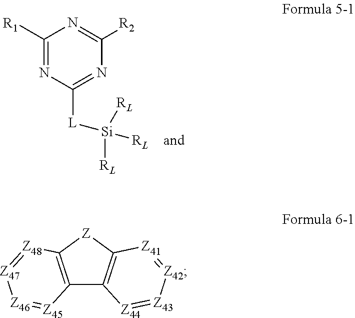

wherein in Formula 5-1,
R₁ and R₂ are each independently selected from substituted or unsubstituted heteroaryl having 3 to 30 carbon atoms;
L is selected from a single bond, substituted or unsubstituted arylene having 6 to 30 carbon atoms, substituted or unsubstituted heteroarylene having 3 to 30 carbon atoms, or a combination thereof;
in Formula 6-1,
Z is selected from O or S;
Z₄₁ to Z₄₈ are, at each occurrence identically or differently, selected from CR₄, CR₄′ or N; at least one of Z₄₁ to Z₄₈ is selected from N, and at least one of Z₄₁ to Z₄₈ is selected from CR₄′;
R₄′ is, at each occurrence identically or differently, selected from substituted or unsubstituted aryl having 6 to 30 carbon atoms, substituted or unsubstituted heteroaryl having 3 to 30 carbon atoms or a combination thereof;
R_{L} and R₄ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₄ can be optionally joined to form a ring.

According to an embodiment of the present disclosure, L is, at each occurrence identically or differently, selected from the group consisting of: a single bond, substituted or unsubstituted arylene having 6 to 18 carbon atoms, substituted or unsubstituted heteroarylene having 3 to 18 carbon atoms, and combinations thereof;

According to an embodiment of the present disclosure, L is, at each occurrence identically or differently, selected from the group consisting of: a single bond, phenylene, biphenylylene, fluorenylidene, triphenylenylene, furylene, thienylene, dibenzofurylene, dibenzothienylene, and combinations thereof.

According to an embodiment of the present disclosure, wherein R_{L} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, R_{L} is, at each occurrence identically or differently, selected from substituted or unsubstituted aryl having 6 to 30 carbon atoms.

According to an embodiment of the present disclosure, R_{L} is, at each occurrence identically or differently, selected from the group consisting of: phenyl, biphenyl, triphenylenyl, indenyl, fluorenyl, indolyl, carbazolyl, benzofuryl, dibenzofuryl, benzosilolyl, dibenzosilolyl, benzothienyl, dibenzothienyl, dibenzoselenophenyl, and combinations thereof.

According to an embodiment of the present disclosure, R₁ to R₄ are, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, R₁ to R₄ are, at each occurrence identically or differently, selected from the group consisting of: hydrogen, deuterium, halogen, a cyano group, substituted or unsubstituted aryl having 6 to 18 carbon atoms, substituted or unsubstituted heteroaryl having 3 to 18 carbon atoms, and combinations thereof.

According to an embodiment of the present disclosure, R₁ to R₄ are, at each occurrence identically or differently, selected from the group consisting of: hydrogen, deuterium, fluorine, cyano, phenyl, biphenyl, triphenylenyl, indenyl, fluorenyl, indolyl, carbazolyl, benzofuryl, dibenzofuryl, benzosilolyl, dibenzosilolyl, benzothienyl, dibenzothienyl, dibenzoselenophenyl, triazinyl, and combinations thereof.

According to an embodiment of the present disclosure, in Formula 6-1, at least one of Z₄₁ to Z₄₈ is selected from N, and at least two of Z₄₁ to Z₄₈ are selected from CR₄′.

According to an embodiment of the present disclosure, in Formula 6-1, only one of Z₄₁ to Z₄₈ is selected from N, and only two of Z₄₁ to Z₄₈ are selected from CR₄′.

According to an embodiment of the present disclosure, in Formula 6-1, Z₄₂ is selected from N, and Z₄₁ and Z₄₆ are selected from CR₄′.

According to an embodiment of the present disclosure, the first host compound has a structure represented by Formula 5-2 or Formula 5-3:

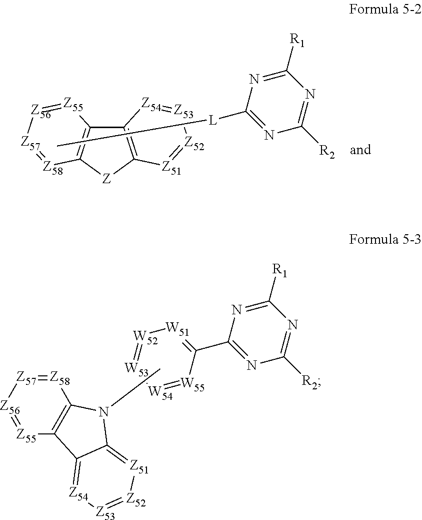

wherein
Z is, at each occurrence identically or differently, selected from the group consisting of O, S, and Se;
in Formula 5-2, Z₅₁ to Z₅₈ are, at each occurrence identically or differently, selected from C, CR₅ or N, and one of Z₅₁ to Z₅₈ is C and is joined to L;
in Formula 5-3, Z₅₁ to Z₅₈ are, at each occurrence identically or differently, selected from CR₅ or N;
W₅₁ to W₅₅ are, at each occurrence identically or differently, selected from C, CR_{w1} or N, and one of W₅₁ to W₅₅ is C and is joined to a structure

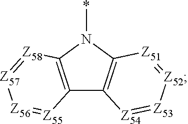

R₁ and R₂ are, at each occurrence identically or differently, selected from substituted or unsubstituted aryl having 6 to 30 carbon atoms, substituted or unsubstituted heteroaryl having 3 to 30 carbon atoms or a combination thereof;
R₅ and R_{w1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{w1} can be optionally joined to form a ring;
adjacent substituents R₅ can be optionally joined to form a ring.

According to an embodiment of the present disclosure, the first host compound is selected from the group consisting of Compound N-1-1 to Compound N-1-60, Compound N-2-1 to Compound N-2-35, Compound N-3-1 to Compound N-3-9, Compound N-4-1 to Compound N-4-34, and Compound NH-1 to Compound NH-224, wherein the specific structures of Compound N-1-1 to Compound N-1-60, Compound N-2-1 to Compound N-2-35, Compound N-3-1 to Compound N-3-9, Compound N-4-1 to Compound N-4-34, and Compound NH-1 to Compound NH-224 are referred to claim 18.

According to an embodiment of the present disclosure, hydrogens in the structures of Compound N-1-1 to Compound N-1-53, Compound N-1-58, Compound N-2-1 to Compound N-2-32, Compound N-3-1 to Compound N-3-7, Compound N-4-1 to Compound N-4-34, and Compound NH-1 to Compound NH-224 can be partially or fully substituted with deuterium.

According to an embodiment of the present disclosure, the second host compound has a structure represented by Formula 8, Formula 9 or Formula 10:

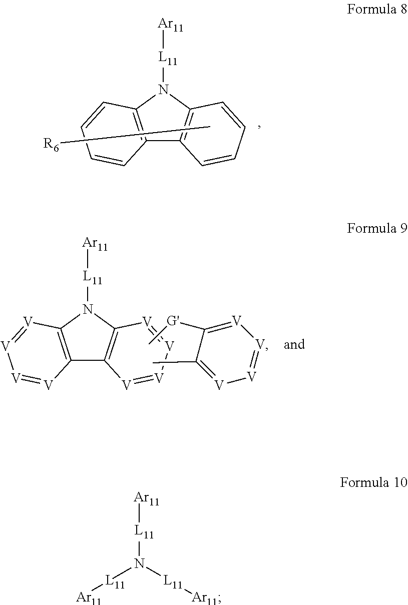

wherein L₁₁ is selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
G′ is, at each occurrence identically or differently, selected from C(R_{g}′)₂, NR_{g}′, O or S; Vis, at each occurrence identically or differently, selected from C, CR₆ or N;
R₆ represents, at each occurrence identically or differently, mono-substitution, multiple substitutions or non-substitution;
R₆ and R_{g}′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₆ can be optionally joined to form a ring.

Herein, “adjacent substituents R₆ can be optionally joined to form a ring” is intended to mean that any two adjacent substituents R₆ can be joined to form a ring. Obviously, it is also possible that two adjacent substituents R₆ are not joined to form a ring.

According to an embodiment of the present disclosure, the second host compound has a structure represented by Formula 8-1 or Formula 8-2:

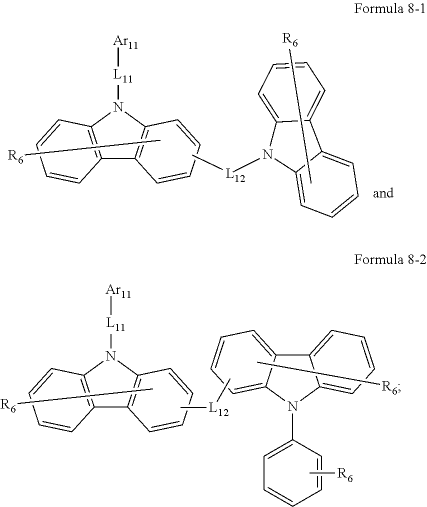

wherein L₁₁ and L₁₂ are selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₆ can be optionally joined to form a ring.

According to an embodiment of the present disclosure, the second host compound has a structure represented by Formula 8-3 or Formula 8-4:

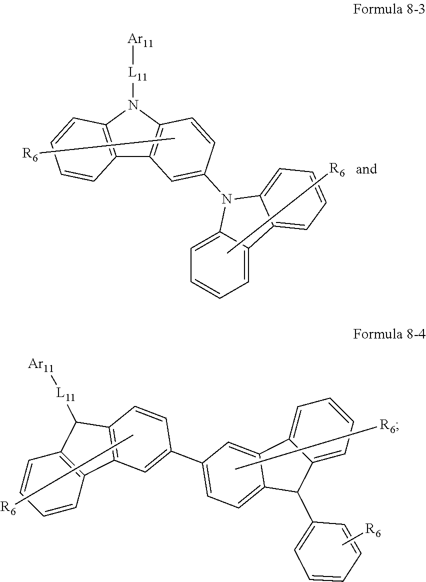

wherein Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof,
L₁₁ is selected from a single bond, substituted or unsubstituted arylene having 6 to 30 carbon atoms, substituted or unsubstituted heteroarylene having 3 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₆ can be optionally joined to form a ring.

According to an embodiment of the present disclosure, R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, R₆ is, at each occurrence identically or differently, selected from the group consisting of: hydrogen, deuterium, halogen, a cyano group, substituted or unsubstituted aryl having 6 to 18 carbon atoms, substituted or unsubstituted heteroaryl having 3 to 18 carbon atoms, and combinations thereof.

According to an embodiment of the present disclosure, R₆ is, at each occurrence identically or differently, selected from the group consisting of: hydrogen, deuterium, fluorine, cyano, phenyl, biphenyl, triphenylenyl, indenyl, fluorenyl, indolyl, carbazolyl, benzofuryl, dibenzofuryl, benzosilolyl, dibenzosilolyl, benzothienyl, dibenzothienyl, dibenzoselenophenyl, and combinations thereof.

According to an embodiment of the present disclosure, the second host compound is selected from the group consisting of Compound P-1 to Compound P-66 and Compound PH-1 to Compound PH-223, wherein the specific structures of Compound P-1 to Compound P-66 and Compound PH-1 to Compound PH-223 are referred to claim 19.

According to an embodiment of the present disclosure, hydrogens in the structures of Compound P-1 to Compound P-23, Compound P-27 to Compound P-38, and Compound PH-1 to Compound PH-223 can be partially or fully substituted with deuterium.

According to an embodiment of the present disclosure, the LUMO energy level of the first host compound is less than or equal to −2.30 eV.

According to an embodiment of the present disclosure, the LUMO energy level of the first host compound is less than or equal to −2.50 eV.

According to an embodiment of the present disclosure, the LUMO energy level of the first host compound is less than or equal to −2.65 eV.

According to an embodiment of the present disclosure, the LUMO energy level of the first host compound is less than or equal to −2.80 eV.

According to an embodiment of the present disclosure, the HOMO energy level of the second host compound is greater than or equal to −5.70 eV.

According to an embodiment of the present disclosure, the HOMO energy level of the second host compound is greater than or equal to −5.60 eV.

According to an embodiment of the present disclosure, the HOMO energy level of the second host compound is greater than or equal to −5.56 eV.

According to an embodiment of the present disclosure, the first host compound and the second host compound may be the same or different.

According to an embodiment of the present disclosure, the first host compound is different from the second host compound.

According to an embodiment of the present disclosure, weights of the first host compound and the second host compound account for 65% to 98.9% of the total weight of the composition, the weight of the phosphorescent sensitizer accounts for 1% to 30% of the total weight of the composition, and the weight of the fluorescent compound accounts for 0.1% to 5% of the total weight of the composition.

According to an embodiment of the present disclosure, weights of the first host compound and the second host compound account for 82% to 94.5% of the total weight of the composition, the weight of the phosphorescent sensitizer accounts for 5% to 15% of the total weight of the composition, and the weight of the fluorescent compound accounts for 0.5% to 3% of the total weight of the composition.

According to an embodiment of the present disclosure, weights of the first host compound and the second host compound account for 86.5% to 91.5% of the total weight of the composition, the weight of the phosphorescent sensitizer accounts for 8% to 12% of the total weight of the composition, and the weight of the fluorescent compound accounts for 0.5% to 1.5% of the total weight of the composition.

According to an embodiment of the present disclosure, weights of the first host compound and the second host compound account for 85% to 98% of the total weight of the composition, the weight of the phosphorescent sensitizer accounts for 1.5% to 12% of the total weight of the composition, and the weight of the fluorescent compound accounts for 0.5% to 3% of the total weight of the composition.

According to an embodiment of the present disclosure, weights of the first host compound and the second host compound account for 87.5% to 97.5% of the total weight of the composition, the weight of the phosphorescent sensitizer accounts for 2% to 10% of the total weight of the composition, and the weight of the fluorescent compound accounts for 0.5% to 2.5% of the total weight of the composition.

According to an embodiment of the present disclosure, the use of the composition in an organic electroluminescent device is disclosed.

According to an embodiment of the present disclosure, the use of the composition in an emissive layer of an organic electroluminescent device is disclosed.

According to an embodiment of the present disclosure, the composition is used in an organic electroluminescent device.

According to an embodiment of the present disclosure, the composition is used in an emissive layer of an organic electroluminescent device.

According to an embodiment of the present disclosure, the composition is used in an emissive layer of an organic electroluminescent device, the first host compound and the second host compound are host materials, and the fluorescent compound is an emissive material.

According to an embodiment of the present disclosure, the composition is used in an emissive layer of an organic electroluminescent device, the first host compound and the second host compound are host materials, the fluorescent compound is an E-type delayed fluorescent compound, and the E-type delayed fluorescent compound is an emissive material.

According to an embodiment of the present disclosure, an organic electroluminescent device is disclosed, which includes:
an anode,
a cathode, and
an organic layer disposed between the anode and the cathode, wherein the organic layer includes the composition described in any one of the above embodiments;
the composition includes a premix and a phosphorescent sensitizer, wherein the premix includes a first host compound, a second host compound, and a fluorescent compound;
the triplet energy level of the first host compound, the triplet energy level of the second host compound, and the triplet energy level of the phosphorescent sensitizer are higher than the triplet energy level of the fluorescent compound;
the first host compound has an evaporation temperature T1, wherein T1 ranges from 100° C. to 400° C.;
the second host compound has an evaporation temperature T2, wherein T2 ranges from 100° C. to 400° C.;
the absolute value of the difference between T1 and T2 is less than or equal to 20° C.

In the present embodiment, the premix is obtained by pre-mixing the first host compound, the second host compound, and the fluorescent compound before device preparation, and the premix is placed in a single evaporation source in a high vacuum evaporation tool during device preparation.

According to an embodiment of the present disclosure, the organic layer is an emissive layer, the first host compound and the second host compound are host materials, and the fluorescent compound is an emissive material.

According to an embodiment of the present disclosure, the (main) source of the light emitted by the device is light emitted by the fluorescent compound.

According to an embodiment of the present disclosure, the device emits blue light.

According to an embodiment of the present disclosure, the device emits dark blue light.

According to an embodiment of the present disclosure, the device emits green light.

According to an embodiment of the present disclosure, the device emits red light.

According to an embodiment of the present disclosure, the device emits white light.

According to an embodiment of the present disclosure, the maximum emission wavelength of the device ranges from 460 nm to 470 nm.

According to an embodiment of the present disclosure, the maximum emission wavelength of the device ranges from 525 nm to 550 nm.

According to an embodiment of the present disclosure, weights of the first host compound and the second host compound account for 65% to 98.9% of the total weight of an emissive layer material, the weight of the phosphorescent sensitizer accounts for 1% to 30% of the total weight of the emissive layer material, and the weight of the fluorescent compound accounts for 0.1% to 5% of the total weight of the emissive layer material.

According to an embodiment of the present disclosure, weights of the first host compound and the second host compound account for 82% to 94.5% of the total weight of the emissive layer material, the weight of the phosphorescent sensitizer accounts for 5% to 15% of the total weight of the emissive layer material, and the weight of the fluorescent compound accounts for 0.5% to 3% of the total weight of the emissive layer material.

According to an embodiment of the present disclosure, weights of the first host compound and the second host compound account for 86.5% to 91.5% of the total weight of the emissive layer material, the weight of the phosphorescent sensitizer accounts for 8% to 12% of the total weight of the emissive layer material, and the weight of the fluorescent compound accounts for 0.5% to 1.5% of the total weight of the emissive layer material.

According to an embodiment of the present disclosure, weights of the first host compound and the second host compound account for 85% to 98% of the total weight of the emissive layer material, the weight of the phosphorescent sensitizer accounts for 1.5% to 12% of the total weight of the emissive layer material, and the weight of the fluorescent compound accounts for 0.5% to 3% of the total weight of the emissive layer material.

According to an embodiment of the present disclosure, weights of the first host compound and the second host compound account for 87.5% to 97.5% of the total weight of the emissive layer material, the weight of the phosphorescent sensitizer accounts for 2% to 10% of the total weight of the emissive layer material, and the weight of the fluorescent compound accounts for 0.5% to 2.5% of the total weight of the emissive layer material.

According to an embodiment of the present disclosure, the ratio of the first host compound to the second host compound may be 99:1 to 1:99; the ratio may be 80:20 to 20:80; the ratio may be 70:30 to 30:70; the ratio may be 60:40 to 40:60; or the ratio may be 50:50.

According to an embodiment of the present disclosure, a preparation method of an organic electroluminescent device is disclosed, wherein the organic electroluminescent device includes an anode, a cathode, and an organic layer disposed between the anode and the cathode, wherein the organic layer includes the composition described in any one of the above embodiments, wherein the preparation method includes:
step 1: providing a substrate and disposing the anode thereon;
step 2: pre-mixing a first host compound, a second host compound, and a fluorescent compound to form a premix, and placing the premix in an evaporation source 1 in a high vacuum evaporation tool; placing a phosphorescent sensitizer in an evaporation source 2 in the high vacuum evaporation tool; co-evaporating the premix in the evaporation source 1 and the phosphorescent sensitizer in the evaporation source 2, and co-evaporating the premix in the evaporation source 1 and the phosphorescent sensitizer in the evaporation source 2 on a surface positioned at a certain distance away from the evaporated premix and the evaporated phosphorescent sensitizer to form the organic layer;
wherein the triplet energy level of the first host compound, the triplet energy level of the second host compound, and the triplet energy level of the phosphorescent sensitizer are higher than the triplet energy level of the fluorescent compound;
the first host compound has an evaporation temperature T1, wherein T1 ranges from 100° C. to 400° C.;
the second host compound has an evaporation temperature T2, wherein T2 ranges from 100° C. to 400° C.;
the absolute value of the difference between T1 and T2 is less than or equal to 20° C.; and
step 3: evaporating the cathode on the organic layer.

In the present embodiment, when the premix in the evaporation source 1 and the phosphorescent sensitizer in the evaporation source 2 in the high vacuum evaporation tool are co-evaporated, those skilled in the art may select a suitable vacuum degree and a suitable evaporation rate according to actual requirements as long as the purpose of evaporation can be achieved. For example, without limitation, the vacuum degree may be 10⁻⁶ Torr or below, for example, 10⁻⁷ Torr or 10⁻⁸ Torr, and the evaporation rate may be 0.2 Å/s to 2 Å/s.

In the present embodiment, the “certain distance” described in the process of evaporating the premix and the phosphorescent sensitizer to form the organic layer may be adaptively adjusted by those skilled in the art according to actual requirements as long as the purpose of evaporation can be achieved. For example, without limitation, the certain distance may be 10 cm to 100 cm, 30 cm to 80 cm or 35 cm to 60 cm.

The device prepared by using the preparation method herein may further include other organic layer, and the other organic layer may be disposed between the organic layer prepared in step 2 and the anode or the cathode and may be prepared in another step between steps 1 and 2 or another step between steps 2 and 3. The organic layer prepared in step 2 is preferably an emissive layer.

According to an embodiment of the present disclosure, the evaporation rate of the first host compound may be 0.01 Å/s to 10 Å/s, 0.1 Å/s to 10 Å/s, 0.1 Å/s to 5 Å/s, or 0.1 Å/s to 2 Å/s at the evaporation temperature T1 and the specific vacuum degree; the evaporation rate of the second host compound may be 0.01 Å/s to 10 Å/s, 0.1 Å/s to 10 Å/s, 0.1 Å/s to 5 Å/s, or 0.1 Å/s to 2 Å/s at the evaporation temperature T2 and the specific vacuum degree; the evaporation rate of the fluorescent compound may be 0.01 Å/s to 2 Å/s, 0.01 Å/s to 1 Å/s, 0.01 Å/s to 0.5 Å/s, or 0.01 Å/s to 0.2 Å/s at the evaporation temperature T3 and the specific vacuum degree.

According to an embodiment of the present disclosure, the premix consists of the first host compound, the second host compound, and the fluorescent compound.

According to an embodiment of the present disclosure, the premix is formed by physically mixing the first host compound, the second host compound, and the fluorescent compound.

According to an embodiment of the present disclosure, the first host compound, the second host compound, and the fluorescent compound in the premix are specifically defined as described in any one of the above embodiments.

According to an embodiment of the present disclosure, the premix is a solid mixture.

According to an embodiment of the present disclosure, the use of a premix in a sensitized device is disclosed, wherein the premix is as described in the above embodiments, and the premix and a phosphorescent sensitizer are co-evaporated to prepare the sensitized device.

Combination with Other Materials

The materials described in the present disclosure for a particular layer in an organic light emitting device can be used in combination with various other materials present in the device. The combinations of these materials are described in more detail in U.S. patent application No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. patent application No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The first host compound, the second host compound, the phosphorescent sensitizer, and the thermally activated delayed fluorescent compound used in the present disclosure can be easily obtained with reference to the preparation method in the related art, and the preparation method thereof is not repeated here.

The preparation method of an organic electroluminescent device is not limited, and the preparation method in the following embodiment is only an example and should not be construed as a limitation. Those skilled in the art can make reasonable improvements on the preparation method in the following embodiment based on the related art. For example, the proportions of various materials in the emissive layer are not particularly limited. Those skilled in the art can reasonably select the proportions of materials within a certain range based on the related art. For example, based on the total weight of the materials of the emissive layer, the two host compounds may account for 65% to 98.9%, the phosphorescent sensitizer may account for 1% to 30%, and the thermally activated delayed fluorescent compound may account for 0.1% to 5%; the two host compounds may account for 82% to 94.5%, the phosphorescent sensitizer may account for 5% to 15%, and the thermally activated delayed fluorescent compound may account for 0.5% to 3%; or the two host compounds may account for 86.5% to 91.5%, the phosphorescent sensitizer may account for 8% to 12%, and the thermally activated delayed fluorescent compound may account for 0.5% to 1.5%. Further, the ratio between the two host compounds therein can range from 99:1 to 1:99; the ratio can range from 80:20 to 20:80; or the ratio can range from 70:30 to 30:70. In the device examples, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art.

In the present disclosure, the evaporation temperature is a temperature at which evaporation is performed at a rate of 0.2 angstroms/second to 2 angstroms/second under a vacuum degree of about 10 8 Torr.

The evaporation temperatures of the first host compound, the second host compound, and the thermally activated delayed fluorescent compound are shown in Table 2.

TABLE 2
Evaporation temperature data

| | Evaporation |
|---|---|
| Material ID | temperature (° C.) |
| P-22 | 238 |
| N-1-15 | 239 |
| BN-BD-1 | 214 |
| BN-BD-2 | 228 |
| BN-BD-20 | 260 |
| BN-BD-34 | 198 |
| PH-24 | 290 |
| NH-144 | 270 |
| PH-1 | 255 |
| NH-45 | 270 |
| PH-51 | 260 |
| NH-147 | 270 |
| BN-GD-12 | 299 |

In the present disclosure, the preparation method of the premix is not limited. For example, the solid powders of the first host compound, the second host compound, and the thermally activated delayed fluorescent compound may be mixed in a certain weight ratio, the resulting mixture is heated and melted twice under a certain vacuum degree and then cooled to obtain a solid, and the solid is ground into powder to obtain the premix.

The preparation methods of the premixes PM1 to PM6 are as follows:

### Preparation of Premix PM1:

The first host compound N-1-15, the second host compound P-22, and the thermally activated delayed fluorescent compound BN-BD-2 were physically mixed in a weight ratio of 49:49:2, rolled, and added to a sample bottle, and the sample bottle was placed in a vacuum chamber. When the vacuum degree was greater than 10⁻³ Pa, the sample bottle was heated to 290° C., and after the temperature was maintained for 0.5 hours, the sample bottle was cooled to room temperature. When the vacuum degree was maintained to be greater than 10⁻³ Pa, the sample bottle was heated to 290° C. again, and after the temperature was maintained for 0.5 hours, the sample bottle was cooled to room temperature. The melted solid is ground into a powder to obtain the premix PM1.

### Preparation of Premix PM2:

The preparation method of the premix PM2 was the same as the preparation method of the premix PM1 except that the compound BN-BD-2 was substituted with the compound BN-BD-20. The molten solid was ground into a powder to obtain the premix PM2.

### Preparation of Premix PM3:

The preparation method of the premix PM3 was the same as the preparation method of the premix PM1 except that the compound BN-BD-2 was substituted with the compound BN-BD-34. The molten solid was ground into a powder to obtain the premix PM3.

### Preparation of Premix PM4:

The preparation method of the premix PM4 was the same as the preparation method of the premix PM1 except that the compound BN-BD-2 was substituted with the compound BN-BD-1. The molten solid was ground into a powder to obtain the premix PM4.

### Preparation of Premix PM5:

The preparation method of the premix PM5 was the same as the preparation method of the premix PM1 except that the weight ratio among the second host compound P-22, the first host compound N-1-15, and the thermally activated delayed fluorescent compound BN-BD-2 was 59:39:2. The melted solid is ground into a powder to obtain the premix PM5.

### Preparation of Premix PM6:

The preparation method of the premix PM6 was the same as the preparation method of the premix PM1 except that the weight ratio among the second host compound P-22, the first host compound N-1-15, and the thermally activated delayed fluorescent compound BN-BD-2 was 39:59:2. The melted solid is ground into a powder to obtain the premix PM6.

The specific structures of the compounds used in the premixes PM1 to PM6 are as follows:

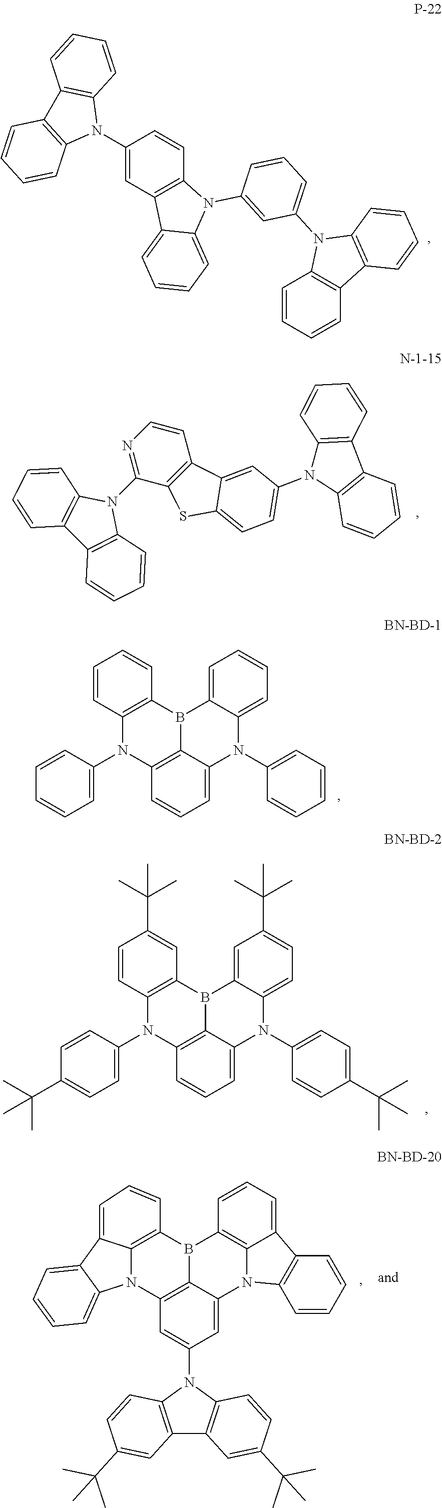 [SMILES: c1cc(-n2c3ccccc3c3ccccc32)cc(-n2c3ccccc3c3cc(-n4c5ccccc5c5ccccc54)ccc32)c1 ; c1ccc2c(c1)c1ccccc1n2-c1ccc2sc3c(-n4c5ccccc5c5ccccc54)nccc3c2c1 ; c1ccc(N2c3ccccc3B3c4ccccc4N(c4ccccc4)c4cccc2c43)cc1 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1 ; CC(C)(C)c1ccc2c(c1)c1cc(C(C)(C)C)ccc1n2-c1cc2c3c(c1)-n1c4ccccc4c4cccc(c41)B3c1cccc3c4ccccc4n-2c13]

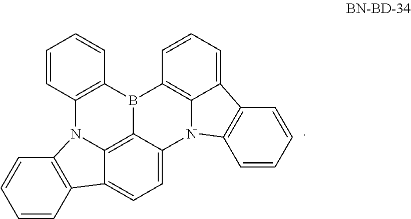 [SMILES: c1ccc2c(c1)B1c3cccc4c5ccccc5n(c34)-c3ccc4c5ccccc5n-2c4c31]

The preparation methods of the premixes PM7 to PM10 and the comparative premix C-PM1 are as follows:

### Preparation of Premix PM7:

The first host compound PH-24, the second host compound NH-144, and the thermally activated delayed fluorescent compound BN-GD-12 were physically mixed in a weight ratio of 73.5:24.5:2, rolled, and added to a sample bottle, and the sample bottle was placed in a vacuum chamber. When the vacuum degree was greater than 103 Pa, the sample bottle was heated to 290° C., and after the temperature was maintained for 0.5 hours, the sample bottle was cooled to room temperature. When the vacuum degree was maintained to be greater than 103 Pa, the sample bottle was heated to 290° C. again, and after the temperature was maintained for 0.5 hours, the sample bottle was cooled to room temperature. The melted solid is ground into a powder to obtain the premix PM7

### Preparation of Premix PM8:

The preparation method of the premix PM8 was the same as the preparation method of the premix PM7 except that the weight ratio among the first host compound PH-24, the second host compound NH-144, and the thermally activated delayed fluorescent compound BN-GD-12 was adjusted to 74.25:24.75:1. The melted solid is ground into a powder to obtain the premix PM8.

### Preparation of Premix PM9:

The first host compound PH-1, the second host compound NH-45, and the thermally activated delayed fluorescent compound BN-GD-12 were physically mixed in a weight ratio of 68.6:29.4:2, rolled, and added to a sample bottle, and the sample bottle was placed in a vacuum chamber. When the vacuum degree was greater than 10⁻³ Pa, the sample bottle was heated to 280° C., and after the temperature was maintained for 0.5 hours, the sample bottle was cooled to room temperature. When the vacuum degree was maintained to be greater than 10⁻³ Pa, the sample bottle was heated to 280° C. again, and after the temperature was maintained for 0.5 hours, the sample bottle was cooled to room temperature. The melted solid is ground into a powder to obtain the premix PM9.

### Preparation of Premix PM10:

The preparation method of the premix PM10 was the same as the preparation method of the premix PM9 except that the first host compound PH-1 was substituted with the first host compound PH-51 and the second host compound NH-45 was substituted with the second host compound NH-147. The melted solid is ground into a powder to obtain the premix PM10.

### Preparation of Comparative Premix C-PM1:

The first host compound PH-51 and the second host compound NH-147 were physically mixed in a weight ratio of 70:30, rolled, and added to a sample bottle, and the sample bottle was placed in a vacuum chamber. When the vacuum degree was greater than 103 Pa, the sample bottle was heated to 280° C., and after the temperature was maintained for 0.5 hours, the sample bottle was cooled to room temperature. When the vacuum degree was maintained to be greater than 103 Pa, the sample bottle was heated to 280° C. again, and after the temperature was maintained for 0.5 hours, the sample bottle was cooled to room temperature. The melted solid is ground into a powder to obtain the comparative premix C-PM1.

The specific structures of the compounds used in the premixes PM7 to PM10 and the comparative premix C-PM1 are as follows:

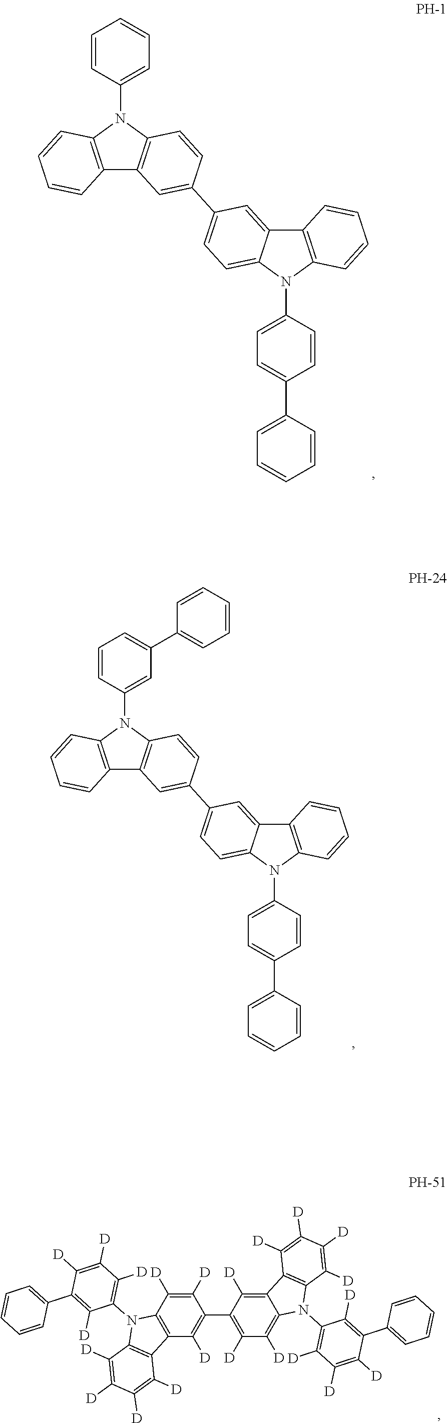 [SMILES: c1ccc(-c2ccc(-n3c4ccccc4c4cc(-c5ccc6c(c5)c5ccccc5n6-c5ccccc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; [2H]c1c([2H])c(-c2ccccc2)c([2H])c(-n2c3c([2H])c([2H])c([2H])c([2H])c3c3c([2H])c(-c4c([2H])c([2H])c5c(c4[2H])c4c([2H])c([2H])c([2H])c([2H])c4n5-c4c([2H])c([2H])c([2H])c(-c5ccccc5)c4[2H])c([2H])c([2H])c32)c1[2H]]

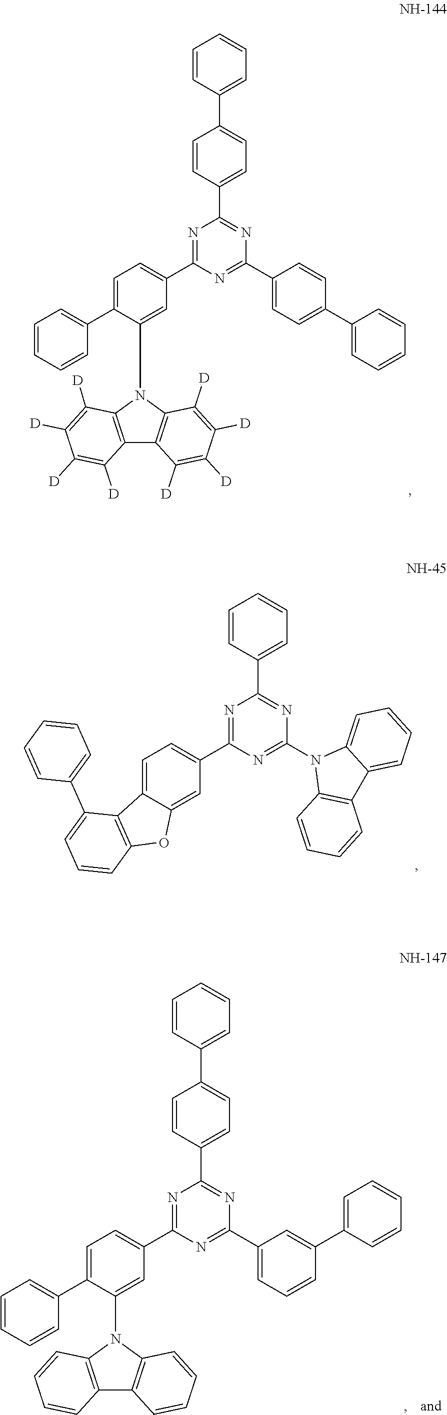 [SMILES: [2H]c1c([2H])c([2H])c2c(c1[2H])c1c([2H])c([2H])c([2H])c([2H])c1n2-c1cc(-c2nc(-c3ccc(-c4ccccc4)cc3)nc(-c3ccc(-c4ccccc4)cc3)n2)ccc1-c1ccccc1 ; c1ccc(-c2nc(-c3ccc4c(c3)oc3cccc(-c5ccccc5)c34)nc(-n3c4ccccc4c4ccccc43)n2)cc1 ; c1ccc(-c2ccc(-c3nc(-c4cccc(-c5ccccc5)c4)nc(-c4ccc(-c5ccccc5)c(-n5c6ccccc6c6ccccc65)c4)n3)cc2)cc1]

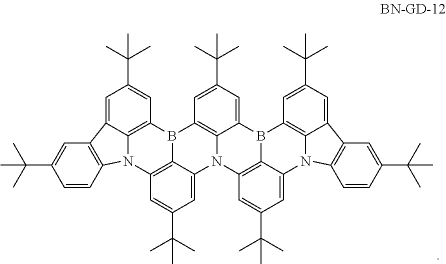 [SMILES: CC(C)(C)c1cc2c3c(c1)B1c4c(cc(C(C)(C)C)cc4-n4c5ccc(C(C)(C)C)cc5c5cc(C(C)(C)C)cc1c54)N3c1cc(C(C)(C)C)cc3c1B2c1cc(C(C)(C)C)cc2c4cc(C(C)(C)C)ccc4n-3c12]

The composition of the present disclosure includes a premix and a phosphorescent sensitizer, and the premix is a three-component premix formed by pre-mixing a first host compound, a second host compound, and a fluorescent compound. The premix shows high evaporation stability and can obtain stable device performance when the premix is applied to continuous evaporation of an organic electroluminescent device. Meanwhile, the premix included in the composition of the present disclosure can be used as a single evaporation source in the preparation process of a device, thereby reducing the cost and complexity of the evaporation process. Continuously evaporated device examples and their device data are provided below for demonstration.

### Continuously Evaporated Device Examples 1-1 to 1-5

First, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially evaporated through vacuum thermal evaporation on the ITO anode at a rate of 0.2 Å/s to 2 Å/s and at a vacuum degree of about 10° Torr. Compound HT and Compound HI were co-evaporated as a hole injection layer (HIL) with a thickness of 100 Å, wherein the weight ratio of Compound HT to Compound HI was 97:3. Compound HT was evaporated as a hole transport layer (HTL) with a thickness of 250 Å. Compound P-21 was evaporated as an electron blocking layer (EBL) with a thickness of 50 Å. Then, the premix PM1 (the weight ratio among Compound P-22, Compound N-1-15, and Compound BN-BD-2 was 49:49:2) was placed in an evaporation source 1, the phosphorescent sensitizer Pt27 was placed in an evaporation source 2, and the premix PM1 and the phosphorescent sensitizer Pt27 were co-evaporated as an emissive layer (EML) with a thickness of 350 Å, wherein the weight ratio of the premix PM1 to the phosphorescent sensitizer Pt27 was 88:12. Compound N-3-2 was evaporated as a hole blocking layer (HBL) with a thickness of 50 Å. On the hole blocking layer, Compound ET and 8-hydroxyquinolinolato-lithium (Liq) were co-evaporated as an electron transport layer (ETL) with a thickness of 310 Å, wherein the weight ratio of Compound ET to Compound Liq was 40:60. Finally, LiF with a thickness of 15 Å was evaporated as an electron injection layer, and aluminum with a thickness of 1200 Å was evaporated as a cathode. The device was transferred back to the glovebox and encapsulated with a glass lid and a moisture absorbent to complete Device Example 1-1. The above operations were repeated four consecutive times to obtain Device Examples 1-2 to 1-5.

### Continuously Evaporated Device Examples 2-1 to 2-5

The implementation mode of Continuously Evaporated Device Example 2-1 was the same as the implementation mode of Continuously Evaporated Device Example 1-1 except that the premix PM1 was substituted with the premix PM2 (the weight ratio among Compound P-22, Compound N-1-15, and Compound BN-BD-20 was 49:49:2) in the emissive layer (EML). The above operations were repeated four consecutive times to obtain Device Examples 2-2 to 2-5.

### Continuously Evaporated Device Examples 3-1 to 3-5

The implementation mode of Continuously Evaporated Device Example 3-1 was the same as the implementation mode of Continuously Evaporated Device Example 1-1 except that the premix PM1 was substituted with the premix PM3 (the weight ratio among Compound P-22, Compound N-1-15, and Compound BN-BD-34 was 49:49:2) in the emissive layer (EML). The above operations were repeated four consecutive times to obtain Device Examples 3-2 to 3-5. Continuously Evaporated Device Examples 4-1 to 4-6

The implementation mode of Continuously Evaporated Device Example 4-1 was the same as the implementation mode of Continuously Evaporated Device Example 1-1 except that the premix PM1 was substituted with the premix PM4 (the weight ratio among Compound P-22, Compound N-1-15, and Compound BN-BD-1 was 49:49:2) in the emissive layer (EML). The above operations were repeated five consecutive times to obtain Device Examples 4-2 to 4-6.

Detailed structures and thicknesses of layers of the devices are shown in the following table. A layer using more than one material was obtained by doping different compounds in their mass ratio as recorded.

TABLE 3
Part of device structures in Device Examples 1-1 to 1-5, Device Examples
2-1 to 2-5, Device Examples 3-1 to 3-5, and Device Examples 4-1 to 4-6

| Device ID | HIL | HTL | EBL | EML | HBL | ETL |
|---|---|---|---|---|---|---|
| Device | Compound | Compound | Compound | Premix | Compound | Compound |
| Examples | HT:Compound | HT | P-21 | PM1:Phosphorescent | N-3-2 | ET:Liq |
| 1-1 to 1-5 | HI (97:3) | (250 Å) | (50 Å) | sensitizer Pt27 | (50 Å) | (40:60) |
| | (100 Å) | | | (88:12) (350 Å) | | (310 Å) |
| Device | Compound | Compound | Compound | Premix | Compound | Compound |
| Examples | HT:Compound | HT | P-21 | PM2:Phosphorescent | N-3-2 | ET:Liq |
| 2-1 to 2-5 | HI (97:3) | (250 Å) | (50 Å) | sensitizer (88:12) | (50 Å) | (40:60) |
| | (100 Å) | | | (350 Å) | | (310 Å) |
| Device | Compound | Compound | Compound | Premix | Compound | Compound |
| Examples | HT:Compound | HT | P-21 | PM3:Phosphorescent | N-3-2 | ET:Liq |
| 3-1 to 3-5 | HI (97:3) | (250 Å) | (50 Å) | sensitizer Pt27 | (50 Å) | (40:60) |
| | (100 Å) | | | (88:12) (350 Å) | | (310 Å) |
| Device | Compound | Compound | Compound | Premix | Compound | Compound |
| Examples | HT:Compound | HT | P-21 | PM4:Phosphorescent | N-3-2 | ET:Liq |
| 4-1 to 4-6 | HI (97:3) | (250 Å) | (50 Å) | sensitizer Pt27 | (50 Å) | (40:60) |
| | (100 Å) | | | (88:12) (350 Å) | | (310 Å) |

The structures of the materials used in the devices are as follows:

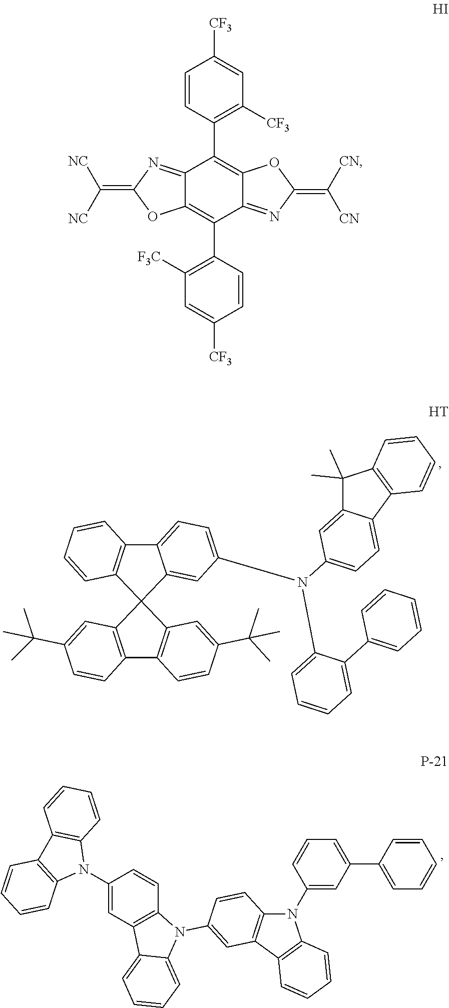 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; c1ccc(-c2cccc(-n3c4ccccc4c4cc(-n5c6ccccc6c6cc(-n7c8ccccc8c8ccccc87)ccc65)ccc43)c2)cc1]

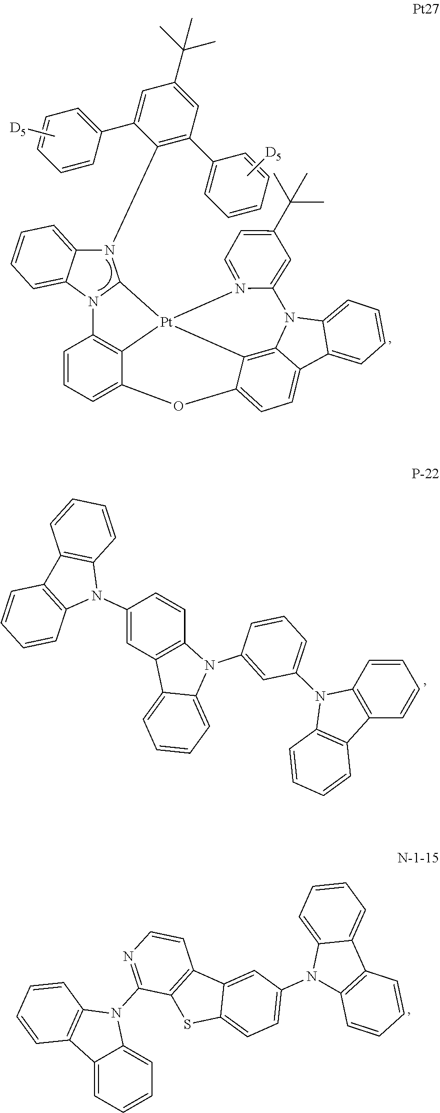

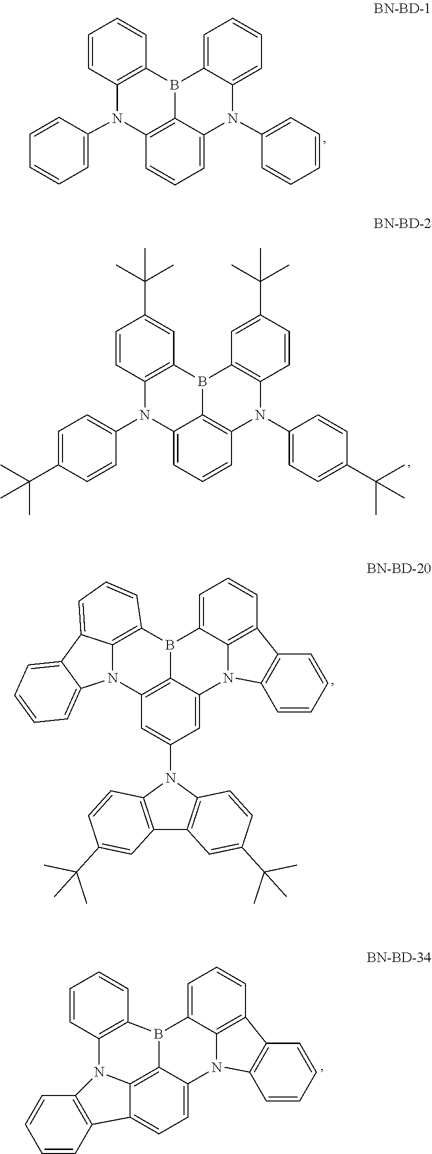 [SMILES: c1ccc(N2c3ccccc3B3c4ccccc4N(c4ccccc4)c4cccc2c43)cc1 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1 ; CC(C)(C)c1ccc2c(c1)c1cc(C(C)(C)C)ccc1n2-c1cc2c3c(c1)-n1c4ccccc4c4cccc(c41)B3c1cccc3c4ccccc4n-2c13 ; c1ccc2c(c1)B1c3cccc4c5ccccc5n(c34)-c3ccc4c5ccccc5n-2c4c31]

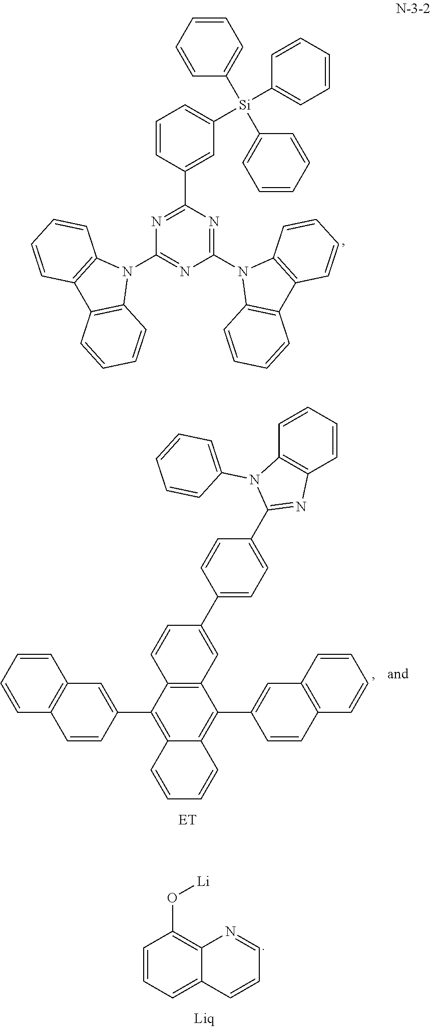

The CIE value, maximum emission wavelength (λₘₐₓ), full width at half maximum (FWHM), and external quantum efficiency (EQE) of each of Device Examples 1-1 to 1-5, Device Examples 2-1 to 2-5, Device Examples 3-1 to 3-5, and Device Examples 4-1 to 4-6 were measured at 10 mA/cm². The related data are shown in Table 4.

TABLE 4
Device data

| | | λₘₐₓ | FWHM | EQE |
|---|---|---|---|---|
| Device ID | CIE (x, y) | [nm] | [nm] | (%) |
| Device Example 1-1 | 0.125, 0.116 | 465 | 27.5 | 19.89 |
| Device Example 1-2 | 0.125, 0.115 | 465 | 27.5 | 19.97 |
| Device Example 1-3 | 0.125, 0.116 | 465 | 27.6 | 19.92 |
| Device Example 1-4 | 0.125, 0.114 | 464 | 27.2 | 20.22 |
| Device Example 1-5 | 0.125, 0.114 | 464 | 27.2 | 20.30 |
| Device Example 2-1 | 0.126, 0.124 | 466 | 26.5 | 20.30 |
| Device Example 2-2 | 0.126, 0.123 | 466 | 26.5 | 20.46 |
| Device Example 2-3 | 0.126, 0.123 | 466 | 26.5 | 20.26 |
| Device Example 2-4 | 0.126, 0.121 | 466 | 26.4 | 20.67 |
| Device Example 2-5 | 0.126, 0.121 | 467 | 26.3 | 20.63 |
| Device Example 3-1 | 0.122, 0.245 | 475 | 42.3 | 12.76 |
| Device Example 3-2 | 0.121, 0.240 | 474 | 42.0 | 12.78 |
| Device Example 3-3 | 0.121, 0.233 | 474 | 41.1 | 12.82 |
| Device Example 3-4 | 0.121, 0.233 | 474 | 41.4 | 12.86 |
| Device Example 3-5 | 0.121, 0.224 | 474 | 40.3 | 12.96 |
| Device Example 4-1 | 0.132, 0.101 | 461 | 27.5 | 16.06 |
| Device Example 4-2 | 0.132, 0.102 | 461 | 27.5 | 15.99 |
| Device Example 4-3 | 0.132, 0.101 | 461 | 27.3 | 16.01 |
| Device Example 4-4 | 0.132, 0.101 | 460 | 27.3 | 16.03 |
| Device Example 4-5 | 0.132, 0.100 | 461 | 27.1 | 16.03 |
| Device Example 4-6 | 0.132, 0.101 | 461 | 27.1 | 16.03 |

As can be seen from the above four groups of continuously evaporated device examples using the composition of the present disclosure as the emissive layer of the device, the maximum emission wavelengths (λₘₐₓ) change by at most 1 nm, and the full widths at half maximum (FWHM) change by at most 2 nm; more importantly, the differences between the highest EQE and the lowest EQE in the four groups of continuously evaporated device examples are 0.41%, 0.37%, 0.20%, and 0.07%, respectively, and these devices maintain substantially equivalent EQEs, which indicates that the three-component premix included in the composition of the present disclosure has high evaporation stability and can obtain stable device performance when the premix is applied to continuous evaporation of an organic electroluminescent device. Meanwhile, the composition of the present disclosure only requires two evaporation sources to complete the preparation of a four-component emissive layer, which reduces the cost and complexity of the evaporation process and has potential application value in industrial mass production.

In addition, the present disclosure also selects a coating layer manufactured by a single evaporation source of the premix PM10 prepared above for composition analysis and again verifies the high evaporation stability of the three-component premix of the present disclosure. The coating layer is specifically described below.

### Preparation of PM10 Coating Layer:

The premix PM10 was loaded into an evaporation source, the distance from the evaporation source to the glass substrate was set to be 35 cm to 60 cm, and the premix PM10 was evaporated at a rate of 0.2 Å/s to 2 Å/s under a vacuum degree of about 10⁻⁷ Torr and deposited on the glass substrate to form a coating layer with a thickness of 400 Å.

The compositions (%) of the PM10 coating layer were analyzed by HPLC. The results are shown in Table 4-1. The HPLC analysis conditions used are as follows: the analysis column used for analysis was a C8 column; the mobile phases were: A: water; B: acetonitrile/tetrahydrofuran mixture (80/20, v/v), wherein A:B=20:80 (v/v), gradient elution; the detection wavelength was 232 nm.

TABLE 4
Composition proportion of the premix in the PM10 coating layer

| | PH-51 (%) | NH-147 (%) | BN-GD-12 (%) |
|---|---|---|---|
| PM10 coating | 68.951 | 29.747 | 1.301 |
| layer | | | |

As can be seen from the data in Table 4-1, the ratio among the three components in the PM10 coating layer is relatively close to the ratio (68.6:29.4:2) among the three components in the premix, which again indicates that the three-component premix of the present disclosure has high evaporation stability.

In addition, four different premixes PM1, PM2, PM3, and PM4 were used in the above four groups of continuously evaporated device examples, respectively, and Compounds BN-BD-2, BN-BD-20, BN-BD-34, and BN-BD-1 were used in the premixes PM1, PM2, PM3, and PM4 as the thermally activated delayed fluorescent compounds, respectively. Compound BN-GD-12 was used in the above PM10 coating layer as a thermally activated delayed fluorescent compound. In conjunction with the evaporation temperatures of different materials in Table 2, the evaporation temperature of Compound BN-BD-2 is 10° C. lower than the evaporation temperature of Compound P-22, the evaporation temperature of Compound BN-BD-20 is 22° C. higher than the evaporation temperature of Compound P-22, the evaporation temperature of Compound BN-BD-34 is 40° C. lower than the evaporation temperature of Compound P-22, the evaporation temperature of Compound BN-BD-1 is 24° C. lower than the evaporation temperature of Compound P-22, and the evaporation temperature of Compound BN-GD-12 is 39° C. and 29° C. higher than Compound PH-51 and Compound NH-147, respectively. In the conventional two-component premix, the evaporation temperatures of the two materials generally need to be matched to obtain a two-component premix with high evaporation stability. For example, the difference between the evaporation temperatures of the two materials cannot be too large. In the three-component premix, even if the difference between the evaporation temperature of the thermally activated delayed fluorescent compound and the evaporation temperatures of the two host materials is large, a three-component premix with high evaporation stability can still be obtained. The thermally activated delayed fluorescent compound included in the composition of the present disclosure is free from the general limitation of matching the evaporation temperatures of two host materials, which greatly increases the choices in the chemical structure of the fluorescent material.

The above data prove that the three-component premix including a first host compound, a second host compound, and a fluorescent compound shows high evaporation stability, and stable device performance can be obtained when the composition of the present disclosure in which the premix cooperates with a phosphorescent sensitizer is applied to continuous evaporation of an organic electroluminescent device. Meanwhile, the premix included in the composition of the present disclosure can be used as a single evaporation source in the preparation process of a device, thereby reducing the cost and complexity of the evaporation process.

In addition, when a device is prepared by using the composition of the present disclosure formed by combining the three-component premix and the phosphorescent sensitizer, not only the cost and complexity of the evaporation process can be reduced, but also excellent device performance can be obtained. Device examples and their device data are provided below for demonstration.

### Blue Organic Electroluminescent Device

### Device Example 1

First, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially evaporated through vacuum thermal evaporation on the ITO anode at a rate of 0.2 Å/s to 2 Å/s and at a vacuum degree of about 10° Torr. Compound HT and Compound HI were co-evaporated as a hole injection layer (HIL) with a thickness of 100 Å, where the weight ratio of Compound HT to Compound HI was 97:3. Compound HT was evaporated as a hole transport layer (HTL) with a thickness of 250 Å. Compound P-21 was evaporated as an electron blocking layer (EBL) with a thickness of 50 Å. Then, the premix PM5 (the weight ratio among Compound P-22, Compound N-1-15, and Compound BN-BD-2 was 59:39:2) was placed in an evaporation source 1, the phosphorescent sensitizer Pt27 was placed in an evaporation source 2, and the premix PM5 and the phosphorescent sensitizer Pt27 were co-evaporated as an emissive layer (EML) with a thickness of 350 Å, wherein the weight ratio of the premix PM5 to the phosphorescent sensitizer Pt27 was 88:12. Compound N-3-2 was evaporated as a hole blocking layer (HBL) with a thickness of 50 Å. On the hole blocking layer, Compound ET and 8-hydroxyquinolinolato-lithium (Liq) were co-evaporated as an electron transport layer (ETL) with a thickness of 310 Å, wherein the weight ratio of Compound ET to Compound Liq was 40:60. Finally, LiF with a thickness of 15 Å was evaporated as an electron injection layer, and aluminum with a thickness of 1200 Å was evaporated as a cathode. The device was transferred back to the glovebox and encapsulated with a glass lid and a moisture absorbent to complete the device.

### Device Example 2

The implementation mode of Device Example 2 was the same as the implementation mode of Device Example 1 except that the premix PM5 was substituted with the premix PM6 (the weight ratio among Compound P-22, Compound N-1-15, and Compound BN-BD-2 was 39:59:2) in the emissive layer (EML).

### Device Example 3

The implementation mode of Device Example 3 was the same as the implementation mode of Device Example 1 except that the premix PM5 was substituted with the premix PM1 (the weight ratio among Compound P-22, Compound N-1-15, and Compound BN-BD-2 was 49:49:2) and the phosphorescent sensitizer Pt27 was substituted with the phosphorescent sensitizer Pt11 in the emissive layer (EML).

### Device Example 4

The implementation mode of Device Example 4 was the same as the implementation mode of Device Example 2 except that the phosphorescent sensitizer Pt27 was substituted with the phosphorescent sensitizer Pt11 in the emissive layer (EML).

### Device Comparative Example 1

The implementation mode of Device Comparative Example 1 was the same as the implementation mode of Device Example 1 except that Compound P-22, Compound N-1-15, and Compound Pt27 were placed into three different evaporation sources and co-evaporated as an emissive layer (EML) with a thickness of 350 Å, wherein the weight ratio among Compound P-22, Compound N-1-15, and Compound Pt27 was 52.8:35.2:12.

### Device Comparative Example 2

The implementation mode of Device Comparative Example 2 was the same as the implementation mode of Device Example 1 except that Compound P-22, Compound N-1-15, and Compound BN-BD-2 were placed into three different evaporation sources and co-evaporated as an emissive layer (EML) with a thickness of 350 Å, wherein the weight ratio among Compound P-22, Compound N-1-15, and Compound BN-BD-2 was 59.4:28.6:12.

Detailed structures and thicknesses of layers of the devices are shown in the following table. A layer using more than one material was obtained by doping different compounds in their mass ratio as recorded.

TABLE 5
Device structures in Device Examples and Device Comparative Examples

| Device ID | HIL | HTL | EBL | EML | HBL | ETL |
|---|---|---|---|---|---|---|
| Example 1 | Compound | Compound | Compound | Premix | Compound | Compound |
| | HT:Compound | HT | P-21 | PM5:Phosphorescent | N-3-2 | ET:Liq |
| | HI (97:3) | (250 Å) | (50 Å) | sensitizer Pt27 (88:12) | (50 Å) | (40:60) |
| | (100 Å) | | | (350 Å) | | (310 Å) |
| Example 2 | Compound | Compound | Compound | Premix | Compound | Compound |
| | HT:Compound | HT | P-21 | PM6:Phosphorescent | N-3-2 | ET:Liq |
| | HI (97:3) | (250 Å) | (50 Å) | sensitizer Pt27 (88:12) | (50 Å) | (40:60) |
| | (100 Å) | | | (350 Å) | | (310 Å) |
| Example 3 | Compound | Compound | Compound | Premix | Compound | Compound |
| | HT:Compound | HT | P-21 | PM1:Phosphorescent | N-3-2 | ET:Liq |
| | HI (97:3) | (250 Å) | (50 Å) | sensitizer Pt11 (88:12) | (50 Å) | (40:60) |
| | (100 Å) | | | (350 Å) | | (310 Å) |
| Example 4 | Compound | Compound | Compound | Premix | Compound | Compound |
| | HT:Compound | HT | P-21 | PM6:Phosphorescent | N-3-2 | ET:Liq |
| | HI (97:3) | (250 Å) | (50 Å) | sensitizer Pt11 (88:12) | (50 Å) | (40:60) |
| | (100 Å) | | | (350 Å) | | (310 Å) |
| Comparative | Compound | Compound | Compound | Compound P-22:Compound | Compound | Compound |
| Example 1 | HT:Compound | HT | P-21 | N-1-15:Phosphorescent | N-3-2 | ET:Liq |
| | HI (97:3) | (250 Å) | (50 Å) | sensitizer Pt27 | (50 Å) | (40:60) |
| | (100 Å) | | | (52.8:35.2:12) (350 Å) | | (310 Å) |
| Comparative | Compound | Compound | Compound | Compound P-22:Compound | Compound | Compound |
| Example 2 | HT:Compound | HT | P-21 | N-1-15:Compound BN-BD-2 | N-3-2 | ET:Liq |
| | HI (97:3) | (250 Å) | (50 Å) | (59.4:28.6:12) (350 Å) | (50 Å) | (40:60) |
| | (100 Å) | | | | | (310 Å) |

The structure of the new material used in the devices is as follows:

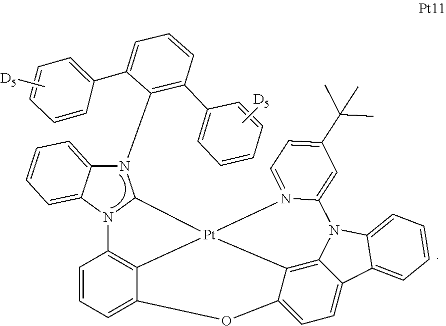

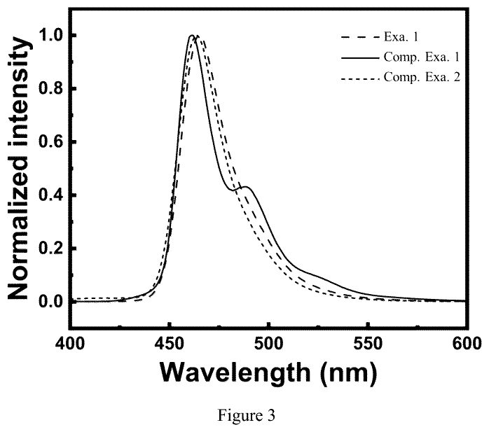

FIG. 3 is a schematic diagram of device emission spectra of Example 1, Comparative Example 1, and Comparative Example 2 after normalization treatment. As can be found from FIG. 3, the emission spectra of Example 1 and Comparative Example 2 substantially overlap, which indicates that in Device Example 1, the thermally activated delayed fluorescent compound BN-BD-2 is used as an emissive material, rather than the phosphorescent sensitizer Pt27.

The CIE value, maximum emission wavelength (λₘₐₓ), full width at half maximum (FWHM), and external quantum efficiency (EQE) of each of Examples 1 to 4 and Comparative Examples 1 to 2 were measured at 10 mA/cm². The related data are shown in Table 6.

TABLE 6
Device data

| | | λₘₐₓ | FWHM | EQE |
|---|---|---|---|---|
| Device ID | CIE (x, y) | [nm] | [nm] | (%) |
| Example 1 | 0.125, 0.116 | 465 | 27.8 | 20.04 |
| Example 2 | 0.125, 0.119 | 466 | 28.0 | 18.68 |
| Example 3 | 0.125, 0.120 | 465 | 27.8 | 19.16 |
| Example 4 | 0.125, 0.122 | 465 | 27.8 | 18.52 |
| Comparative | 0.132, 0.139 | 461 | 22.0 | 17.51 |
| Example 1 | | | | |
| Comparative | 0.129, 0.095 | 464 | 26.9 | 6.65 |
| Example 2 | | | | |

Examples 1 to 4 and Comparative Example 2 all use the thermally activated delayed fluorescent compound BN-BD-2 as the emissive material, and Comparative Example 2 is a normal TADF device with no phosphorescent sensitizer used. Compared with Comparative Example 2, Examples 1 to 4 can maintain narrow full widths at half maximum which are substantially equivalent to the full width at half maximum of Comparative Example 2 in terms of full width at half maximum, and more importantly, the EQEs of Examples 1 to 4 are greatly improved by 178% to 201%. Comparative Example 1 is a blue phosphorescent device and has great advantages over the normal TADF device in terms of full width at half maximum and EQE, and although the full widths at half maximum of Examples 1 to 4 are slightly wider than the full width at half maximum of Comparative Example 1, the EQEs of Examples 1 to 4 are further improved compared with the EQE of Comparative Example 1, which is very rare. As can be seen, when a device is prepared by using the composition of the present disclosure, not only the cost and complexity of the evaporation process can be reduced, but also more excellent device performance with a narrow full width at half maximum and high external quantum efficiency can be obtained, compared with the normal TADF device and the blue phosphorescent device. Therefore, it is proved that the composition of the present disclosure can obtain excellent device performance when the composition is applied to an organic electroluminescent device.

In addition, Example 1 and Example 2 use the phosphorescent sensitizer Pt27 and the premixes which have the same three component materials but are different in the ratio of the first host compound to the second host compound, and both Example 1 and Example 2 show excellent device performance, which indicates that the first host compound and the second host compound in the three-component premix included in the composition of the present disclosure can be mixed in different ratios, and the resulting premix has high evaporation stability and thus shows excellent device performance. Example 2 and Example 4 use another phosphorescent sensitizer Pt11 and also achieve excellent device performance, which indicates that the premix included in the composition of the present disclosure can also have good adaptability to different phosphorescent sensitizers.

### Green Organic Electroluminescent Device

### Device Example 5

First, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially evaporated through vacuum thermal evaporation on the ITO anode at a rate of 0.2 Å/s to 2 Å/s and at a vacuum degree of about 107 Torr. Compound HT and Compound HT1 were co-evaporated as a hole injection layer (HIL) with a thickness of 100 Å, wherein the weight ratio of Compound HT to Compound HT1 was 3:97. Compound HT1 was evaporated as a hole transport layer (HTL) with a thickness of 350 Å. Compound PH-1 was evaporated as an electron blocking layer (EBL) with a thickness of 50 Å. Then, the premix PM7 (the weight ratio among the compound PH-24, the compound NH-144, and the compound BN-GD-12 was 73.5:24.5:2) was placed in an evaporation source 1, the phosphorescent sensitizer GD100 was placed in an evaporation source 2, and the premix PM7 and the phosphorescent sensitizer GD100 were co-evaporated as an emissive layer (EML) with a thickness of 400 Å, wherein the weight ratio of the premix PM7 to the phosphorescent sensitizer GD100 was 94:6. Compound N-4-1 was evaporated as a hole blocking layer (HBL) with a thickness of 50 Å. On the hole blocking layer, Compound ET and 8-hydroxyquinolinolato-lithium (Liq) were co-evaporated as an electron transport layer (ETL) with a thickness of 350 Å, wherein the weight ratio of Compound ET to Liq was 40:60. Finally, LiF with a thickness of 10 Å was evaporated as an electron injection layer, and aluminum with a thickness of 1200 Å was evaporated as a cathode. The device was transferred back to the glovebox and encapsulated with a glass lid and a moisture absorbent to complete the device.

### Device Example 6

The implementation mode of Device Example 6 was the same as the implementation mode of Device Example 5 except that the premix PM7 was substituted with the premix PM8 (the weight ratio among Compound PH-24, Compound NH-144, and Compound BN-GD-12 was 74.25:24.75:1) in the emissive layer (EML).

### Device Example 7

The implementation mode of Device Example 7 was the same as the implementation mode of Device Example 5 except that the premix PM7 was substituted with the premix PM9 (the weight ratio among Compound PH-1, Compound NH-45, and Compound BN-GD-12 was 68.6:29.4:2) in the emissive layer (EML).

### Device Example 8

The implementation mode of Device Example 8 was the same as the implementation mode of Device Example 5 except that the premix PM7 was substituted with the premix PM10 (the weight ratio among Compound PH-51, Compound NH-147, and Compound BN-GD-12 was 68.6:29.4:2) in the emissive layer (EML).

### Device Comparative Example 3

The implementation mode of Device Comparative Example 3 was the same as the implementation mode of Device Example 5 except that Compound PH-24, Compound NH-144, Compound BN-GD-12, and the phosphorescent sensitizer GD100 were placed into four different evaporation sources and co-evaporated as an emissive layer (EML) with a thickness of 400 Å, wherein the weight ratio among Compound PH-24, Compound NH-144, Compound BN-GD-12, and the phosphorescent sensitizer GD100 was 69:23:2:6.

### Device Comparative Example 4

The implementation mode of Device Comparative Example 4 was the same as the implementation mode of Device Example 6 except that Compound PH-24, Compound NH-144, Compound BN-GD-12, and the phosphorescent sensitizer GD100 were placed into four different evaporation sources and co-evaporated as an emissive layer (EML) with a thickness of 400 Å, wherein the weight ratio among Compound PH-24, Compound NH-144, Compound BN-GD-12, and the phosphorescent sensitizer GD100 was 69.75:23.25:1:6.

### Device Comparative Example 5

The implementation mode of Device Comparative Example 5 was the same as the implementation mode of Device Example 7 except that Compound PH-1, Compound NH-45, Compound BN-GD-12, and the phosphorescent sensitizer GD100 were placed into four different evaporation sources and co-evaporated as an emissive layer (EML) with a thickness of 400 Å, wherein the weight ratio among Compound PH-1, Compound NH-45, Compound BN-GD-12, and the phosphorescent sensitizer GD100 was 64.4:27.6:2:6.

### Device Comparative Example 6

The implementation mode of Device Comparative Example 6 was the same as the implementation mode of Device Example 8 except that the comparative premix C-PM1 (the weight ratio of Compound PH-51 to Compound NH-147 was 70:30), Compound BN-GD-12, and the phosphorescent sensitizer GD100 were placed into three different evaporation sources and co-evaporated as an emissive layer (EML) with a thickness of 400 Å, wherein the weight ratio among the comparative premix C-PM1, Compound BN-GD-12, and the phosphorescent sensitizer GD100 was 92:2:6.

The structures and thicknesses of part of layers of the devices in Device Examples 5 to 8 and Device Comparative Examples 3 to 6 are shown in Table 7 below. A layer using more than one material was obtained by doping different compounds in their mass ratio as recorded.

TABLE 7
Part of device structures in Device Examples and Device Comparative Examples

| Device ID | HIL | HTL | EBL | EML | HBL | ETL |
|---|---|---|---|---|---|---|
| Example 5 | Compound | Compound | Compound | Premix | Compound | Compound |
| | HT1:Compound | HT1 | PH-1 | PM7:Phosphorescent | N-4-1 | ET:Liq |
| | HI (97:3) | (350 Å) | (50 Å) | sensitizer GD100 | (50 Å) | (40:60) |
| | (100 Å) | | | (94:6) (400 Å) | | (350 Å) |
| Example 6 | Compound | Compound | Compound | Premix | Compound | Compound |
| | HT1:Compound | HT1 | PH-1 | PM8:Phosphorescent | N-4-1 | ET:Liq |
| | HI (97:3) | (350 Å) | (50 Å) | sensitizer GD100 | (50 Å) | (40:60) |
| | (100 Å) | | | (94:6) (400 Å) | | (350 Å) |
| Example 7 | Compound | Compound | Compound | Premix | Compound | Compound |
| | HT1:Compound | HT1 | PH-1 | PM9:Phosphorescent | N-4-1 | ET:Liq |
| | HI (97:3) | (350 Å) | (50 Å) | sensitizer GD100 | (50 Å) | (40:60) |
| | (100 Å) | | | (94:6) (400 Å) | | (350 Å) |
| Example 8 | Compound | Compound | Compound | Premix | Compound | Compound |
| | HT1:Compound | HT1 | PH-1 | PM10:Phosphorescent | N-4-1 | ET:Liq |
| | HI (97:3) | (350 Å) | (50 Å) | sensitizer GD100 | (50 Å) | (40:60) |
| | (100 Å) | | | (94:6) (400 Å) | | (350 Å) |
| Comparative | Compound | Compound | Compound | Compound PH-24:Compound | Compound | Compound |
| Example 3 | HT1:Compound | HT1 | PH-1 | NH-144:Compound | N-4-1 | ET:Liq |
| | HI (97:3) | (350 Å) | (50 Å) | BN-GD-12:Phosphorescent | (50 Å) | (40:60) |
| | (100 Å) | | | sensitizer GD100 | | (350 Å) |
| | | | | (69:23:2:6) (400 Å) | | |
| Comparative | Compound | Compound | Compound | Compound PH-24:Compound | Compound | Compound |
| Example 4 | HT1:Compound | HT1 | PH-1 | NH-144:Compound | N-4-1 | ET:Liq |
| | HI (97:3) | (350 Å) | (50 Å) | BN-GD-12:Phosphorescent | (50 Å) | (40:60) |
| | (100 Å) | | | sensitizer GD100 | | (350 Å) |
| | | | | (69.75:23.25:1:6) (400 Å) | | |
| Comparative | Compound | Compound | Compound | Compound PH-1:Compound | Compound | Compound |
| Example 5 | HT1:Compound | HT1 | PH-1 | NH-45:Compound | N-4-1 | ET:Liq |
| | HI (97:3) | (350 Å) | (50 Å) | BN-GD-12:Phosphorescent | (50 Å) | (40:60) |
| | (100 Å) | | | sensitizer GD100 | | (350 Å) |
| | | | | (64.4:27.6:2:6) (400 Å) | | |
| Comparative | Compound | Compound | Compound | Comparative premix | Compound | Compound |
| Example 6 | HT1:Compound | HT1 | PH-1 | C-PM1:Compound | N-4-1 | ET:Liq |
| | HI (97:3) | (350 Å) | (50 Å) | BN-GD-12:Phosphorescent | (50 Å) | (40:60) |
| | (100 Å) | | | sensitizer GD100 | | (350 Å) |
| | | | | (92:2:6) (400 Å) | | |

The structures of new materials used in the devices are as follows:

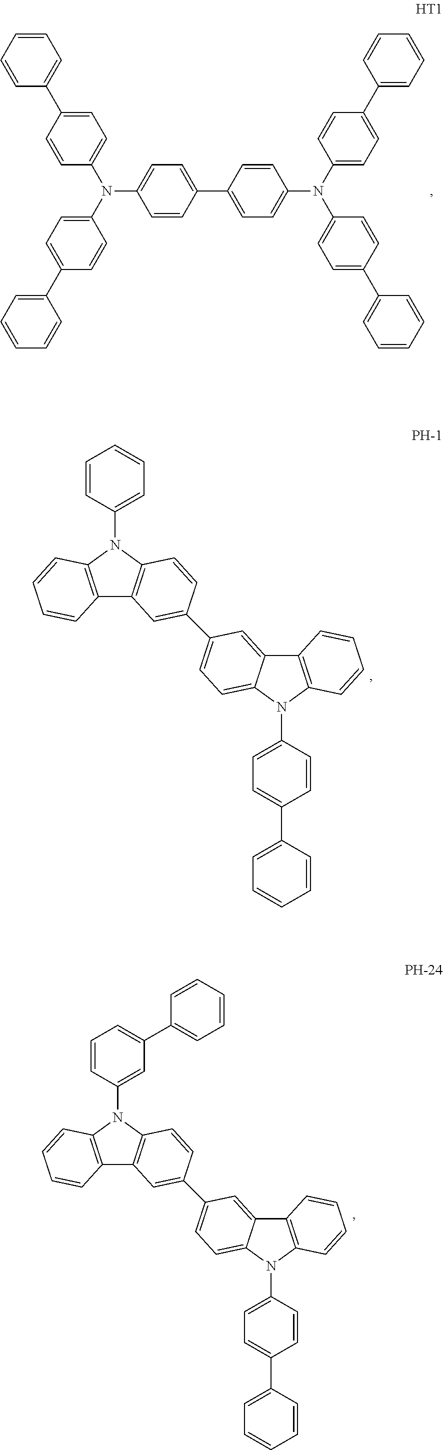 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

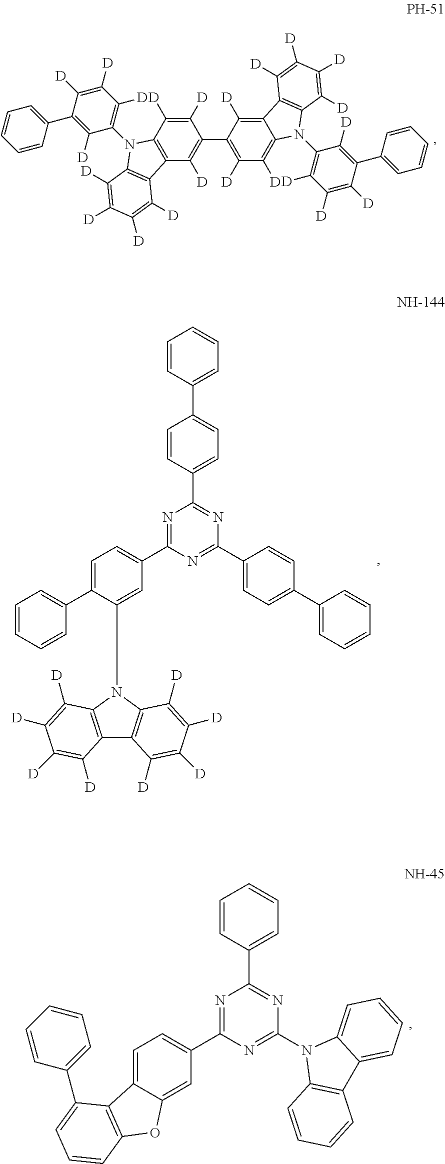 [SMILES: [2H]c1c([2H])c(-c2ccccc2)c([2H])c(-n2c3c([2H])c([2H])c([2H])c([2H])c3c3c([2H])c(-c4c([2H])c([2H])c5c(c4[2H])c4c([2H])c([2H])c([2H])c([2H])c4n5-c4c([2H])c([2H])c([2H])c(-c5ccccc5)c4[2H])c([2H])c([2H])c32)c1[2H] ; [2H]c1c([2H])c([2H])c2c(c1[2H])c1c([2H])c([2H])c([2H])c([2H])c1n2-c1cc(-c2nc(-c3ccc(-c4ccccc4)cc3)nc(-c3ccc(-c4ccccc4)cc3)n2)ccc1-c1ccccc1 ; c1ccc(-c2nc(-c3ccc4c(c3)oc3cccc(-c5ccccc5)c34)nc(-n3c4ccccc4c4ccccc43)n2)cc1]

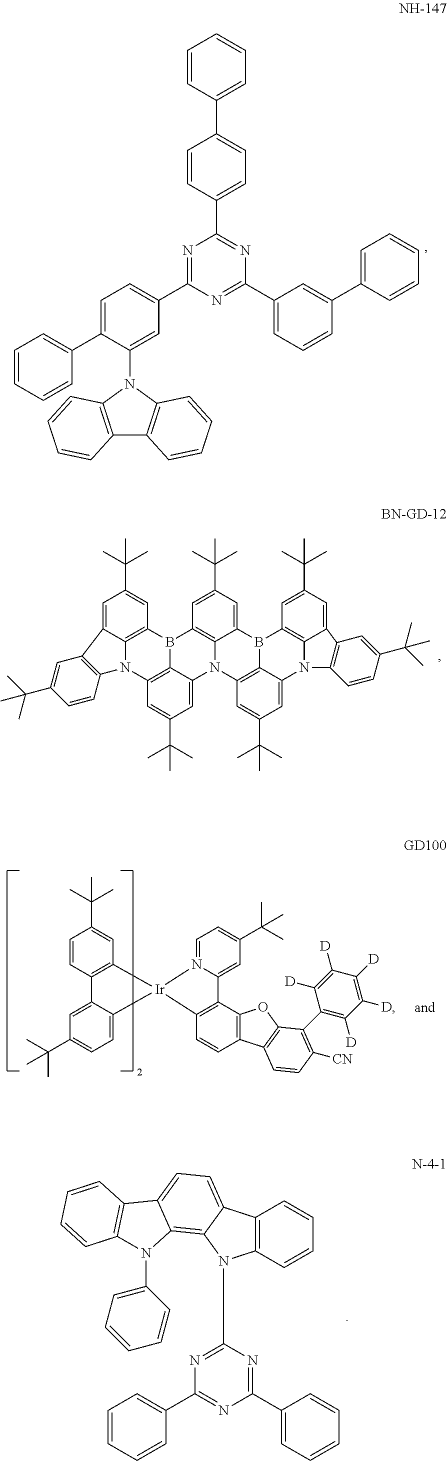

The CIE value, maximum emission wavelength (λₘₐₓ), full width at half maximum (FWHM), and external quantum efficiency (EQE) of each of Device Examples 5 to 8 and Device Comparative Examples 3 to 6 were measured at 15 mA/cm², and the lifetime LT97 (h) of each of Device Examples 5 to 8 and Device Comparative Examples 3 to 6 was measured at 80 mA/cm², wherein the LT97 is the time for the brightness of the device to decay to 97% of the initial brightness. The related data are shown in Table 8.

TABLE 8
Device data

| | CIE | λₘₐₓ | FWHM | EQE | LT97 |
|---|---|---|---|---|---|
| Device ID | (x, y) | [nm] | [nm] | (%) | (h) |
| Example 5 | 0.355, 0.635 | 548 | 34.0 | 25.7 | 25.5 |
| Comparative | 0.358, 0.633 | 548 | 33.7 | 25.8 | 12.7 |
| Example 3 | | | | | |
| Example 6 | 0.335, 0.648 | 543 | 38.6 | 26.3 | 26.0 |
| Comparative | 0.344, 0.644 | 546 | 34.8 | 27.2 | 20.7 |
| Example 4 | | | | | |
| Example 7 | 0.333, 0.647 | 539 | 43.2 | 25.5 | 30.8 |
| Comparative | 0.364, 0.628 | 550 | 33.6 | 24.9 | 25.5 |
| Example 5 | | | | | |
| Example 8 | 0.354, 0.636 | 548 | 34.4 | 25.7 | 16.2 |
| Comparative | 0.360, 0.631 | 549 | 34.2 | 25.1 | 12.5 |
| Example 6 | | | | | |

### Discussion

Example 5 uses a composition of the premix PM7 (Compound PH-24, Compound NH-144, and Compound BN-GD-12) and a phosphorescent sensitizer as an emissive layer, the premix is evaporated in a single evaporation source, and the phosphorescent sensitizer is evaporated in another evaporation source. Comparative Example 3 also uses Compound PH-24, Compound NH-144, Compound BN-GD-12, and a phosphorescent sensitizer as an emissive layer. The difference is that the emissive layer of Comparative Example 3 is formed by four-source co-evaporation (that is, four compounds are co-evaporated in four different evaporation sources respectively). As can be seen from the data in Table 8, Comparative Example 3 already has very high device performance; compared with Comparative Example 3, Example 5 has a narrow full width at half maximum and a high EQE, both of which are substantially equivalent to those of Comparative Example 3, and unexpectedly, the lifetime of Example 5 is greatly improved by 100%. Therefore, when a device is prepared by using the premix of the present disclosure, not only the cost and complexity of the evaporation process can be reduced, but also more excellent device performance can be obtained.

The material structures of the three components (Compound PH-24, Compound NH-144, and Compound BN-GD-12) in the premix PM8 used in Example 6 are the same as the material structures in the premix PM7, but the ratio among the three components is different. The difference between Comparative Example 4 and Example 6 lies in the number of evaporation sources. As can be seen from the data in Table 8, compared with Comparative Example 4, although the full width at half maximum of Example 6 is slightly wider and the EQE is slightly lower, the full width at half maximum and the EQE of Example 6 are still at a high level, and more importantly, the lifetime of Example 6 achieves an unexpectedly great improvement by 26%, which indicates that the first host compound, the second host compound, and the thermally activated delayed fluorescent compound in the premix of the present disclosure can be mixed in different ratios, and the resulting premix has high evaporation stability and thus shows excellent device performance.

Example 7 uses a composition of the premix PM9 (Compound PH-1, Compound NH-45, and Compound BN-GD-12) and a phosphorescent sensitizer as an emissive layer, and Comparative Example 5 also uses Compound PH-1, Compound NH-45, Compound BN-GD-12, and a phosphorescent sensitizer as an emissive layer. The difference between Example 7 and Comparative Example 5 lies in the number of evaporation sources. As can be seen from the data in Table 8, Comparative Example 5 already has very high device performance; compared with Comparative Example 5, although the full width at half maximum of Example 7 is slightly wider, the full width at half maximum of Example 7 is still at a narrow level; and more importantly, Example 7 has a high EQE which is substantially equivalent to the EQE of Comparative Example 5, and unexpectedly, the lifetime of Example 7 is greatly improved by 21%, which indicates again that when the premix of the present disclosure is applied to a device, not only the cost and complexity of the evaporation process can be reduced, but also more excellent device performance can be obtained.

In addition, Example 8 uses a composition of the premix PM10 (Compound PH-51, Compound NH-147, and Compound BN-GD-12) and a phosphorescent sensitizer as an emissive layer and uses two evaporation sources for evaporation; Comparative Example 6 uses the comparative premix C-PM1 (Compound PH-51 and Compound NH-147), Compound BN-GD-12, and a phosphorescent sensitizer as an emissive layer and uses three evaporation sources for evaporation. As can be seen from the data in Table 8, Comparative Example 6 already has very high device performance; compared with Comparative Example 6, Example 8 has a narrow full width at half maximum and a high EQE, both of which are substantially equivalent to those of Comparative Example 6, and unexpectedly, the lifetime of Example 8 is greatly improved by 30%. It can be seen that, compared with the device commonly used in the related art in which the premix having dual hosts and an emissive material are co-evaporated as an emissive layer, Example 8 of the present disclosure further reduces the number of evaporation sources, which reduces the cost and complexity of the evaporation process and can provide more excellent overall device performance. This result is beyond expected, which provides an idea for further commercial application.

In summary, in the present disclosure, the use of the composition formed by combining the specific three-component premix and the phosphorescent sensitizer to prepare a device can reduce the cost and complexity of the evaporation process, and the co-doping of the phosphorescent sensitizer and the fluorescent compound in dual hosts can achieve a good device effect of phosphor-sensitized thermally activated delayed fluorescence. Therefore, the device can maintain a narrow full width at half maximum and a high EQE, the lifetime of the device can be unexpectedly improved, the device can obtain more excellent overall performance, and broad application prospects are provided.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. A composition, comprising:
a premix and a phosphorescent sensitizer, wherein the premix comprises a first host compound, a second host compound, and a fluorescent compound;
a triplet energy level of the first host compound, a triplet energy level of the second host compound, and a triplet energy level of the phosphorescent sensitizer are higher than a triplet energy level of the fluorescent compound;
the first host compound has an evaporation temperature T1, wherein T1 ranges from 100° C. to 400° C.;
the second host compound has an evaporation temperature T2, wherein T2 ranges from 100° C. to 400° C.;
an absolute value of a difference between T1 and T2 is less than or equal to 20° C.

2. The composition of claim 1, wherein the fluorescent compound is a P-type delayed fluorescent compound or an E-type delayed fluorescent compound; and preferably, the fluorescent compound is an E-type delayed fluorescent compound.

3. The composition of claim 1, wherein T1 ranges from 150° C. to 350° C., and T2 ranges from 150° C. to 350° C.;
preferably, T1 ranges from 200° C. to 350° C., and T2 ranges from 200° C. to 350° C.

4. The composition of claim 1, wherein the fluorescent compound has an evaporation temperature T3, wherein T3 ranges from 150° C. to 400° C.; and preferably, T3 ranges from 180° C. to 350° C.

5. The composition of claim 1, wherein the absolute value of the difference between T1 and T2 is less than or equal to 10° C.

6. The composition of claim 4, wherein the absolute value of the difference between T3 and T1 or the absolute value of the difference between T3 and T2 is less than or equal to 80° C.; preferably, the absolute value of the difference between T3 and T1 or the absolute value of the difference between T3 and T2 is less than or equal to 60° C.; and more preferably, the absolute value of the difference between T3 and T1 or the absolute value of the difference between T3 and T2 is less than or equal to 50° C.

7. The composition of claim 2, wherein the E-type delayed fluorescent compound has a structure represented by Formula 1: 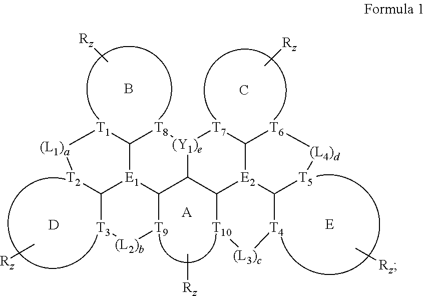
wherein in Formula 1,
the ring A, the ring B, the ring C, the ring D, and the ring E are each independently selected from an unsaturated carbocyclic ring having 5 to 30 carbon atoms or an unsaturated heterocyclic ring having 3 to 30 carbon atoms;
Y₁, E₁, and E₂ are each independently selected from B, N, P, P═S, As, As═O, As═S, SiR′ or GeR′;
T₁ to T₁₀ are each independently selected from C, CR_{z} or N;
L₁, L₂, L₃, and L₄ are, at each occurrence identically or differently, selected from a single bond, O, S, Se, BRᵥ or NRᵥ;
a, b, c, d, and e are each independently selected from 0 or 1;
R_{z} represents, at each occurrence identically or differently, mono-substitution, multiple substitutions or non-substitution;
Rᵥ, R_{z}, and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rᵥ, R_{z}, R′, and R″ can be optionally joined to form a ring.

8. The composition of claim 2, wherein the E-type delayed fluorescent compound has a structure represented by one of Formula 1-1 to Formula 1-4: 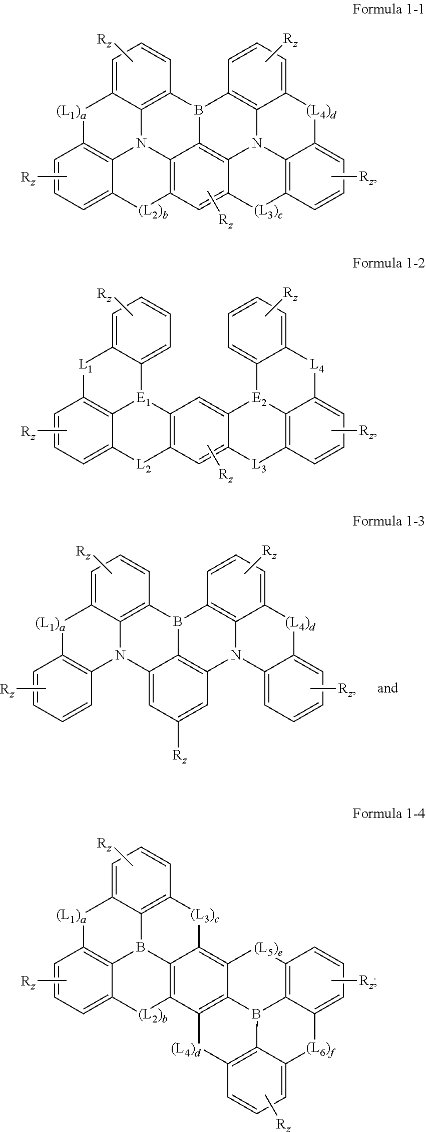
wherein
a, b, c, d, e, and f are each independently selected from 0 or 1;
E₁ and E₂ are each independently selected from B or N;
L₁, L₂, L₃, and L₄ are, at each occurrence identically or differently, selected from a single bond, O, S, BRᵥ or NRᵥ;
L₅ and L₆ are, at each occurrence identically or differently, selected from a single bond, O, S or NRᵥ;
R_{z} represents, at each occurrence identically or differently, mono-substitution, multiple substitutions or non-substitution;
Rᵥ and R_{z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rᵥ, R_{z}, and R″ can be optionally joined to form a ring.

9. The composition of claim 1, wherein the fluorescent compound is selected from the group consisting of Compound BN-BD-1 to Compound BN-BD-53, Compound BN-RD-1 to Compound BN-RD-22, Compound BN-GD-1 to Compound BN-GD-51, Compound BN-GD-53 to Compound BN-GD-63, and Compound FD-1-1 to Compound FD-1-53: 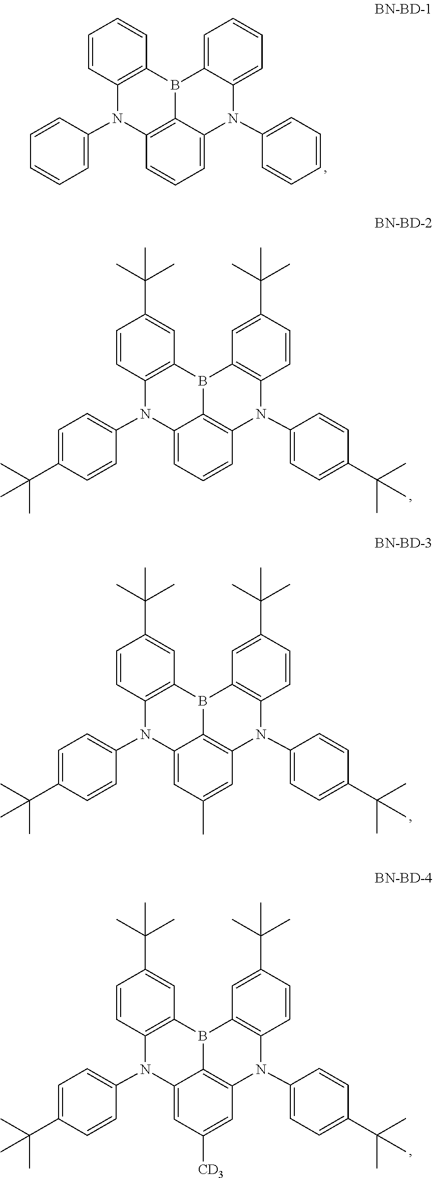 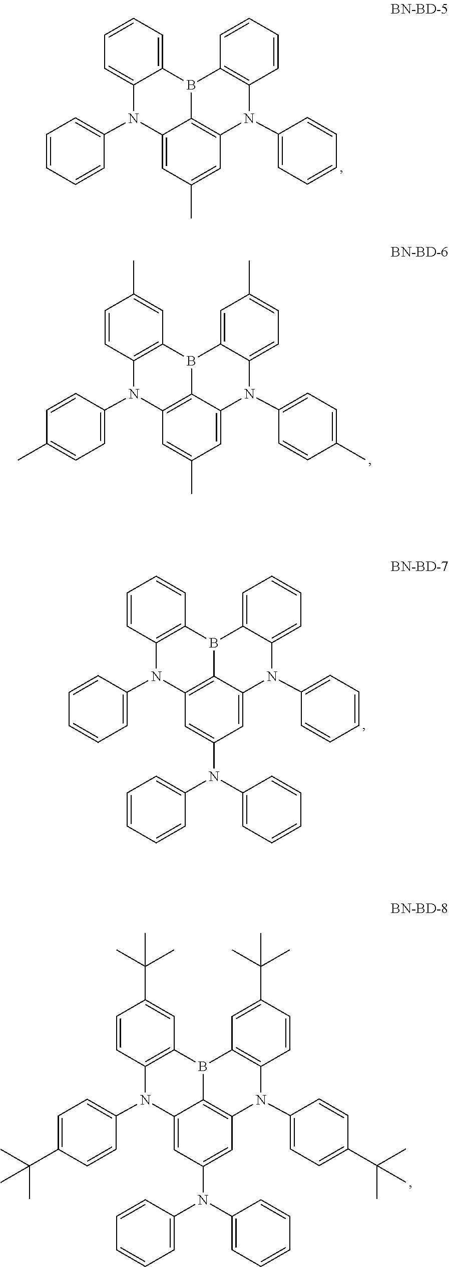 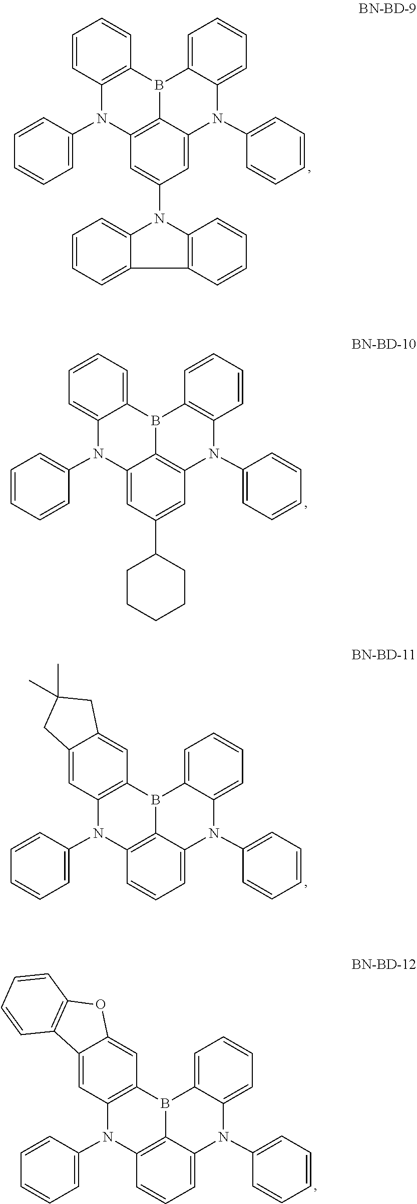 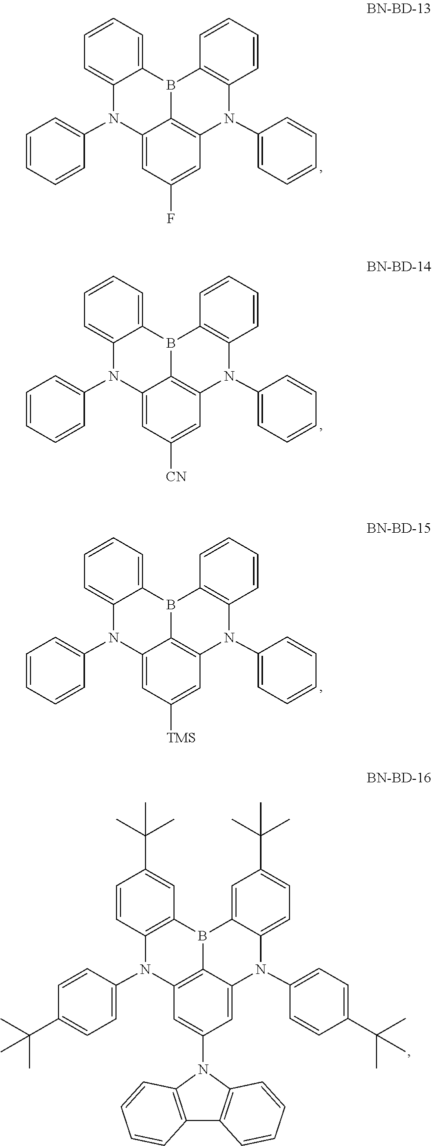 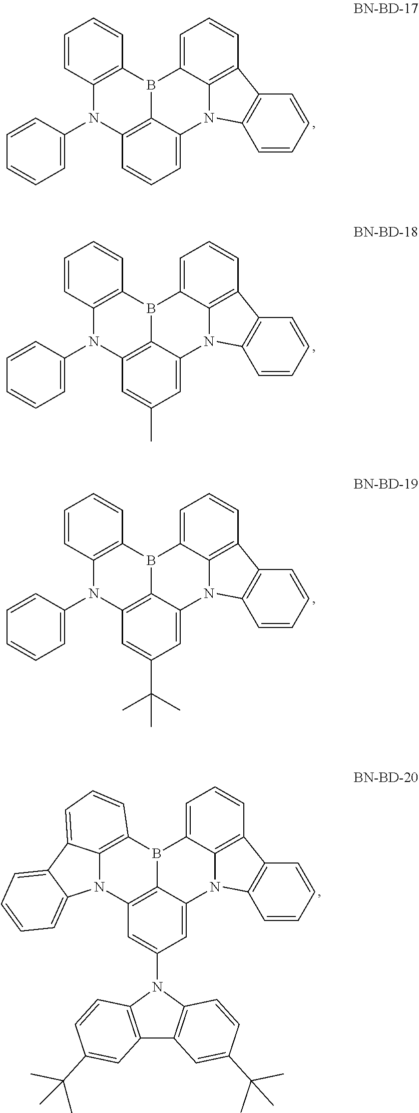 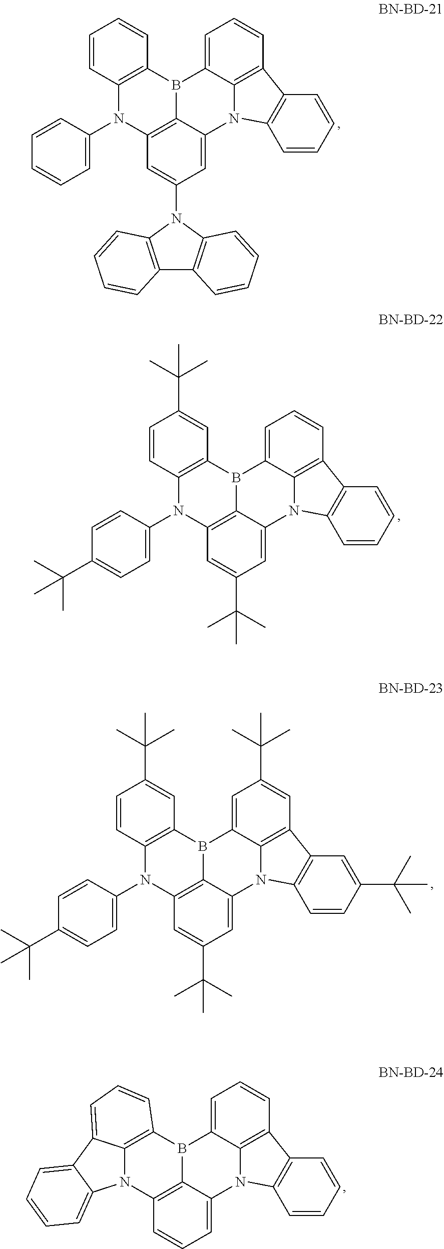 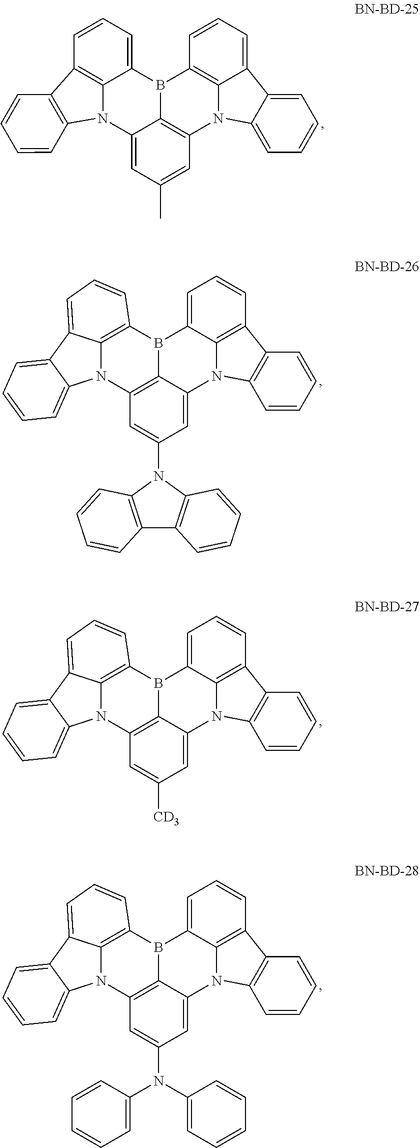 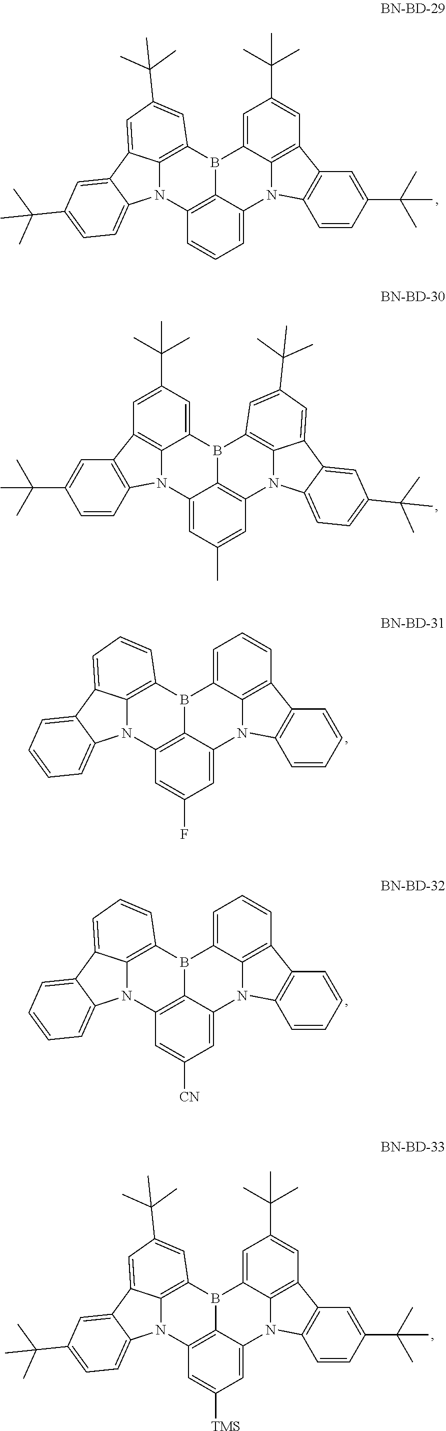 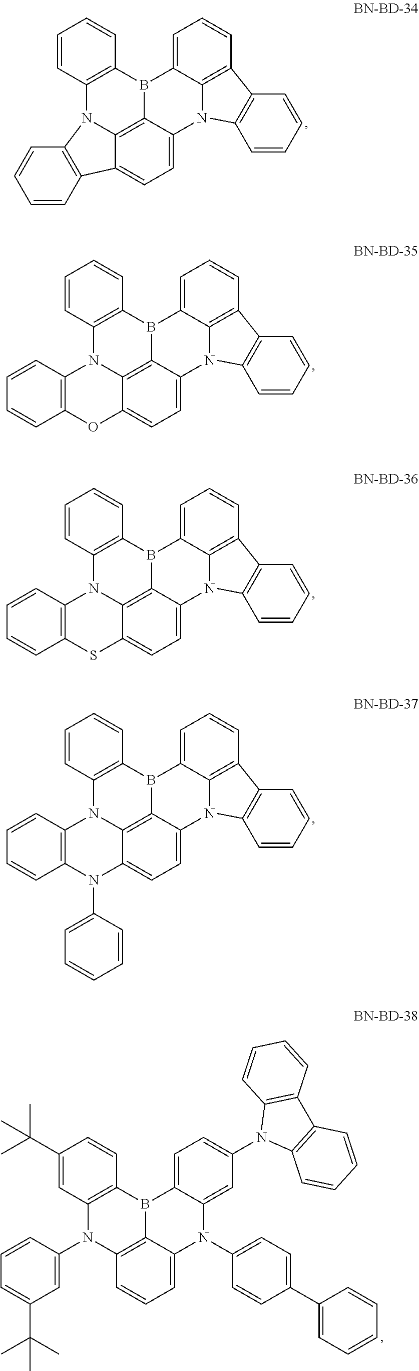 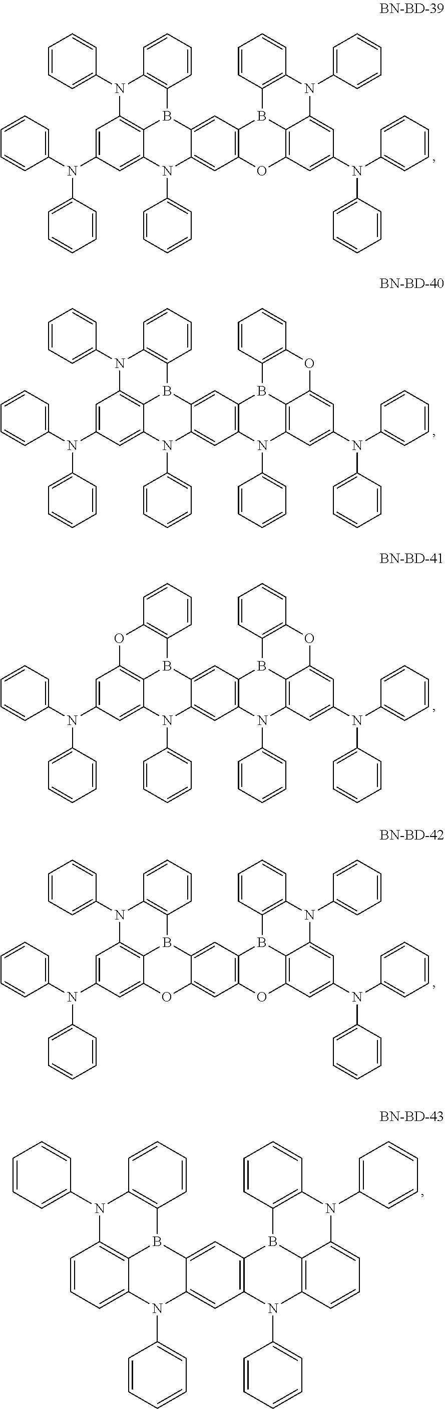 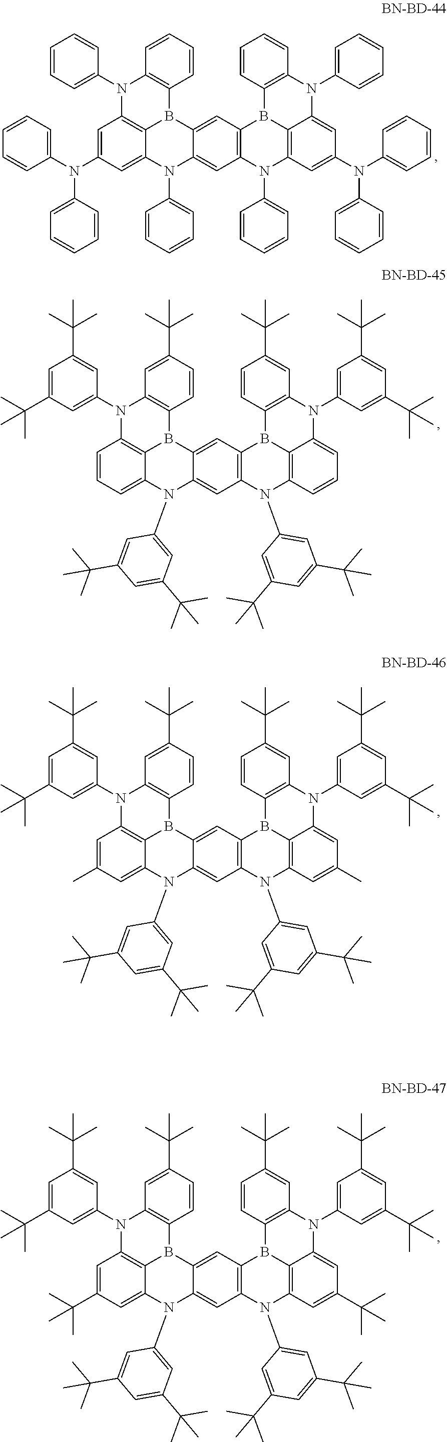 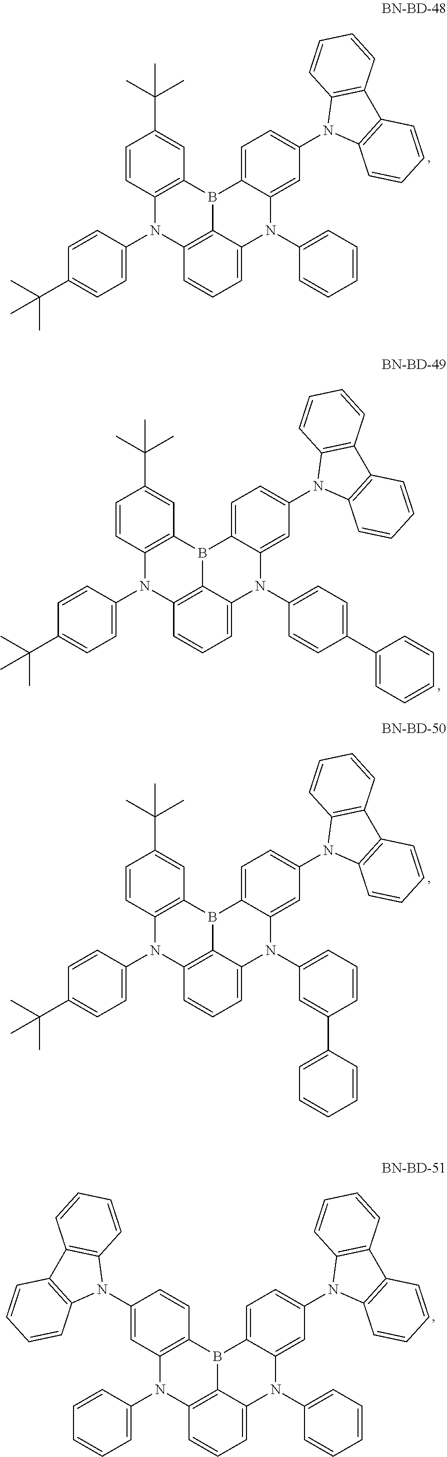 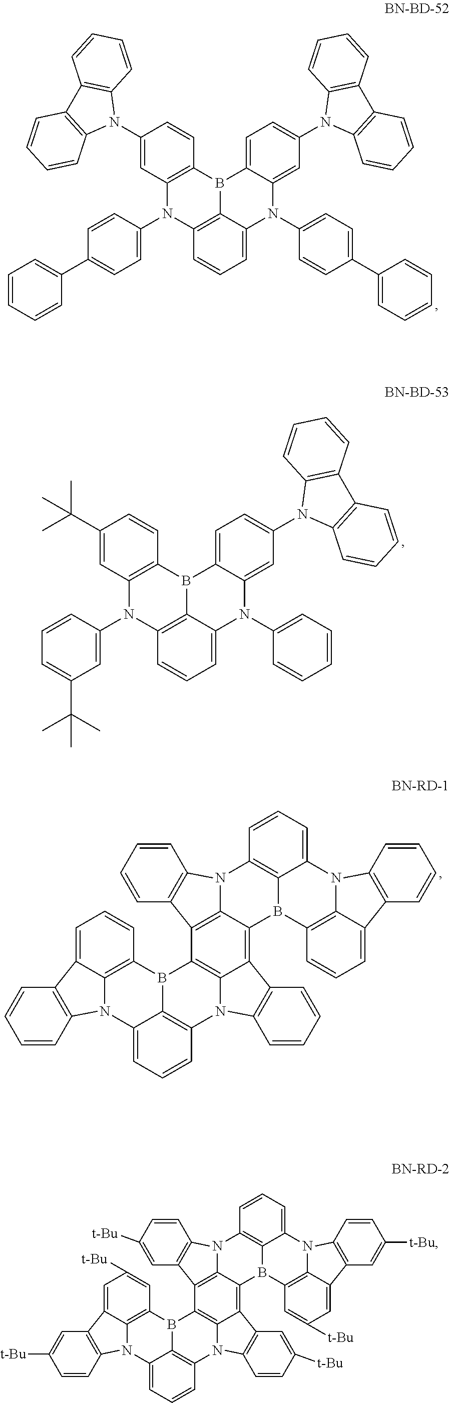 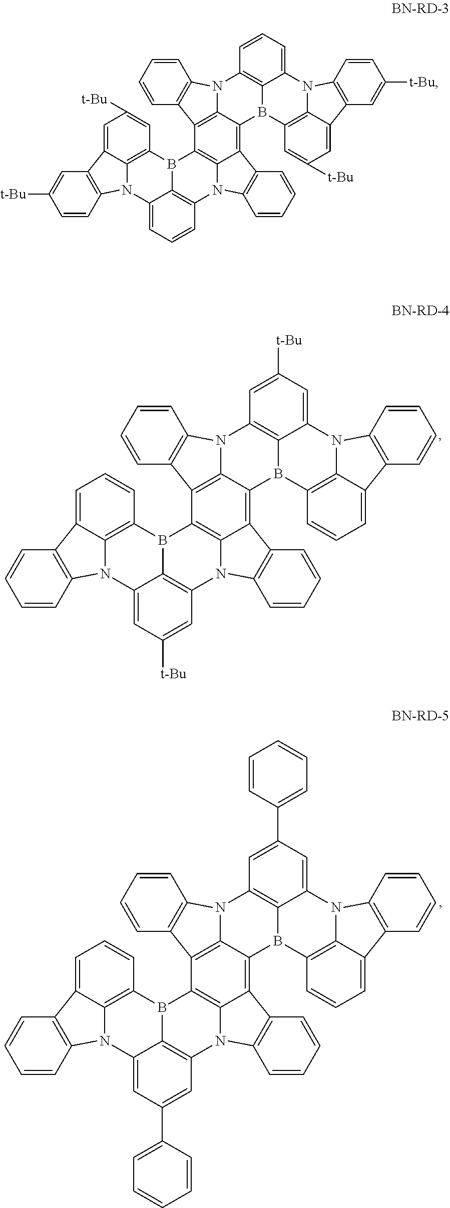 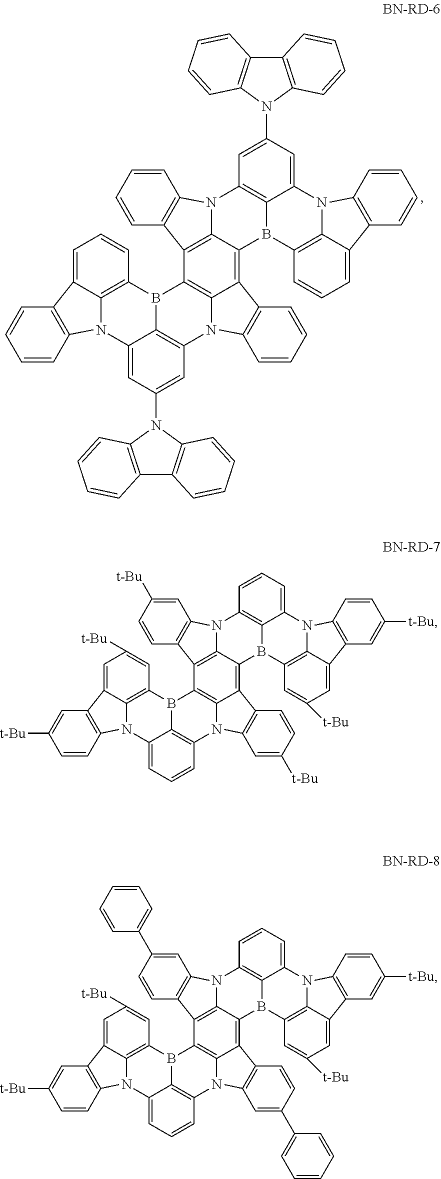 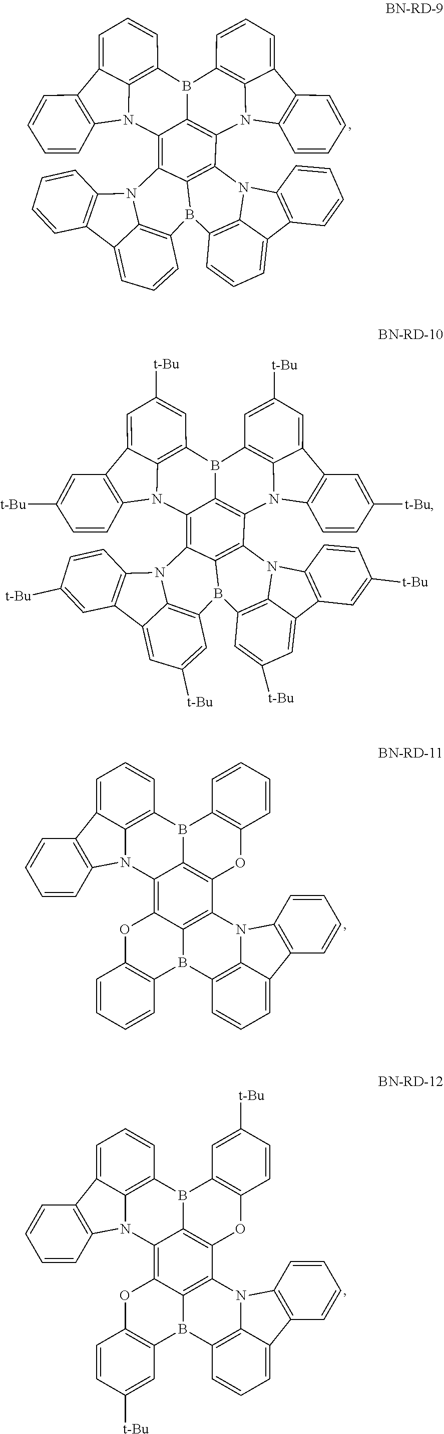 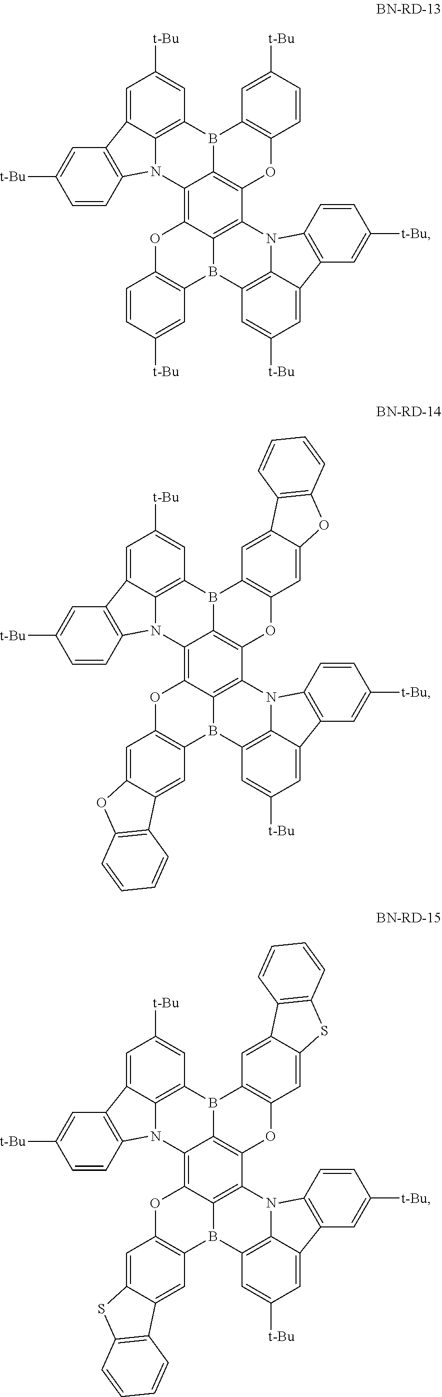 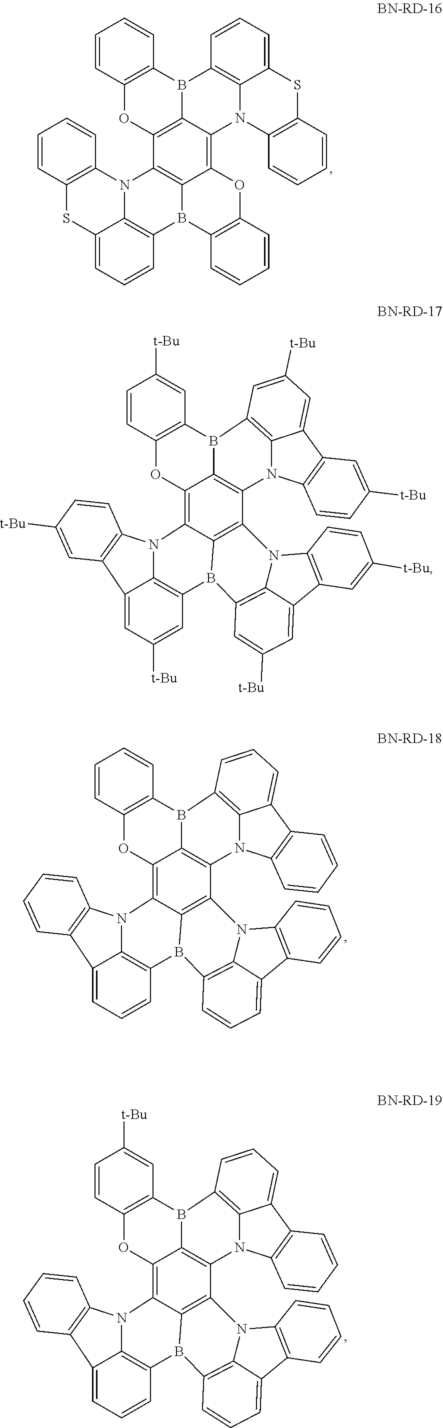 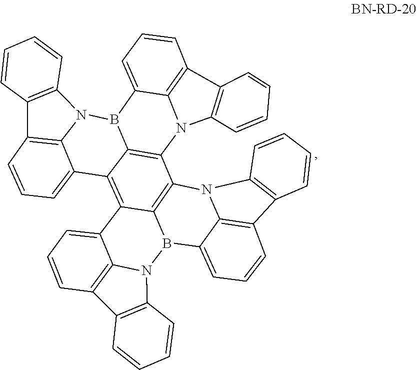 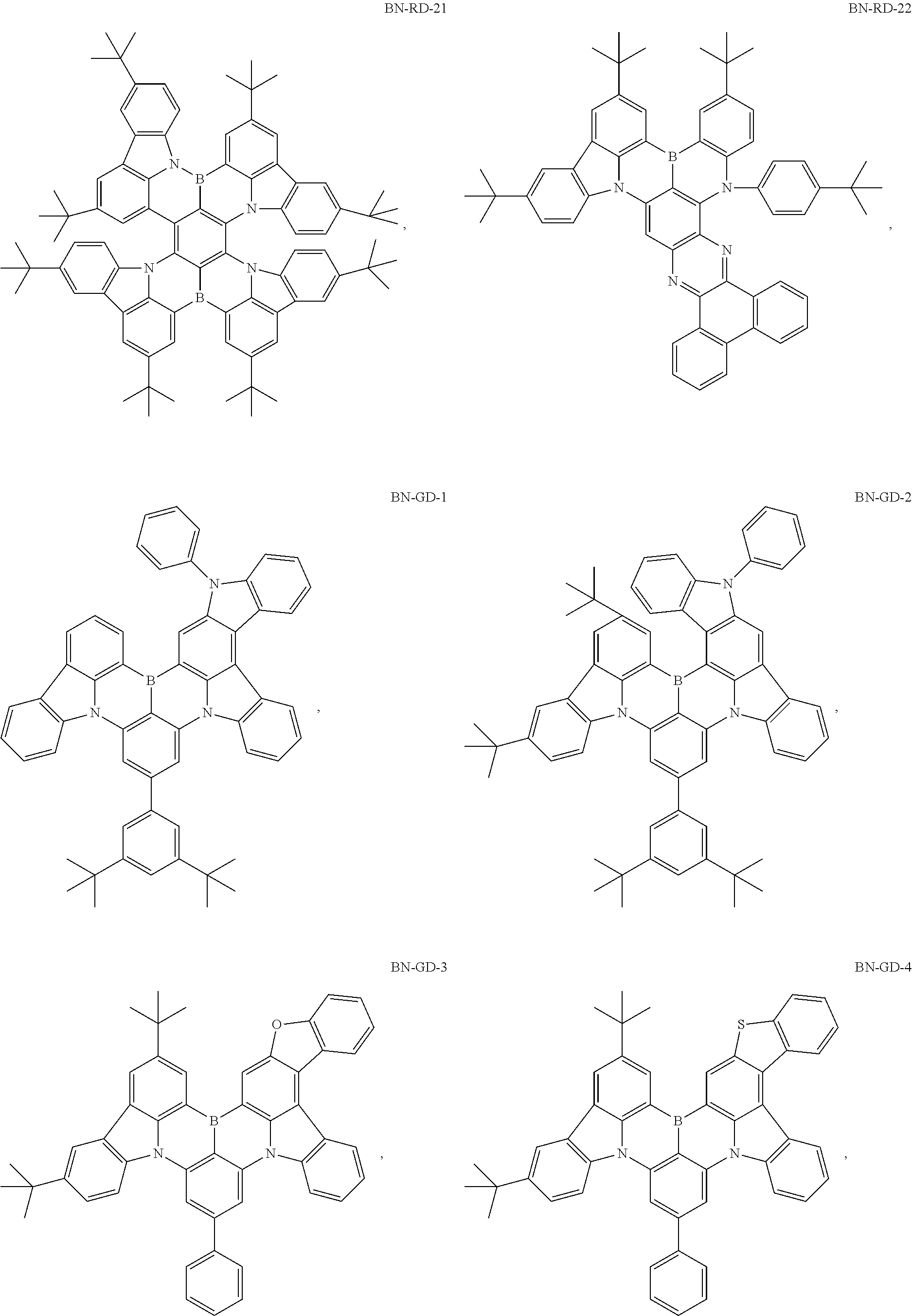 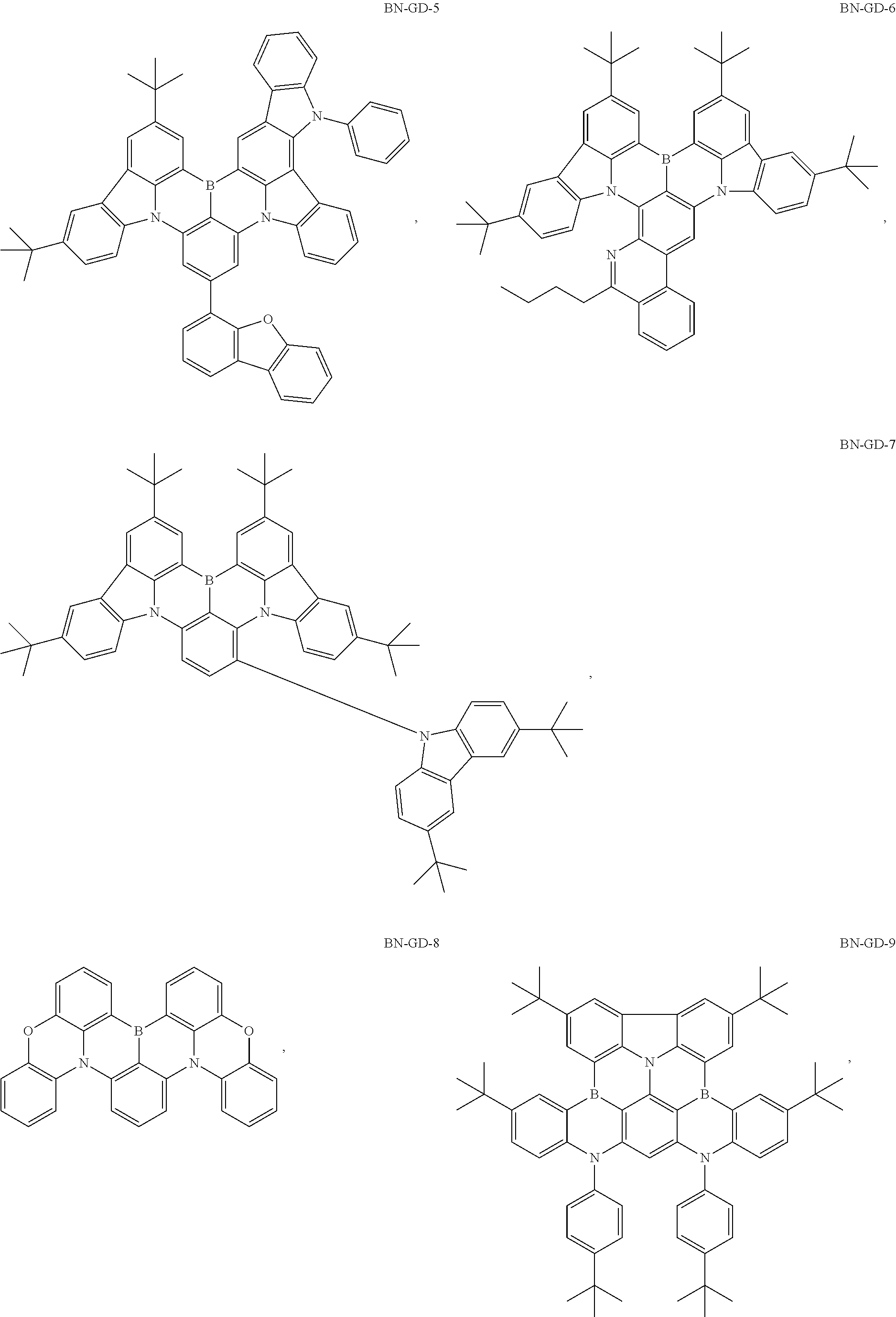 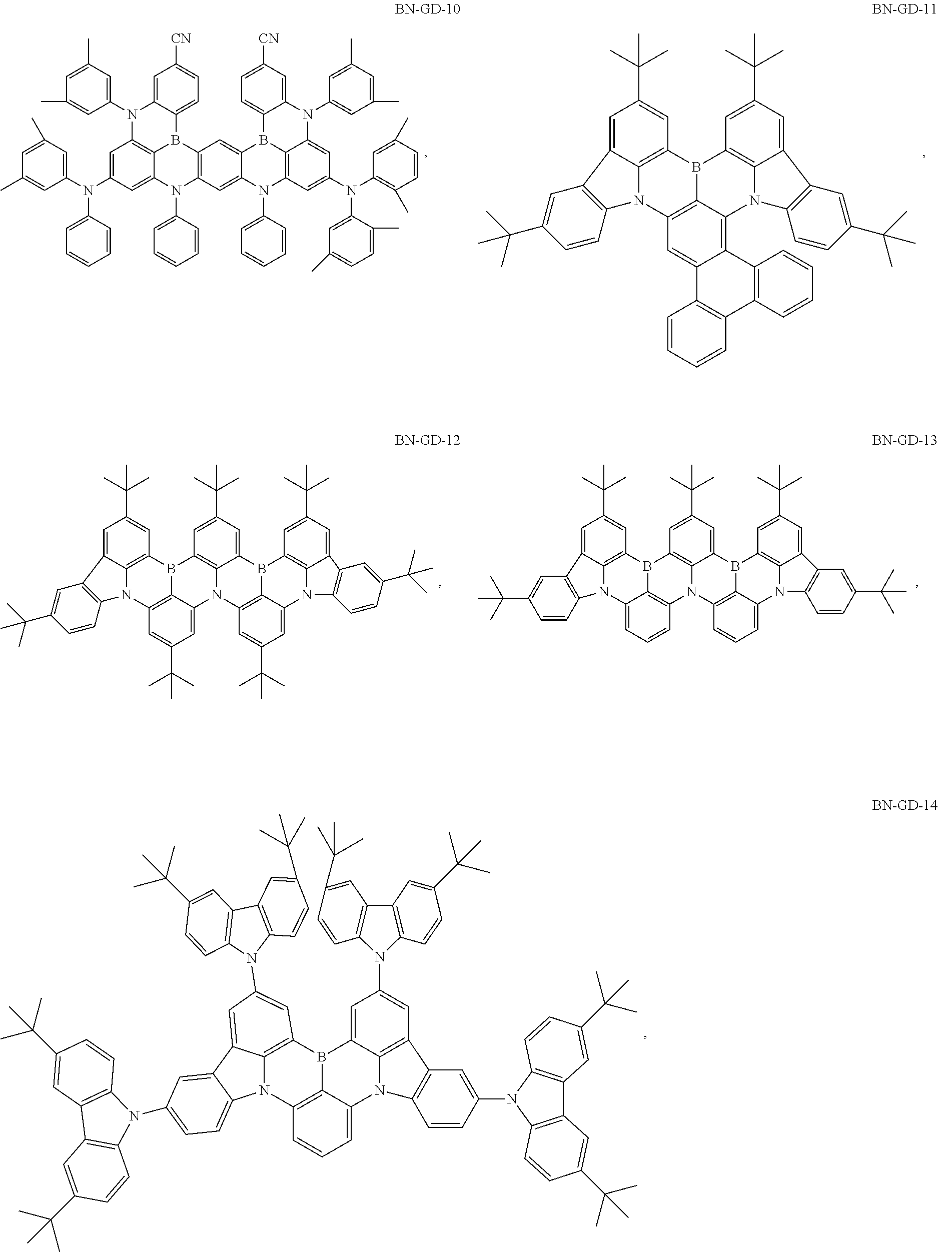 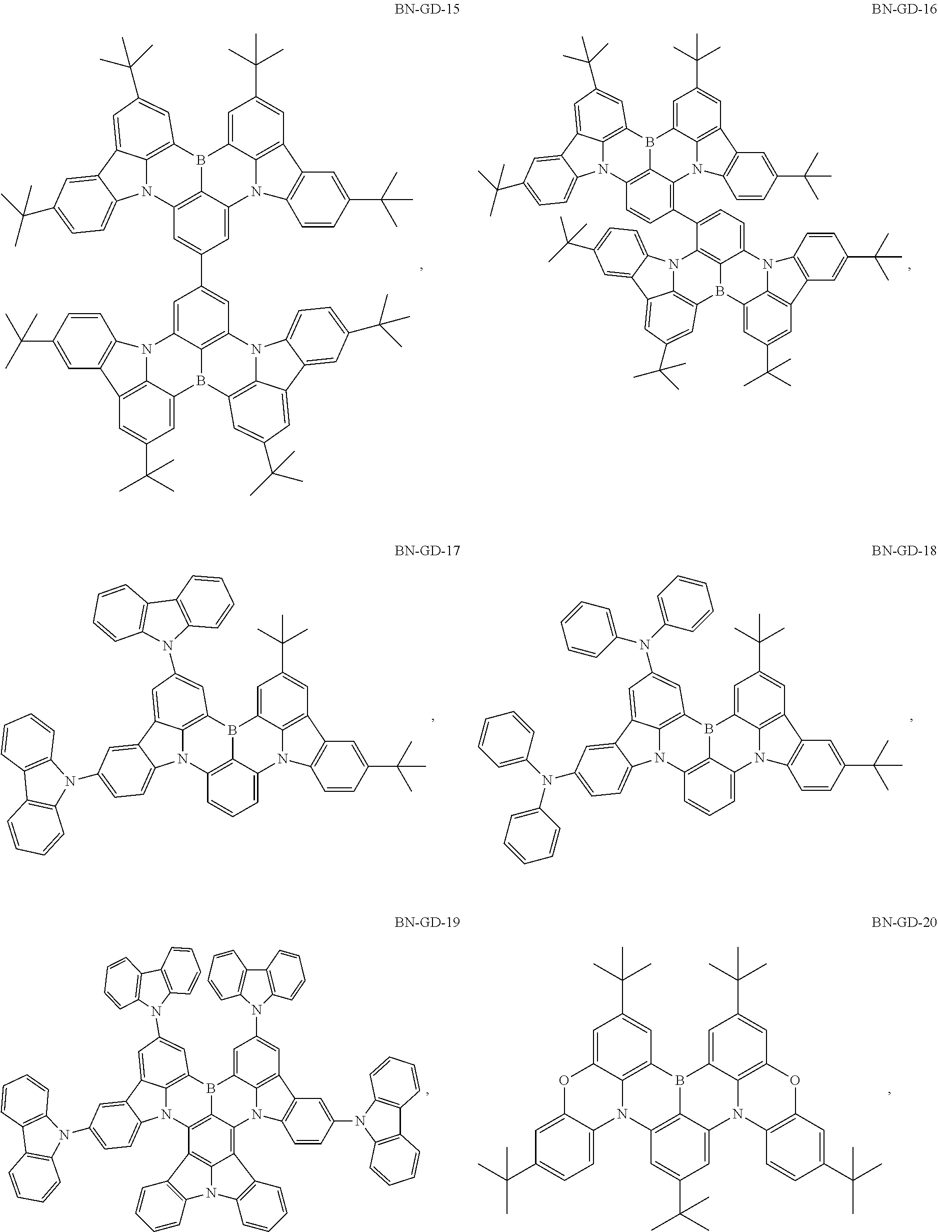 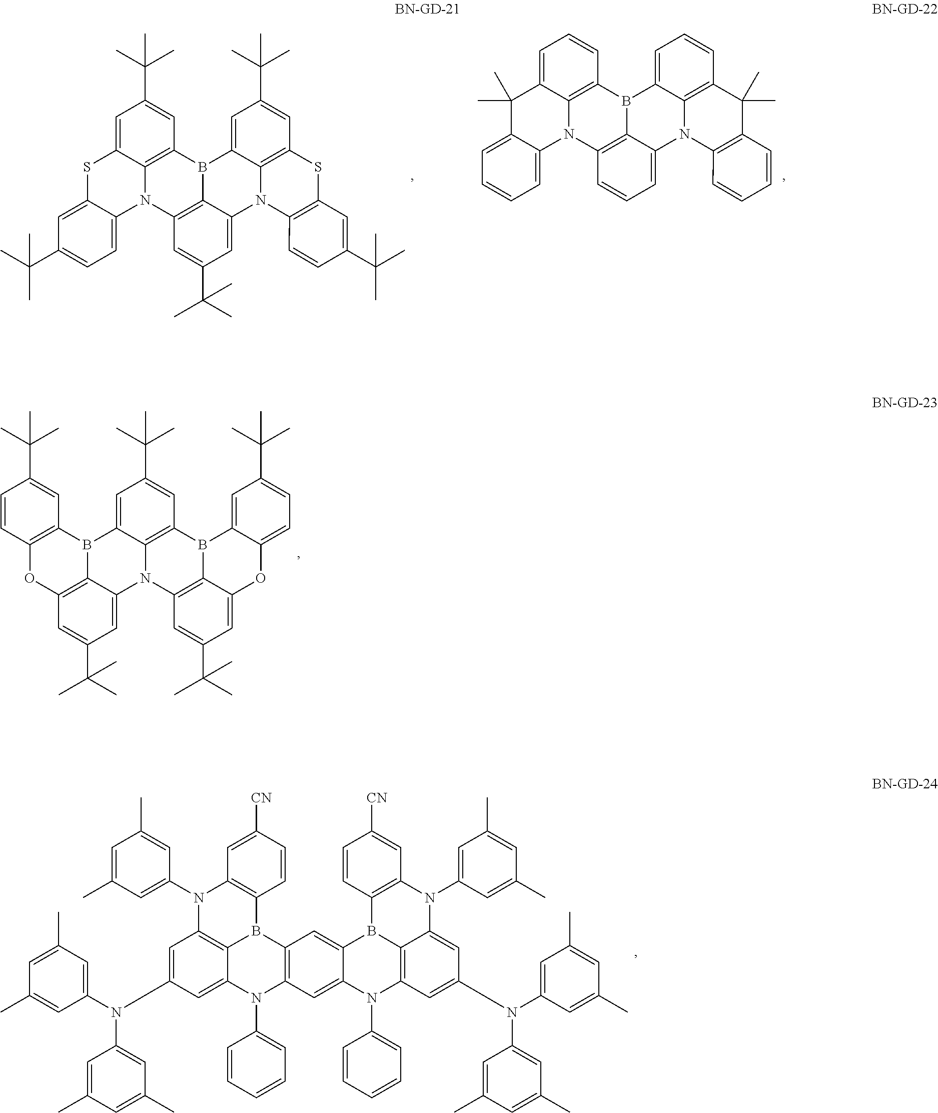 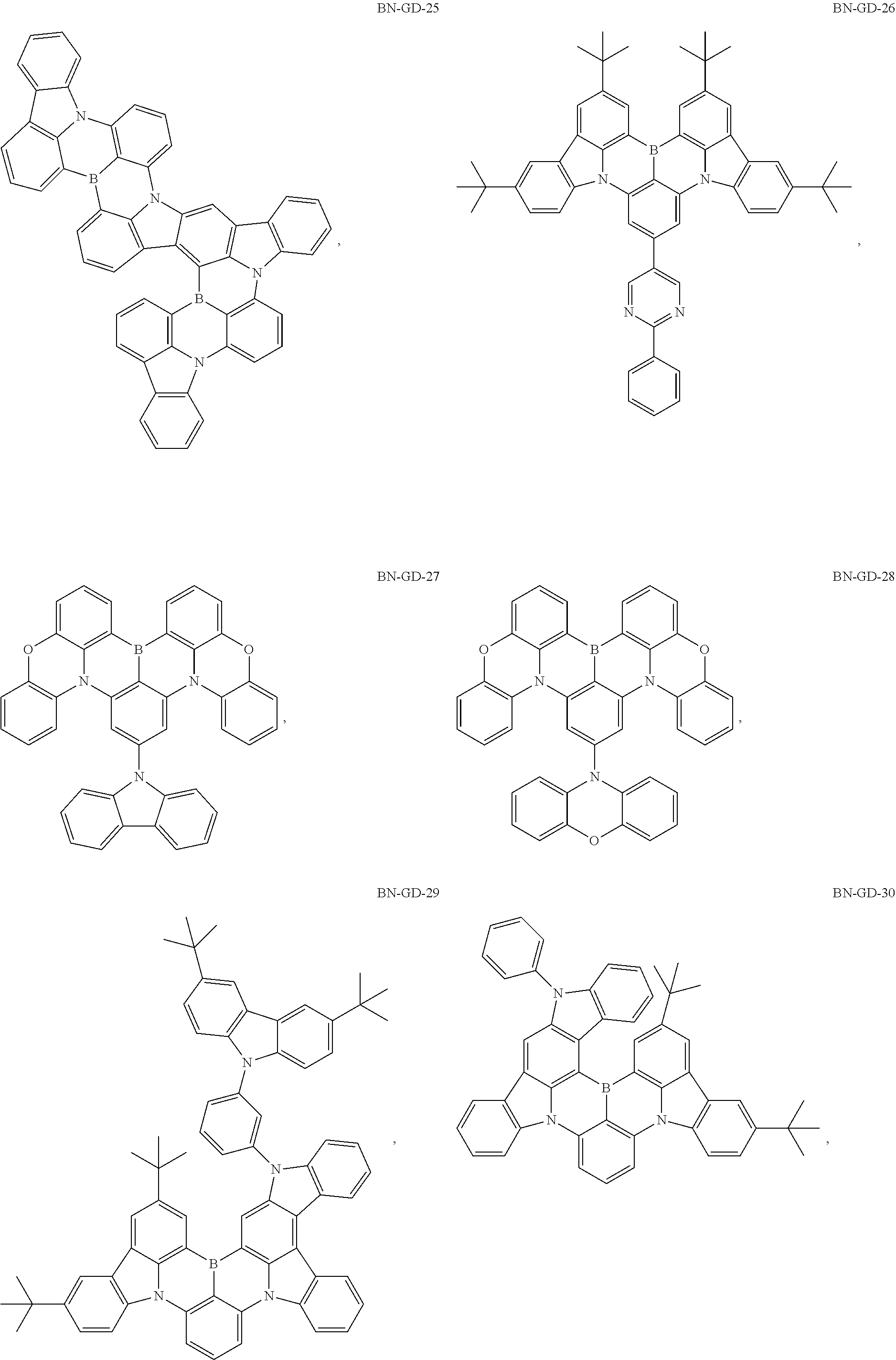 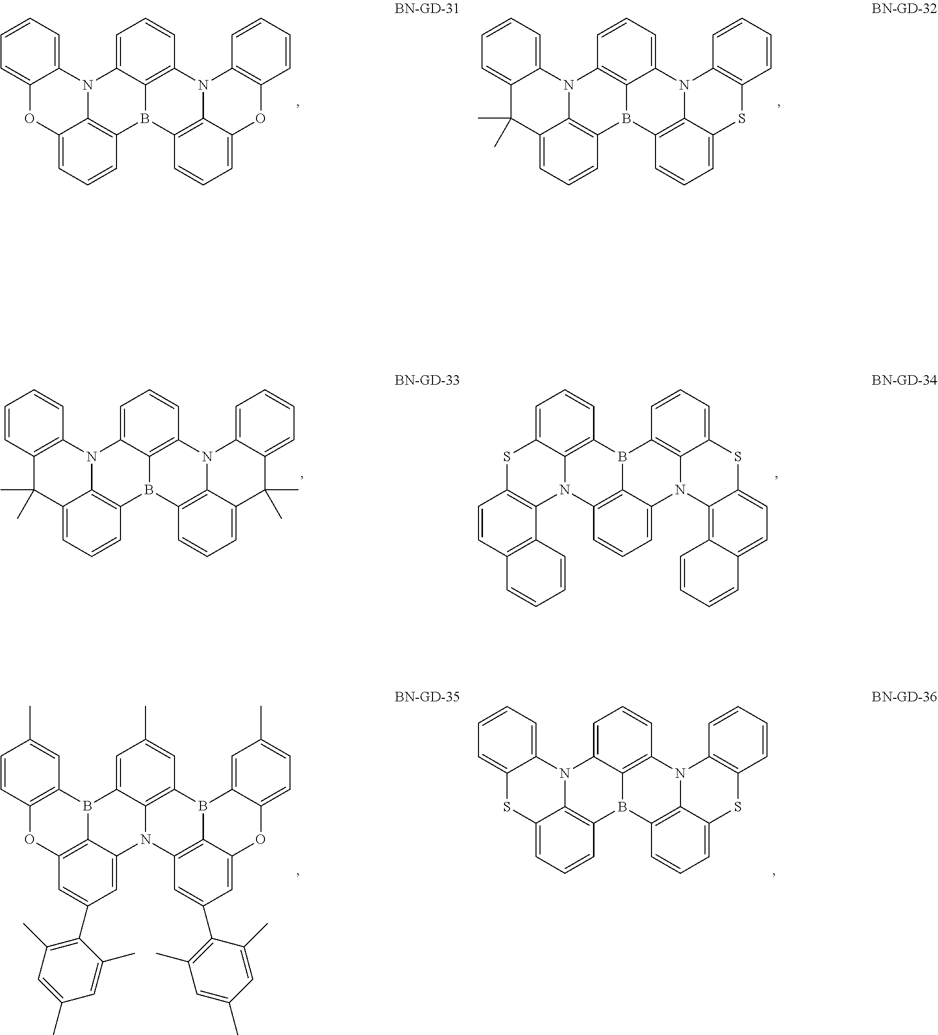 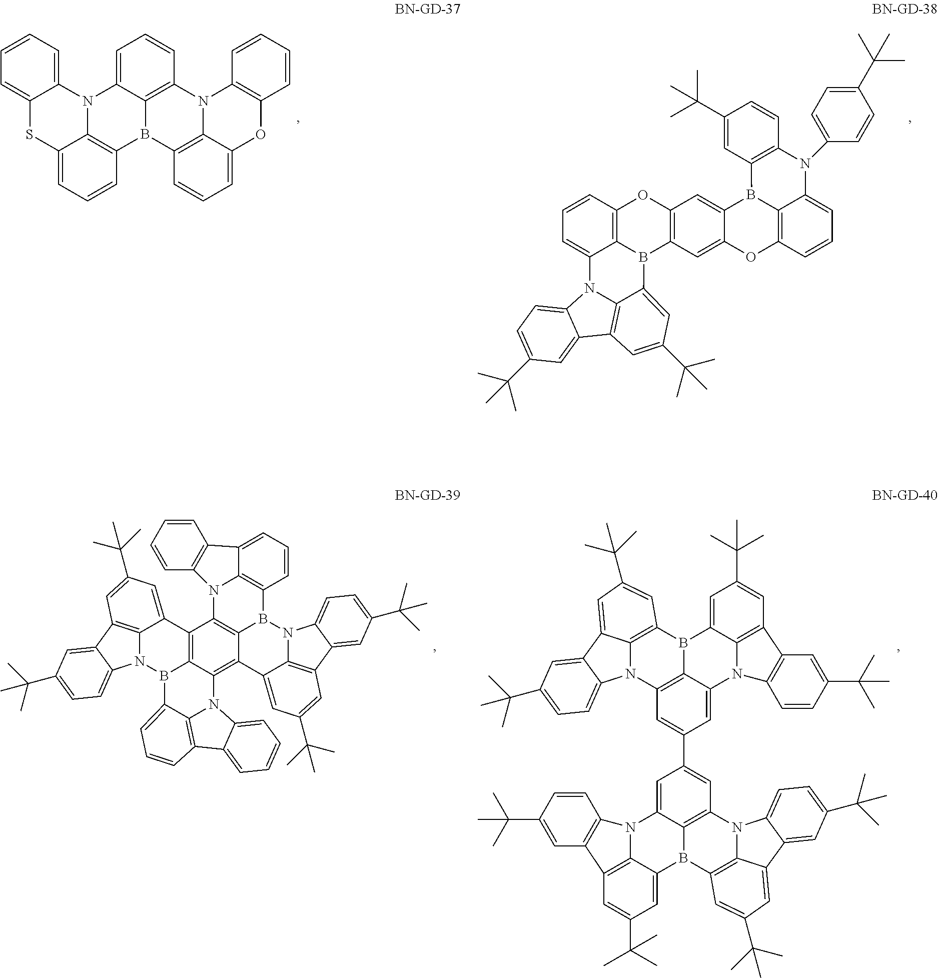 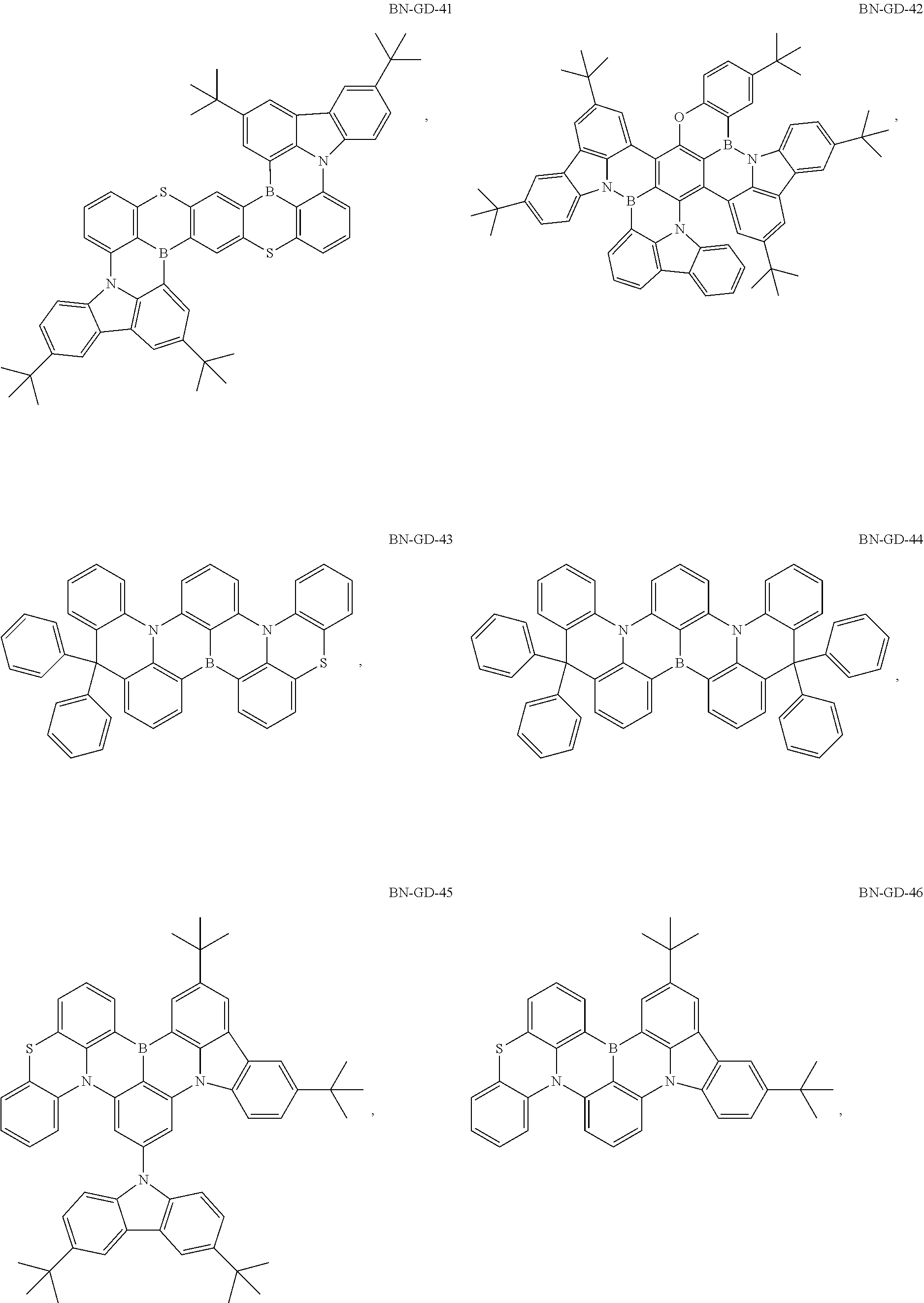 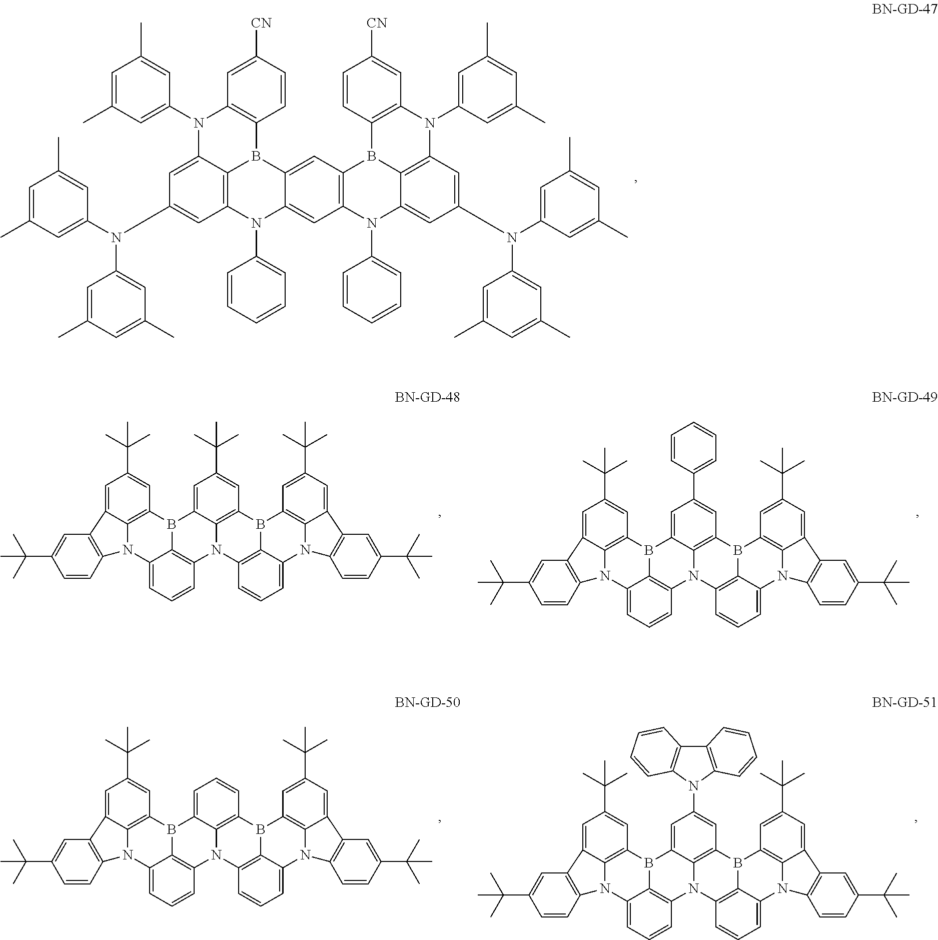 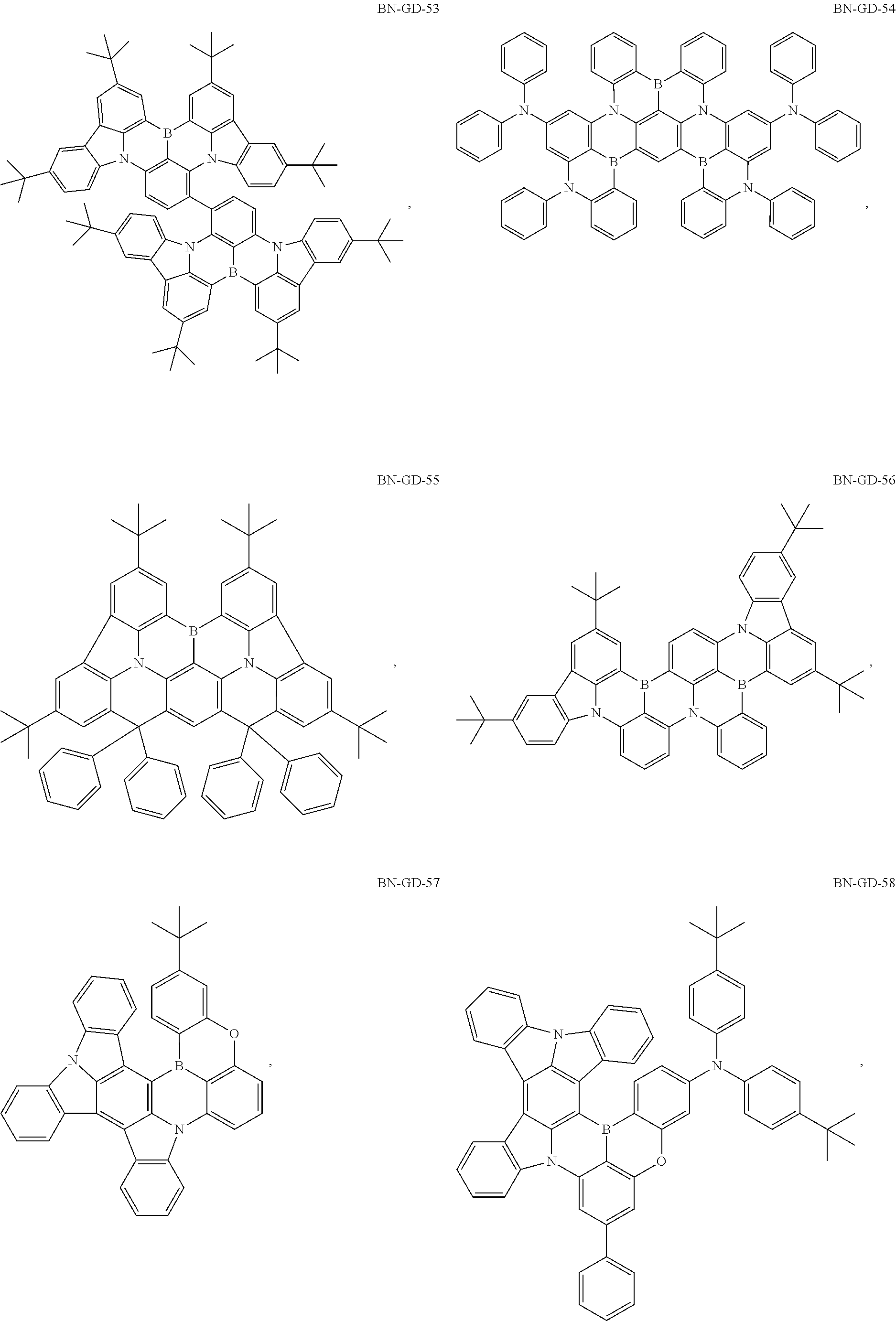 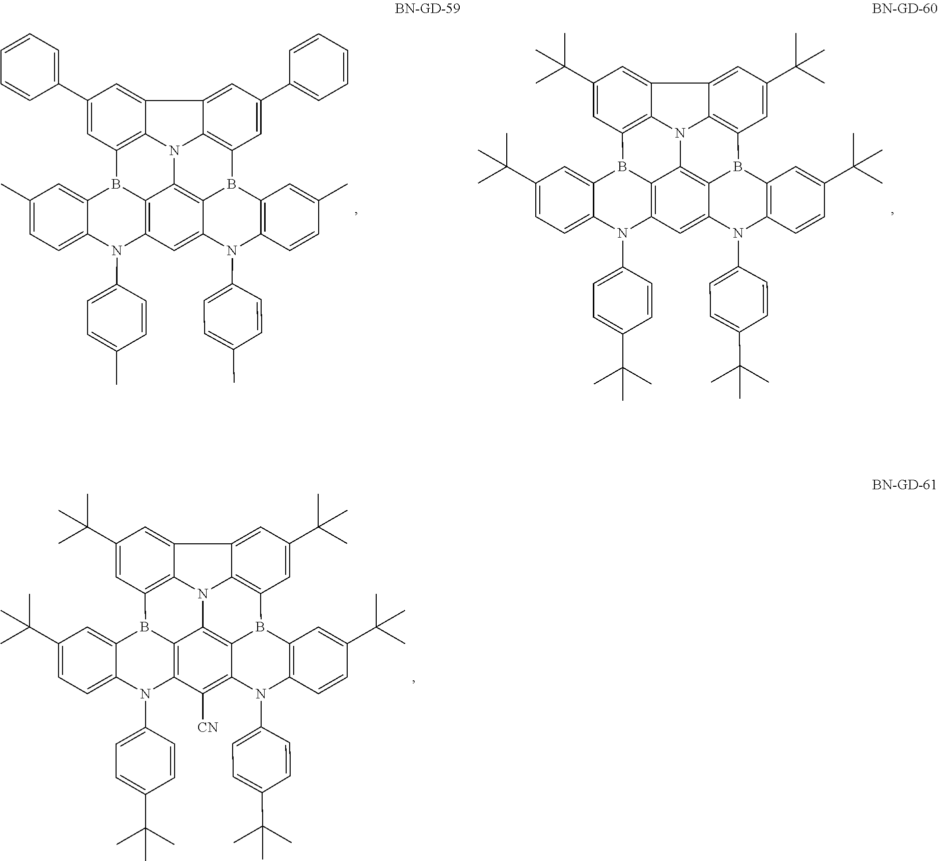 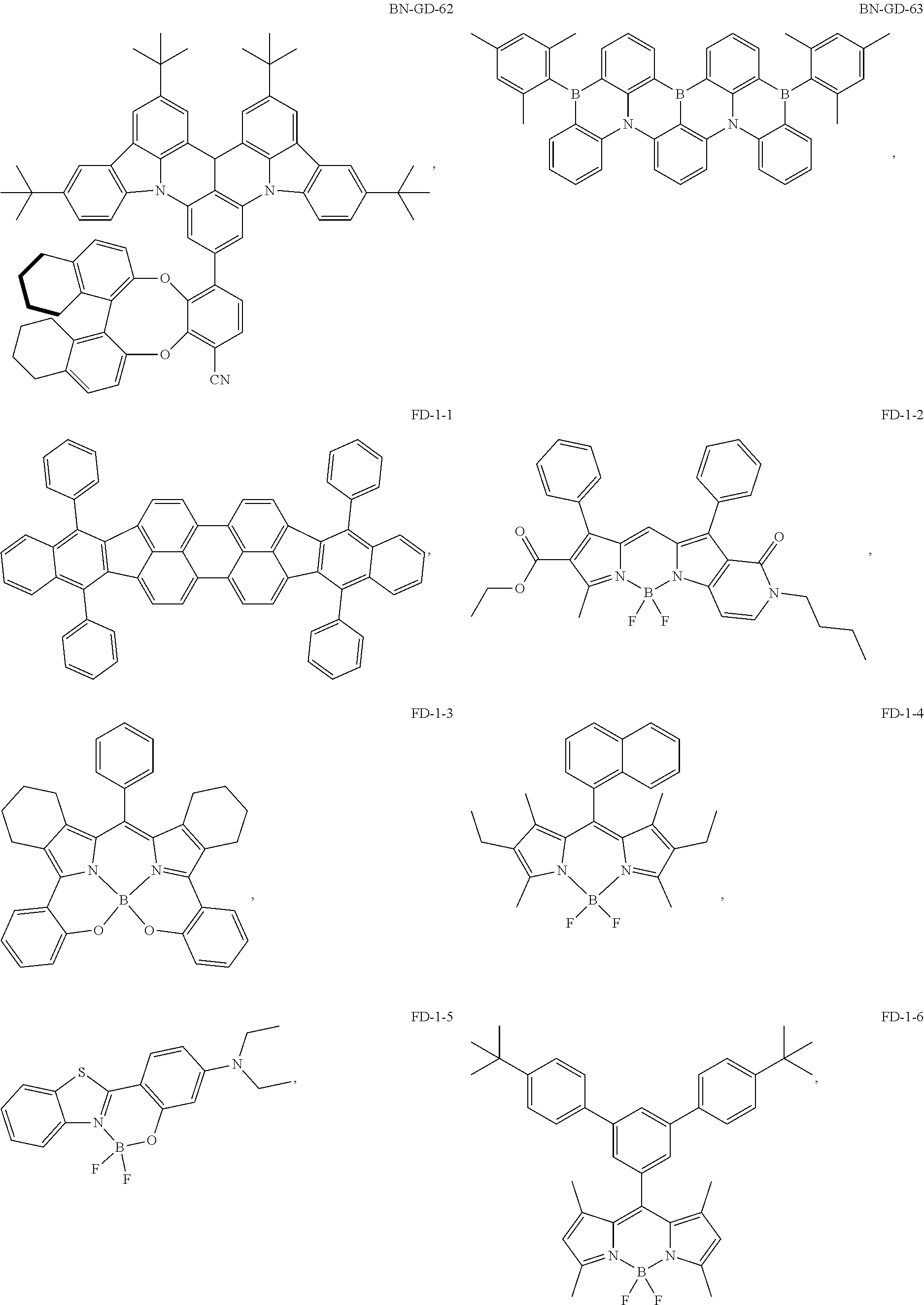 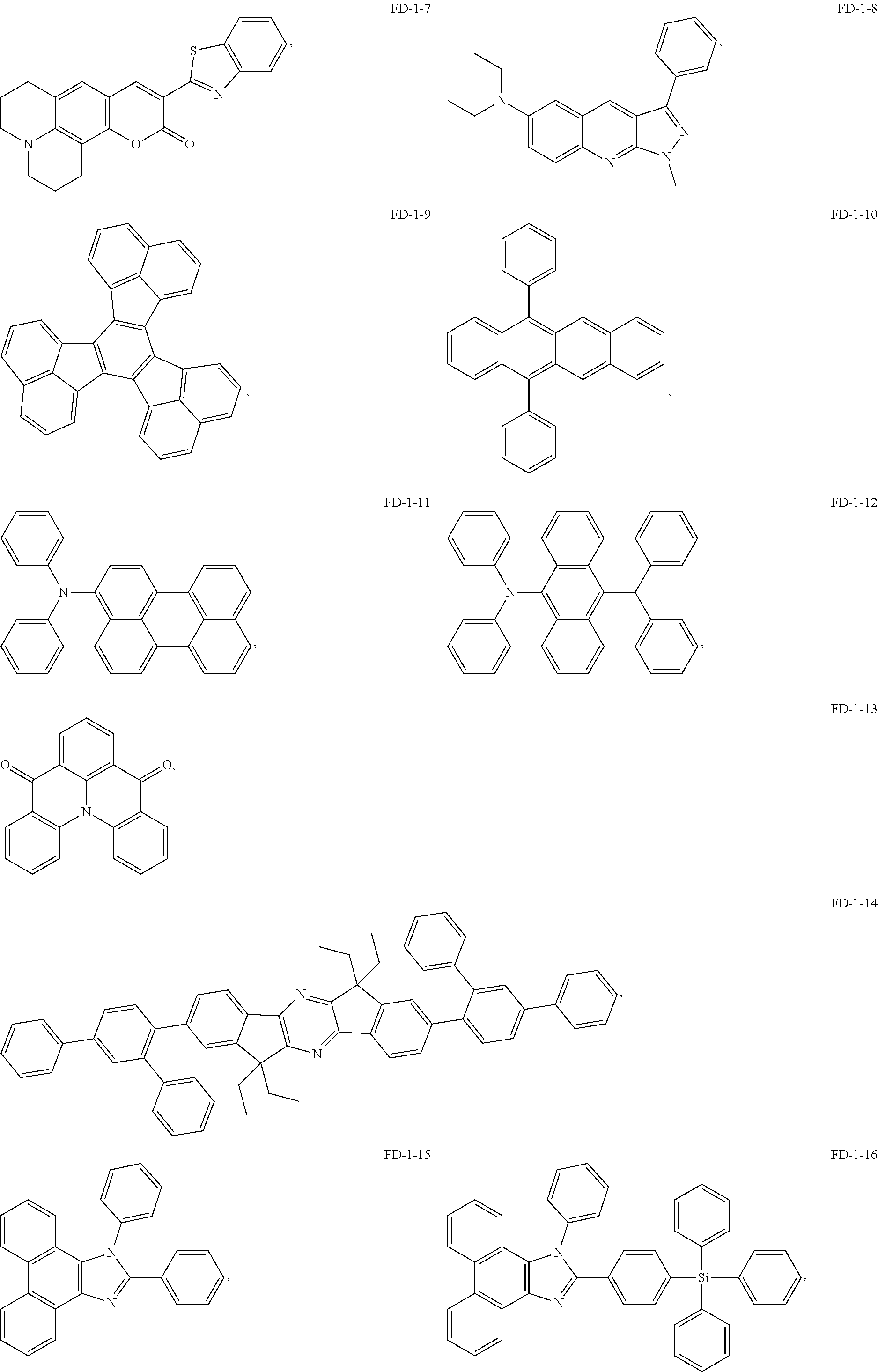 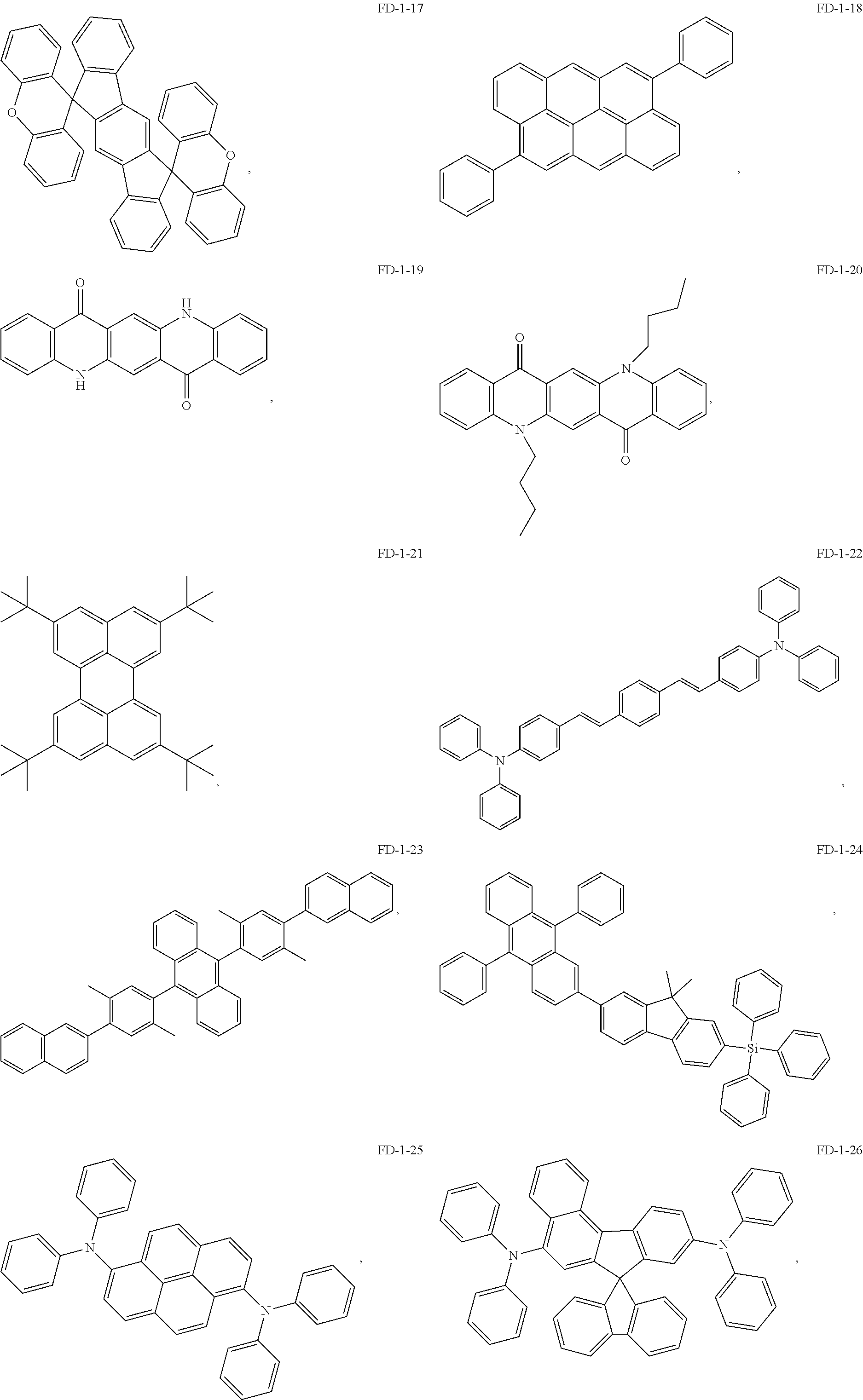 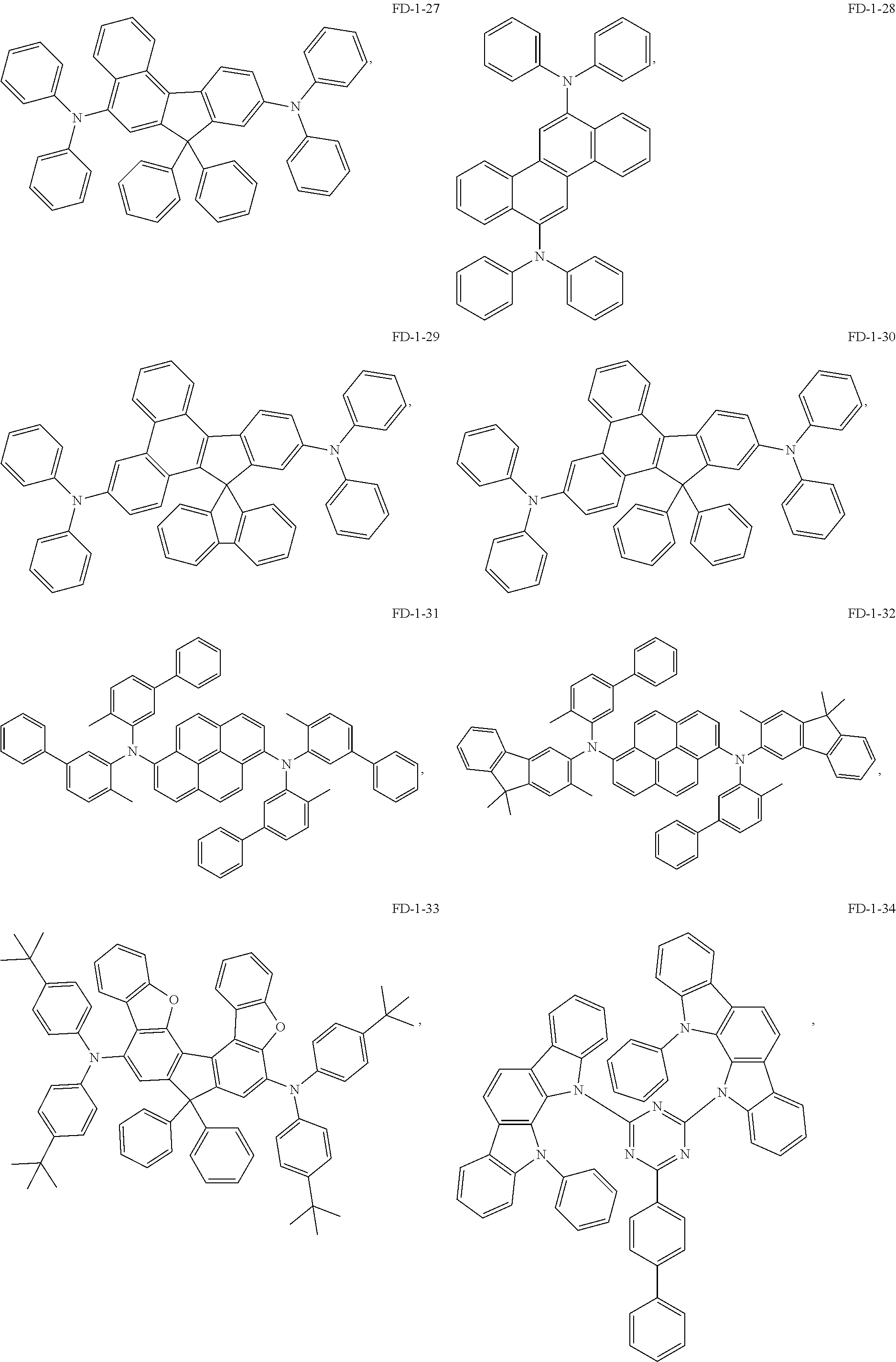 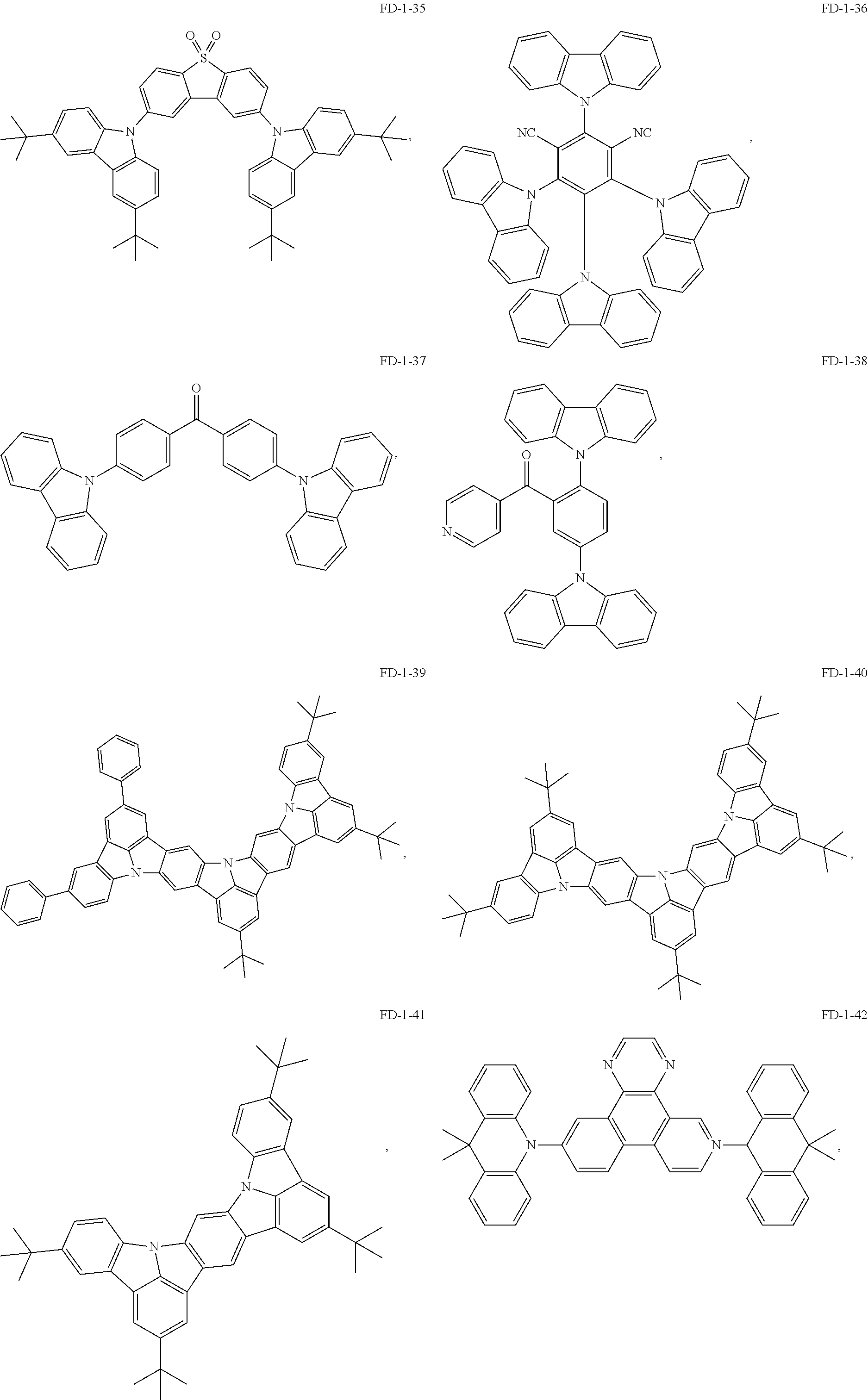 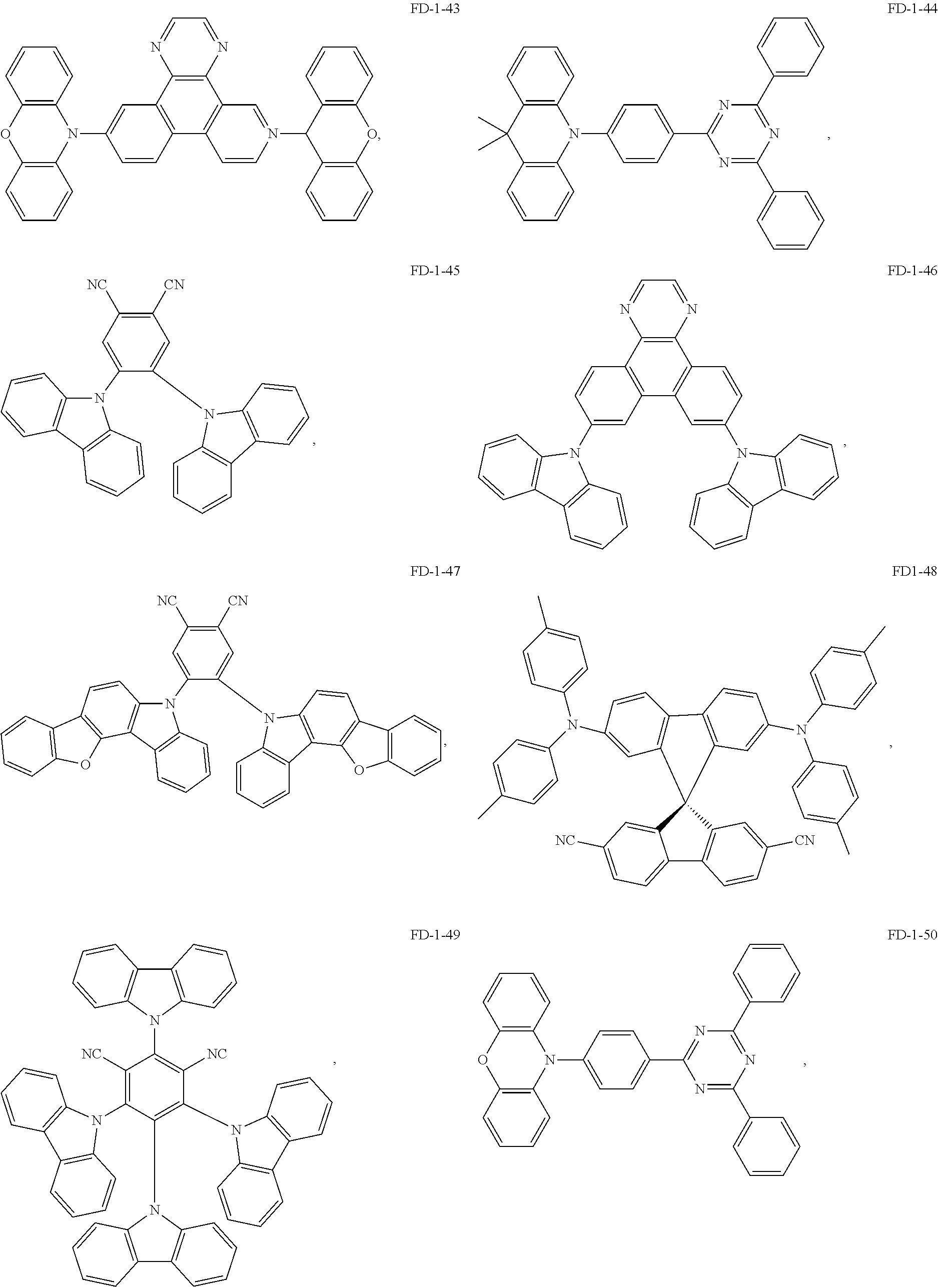 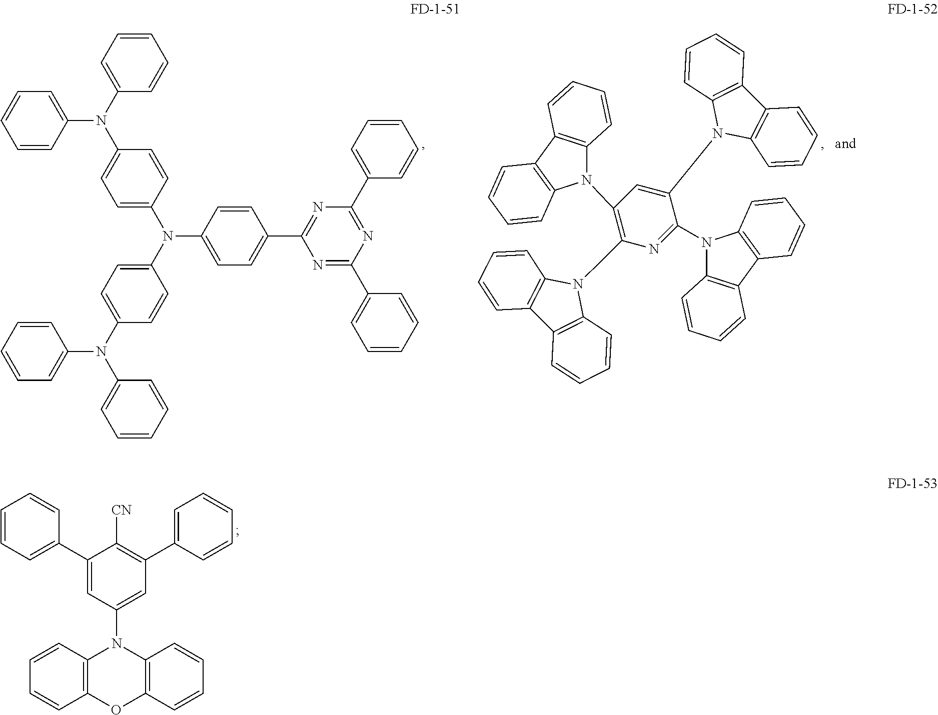
wherein, optionally, hydrogens in Compound BN-BD-1 to Compound BN-BD-53, Compound BN-RD-1 to Compound BN-RD-22, Compound BN-GD-1 to Compound BN-GD-51, Compound BN-GD-53 to Compound BN-GD-63, and Compound FD-1-1 to Compound FD-1-53 can be partially or fully substituted with deuterium.

10. The composition of claim 1, wherein a maximum phosphorescence emission wavelength of the fluorescent compound ranges from 450 nm to 500 nm;
preferably, the maximum phosphorescence emission wavelength of the fluorescent compound ranges from 450 nm to 470 nm;
more preferably, the maximum phosphorescence emission wavelength of the fluorescent compound ranges from 455 nm to 465 nm.

11. The composition of claim 1, wherein a maximum emission wavelength of a photoluminescence spectrum of the fluorescent compound ranges from 520 nm to 650 nm;
preferably, the maximum emission wavelength of the photoluminescence spectrum of the fluorescent compound ranges from 520 nm to 630 nm;
more preferably, the maximum emission wavelength of the photoluminescence spectrum of the fluorescent compound ranges from 520 nm to 580 nm.

12. The composition of claim 1, wherein a full width at half maximum of photoluminescence of the fluorescent compound is less than 45 nm;
preferably, the full width at half maximum of the fluorescent compound is less than 35 nm;
more preferably, the full width at half maximum of the fluorescent compound is less than 30 nm.

13. The composition of claim 1, wherein the phosphorescent sensitizer has a general formula of M(Lₐ)ₘ(L_{b})ₙ(L_{c})_{q};
wherein M is selected from a metal with a relative atomic mass greater than 40; preferably, the metal M is selected from the group consisting of Cu, Ag, Au, Zn, Rᵤ, Rh, Pd, Os, Ir, and Pt;
the ligands Lₐ, L_{b}, and L_{c} are a first ligand, a second ligand, and a third ligand coordinated to the metal M, respectively, and the ligands Lₐ, L_{b}, and L_{c} may be the same or different;
the ligands Lₐ, L_{b}, and L_{c} can be optionally joined to form a multidentate ligand;
m is 1, 2 or 3; n is 0, 1 or 2; q is 0, 1 or 2; the sum of m, n, and q is equal to an oxidation state of the metal M; when m is greater than or equal to 2, a plurality of Lₐ may be the same or different; when n is 2, two L_{b} may be the same or different; when q is 2, two L_{c} may be the same or different;
the ligand Lₐ has a structure represented by Formula 2: 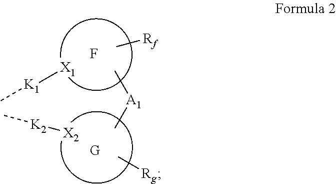
wherein the ring F and the ring G are each independently selected from an unsaturated carbocyclic ring having 5 to 30 carbon atoms, an unsaturated heterocyclic ring having 1 to 30 carbon atoms or a combination thereof;
X₁ and X₂ are, at each occurrence identically or differently, selected from C or N;
K₁ and K₂ are each independently selected from a single bond, O or S;
A₁ is selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof; y is, at each occurrence identically or differently, selected from 1, 2, 3, 4 or 5;
R_{f} and R_{g} represent, at each occurrence identically or differently, mono-substitution, multiple substitutions or non-substitution;
R_{f} and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{f} and R_{g} can be optionally joined to form a ring;
the ligands L_{b} and L_{c} are, at each occurrence identically or differently, selected from a monoanionic bidentate ligand;
preferably, the ligands L_{b} and L_{c} are, at each occurrence identically or differently, selected from the group consisting of the following structures: 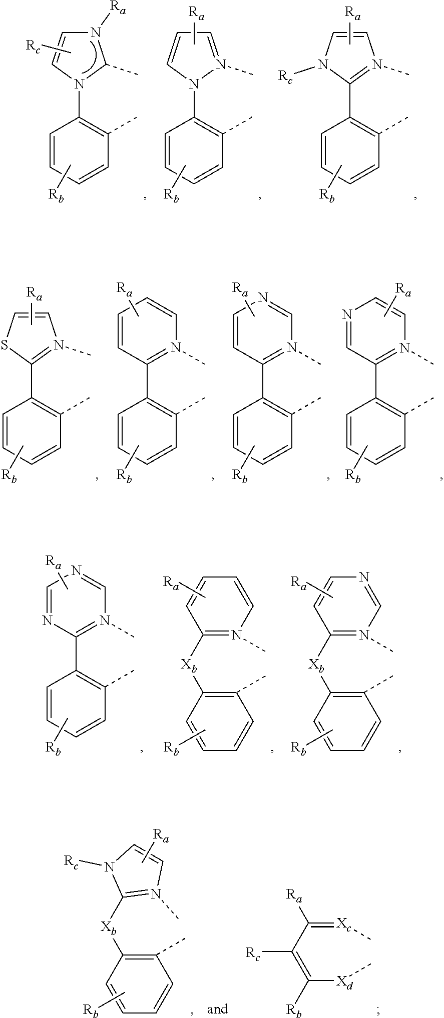
wherein
Rₐ and R_{b} represent, at each occurrence identically or differently, mono-substitution, multiple substitutions or non-substitution;
X_{b} is, at each occurrence identically or differently, selected from the group consisting of O, S, Se, NR_{N1}, and CR_{C1}R_{C2};
X_{c} and X_{d} are, at each occurrence identically or differently, selected from the group consisting of O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ, R_{b}, R_{c}, R_{N1}, R_{N2}, R_{C1}, and R_{C2} can be optionally joined to form a ring.

14. The composition of claim 13, wherein the ligand Lₐ has a structure represented by Formula 2-1 or Formula 2-2: 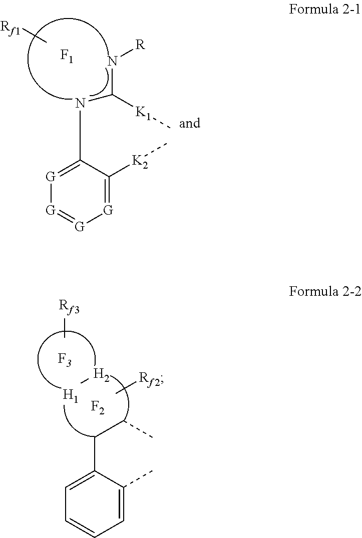
wherein in Formula 2-1, the ring F₁ is selected from an unsaturated heterocyclic ring having 1 to 30 carbon atoms;
in Formula 2-2, the ring F₂ and the ring F₃ are each independently selected from an unsaturated carbocyclic ring having 5 to 30 carbon atoms, an unsaturated heterocyclic ring having 3 to 30 carbon atoms or a combination thereof;
the ring F₂ and the ring F₃ are fused via H₁ and H₂;
X₁ and X₂ are each independently selected from C or N, and X₁ is different from X₂;
H₁ and H₂ are, at each occurrence identically or differently, selected from C or N;
K₁ and K₂ are each independently selected from a single bond, O or S;
G is, at each occurrence identically or differently, selected from CR_{g} or N;
R_{f1}, R_{f2}, and R_{f3} represent, at each occurrence identically or differently, mono-substitution, multiple substitutions or non-substitution;
R, R_{g}, R_{f1}, R_{f2}, and R_{f3} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R, R_{g}, R_{f}, R_{f2}, and R_{f3} can be optionally joined to form a ring.

15. The composition of claim 1, wherein the phosphorescent sensitizer has a structure represented by one of Formula 3-1 to Formula 3-24: 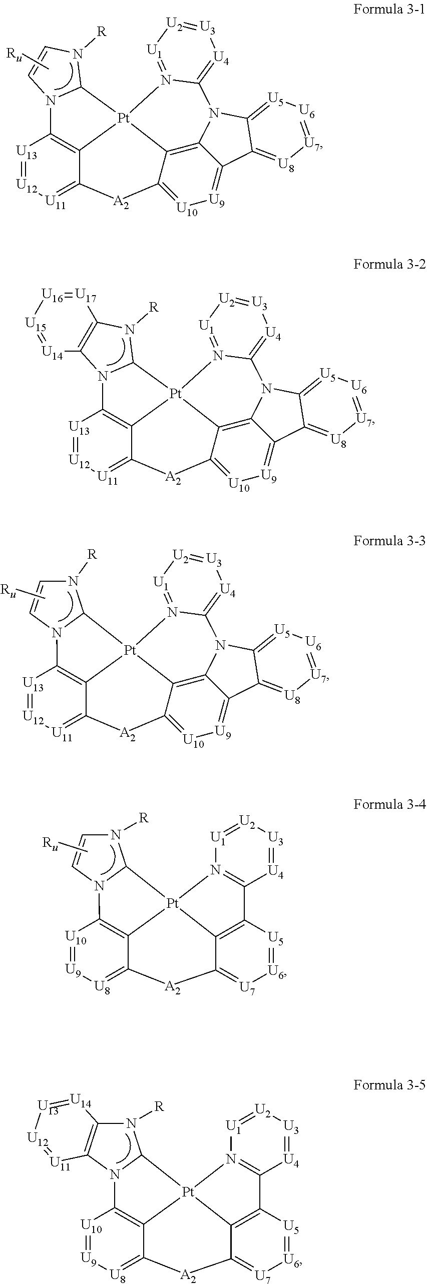 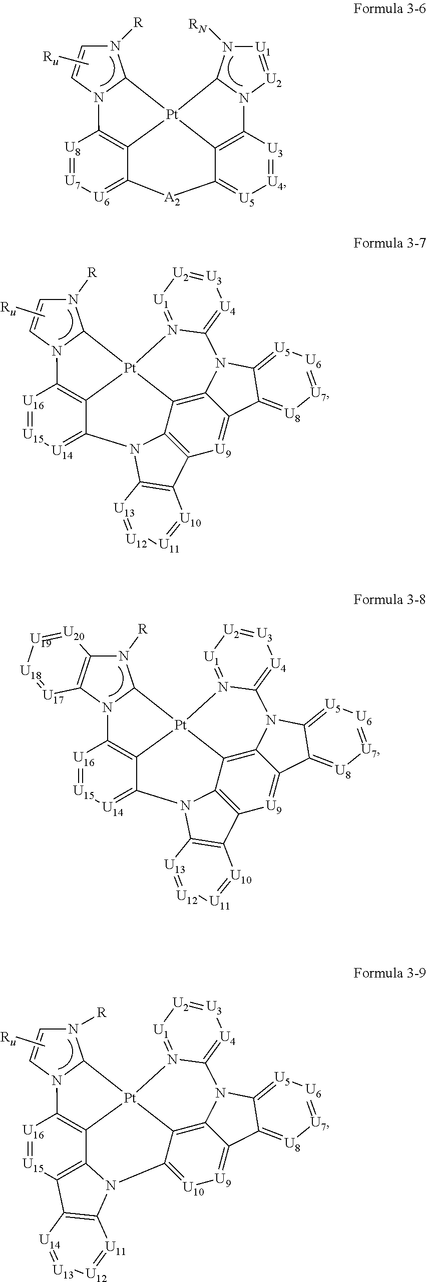 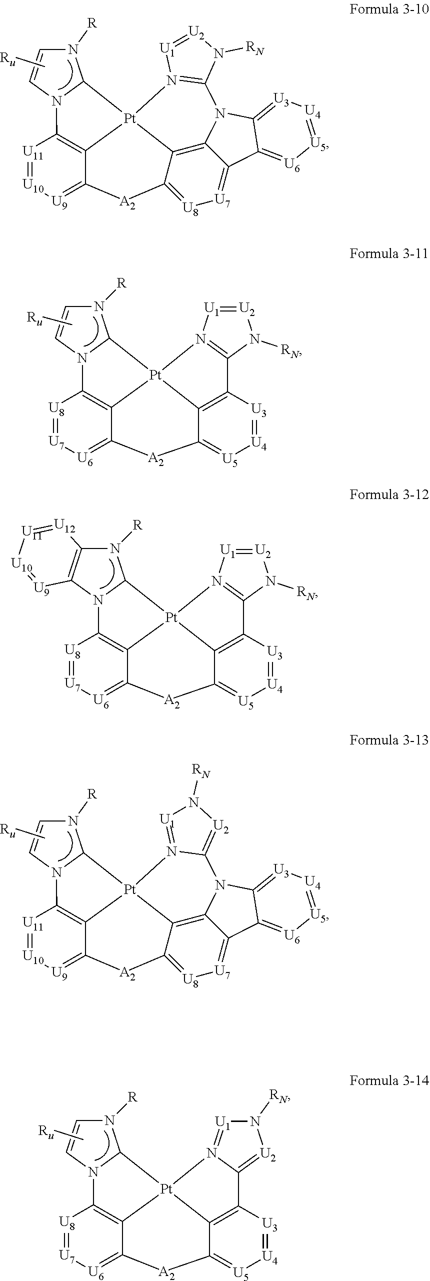 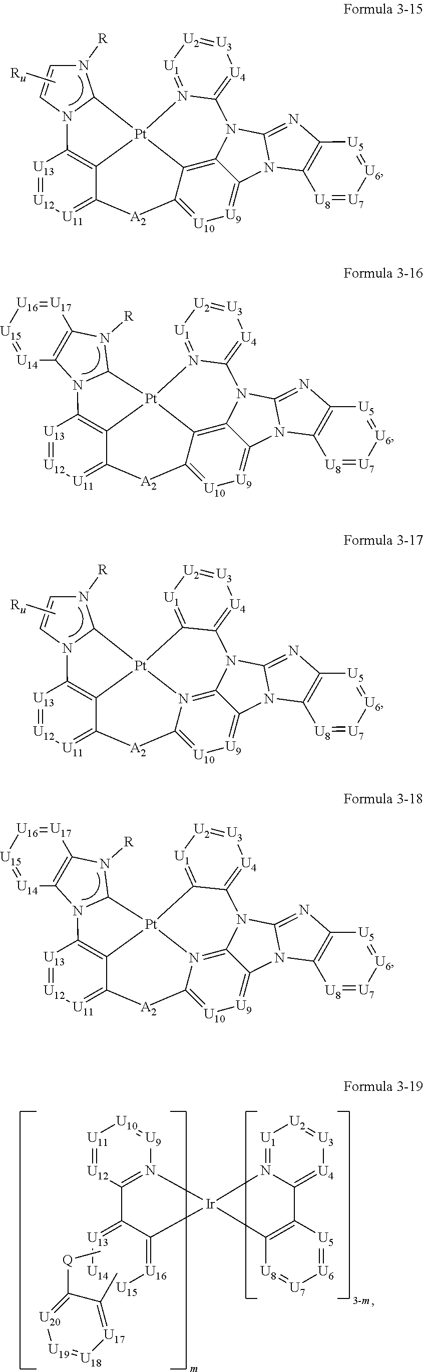 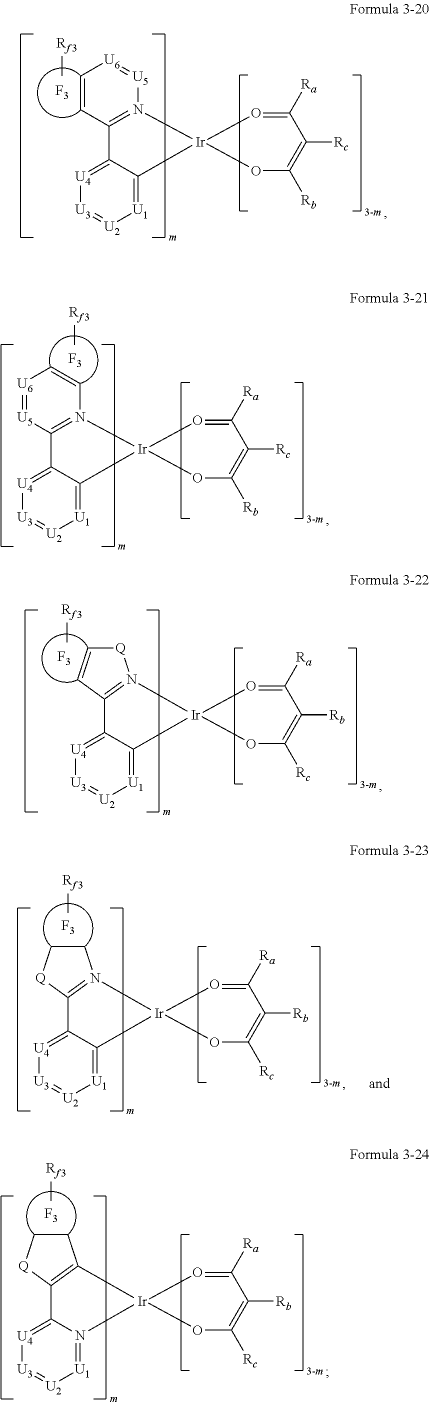
wherein
A₂ is, at each occurrence identically or differently, selected from a single bond, O, S, Se, (SiR_{q}R_{q})_{y}, PR_{q}, NR_{q}, substituted or unsubstituted arylene having 6 to 30 carbon atoms, substituted or unsubstituted heteroarylene having 3 to 30 carbon atoms or a combination thereof; y is, at each occurrence identically or differently, selected from 1, 2 or 3;
U₁ to U₂₀ are, at each occurrence identically or differently, selected from CRₙ or N;
the ring F₃ is, at each occurrence identically or differently, selected from an unsaturated carbocyclic ring having 5 to 30 carbon atoms, an unsaturated heterocyclic ring having 3 to 30 carbon atoms or a combination thereof;
Q is, at each occurrence identically or differently, selected from O, S or Se;
m is, at each occurrence identically or differently, selected from 0, 1, 2 or 3;
Rᵤ and R_{f3} represent, at each occurrence identically or differently, mono-substitution, multiple substitutions or non-substitution;
R, R_{N}, R_{q}, Rᵤ, Rₙ, R_{f3}, Rₐ, R_{b}, and R_{c} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R, R_{N}, R_{q}, Rᵤ, Rₙ, and R_{f3} can be optionally joined to form a ring;
preferably, the phosphorescent sensitizer has a structure represented by Formula 3-1 or Formula 3-2;
more preferably, R has a structure represented by Formula 4: 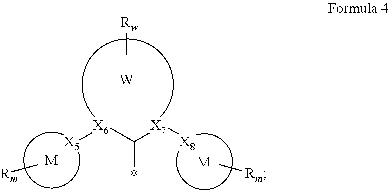
wherein in Formula 4,
the ring M and the ring W are, at each occurrence identically or differently, selected from an unsaturated carbocyclic ring having 5 to 30 carbon atoms, an unsaturated heterocyclic ring having 3 to 30 carbon atoms or a combination thereof;
X₅ to X₈ are, at each occurrence identically or differently, selected from C or N;
“*” represents a position where Formula 4 is joined;
Rₘ represents, at each occurrence identically or differently, mono-substitution, multiple substitutions or non-substitution;
R_{w} represents, at each occurrence identically or differently, mono-substitution or multiple substitutions;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₘ and R_{w} can be optionally joined to form a ring.

16. The composition of claim 1, wherein the phosphorescent sensitizer has a general structure of Ir(Lₐ)ₘ(L_{b})₃₋ₘ and has a structure represented by Formula M-a: 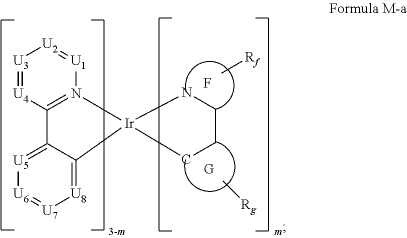
wherein
m is selected from 1, 2 or 3; when m is selected from 1, two L_{b} are the same or different;
when m is selected from 2 or 3, a plurality of Lₐ are the same or different;
the ring F is selected from a heteroaromatic ring having 5 to 30 ring atoms;
the ring G is selected from an aromatic ring having 6 to 30 ring atoms, a heteroaromatic ring having 5 to 30 ring atoms or a combination thereof;
U₁ to U₈ are, at each occurrence identically or differently, selected from CRₙ or N;
R_{f} and R_{g} represent, at each occurrence identically or differently, mono-substitution, multiple substitutions or non-substitution;
R_{f}, R_{g}, and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{f}, R_{g}, and Rₙ can be optionally joined to form a ring;
preferably, the ring F is selected from any one of the following structures: 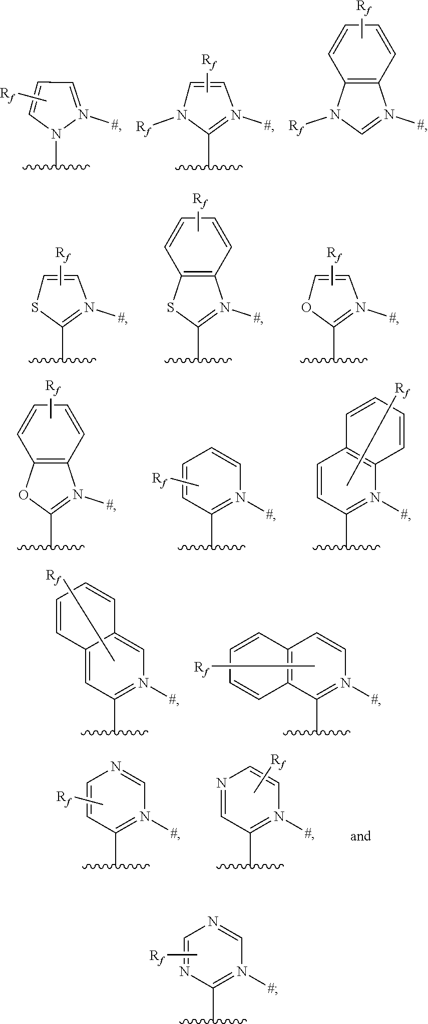
the ring G is selected from any one of the following structures: 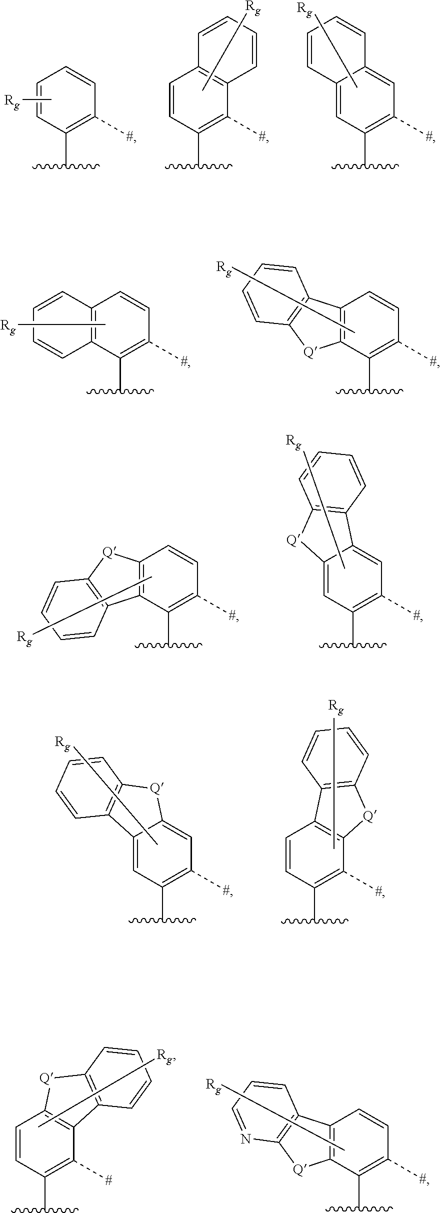 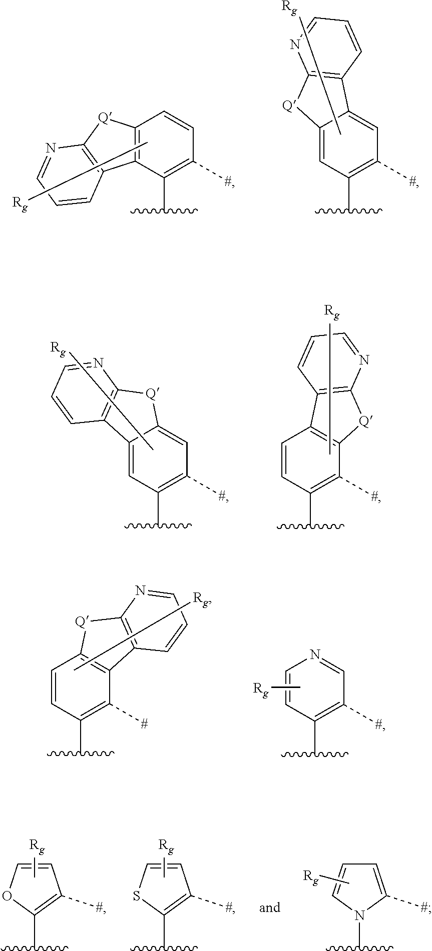
wherein
Q′ is selected from the group consisting of O, S, Se, NR_{Q}, CR_{Q}R_{Q}, SiR_{Q}R_{Q}, and GeR_{Q}R_{Q}; when a plurality of R_{Q} are present, the plurality of R_{Q} are the same or different;
R_{f} and R_{g} represent, at each occurrence identically or differently, mono-substitution, multiple substitutions or non-substitution; when a plurality of R_{f} or R_{g} are present in any structure, the plurality of R_{f} or R_{g} are the same or different;
R_{f}, R_{g}, and R_{Q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{f}, R_{g}, and R_{Q} can be optionally joined to form a ring;
“#” represents a position joined to the metal Ir, and 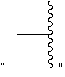
represents a position joined to the ring G;
more preferably, the ring F is selected from 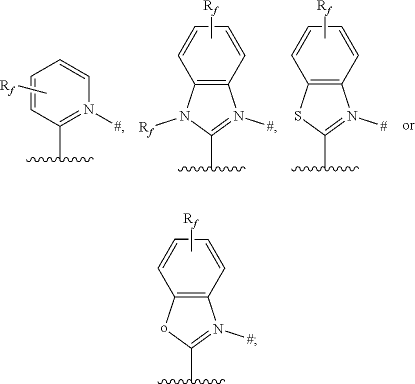
the ring G is selected from

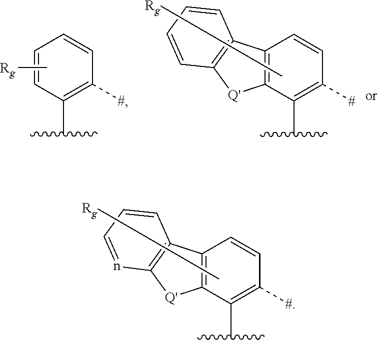

17. The composition of claim 1, wherein the phosphorescent sensitizer is selected from the group consisting of BD1 to BD18, RD1 to RD209, and GD1 to GD177: 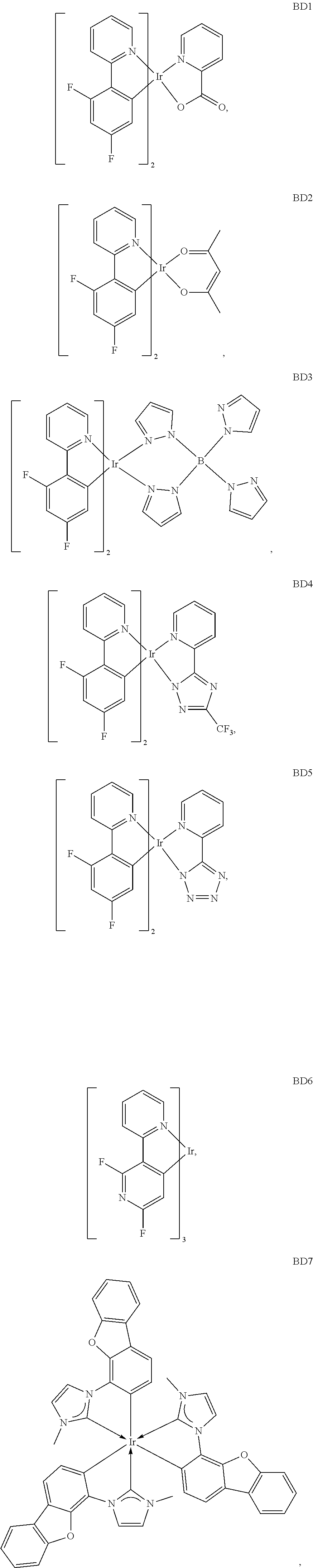 [chemical structure] 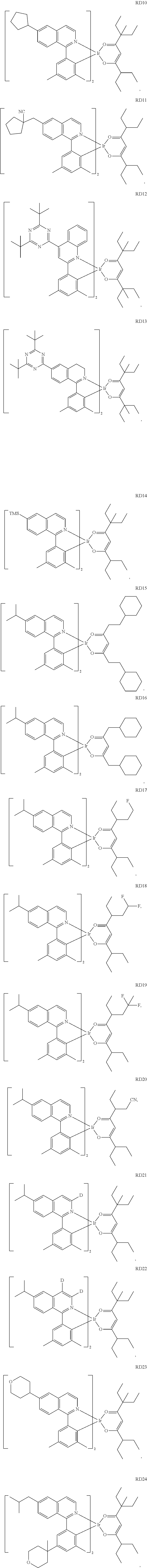 [chemical structure] 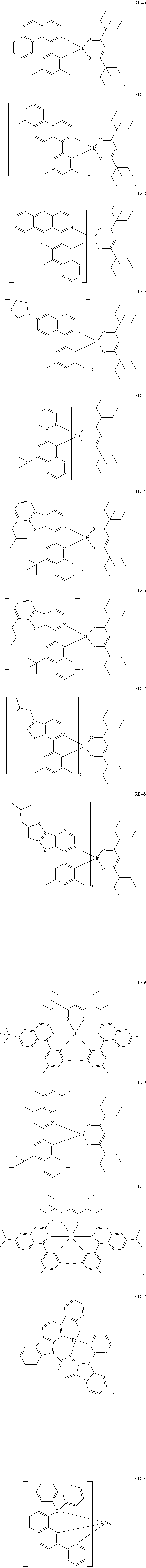 [chemical structure] [chemical structure] 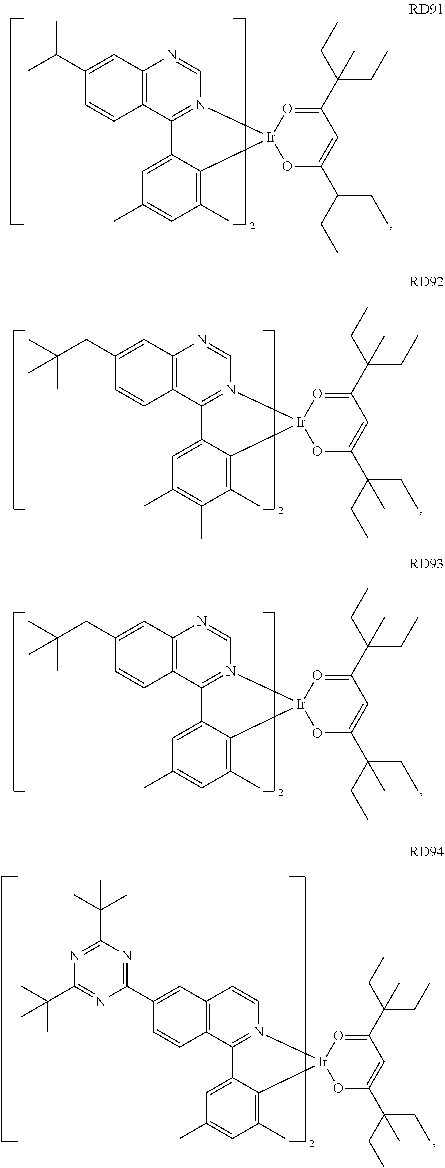 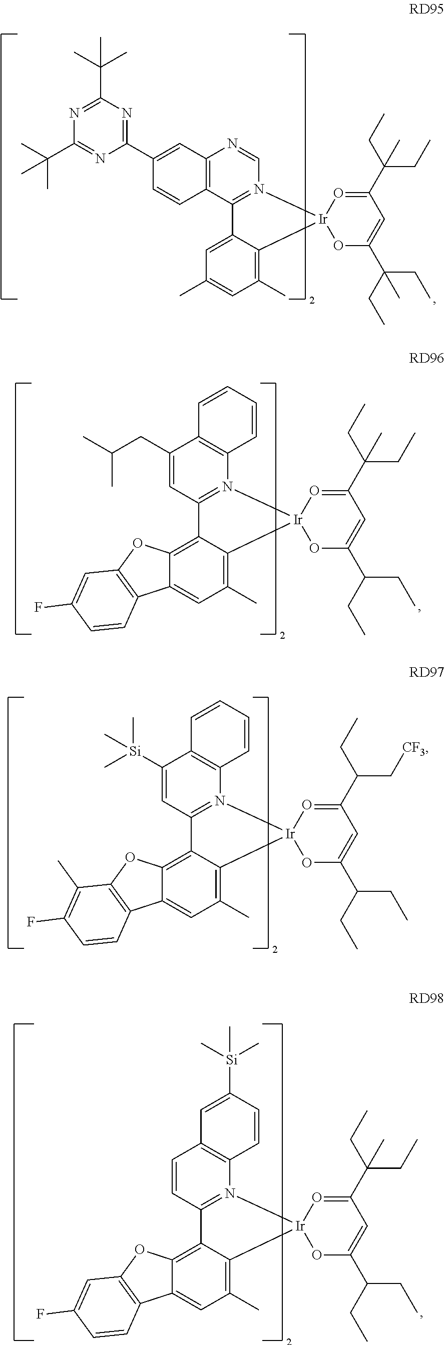 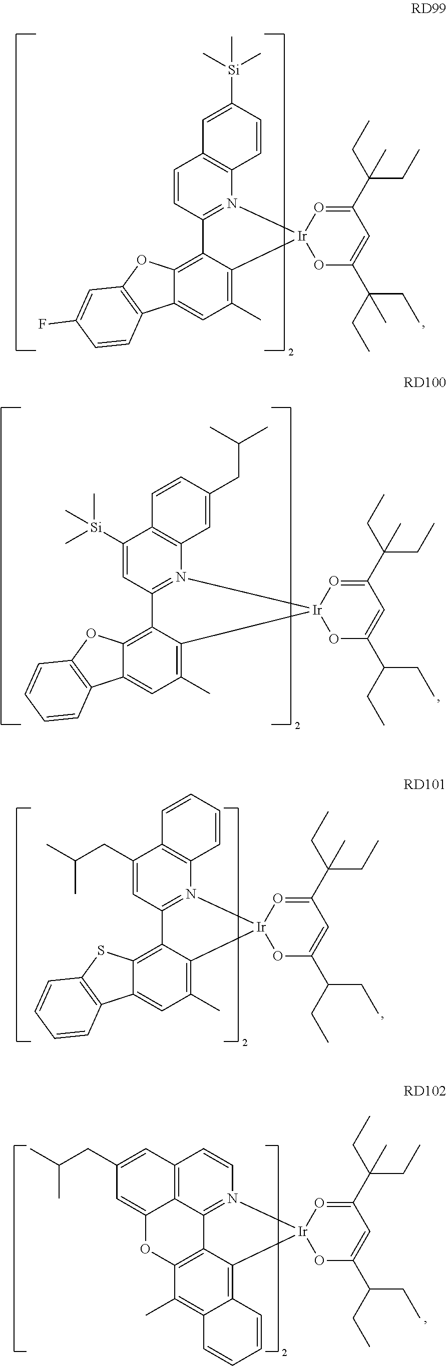 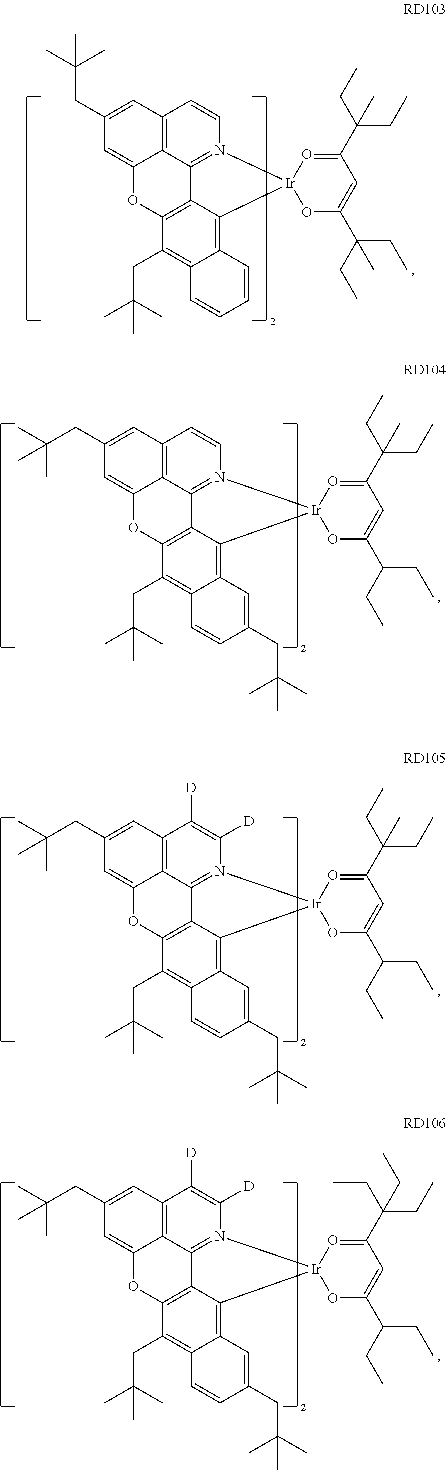 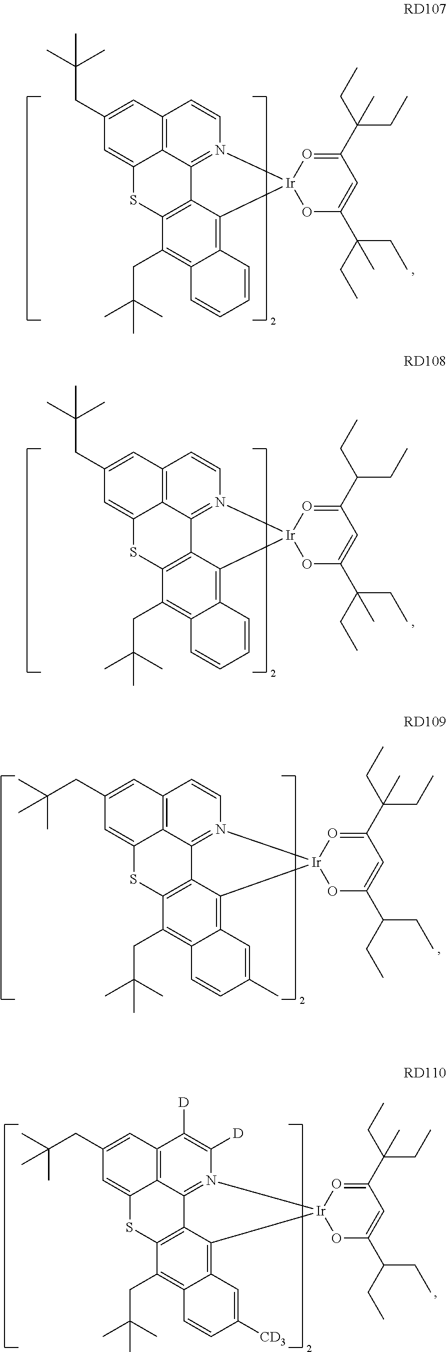 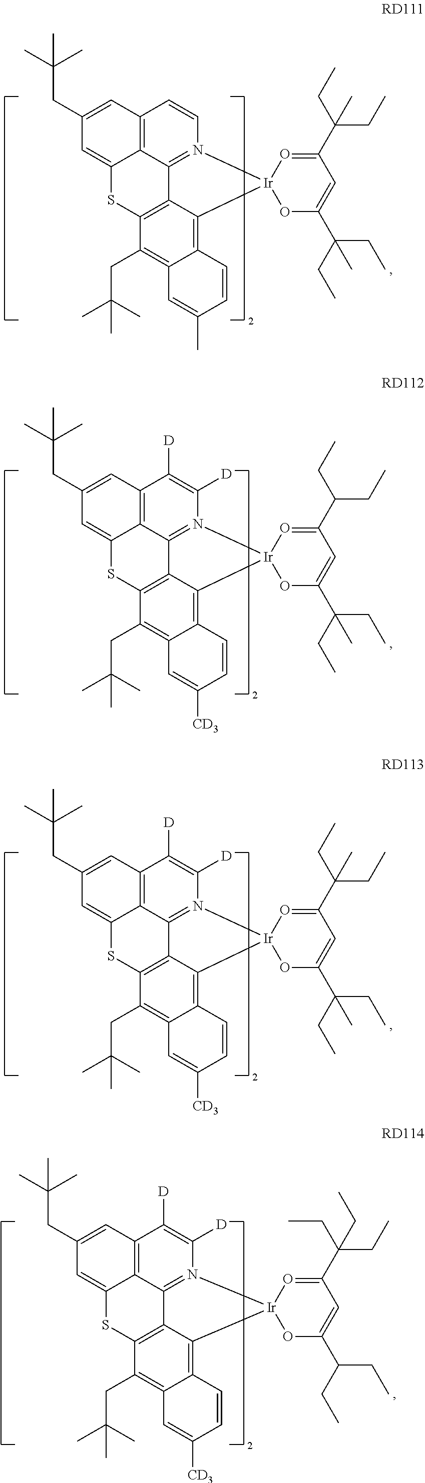 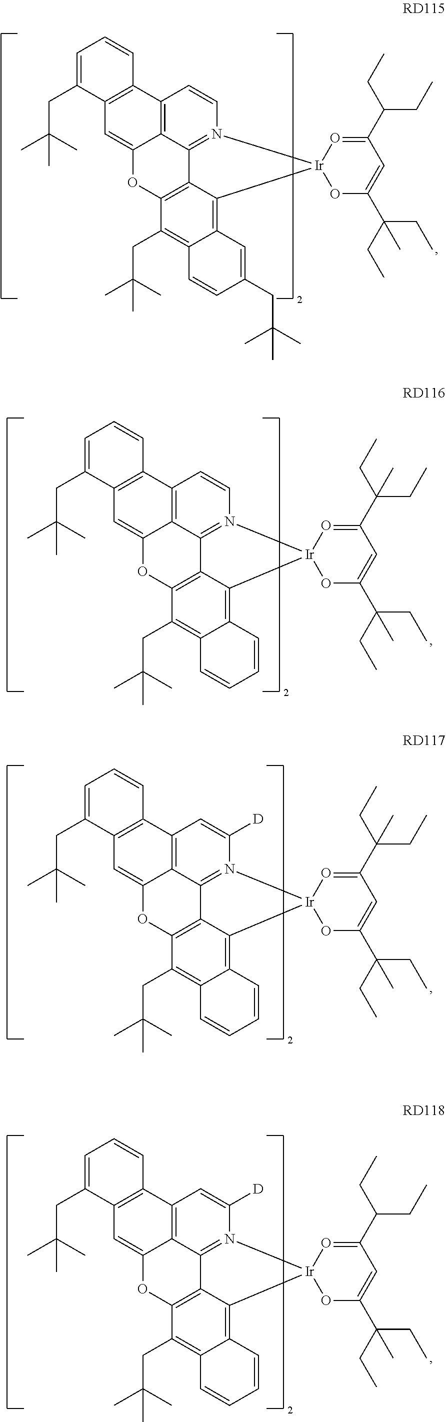 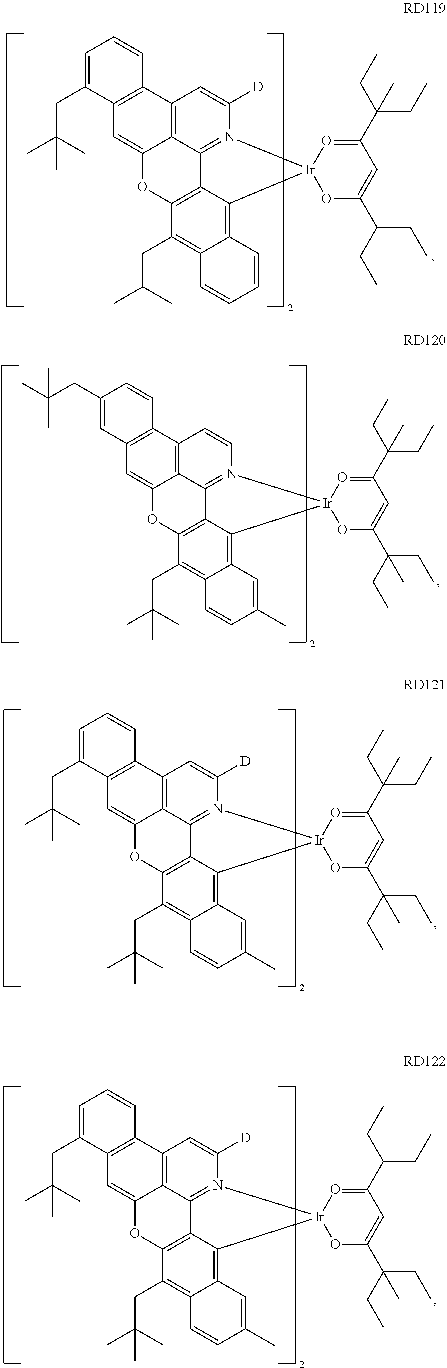 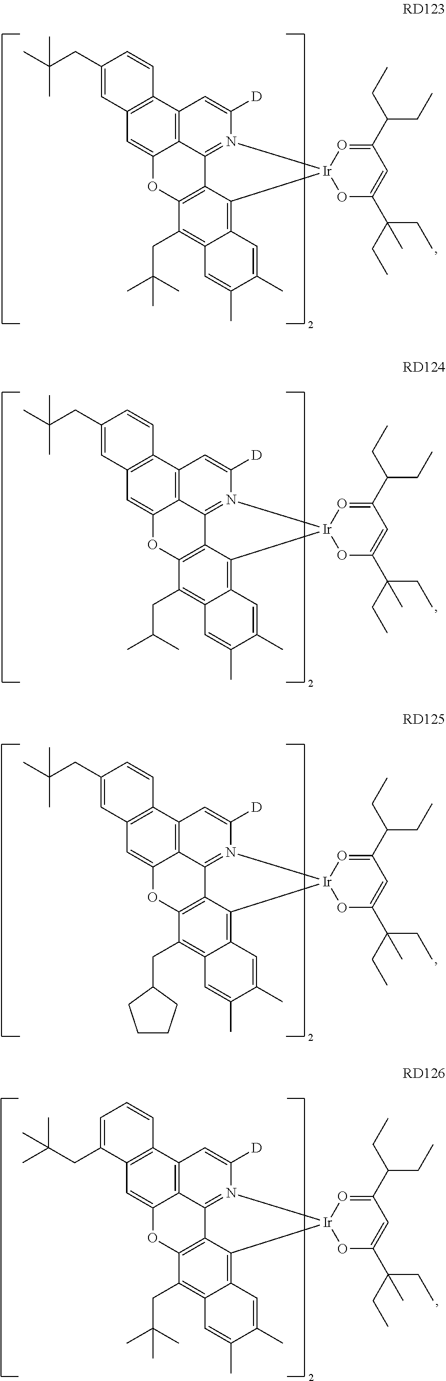 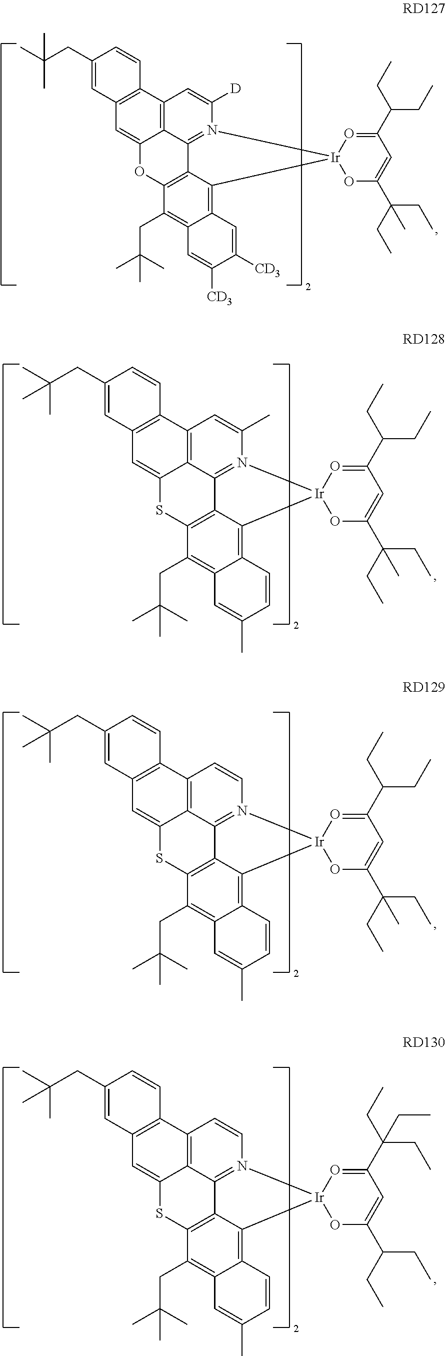 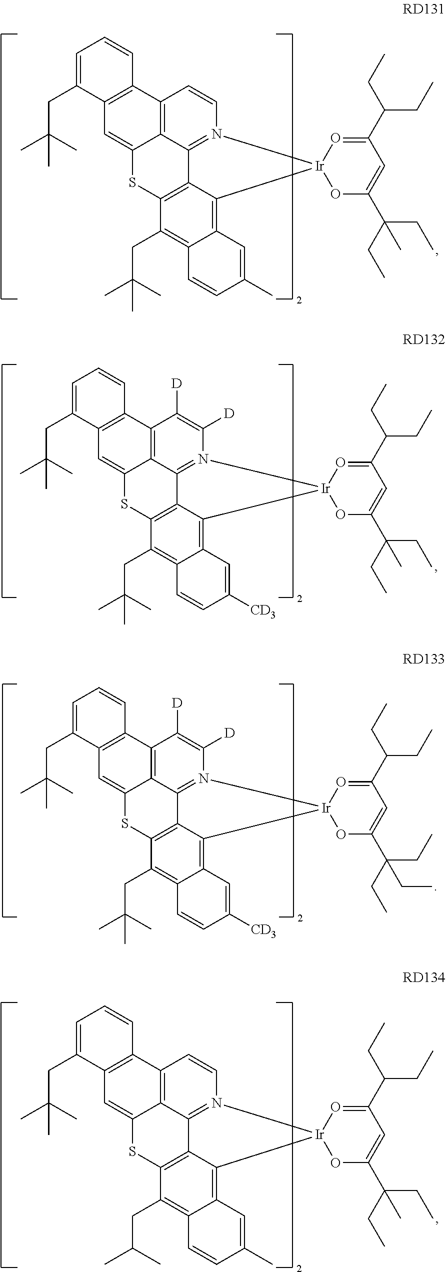 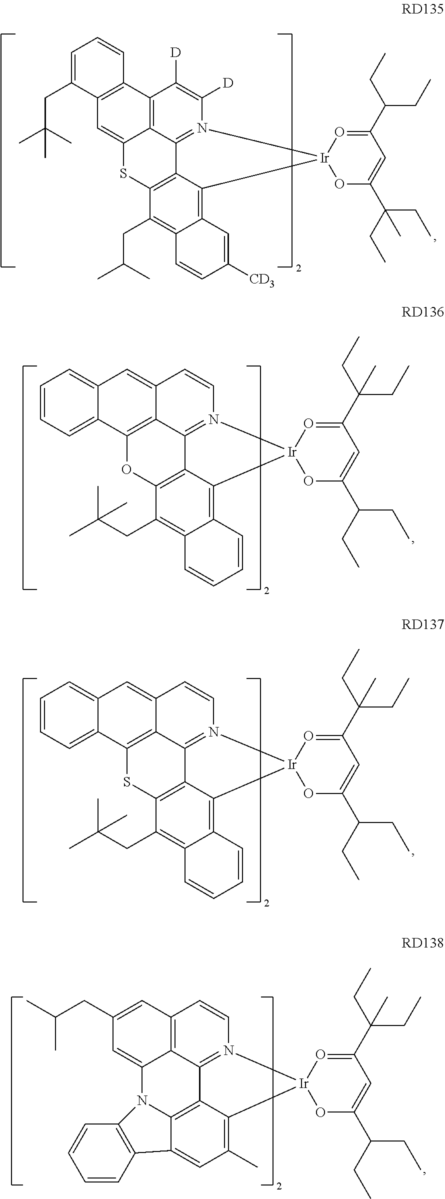 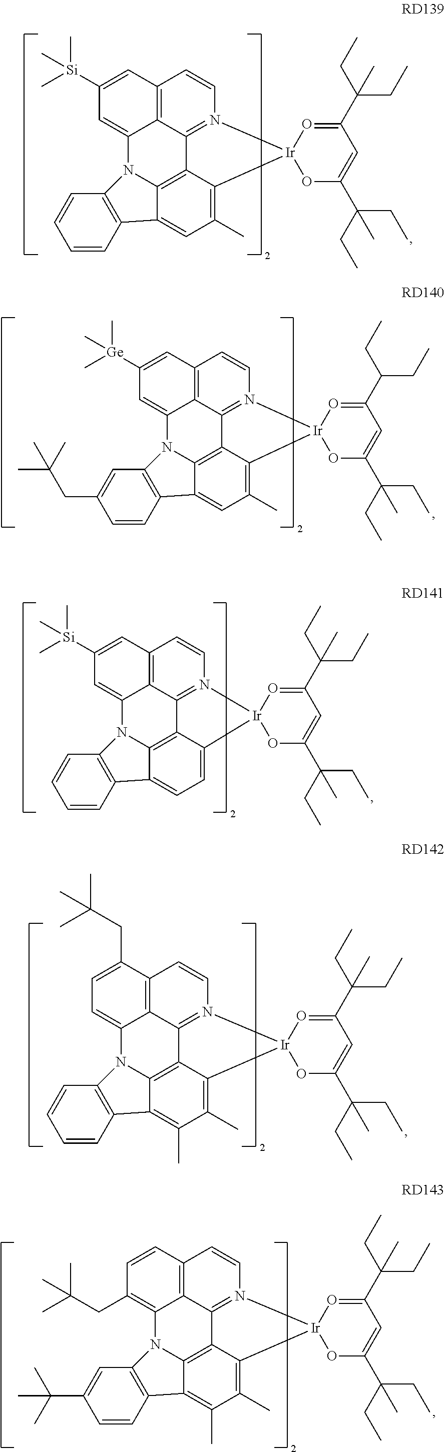 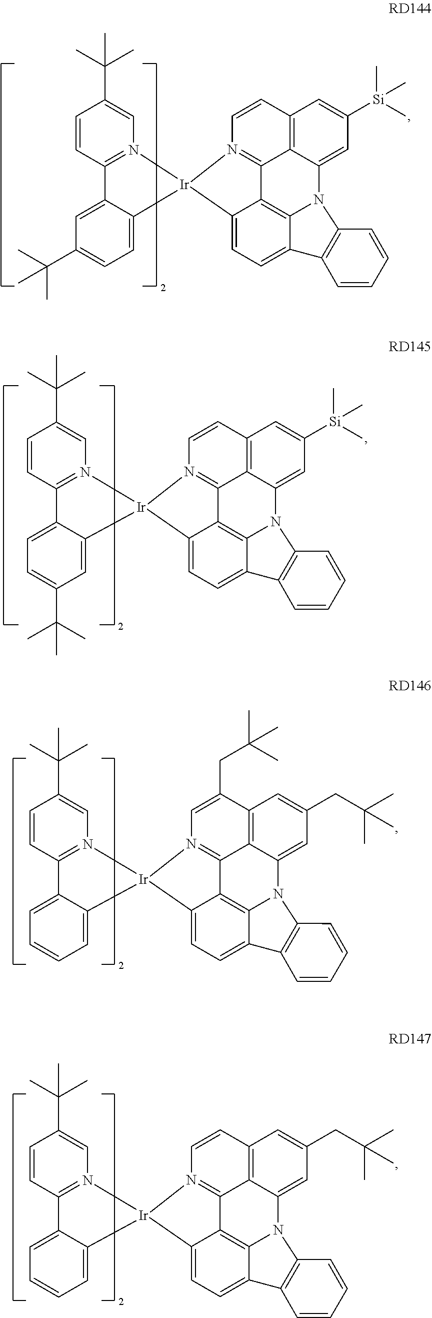 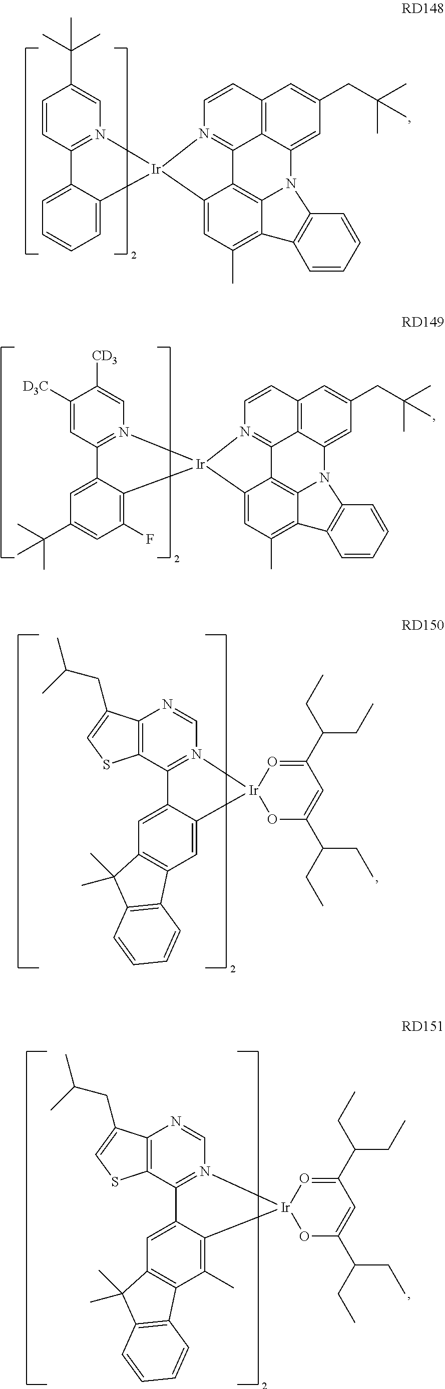 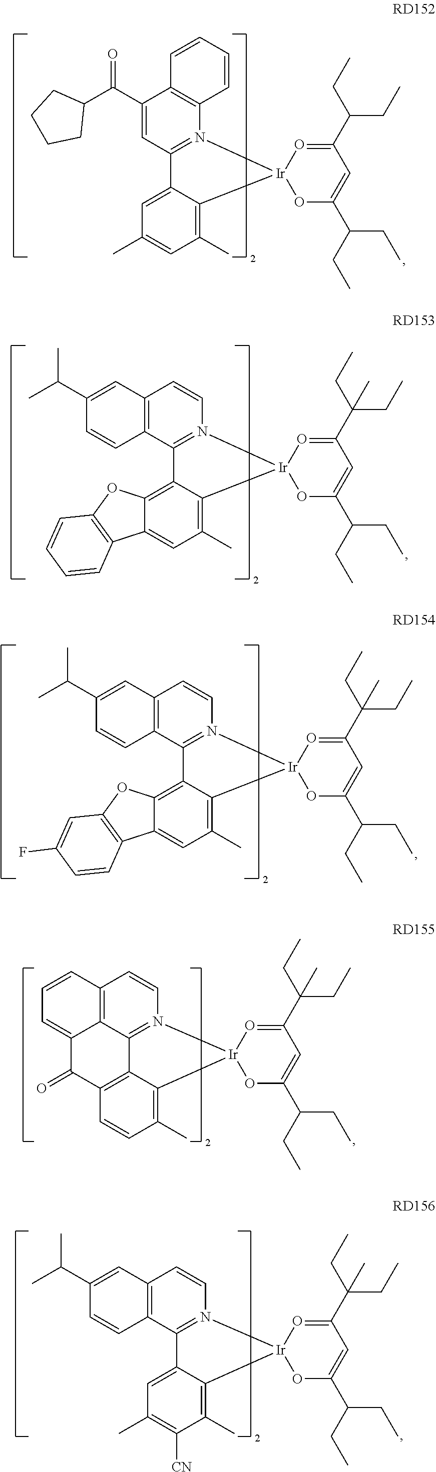 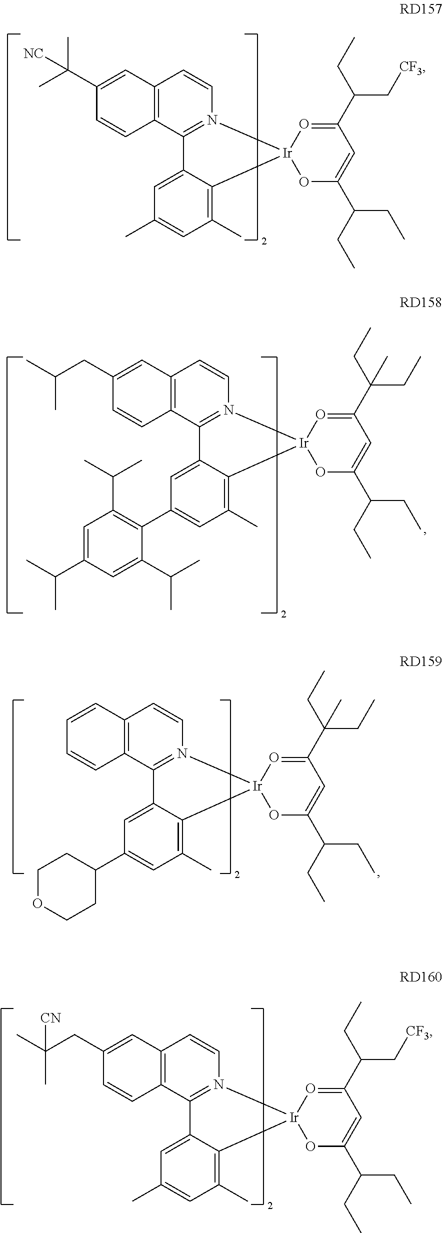 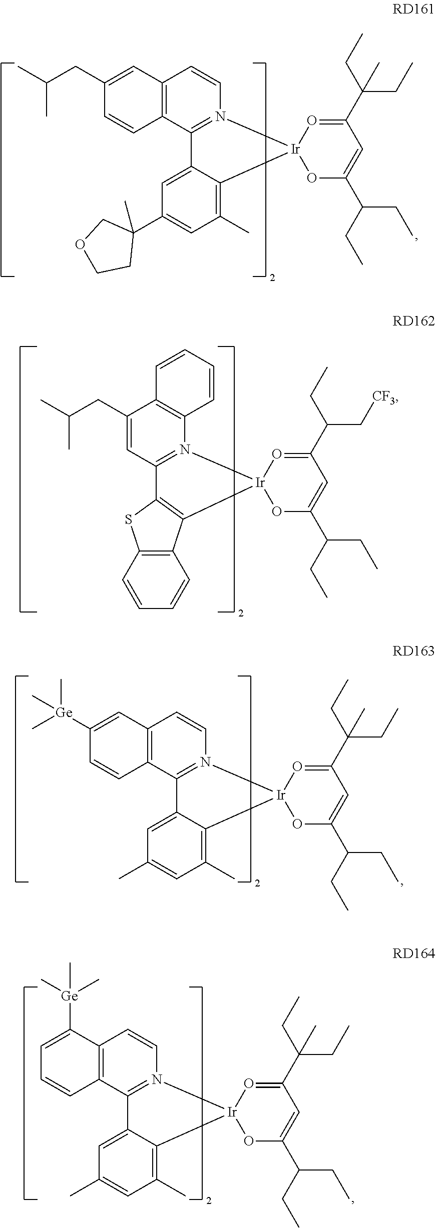 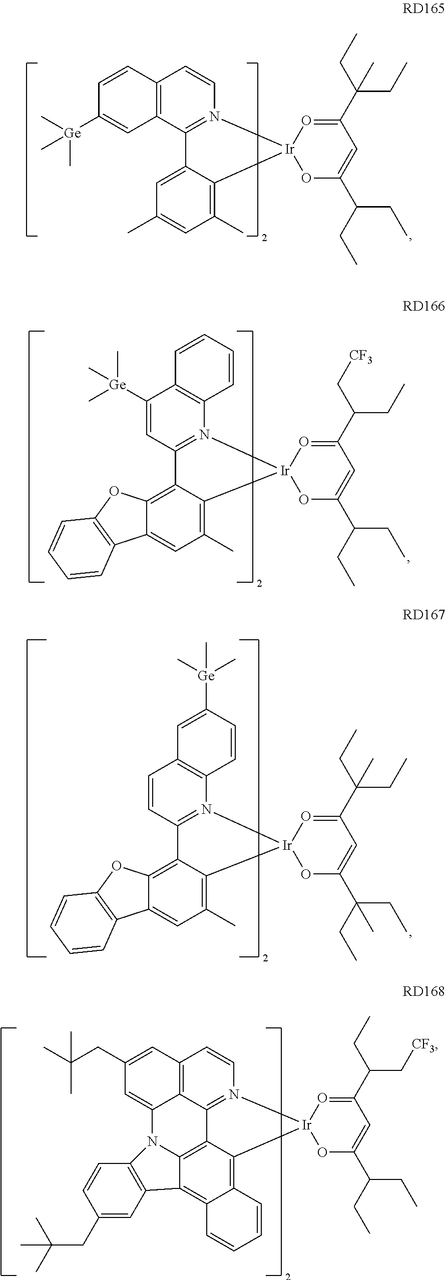 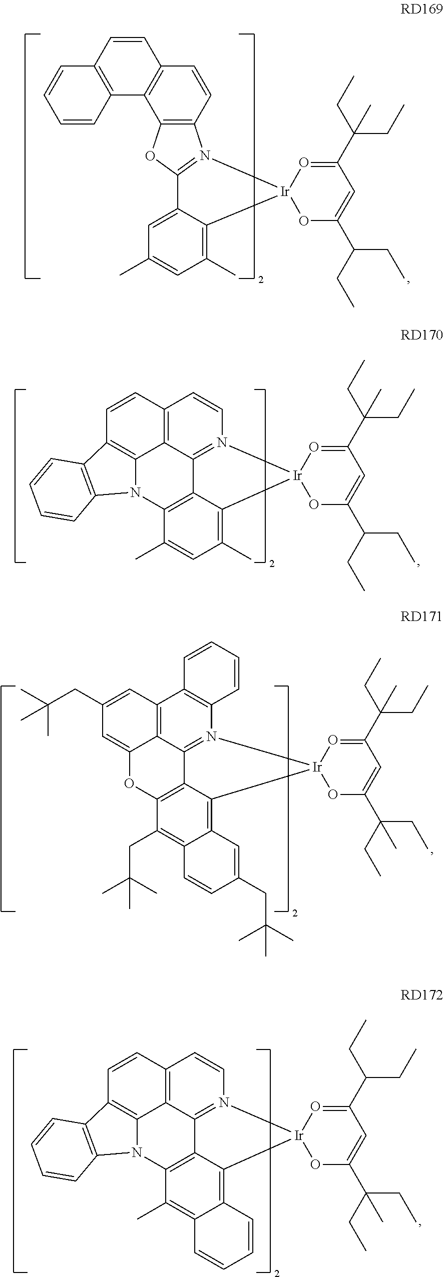 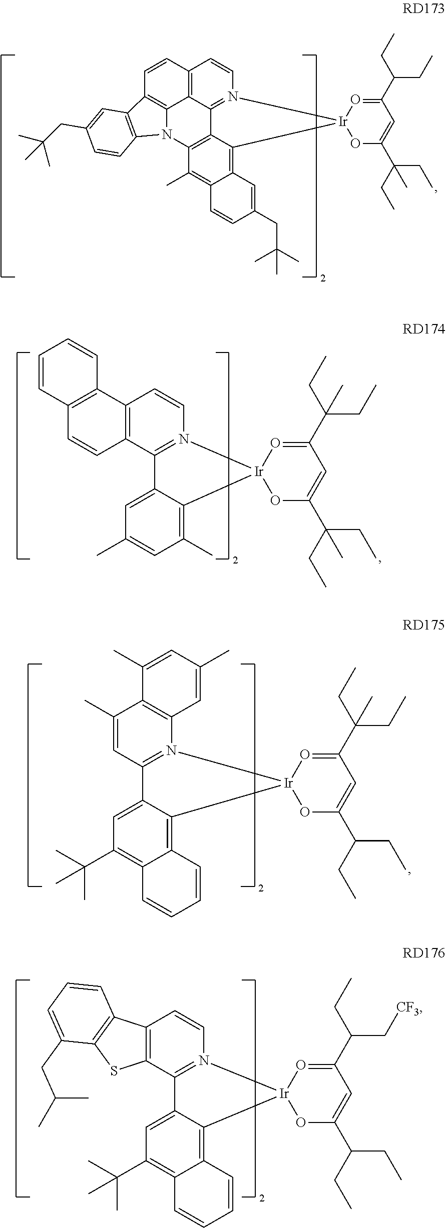 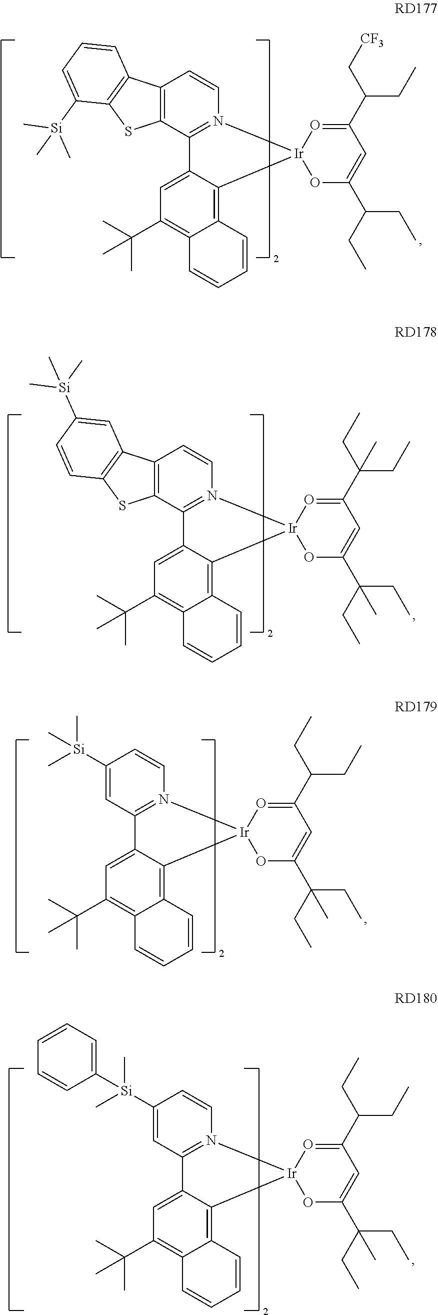 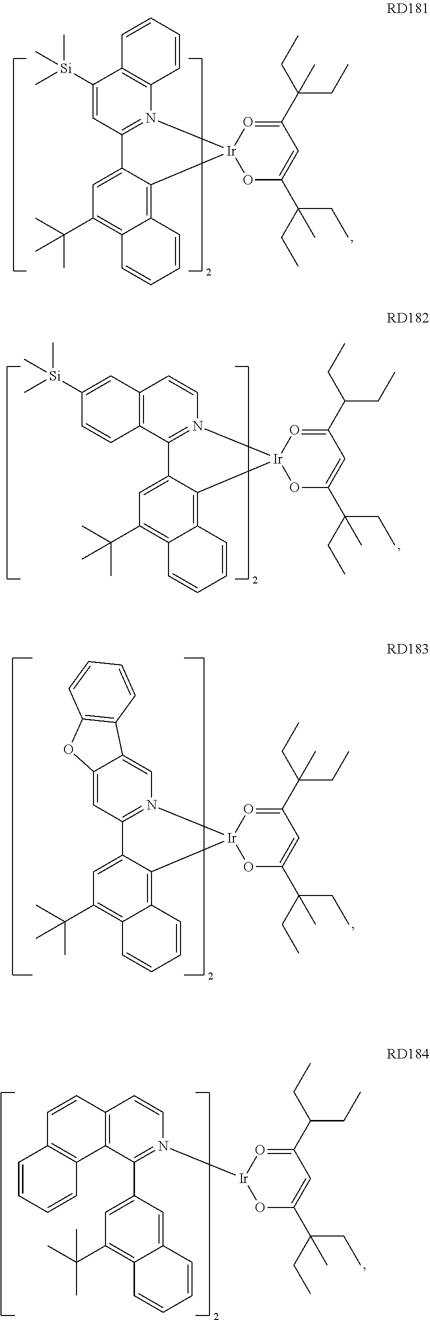 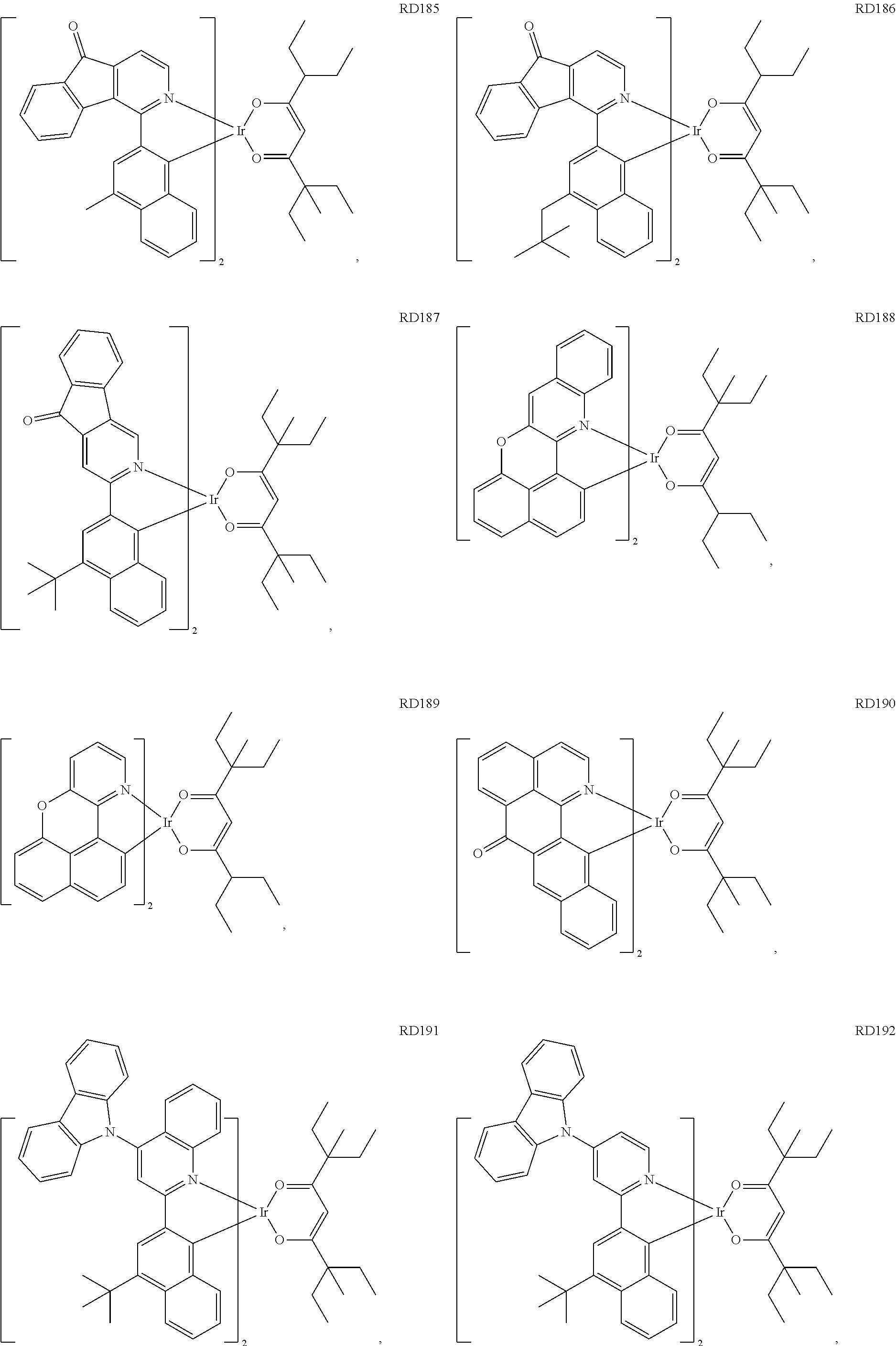 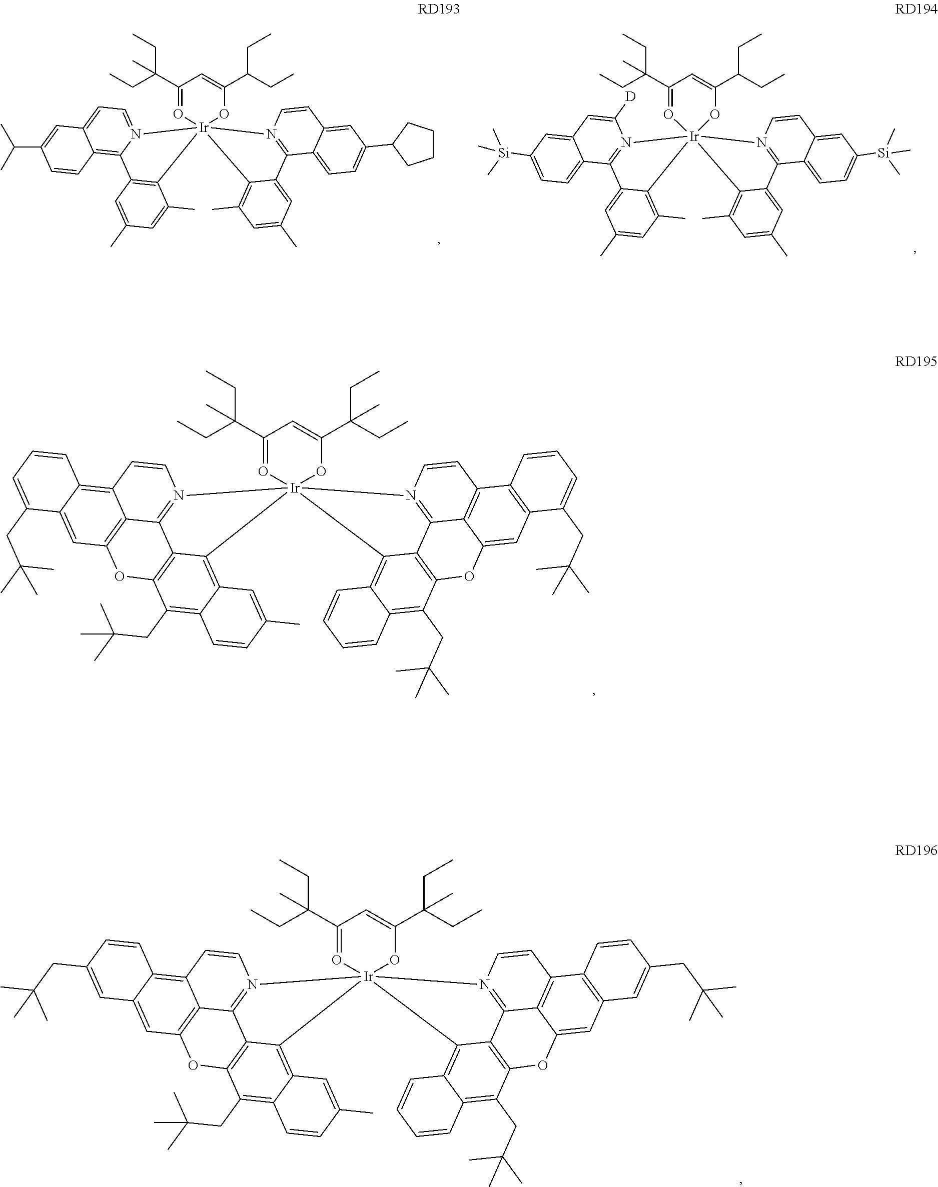 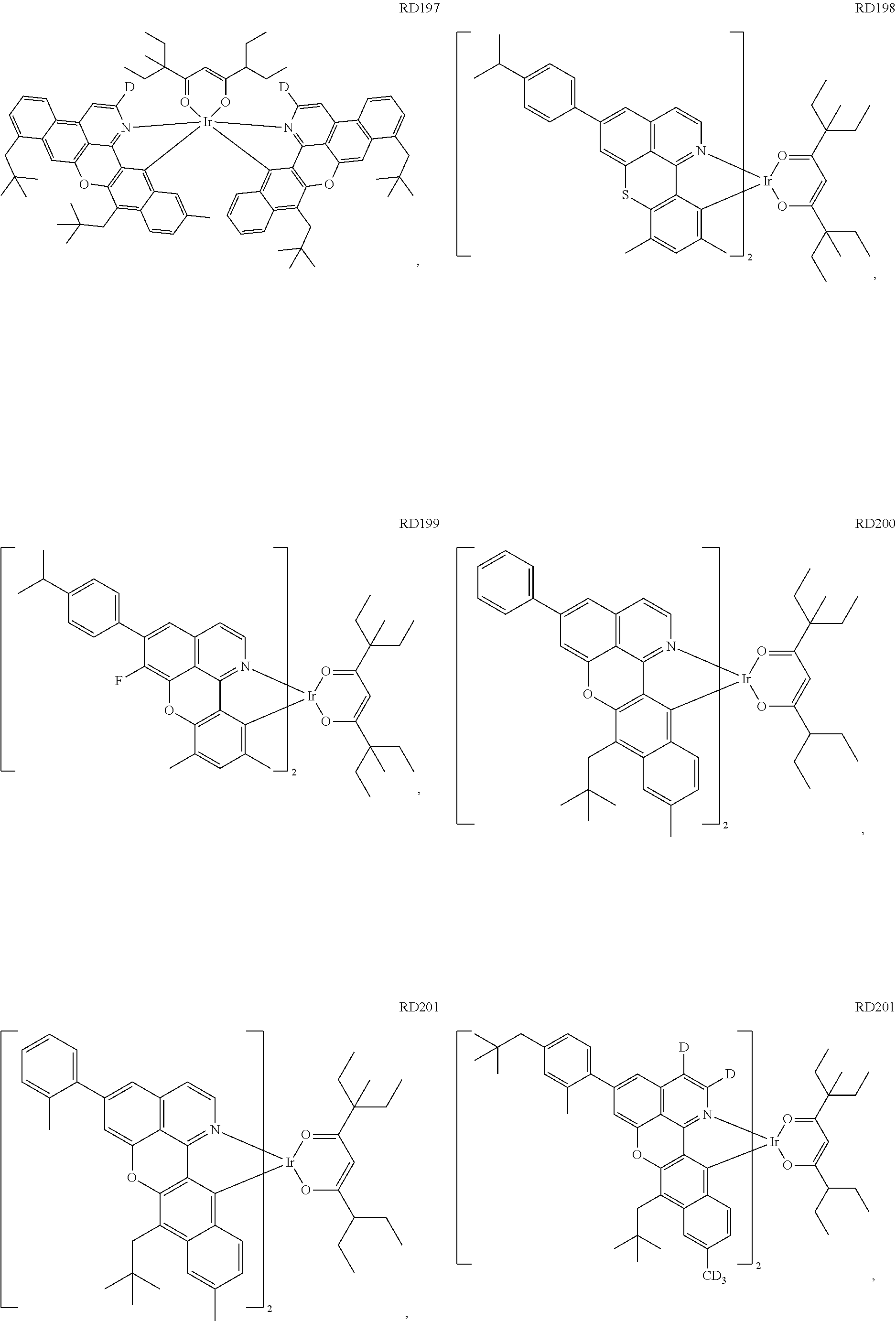 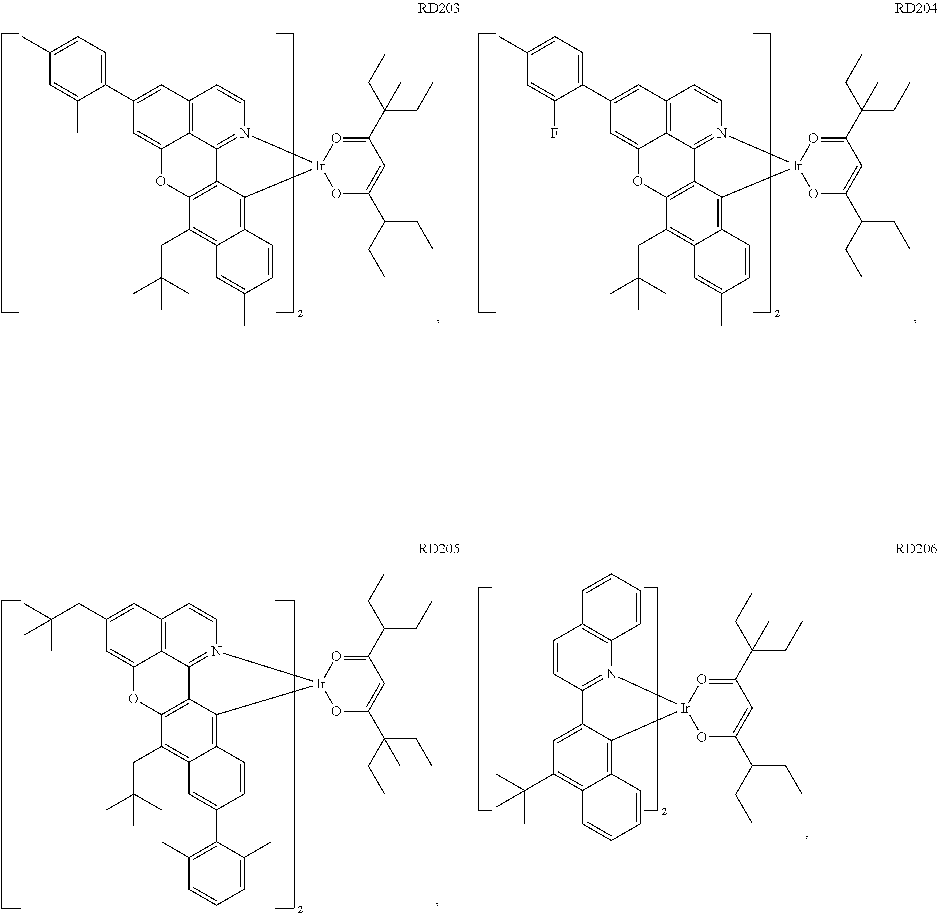 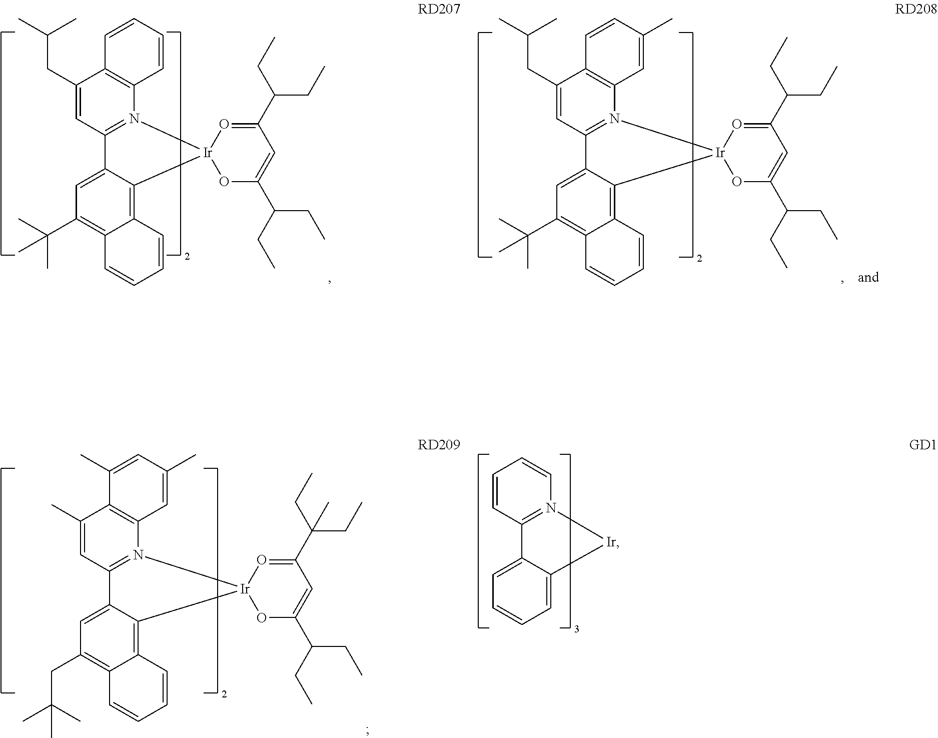 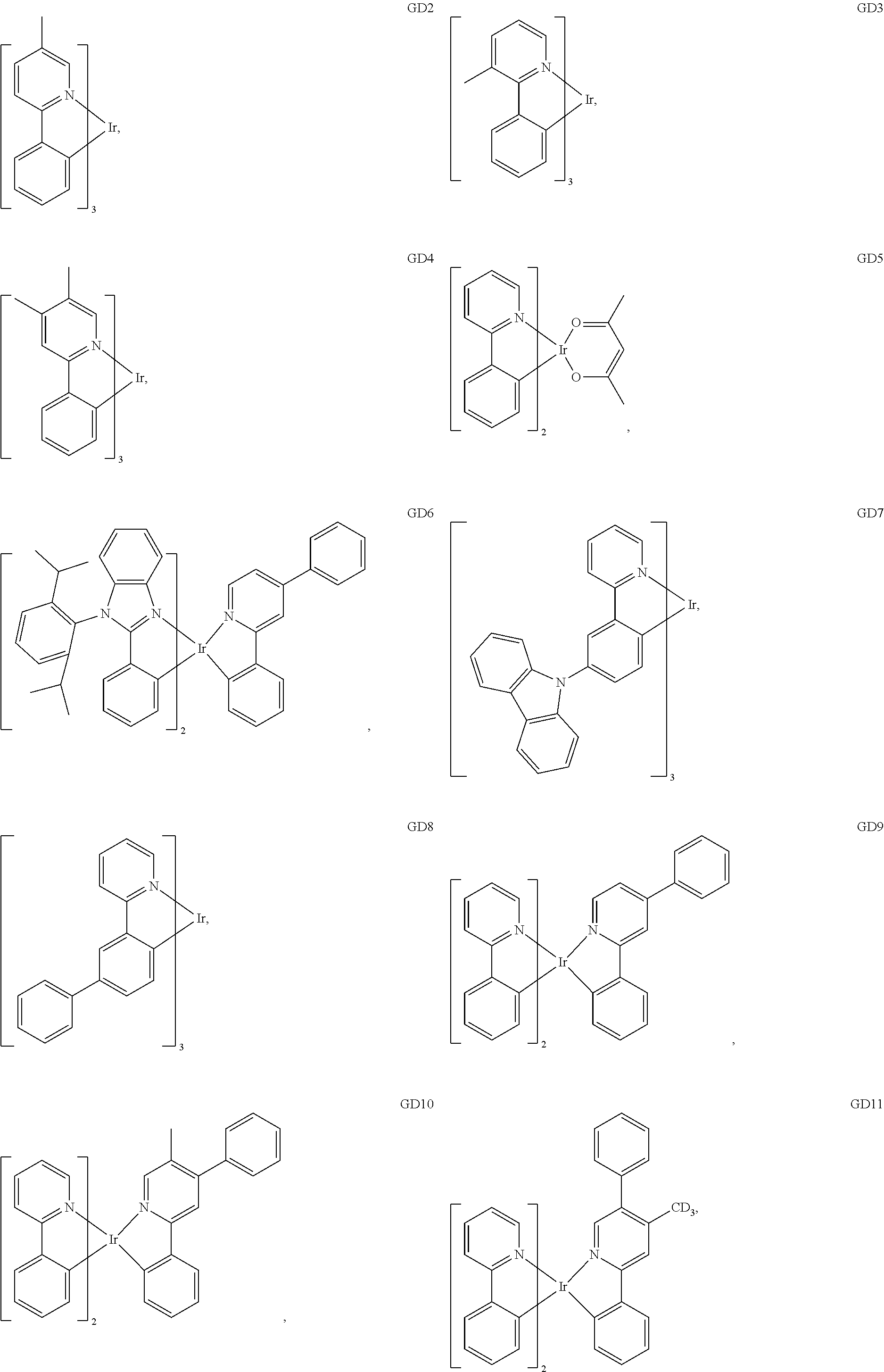 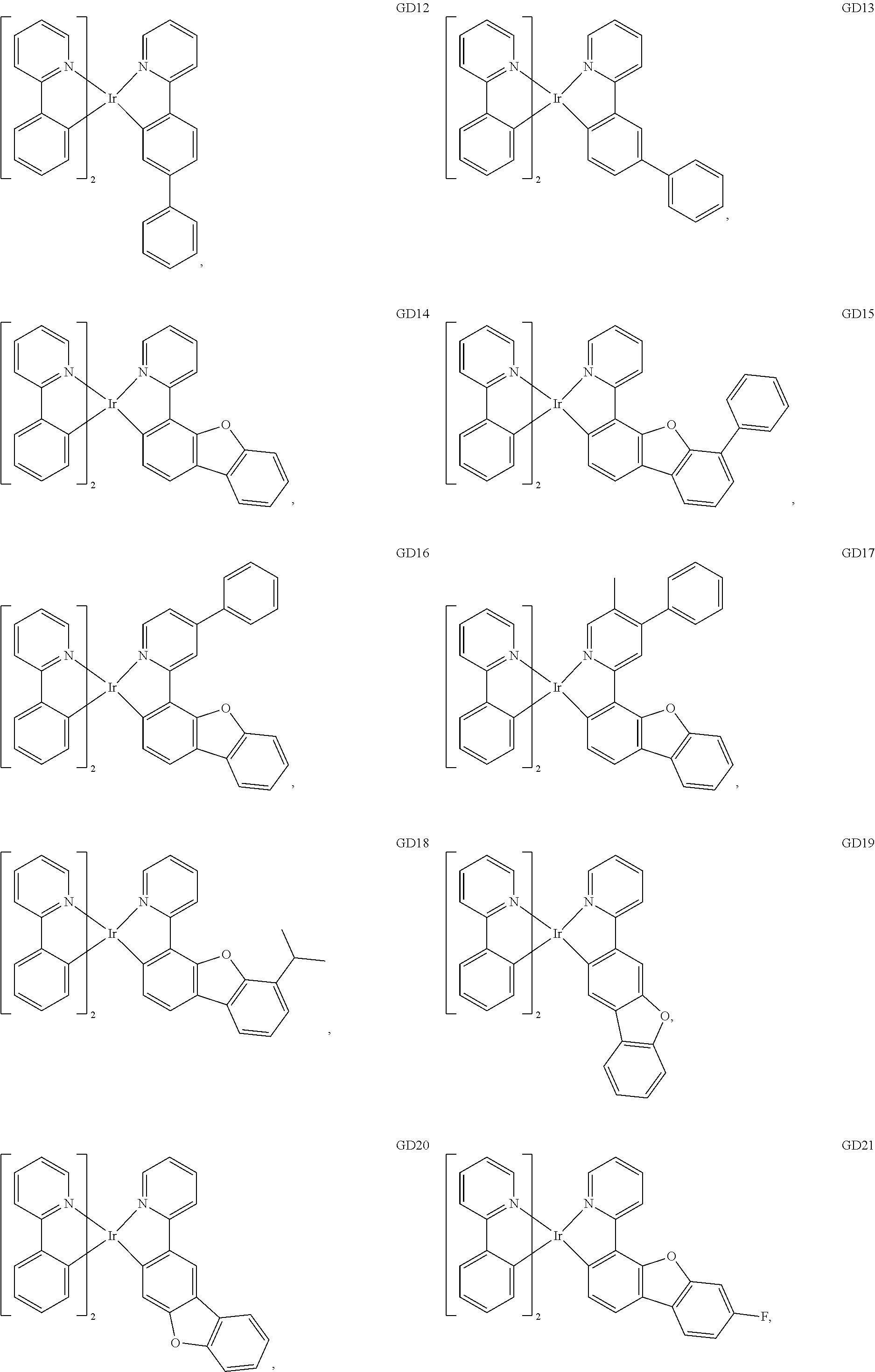 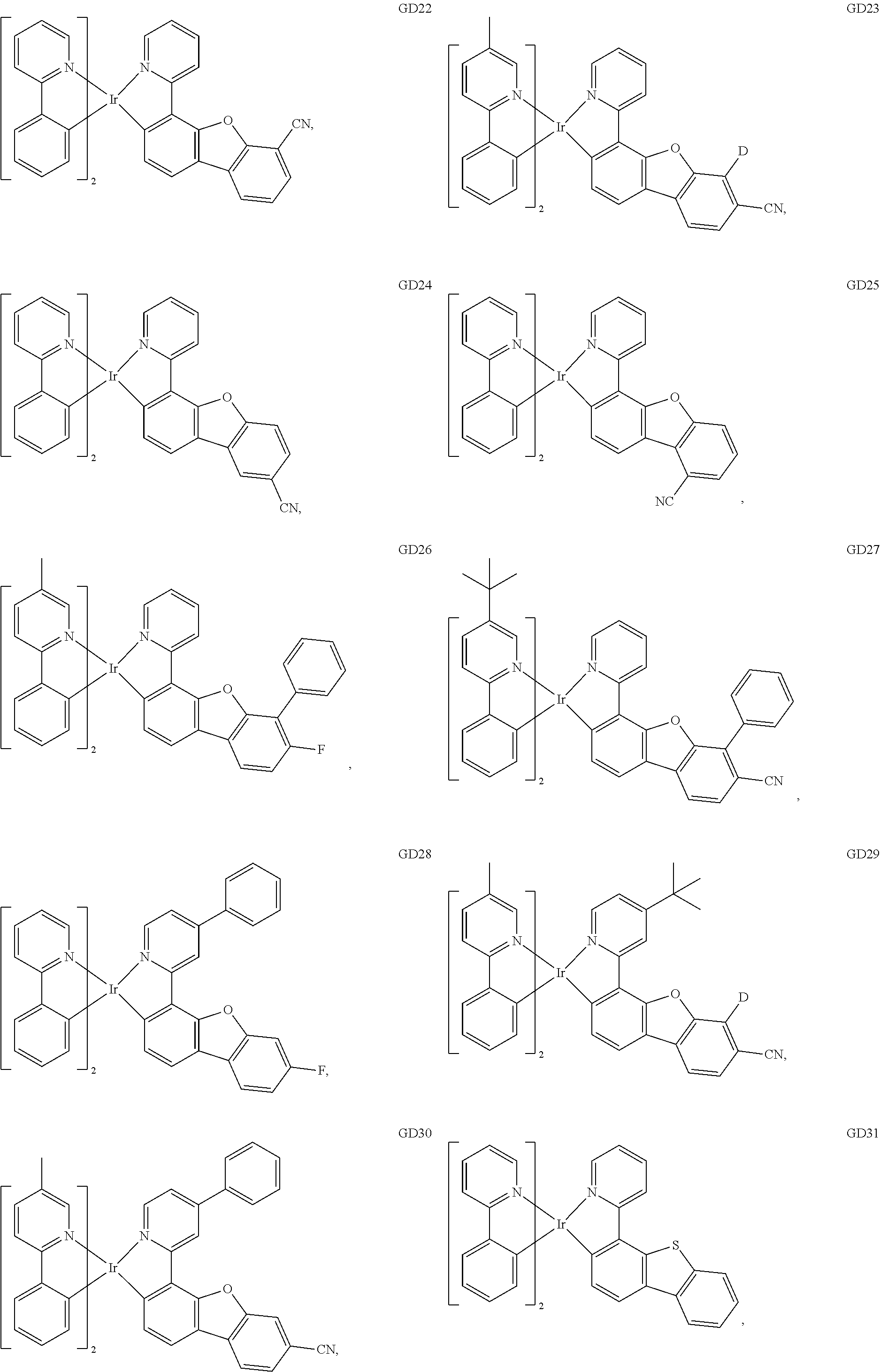 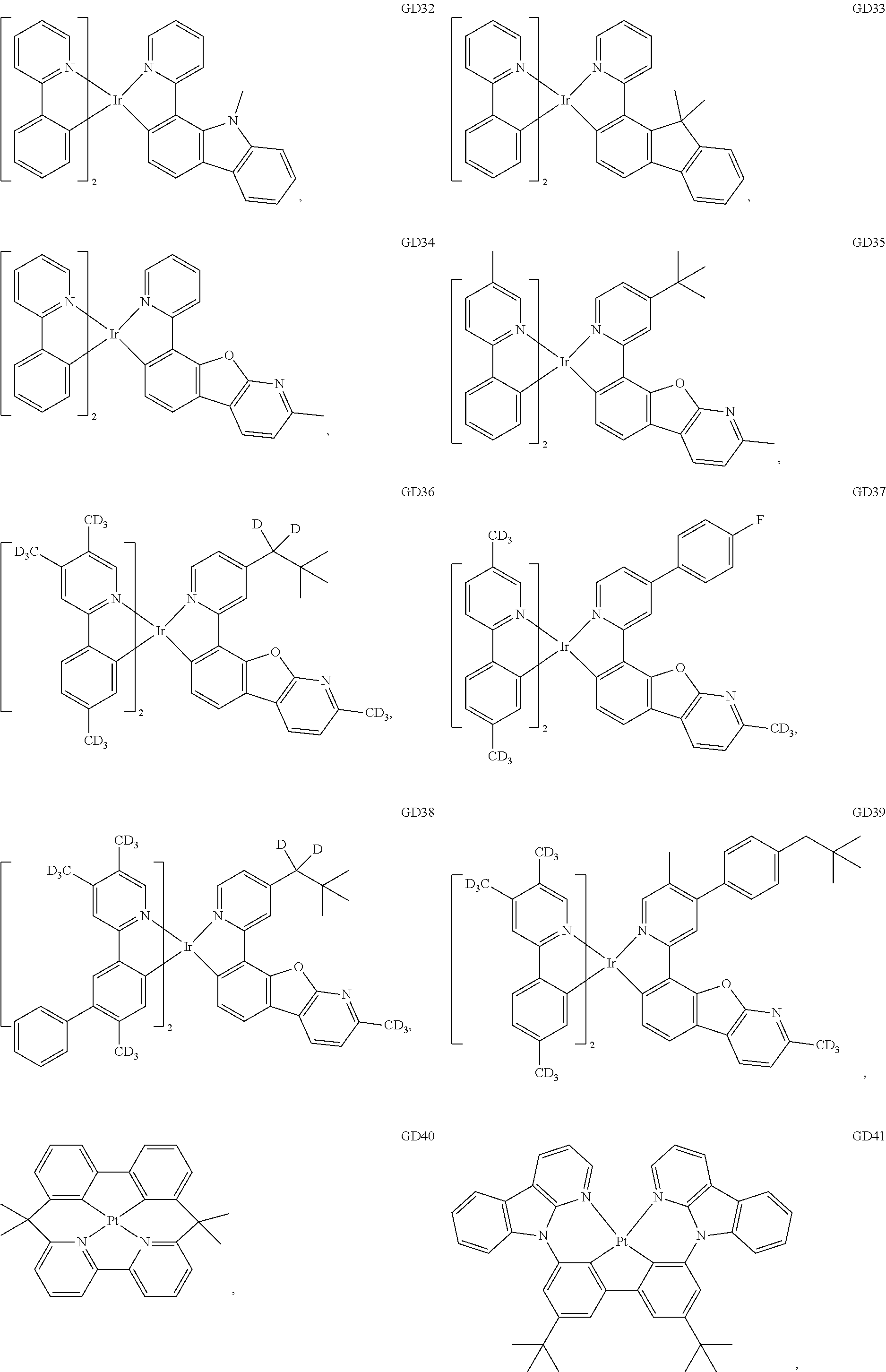 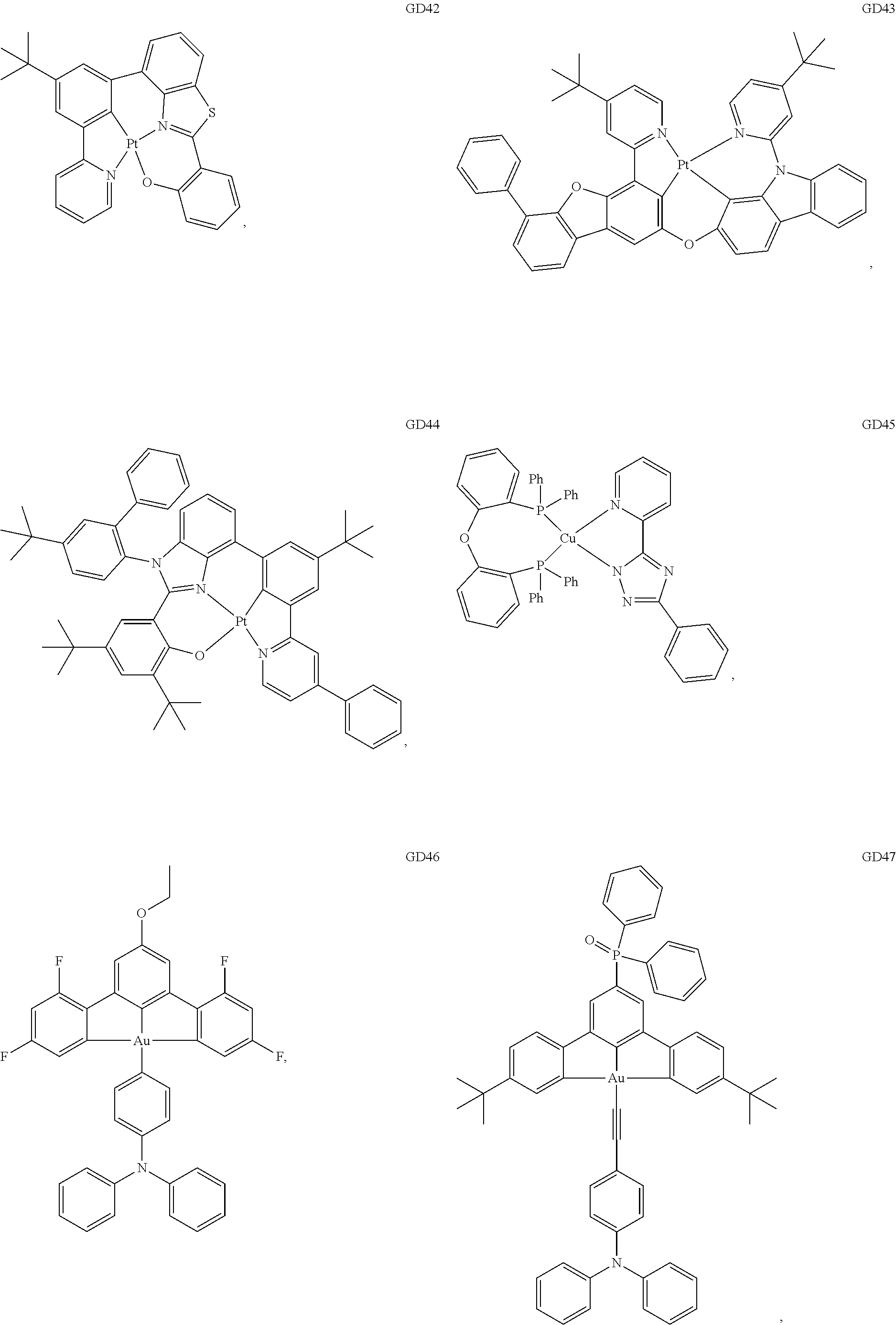 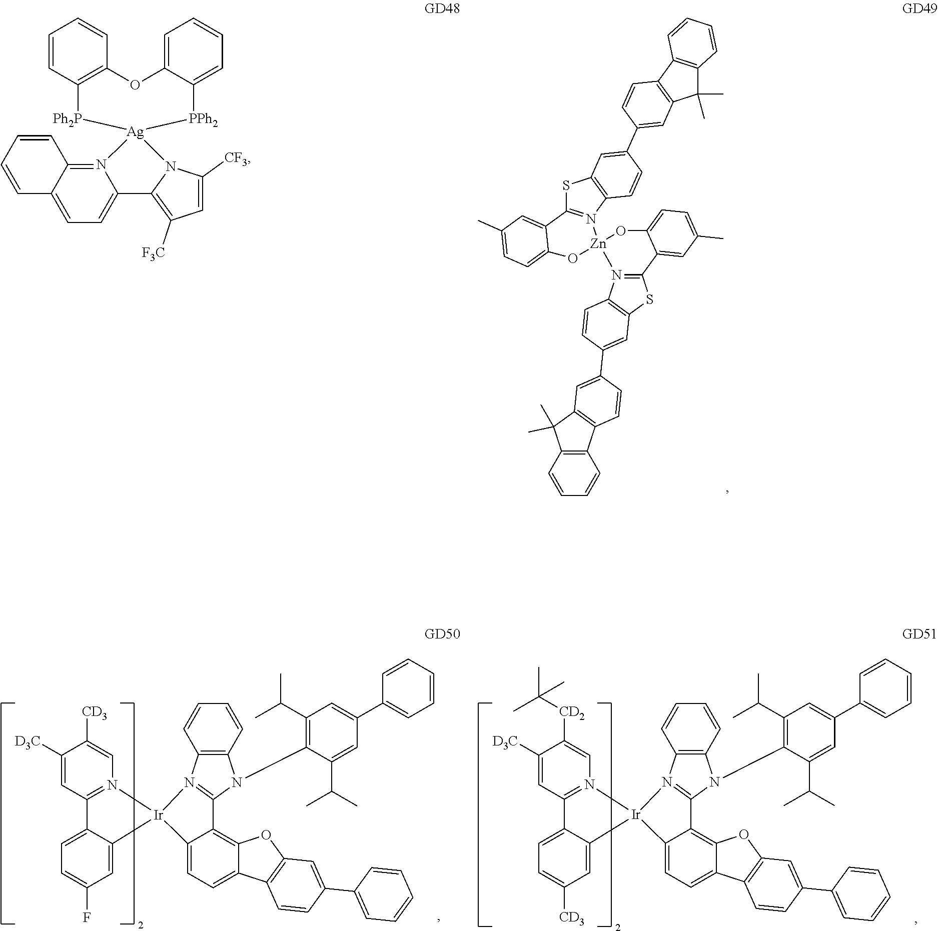 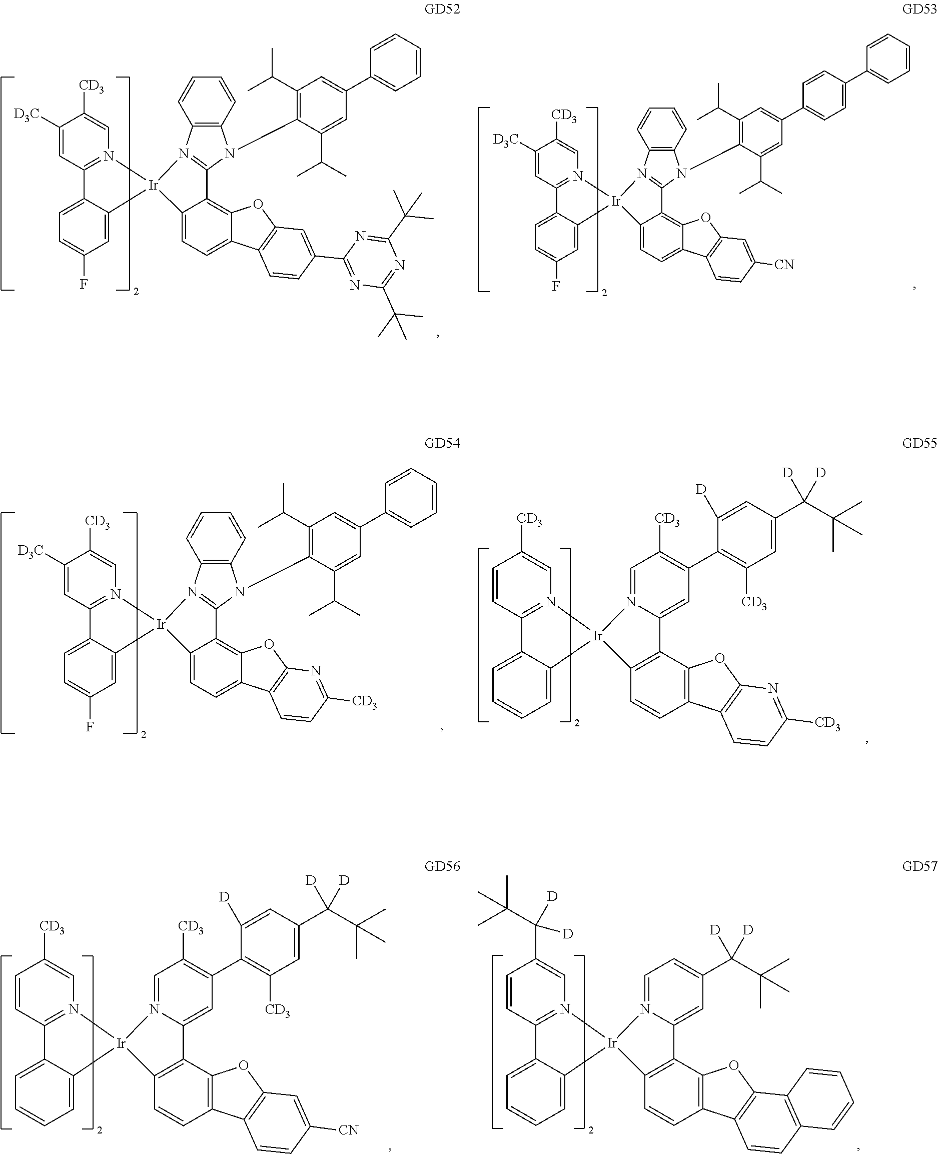 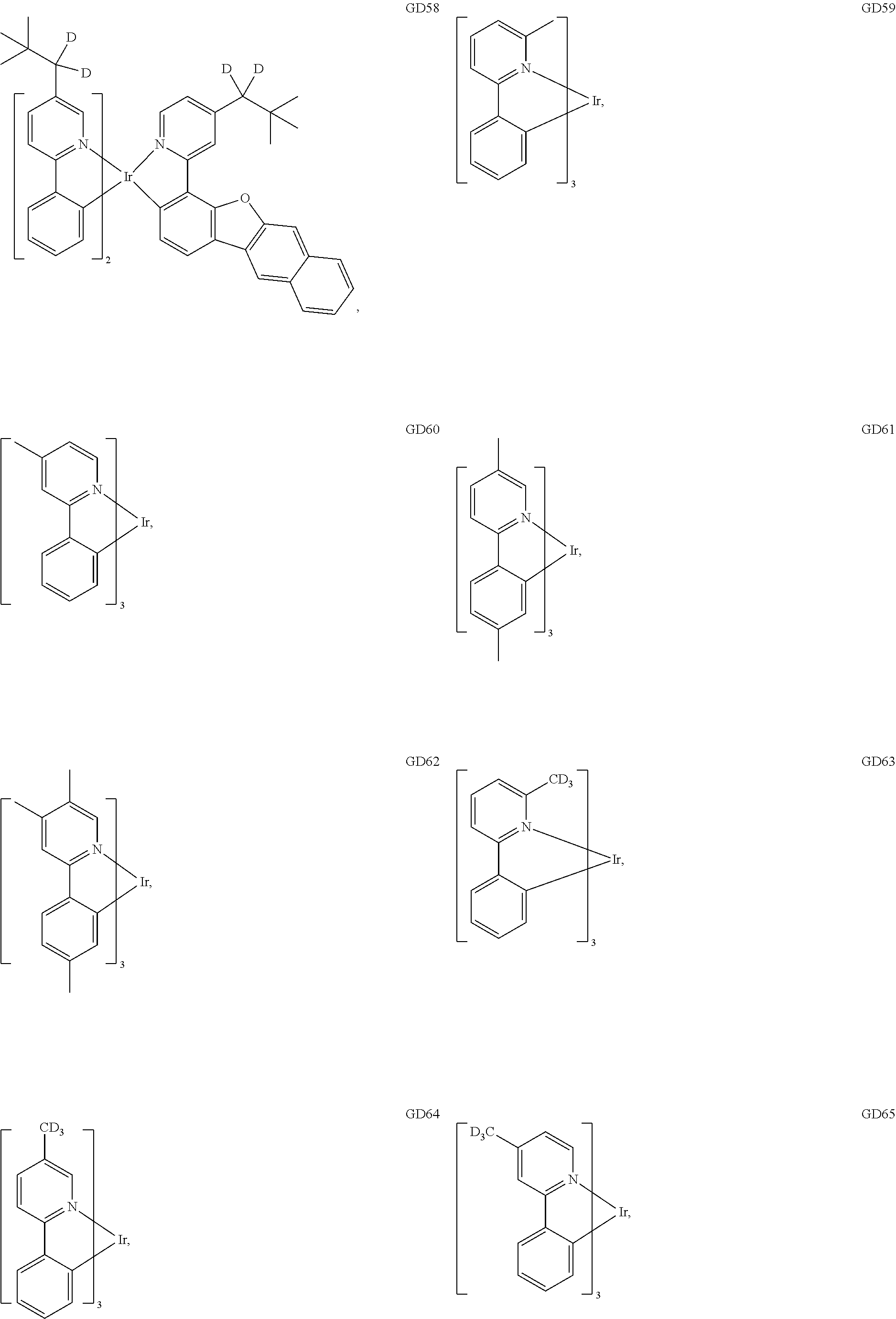 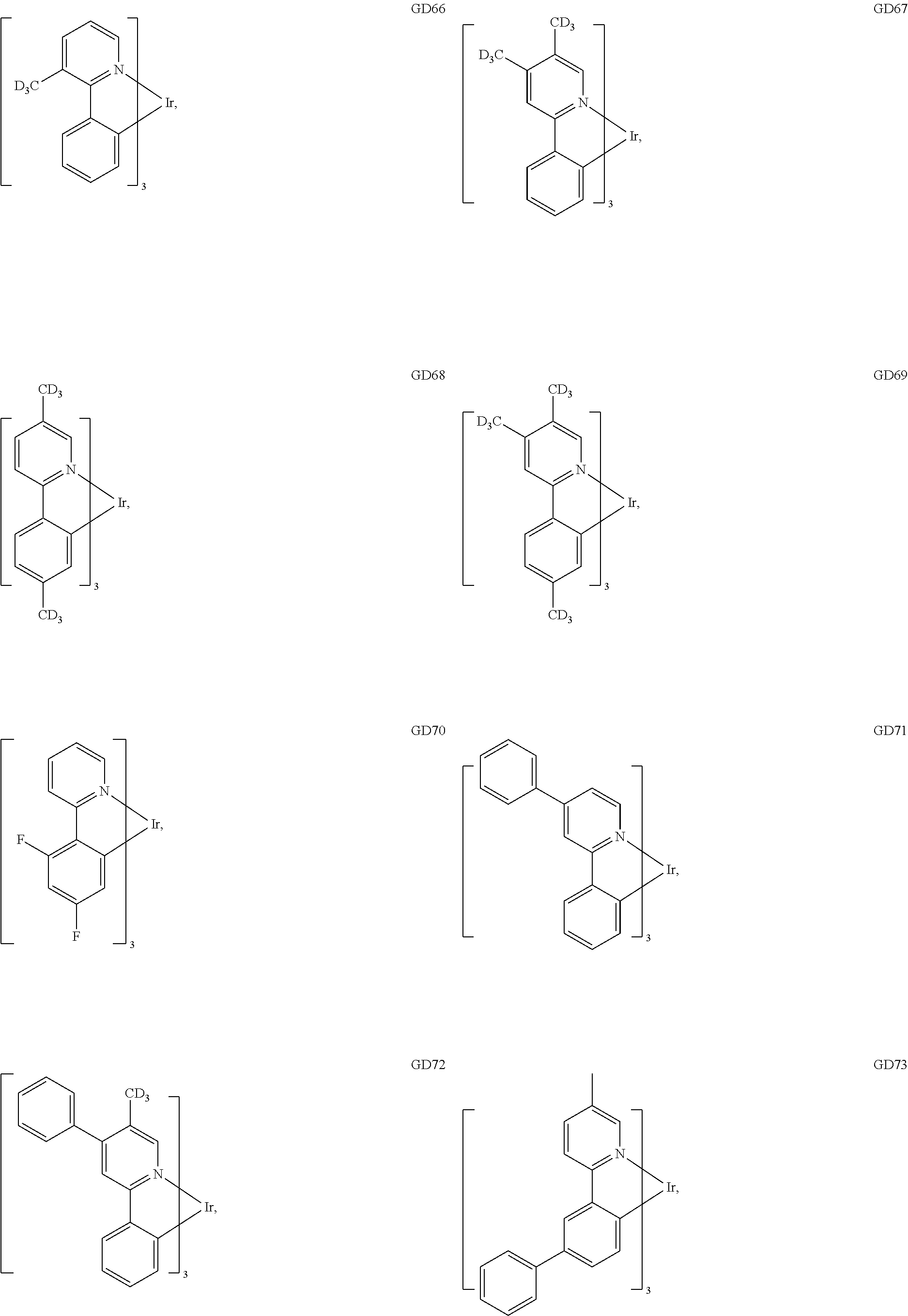 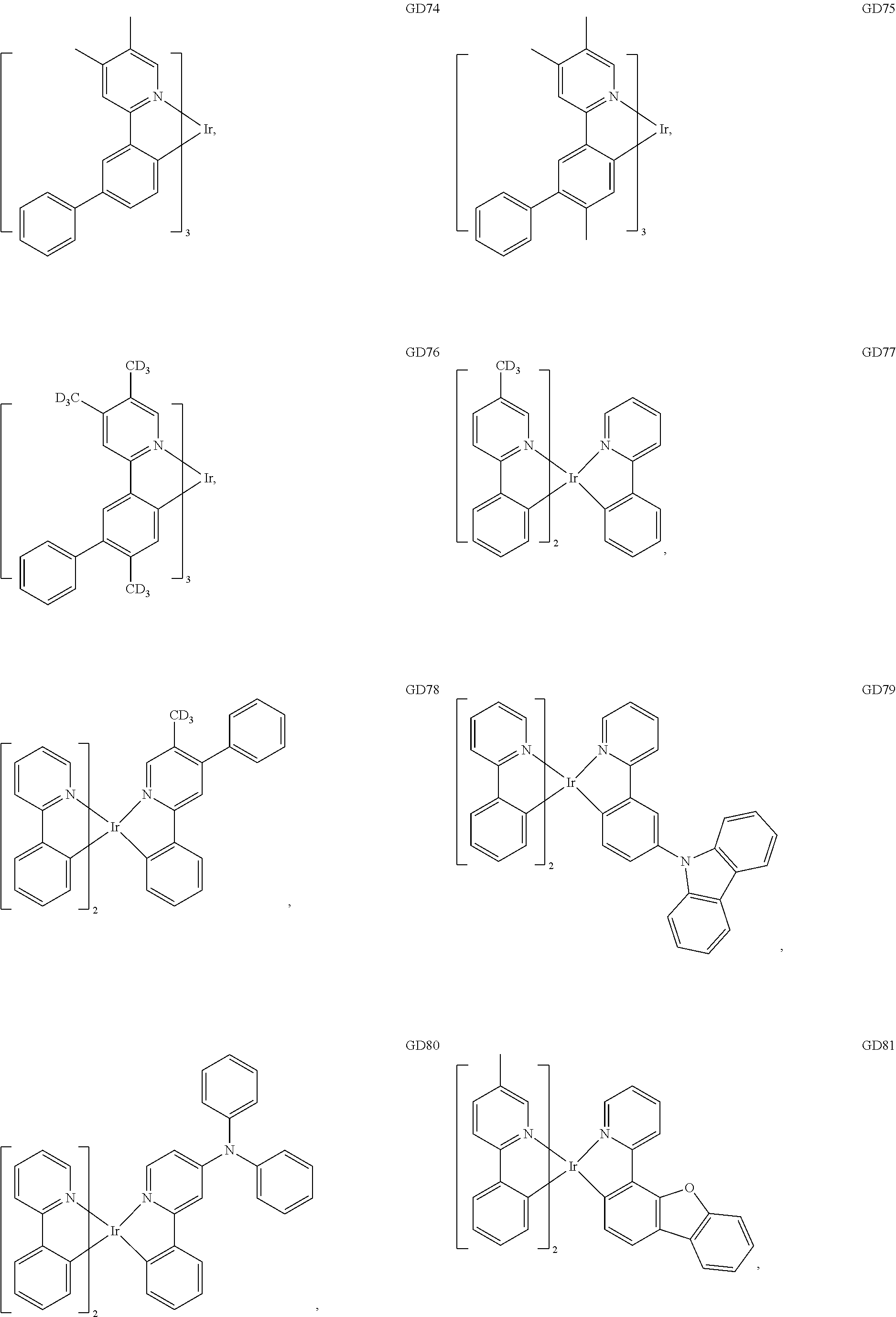 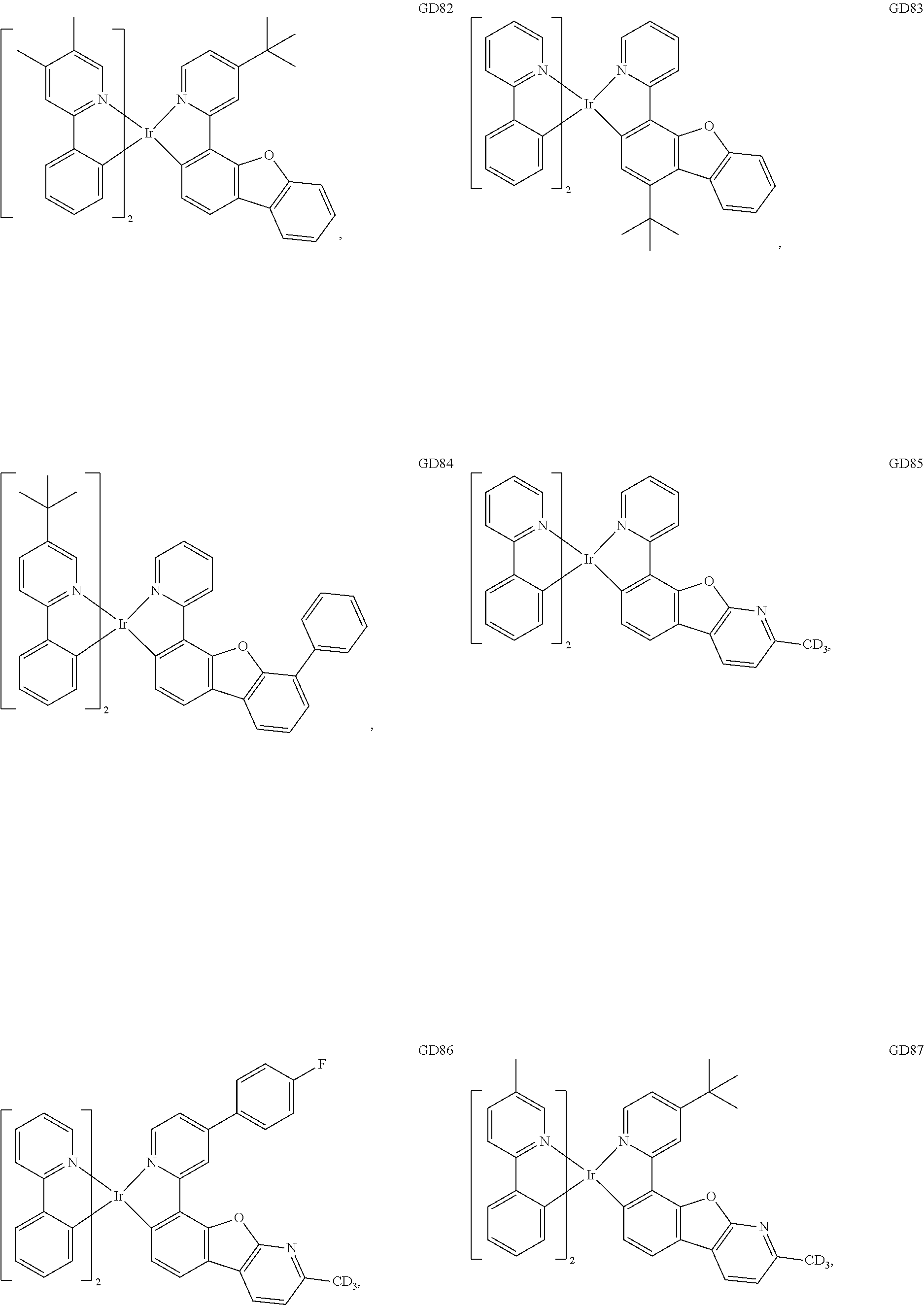 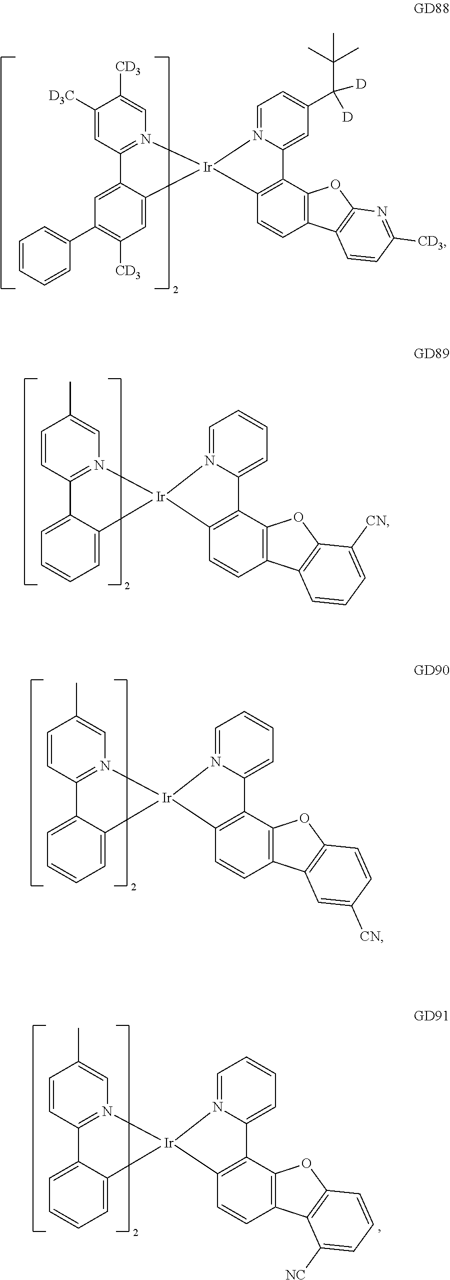 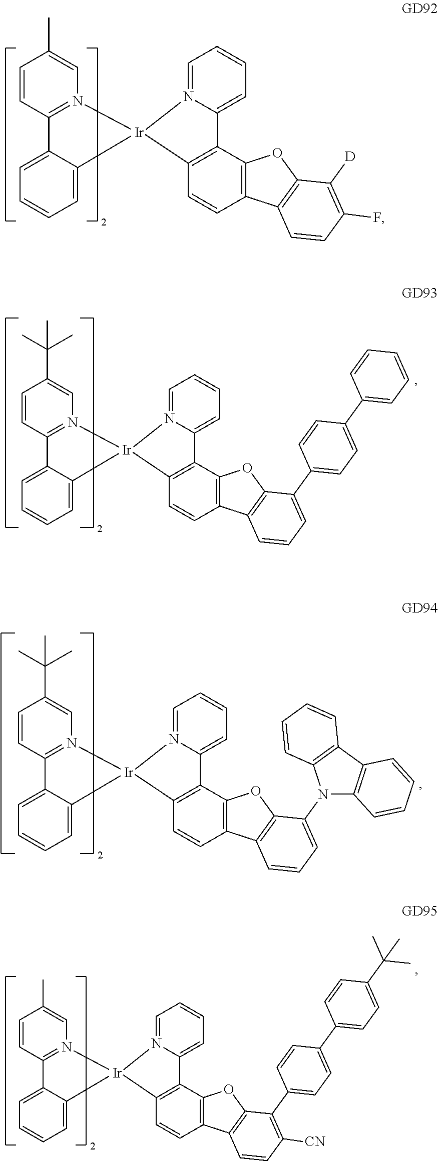 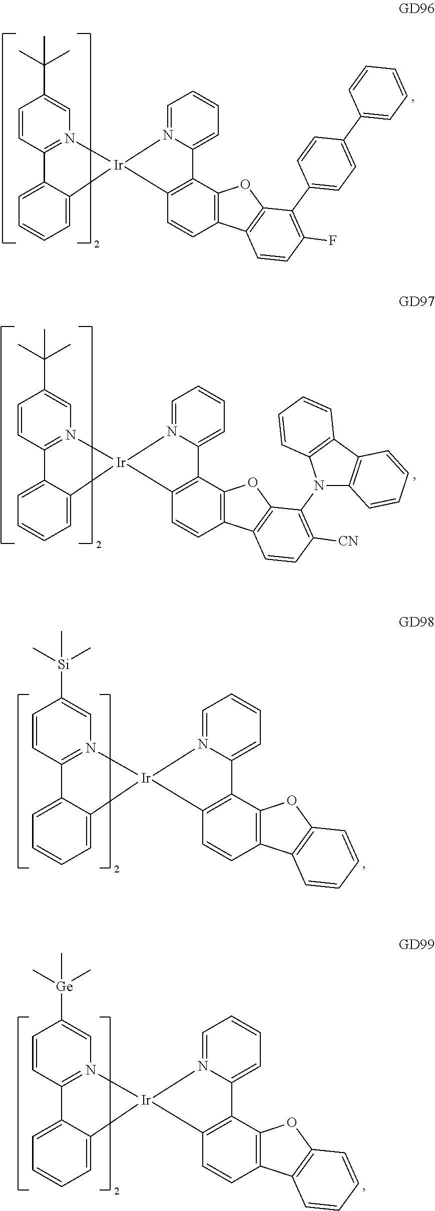 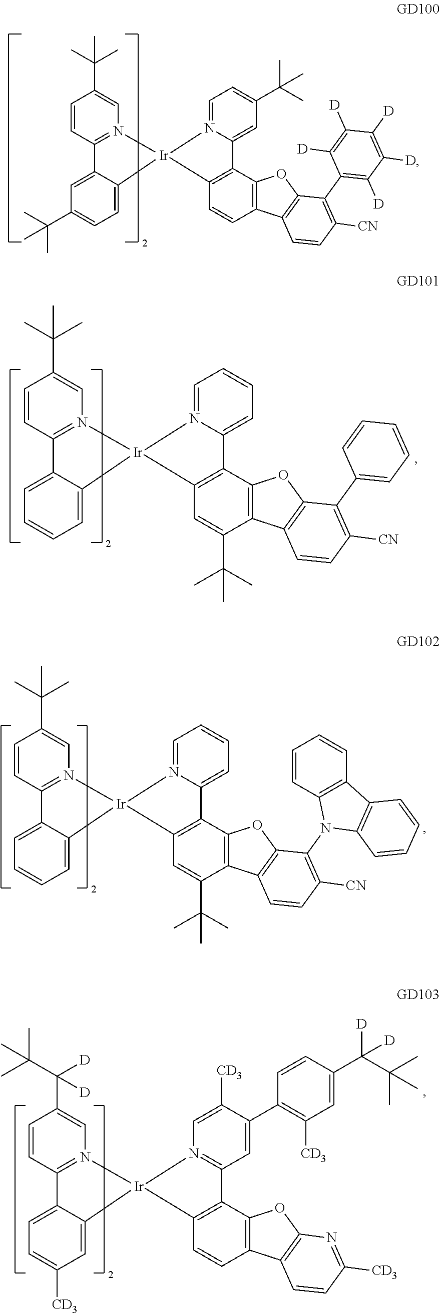 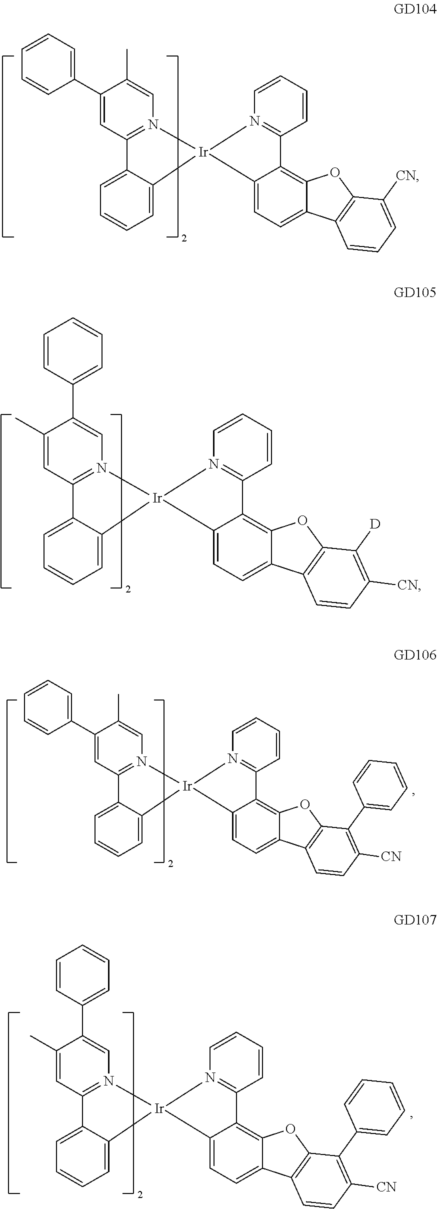 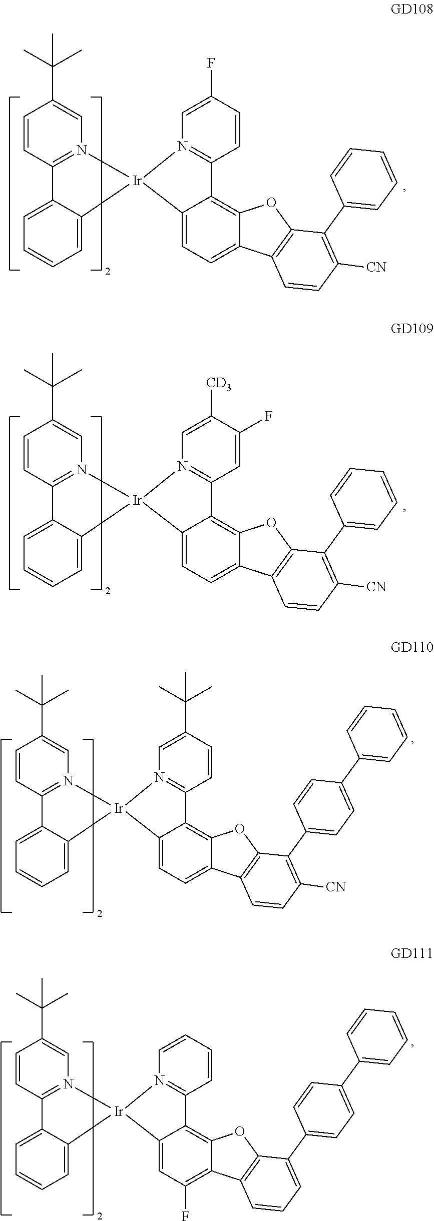 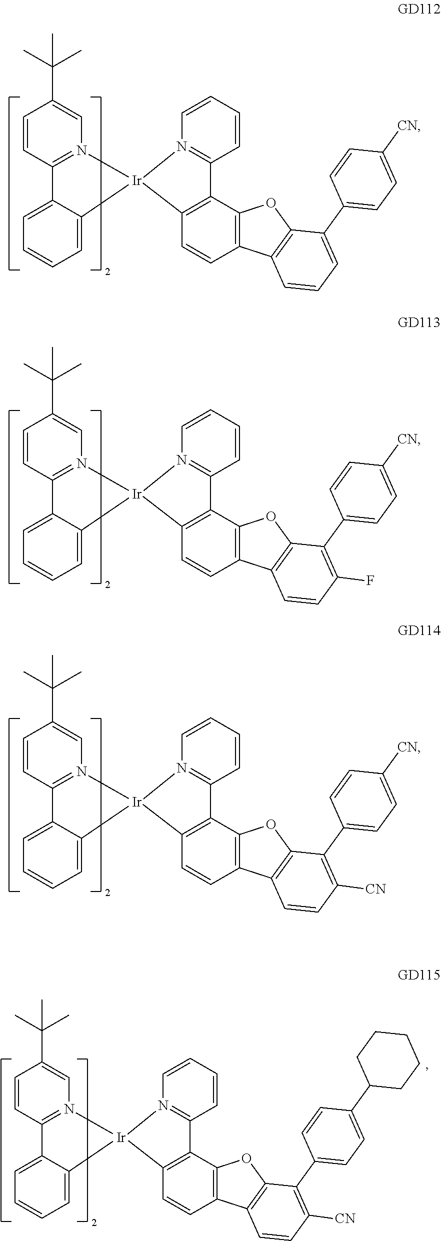 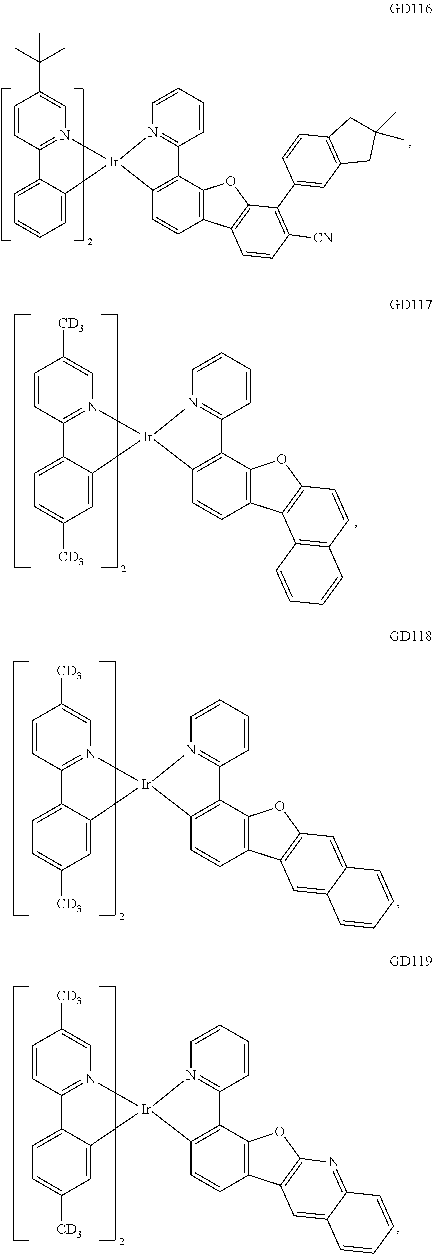 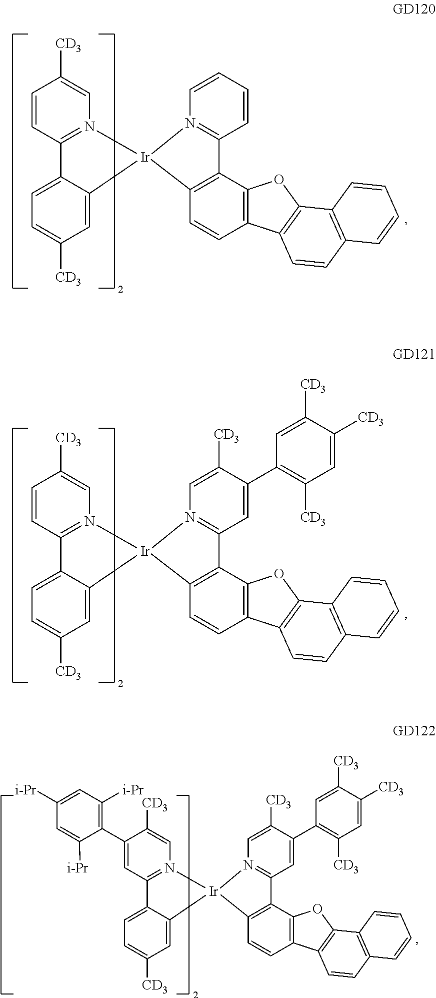 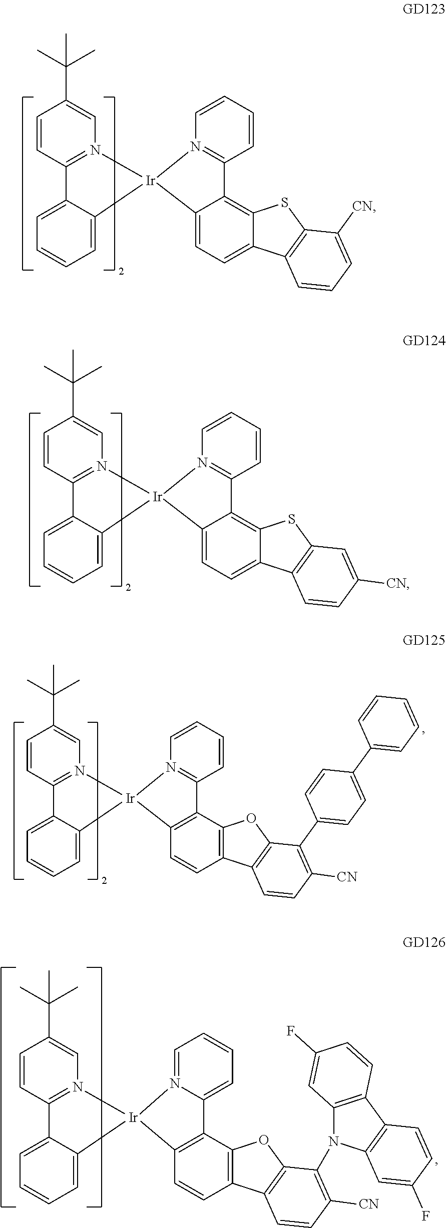 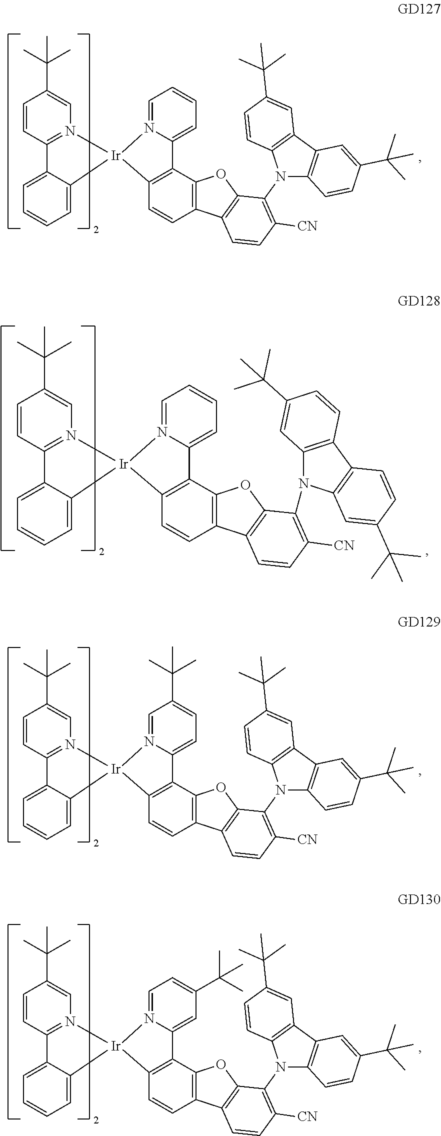 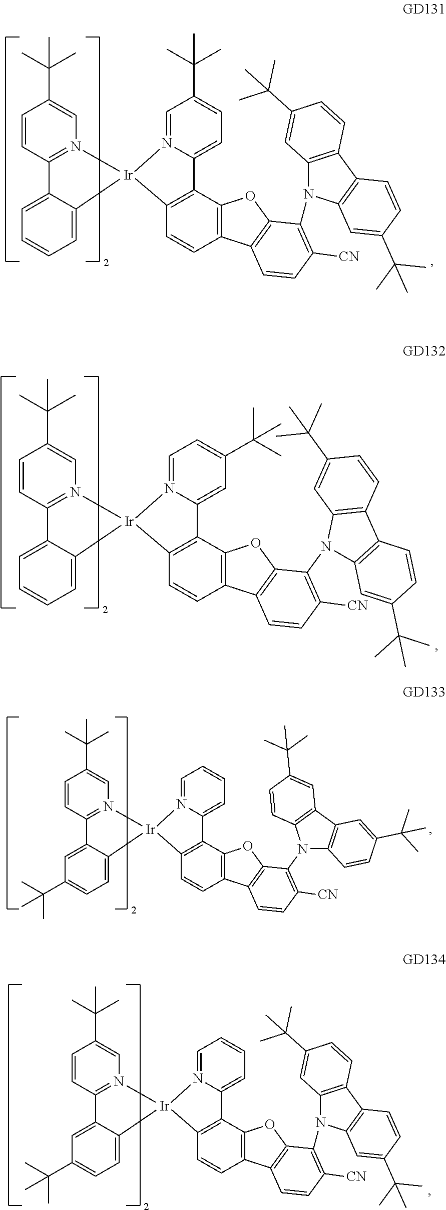 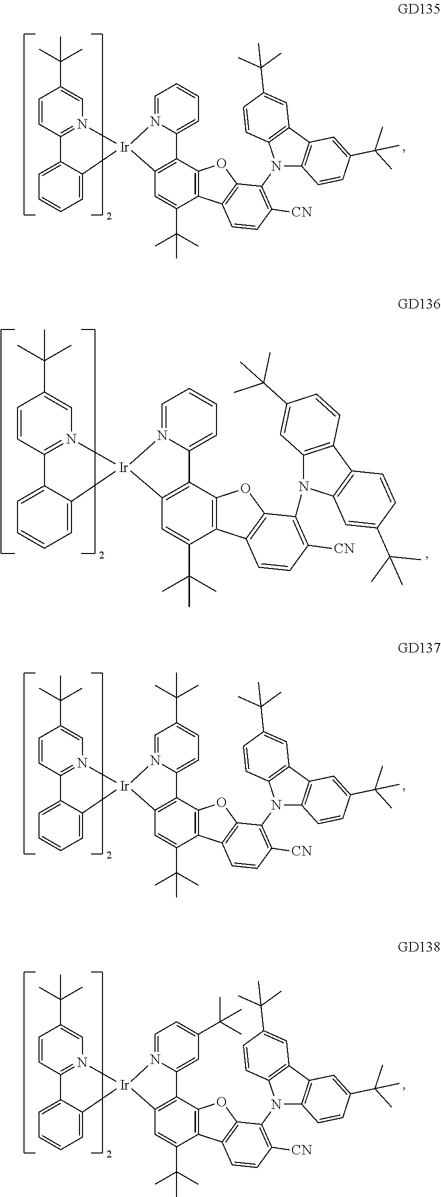 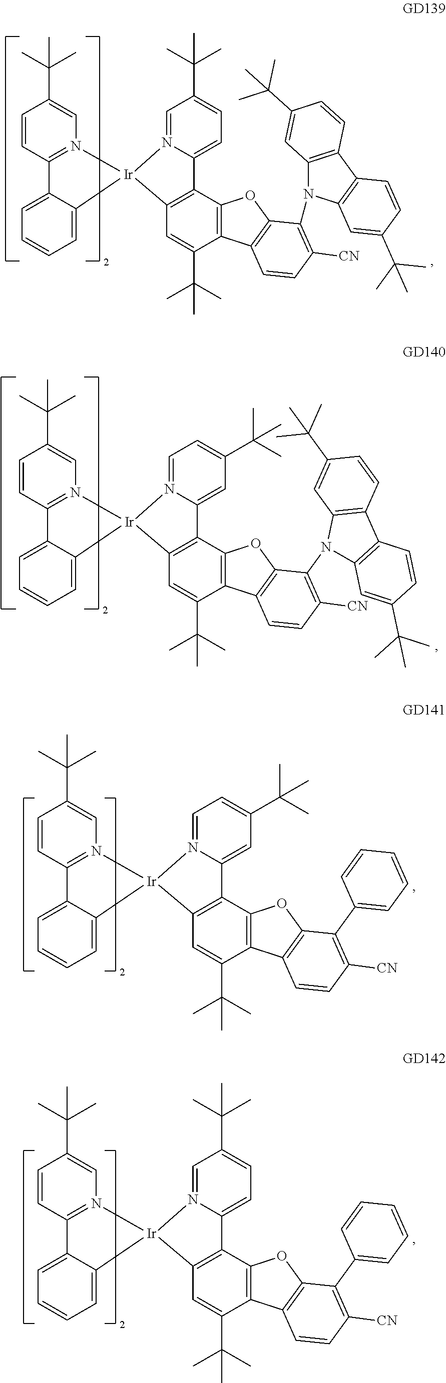 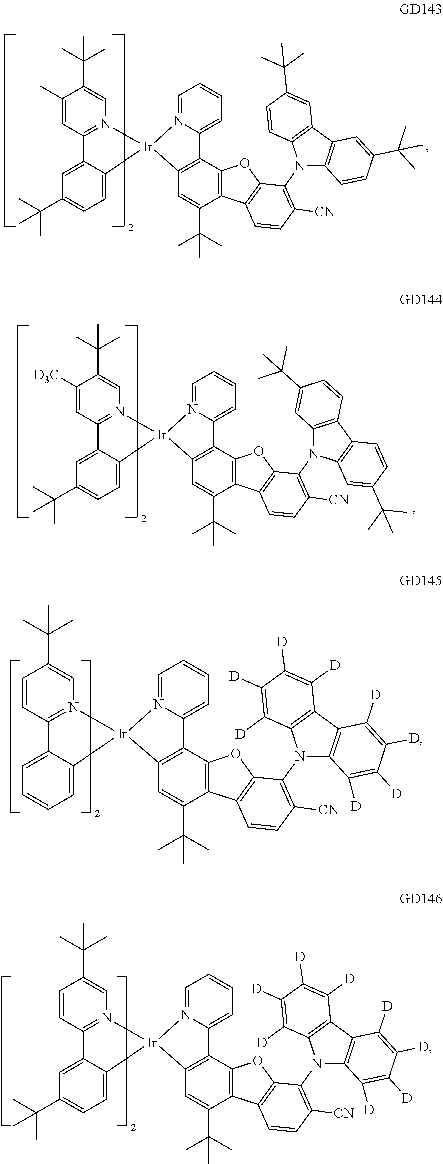 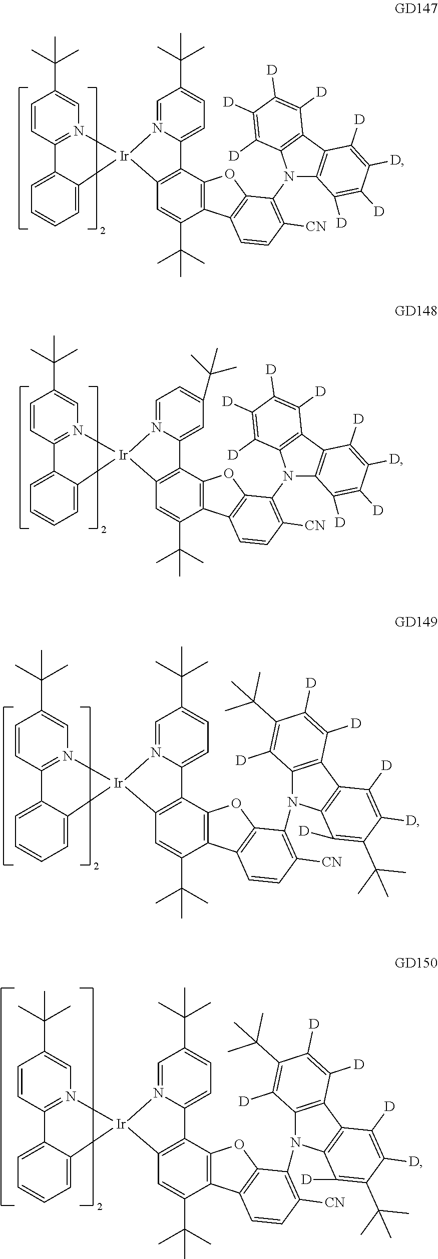 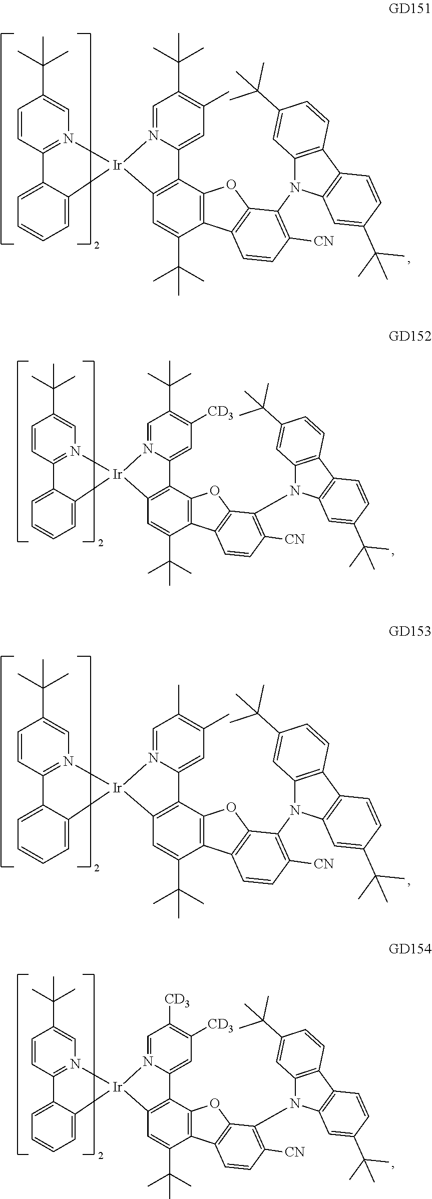 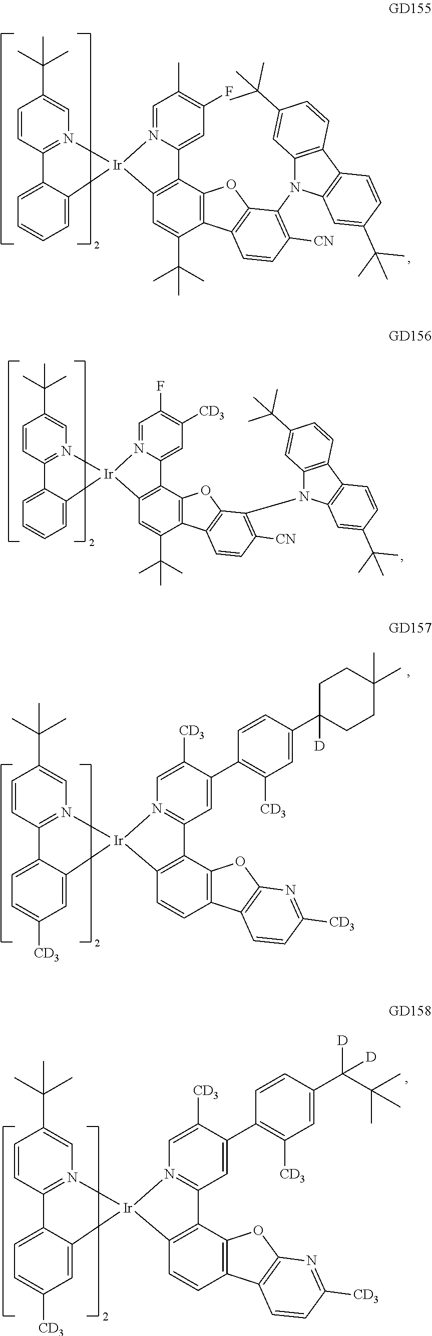 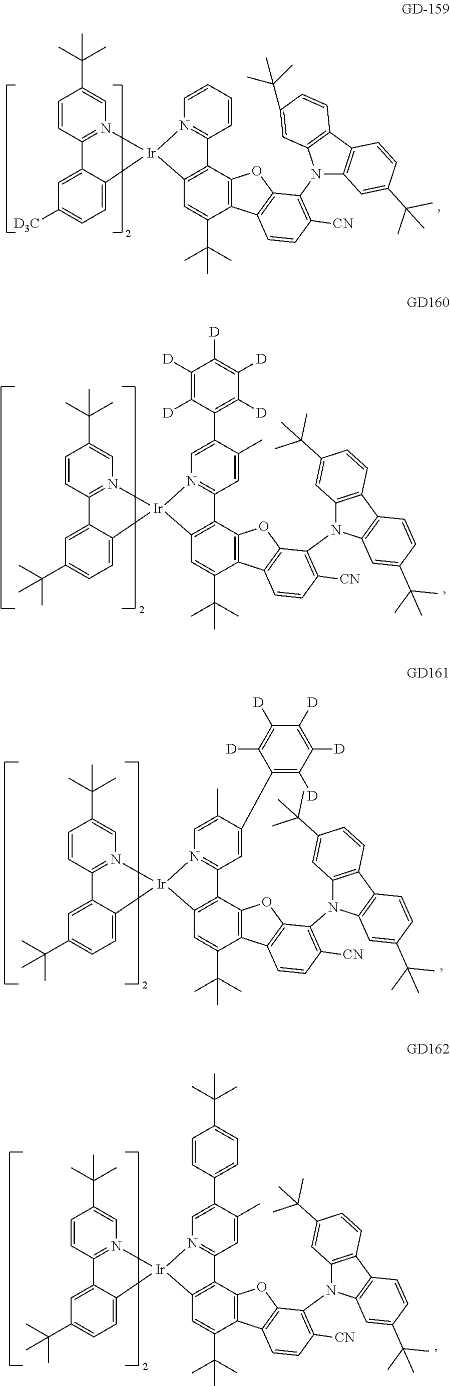 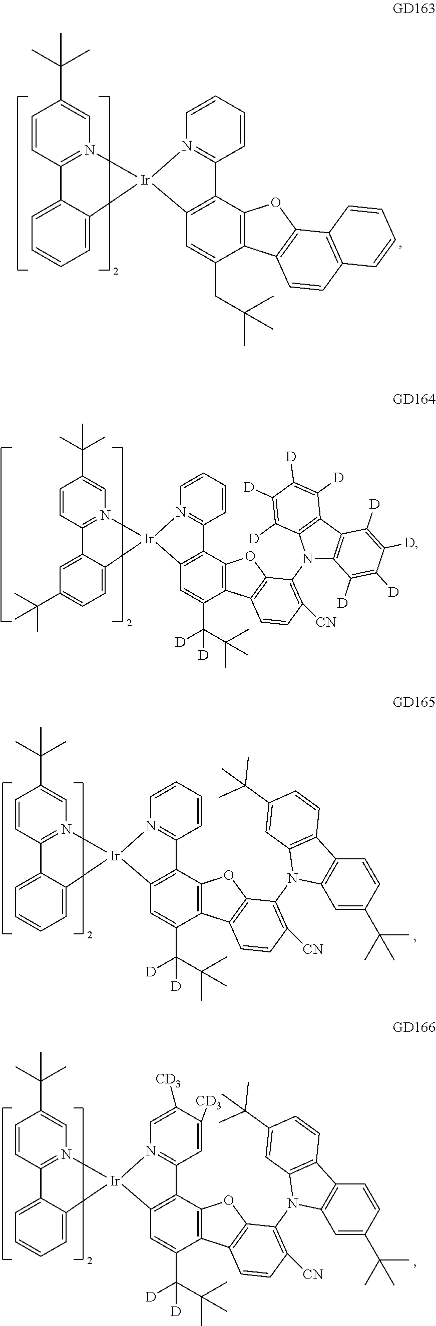 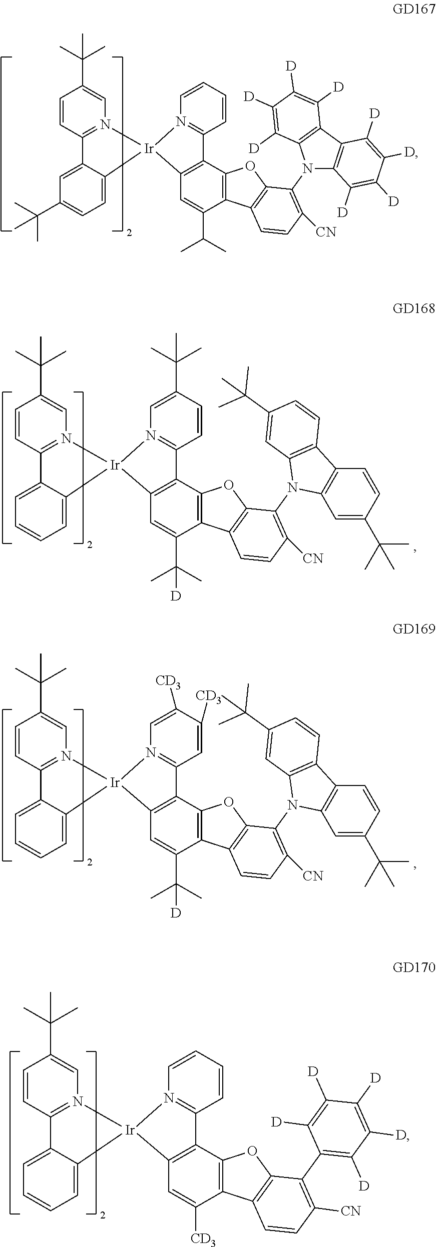 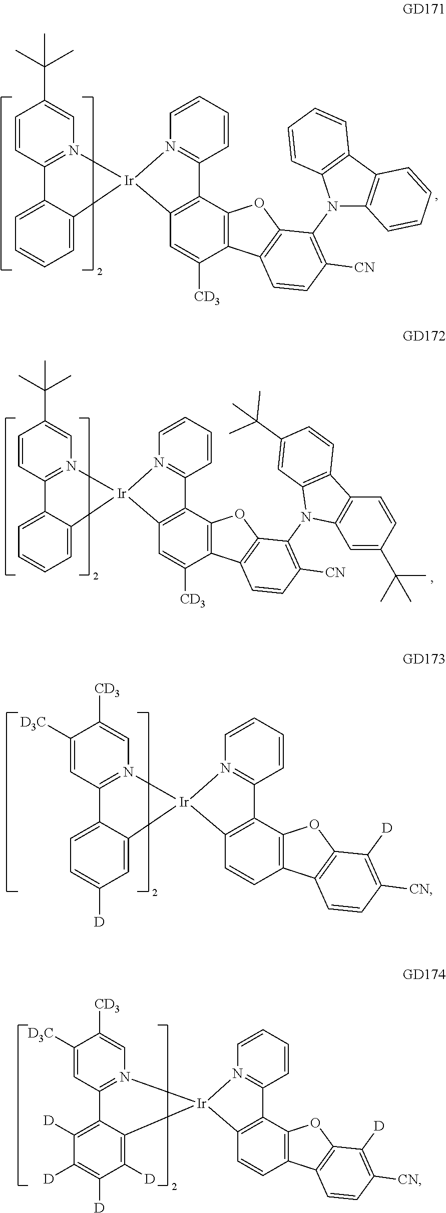 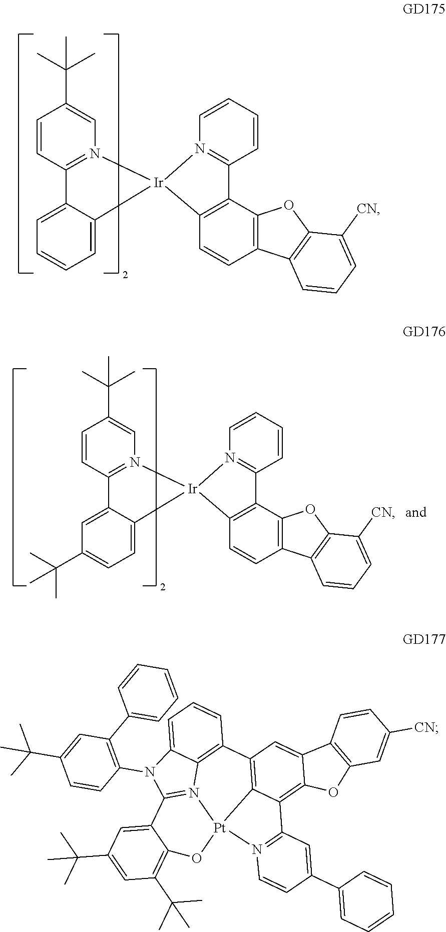
or the phosphorescent sensitizer has a structure represented by Pt(Lₐ) (L_{b}), wherein Lₐ and L_{b} are a first ligand and a second ligand coordinated to the metal Pt, respectively, and Lₐ is selected from the group consisting of Lₐ1-1 to Lₐ1-25 and Lₐ2-1 to Lₐ2-10: 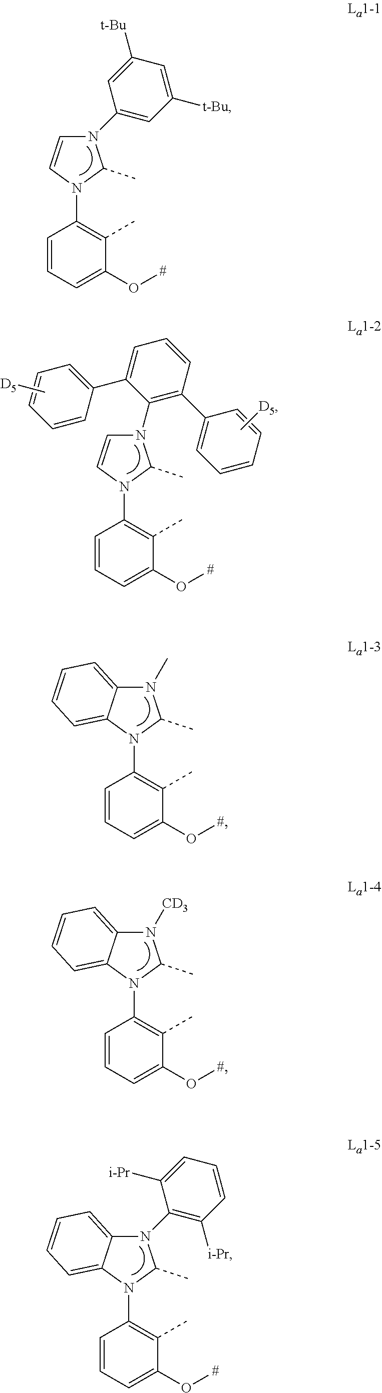 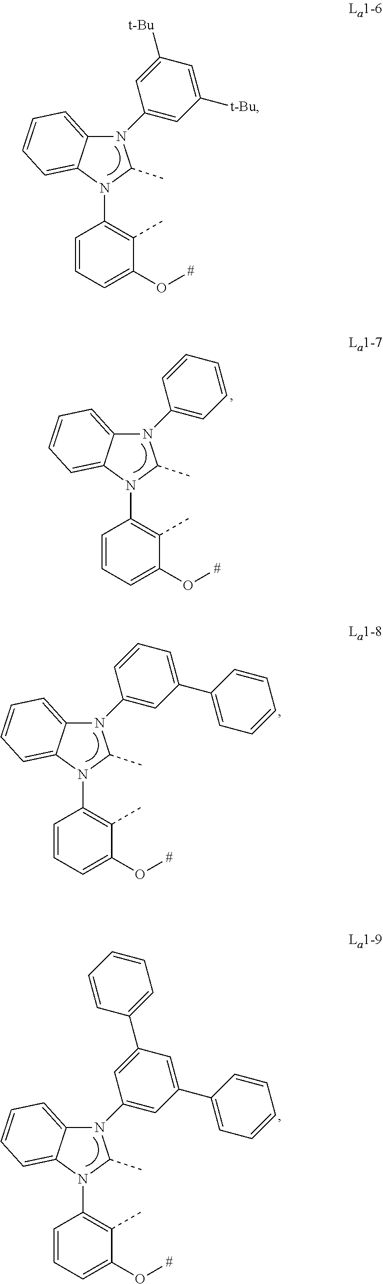 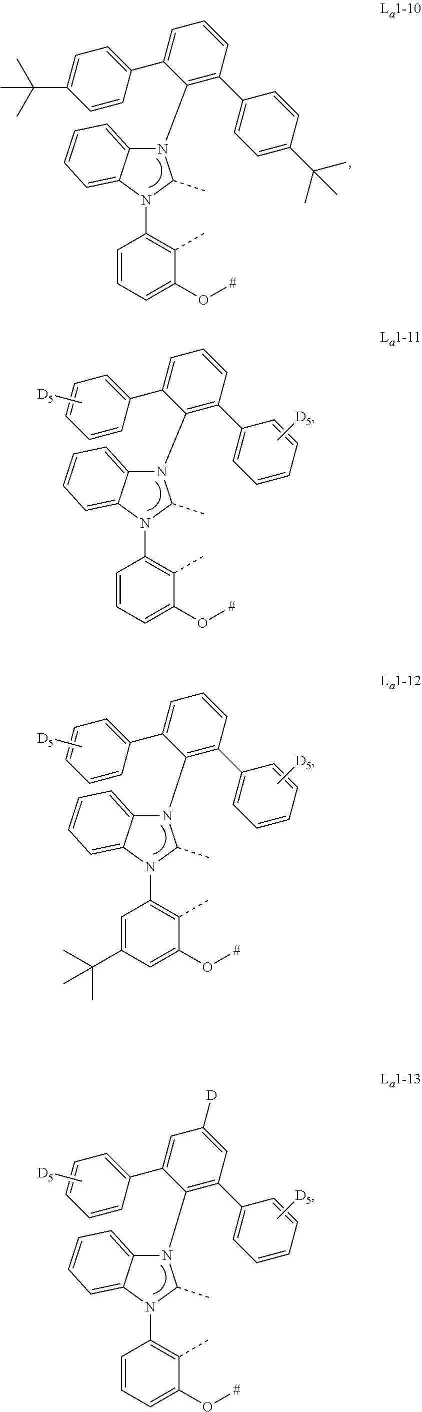 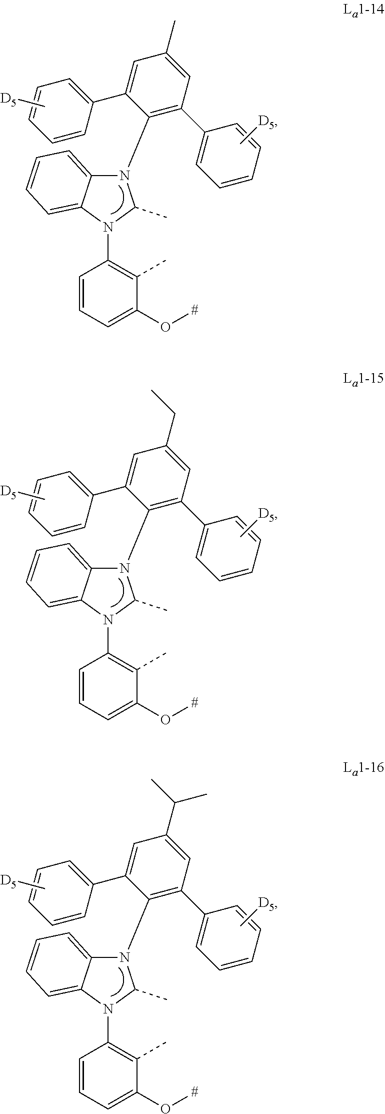 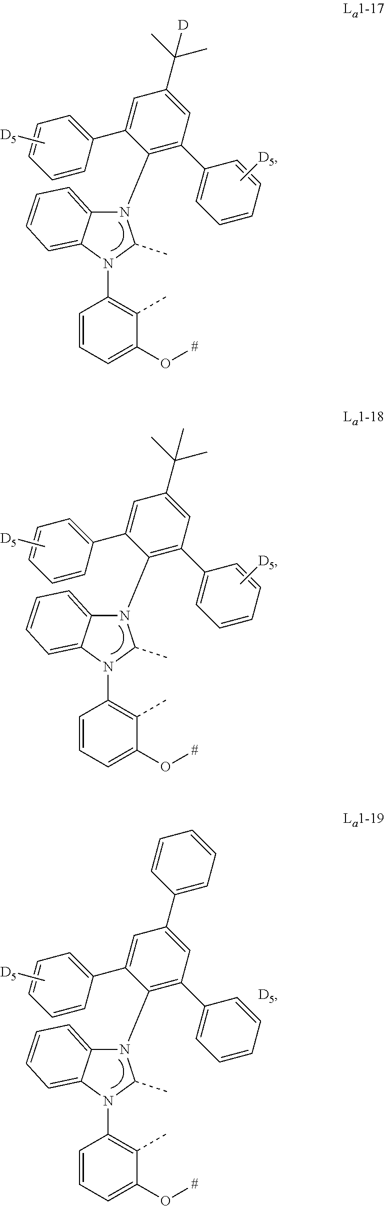 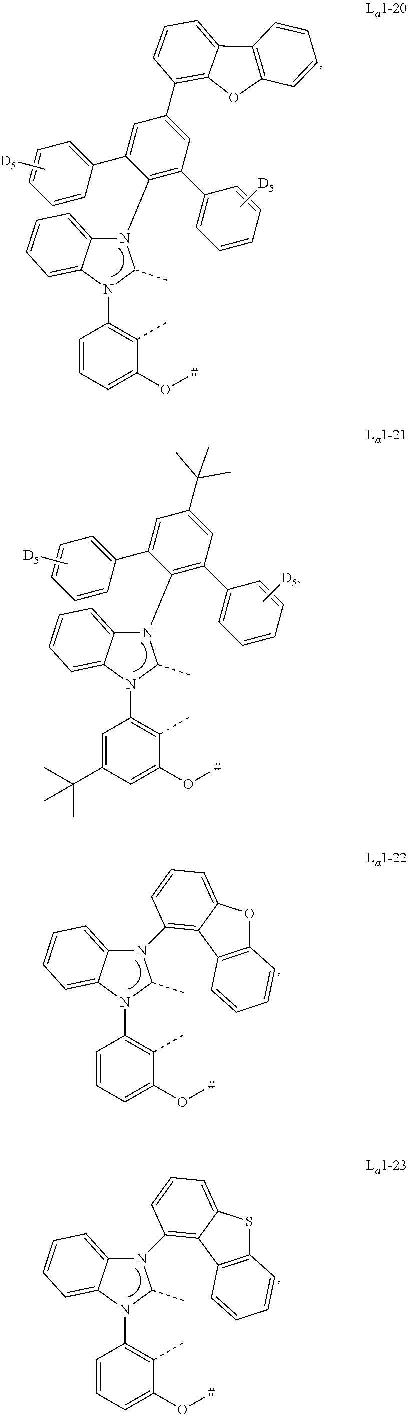 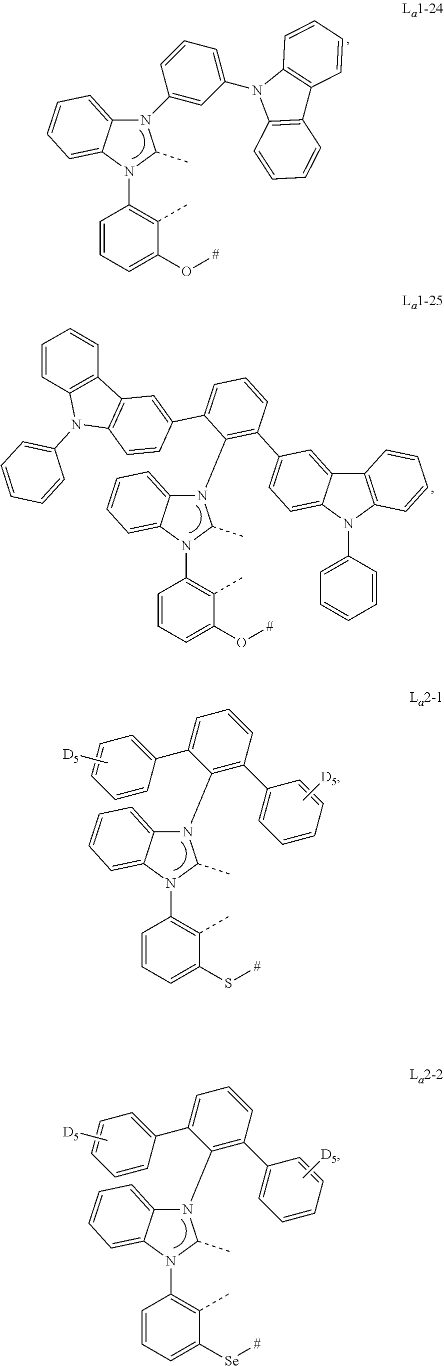 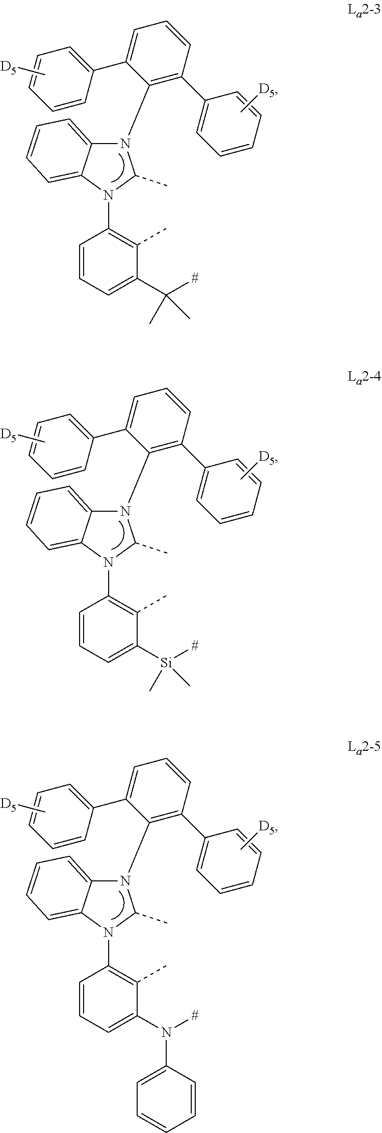 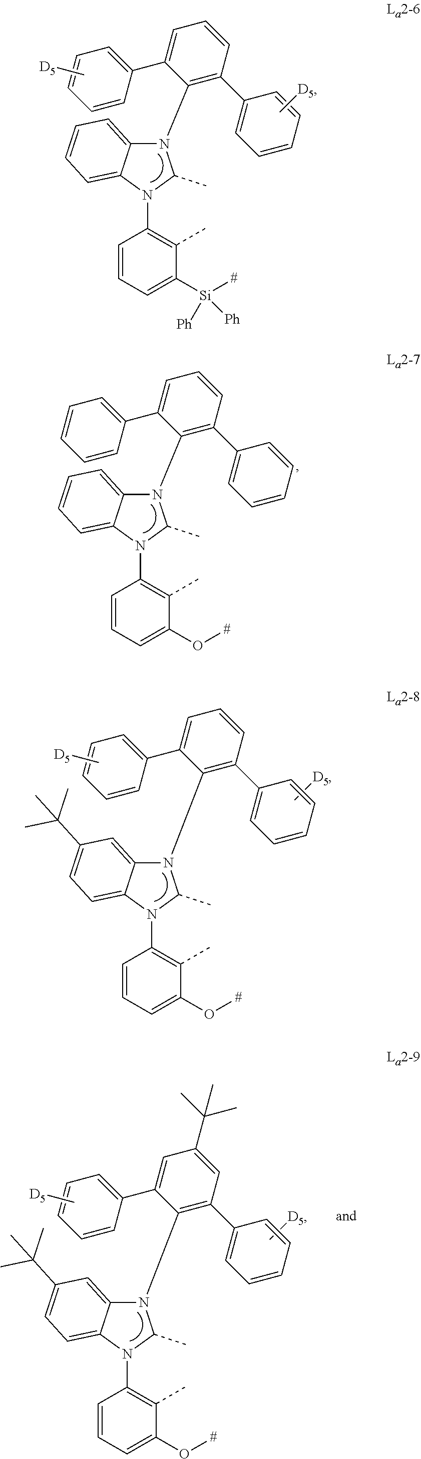 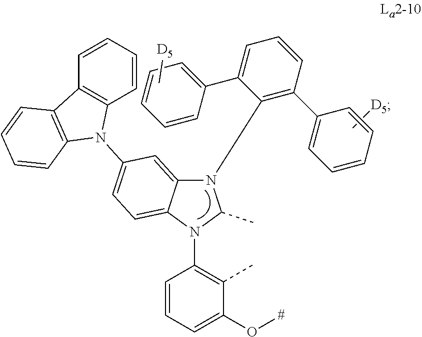
wherein “#” in the structures Lₐ1-1 to Lₐ1-25 and Lₐ2-1 to Lₐ2-10 represents a position joined to L_{b};
L_{b} is selected from the group consisting of L_{b}1-1 to L_{b}1-8 and L_{b}2-1 to L_{b}2-24: 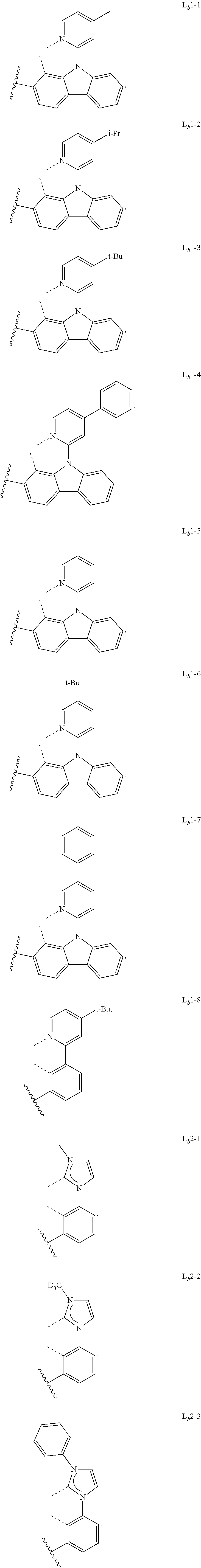 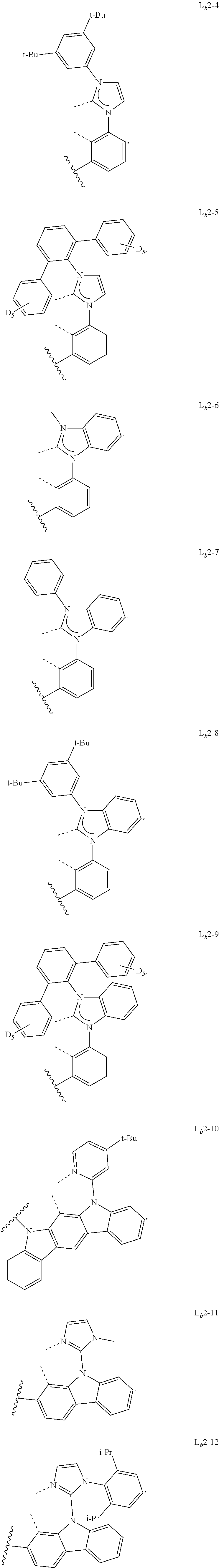 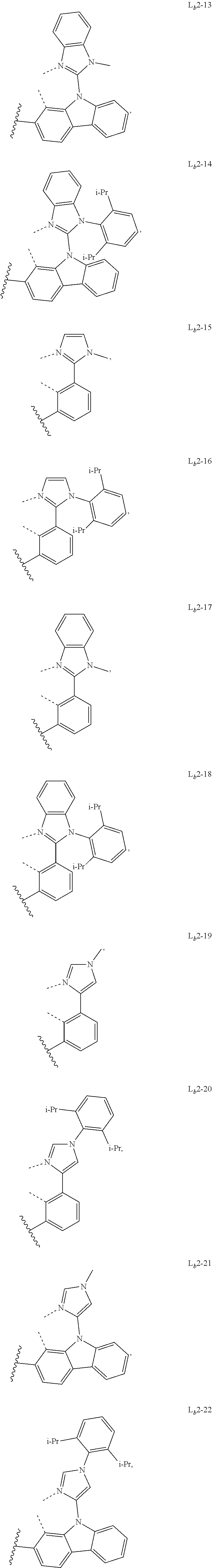 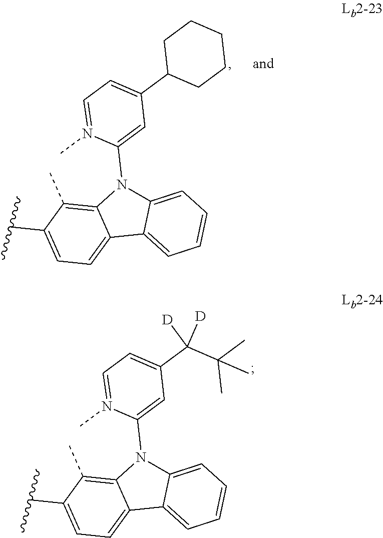
wherein “#” in the structures L_{b}1-1 to L_{b}1-8 and L_{b}2-1 to L_{b}2-24 represents a position joined to L_{b};
preferably, the phosphorescent sensitizer is selected from the group consisting of Pt1 to Pt96, wherein Pt1 to Pt96 have a structure represented by Pt(Lₐ) (L_{b}), and Lₐ and L_{b} correspond to structures selected from the following table, respectively:

| Phosphorescent | | | Phosphorescent | | |
|---|---|---|---|---|---|
| sensitizer No. | Lₐ | L_{b} | sensitizer No. | Lₐ | L_{b} |
| Pt1 | Lₐ1-6 | L_{b}1-1 | Pt2 | Lₐ1-6 | L_{b}1-2 |
| Pt3 | Lₐ1-6 | L_{b}1-3 | Pt4 | Lₐ1-6 | L_{b}1-4 |
| Pt5 | Lₐ1-6 | L_{b}1-5 | Pt6 | Lₐ1-6 | L_{b}1-6 |
| Pt7 | Lₐ1-6 | L_{b}1-7 | Pt8 | Lₐ1-6 | L_{b}1-8 |
| Pt9 | Lₐ1-11 | L_{b}1-1 | Pt10 | Lₐ1-11 | L_{b}1-2 |
| Pt11 | Lₐ1-11 | L_{b}1-3 | Pt12 | Lₐ1-11 | L_{b}1-4 |
| Pt13 | Lₐ1-11 | L_{b}1-5 | Pt14 | Lₐ1-11 | L_{b}1-6 |
| Pt15 | Lₐ1-11 | L_{b}1-7 | Pt16 | Lₐ1-11 | L_{b}1-8 |
| Pt17 | Lₐ1-12 | L_{b}1-1 | Pt18 | Lₐ1-12 | L_{b}1-2 |
| Pt19 | Lₐ1-12 | L_{b}1-3 | Pt20 | Lₐ1-12 | L_{b}1-4 |
| Pt21 | Lₐ1-12 | L_{b}1-5 | Pt22 | Lₐ1-12 | L_{b}1-6 |
| Pt23 | Lₐ1-12 | L_{b}1-7 | Pt24 | Lₐ1-12 | L_{b}1-8 |
| Pt25 | Lₐ1-18 | L_{b}1-1 | Pt26 | Lₐ1-18 | L_{b}1-2 |
| Pt27 | Lₐ1-18 | L_{b}1-3 | Pt28 | Lₐ1-18 | L_{b}1-4 |
| Pt29 | Lₐ1-18 | L_{b}1-5 | Pt30 | Lₐ1-18 | L_{b}1-6 |
| Pt31 | Lₐ1-18 | L_{b}1-7 | Pt32 | Lₐ1-18 | L_{b}1-8 |
| Pt33 | Lₐ1-18 | L_{b}2-1 | Pt34 | Lₐ1-18 | L_{b}2-2 |
| Pt35 | Lₐ1-18 | L_{b}2-3 | Pt36 | Lₐ1-18 | L_{b}2-4 |
| Pt37 | Lₐ1-18 | L_{b}2-5 | Pt38 | Lₐ1-18 | L_{b}2-6 |
| Pt39 | Lₐ1-18 | L_{b}2-7 | Pt40 | Lₐ1-18 | L_{b}2-8 |
| Pt41 | Lₐ1-18 | L_{b}2-9 | Pt42 | Lₐ1-18 | L_{b}2-10 |
| Pt43 | Lₐ1-18 | L_{b}2-11 | Pt44 | Lₐ1-18 | L_{b}2-12 |
| Pt45 | Lₐ1-18 | L_{b}2-13 | Pt46 | Lₐ1-18 | L_{b}2-14 |
| Pt47 | Lₐ1-18 | L_{b}2-15 | Pt48 | Lₐ1-18 | L_{b}2-16 |
| Pt49 | Lₐ1-18 | L_{b}2-17 | Pt50 | Lₐ1-18 | L_{b}2-18 |
| Pt51 | Lₐ1-18 | L_{b}2-19 | Pt52 | Lₐ1-18 | L_{b}2-20 |
| Pt53 | Lₐ1-18 | L_{b}2-21 | Pt54 | Lₐ1-18 | L_{b}2-22 |
| Pt55 | Lₐ1-1 | L_{b}1-3 | Pt56 | Lₐ1-2 | L_{b}1-3 |
| Pt57 | Lₐ1-3 | L_{b}1-3 | Pt58 | Lₐ1-4 | L_{b}1-3 |
| Pt59 | Lₐ1-5 | L_{b}1-3 | Pt60 | Lₐ1-7 | L_{b}1-3 |
| Pt61 | Lₐ1-8 | L_{b}1-3 | Pt62 | Lₐ1-9 | L_{b}1-3 |
| Pt63 | Lₐ1-10 | L_{b}1-3 | Pt64 | Lₐ1-13 | L_{b}1-3 |
| Pt65 | Lₐ1-14 | L_{b}1-3 | Pt66 | Lₐ1-15 | L_{b}1-3 |
| Pt67 | Lₐ1-16 | L_{b}1-3 | Pt68 | Lₐ1-17 | L_{b}1-3 |
| Pt69 | Lₐ1-19 | L_{b}1-3 | Pt70 | Lₐ1-20 | L_{b}1-3 |
| Pt71 | Lₐ1-21 | L_{b}1-3 | Pt72 | Lₐ1-22 | L_{b}1-3 |
| Pt73 | Lₐ1-23 | L_{b}1-3 | Pt74 | Lₐ1-24 | L_{b}1-3 |
| Pt75 | Lₐ1-25 | L_{b}1-3 | Pt76 | Lₐ2-1 | L_{b}1-3 |
| Pt77 | Lₐ2-2 | L_{b}1-3 | Pt78 | Lₐ2-3 | L_{b}1-3 |
| Pt79 | Lₐ2-4 | L_{b}1-3 | Pt80 | Lₐ2-5 | L_{b}1-3 |
| Pt81 | Lₐ2-6 | L_{b}1-3 | Pt82 | Lₐ2-7 | L_{b}1-3 |
| Pt83 | Lₐ2-8 | L_{b}1-3 | Pt84 | Lₐ2-9 | L_{b}1-3 |
| Pt85 | Lₐ2-10 | L_{b}1-3 | Pt86 | Lₐ1-11 | L_{b}1-3 |
| Pt87 | Lₐ1-18 | L_{b}2-23 | Pt88 | Lₐ2-7 | L_{b}2-23 |
| Pt89 | Lₐ2-8 | L_{b}2-23 | Pt90 | Lₐ2-9 | L_{b}2-23 |
| Pt91 | Lₐ2-10 | L_{b}2-23 | Pt92 | Lₐ2-7 | L_{b}2-24 |
| Pt93 | Lₐ1-18 | L_{b}2-24 | Pt94 | Lₐ2-9 | L_{b}2-24 |
| Pt95 | Lₐ2-8 | L_{b}2-24 | Pt96 | Lₐ2-10 | L_{b}2-24 |

18. The composition of claim 1, wherein the first host compound has a structure represented by one of Formula 5 to Formula 7: 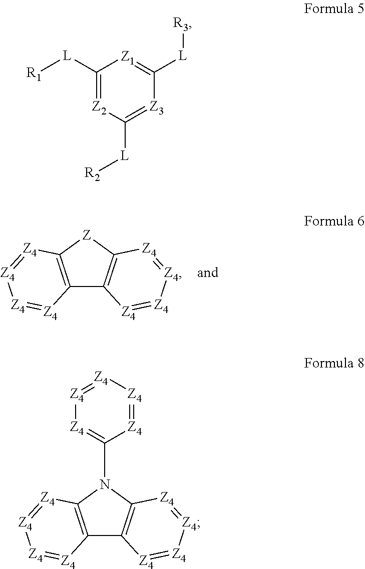
wherein in Formula 5, Z₁ to Z₃ are, at each occurrence identically or differently, selected from CR₄ or N, and at least one of Z₁ to Z₃ is N;
L is, at each occurrence identically or differently, selected from the group consisting of a single bond, substituted or unsubstituted arylene having 6 to 30 carbon atoms, substituted or unsubstituted heteroarylene having 3 to 30 carbon atoms, and combinations thereof;
in Formula 6 and Formula 7, Z₄ is, at each occurrence identically or differently, selected from CR₄ or N, and at least one Z₄ is N;
Z is, at each occurrence identically or differently, selected from O or S;
R₁ to R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₄ can be optionally joined to form a ring;
preferably, the first host compound is selected from the group consisting of Compound N-1-1 to Compound N-1-60, Compound N-2-1 to Compound N-2-35, Compound N-3-1 to Compound N-3-9, Compound N-4-1 to Compound N-4-34, and Compound NH-1 to Compound NH-224: 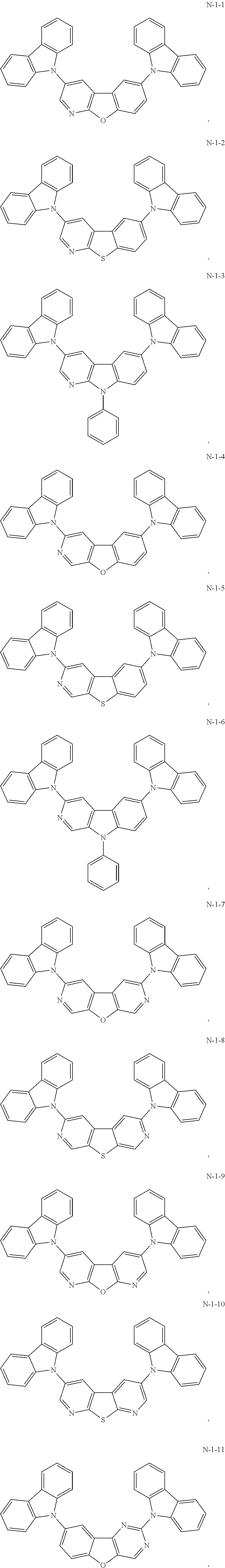 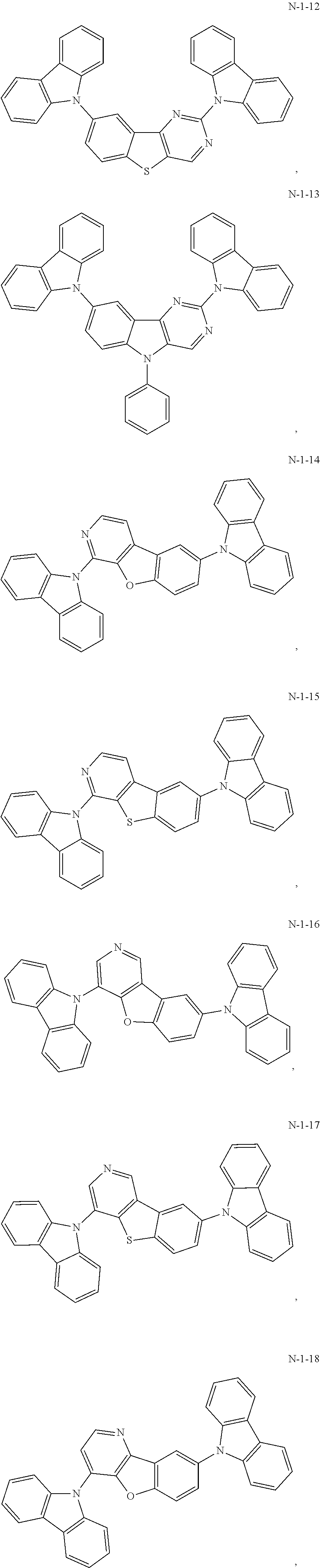 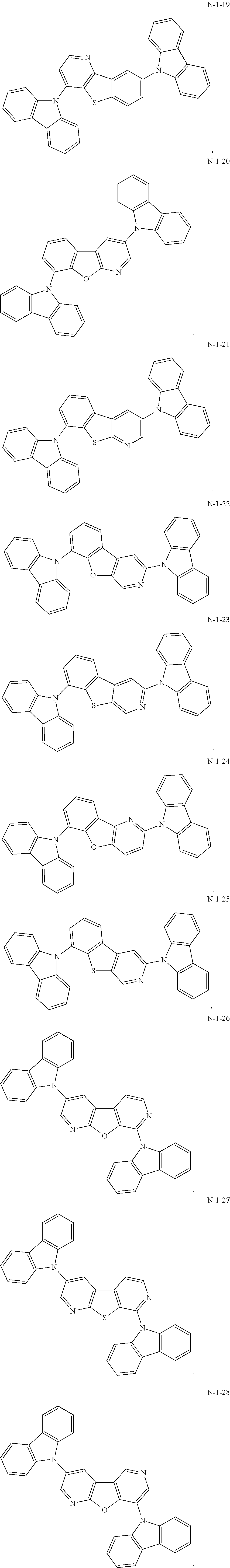 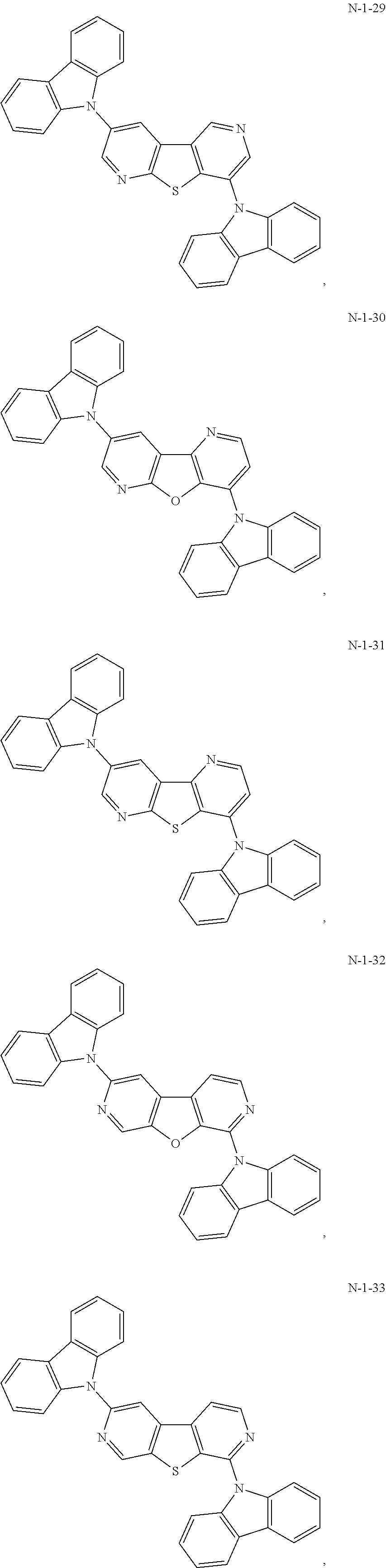 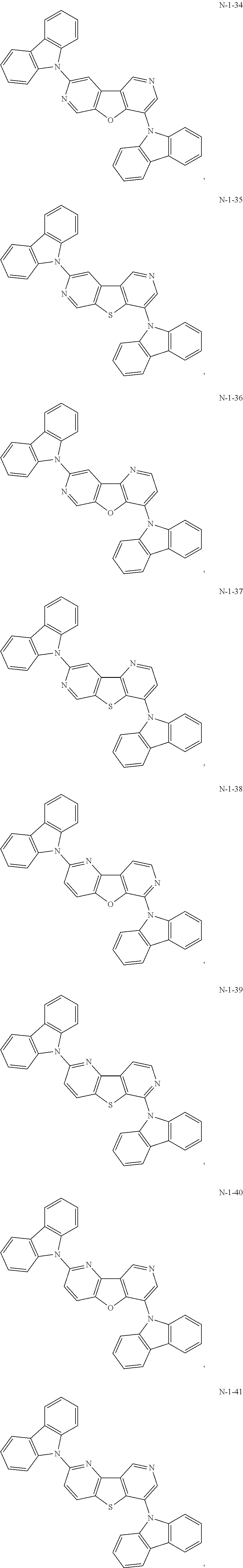 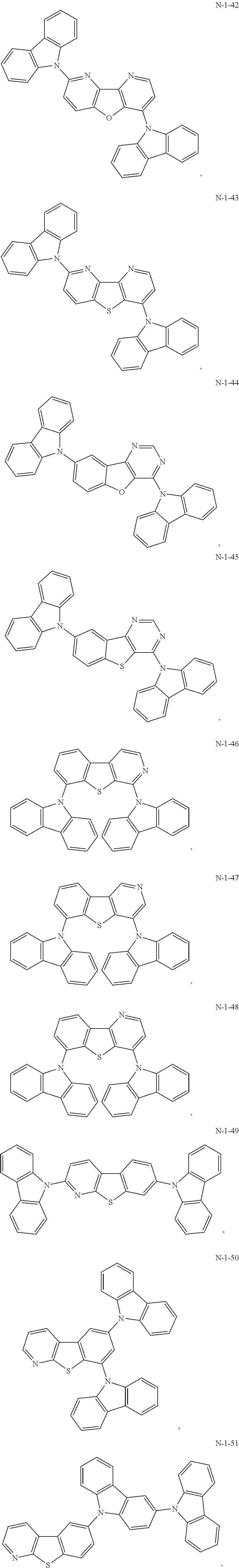 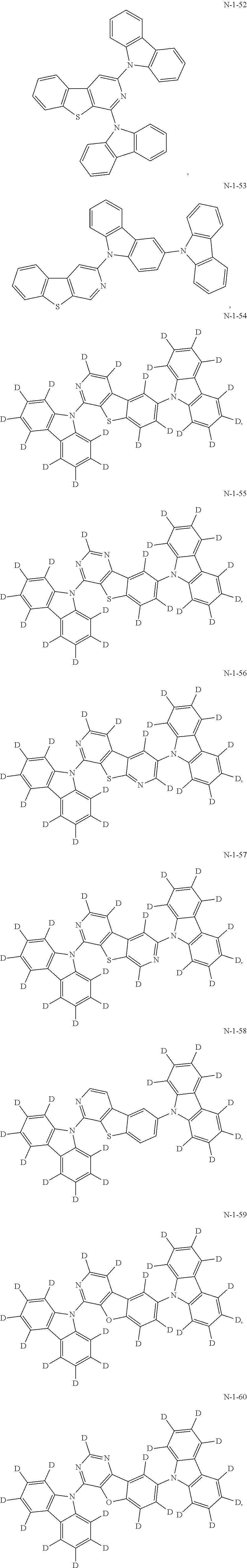 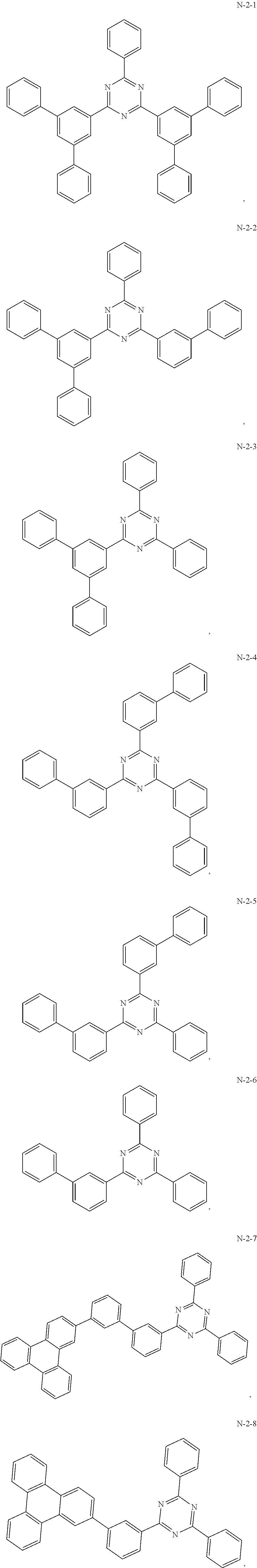 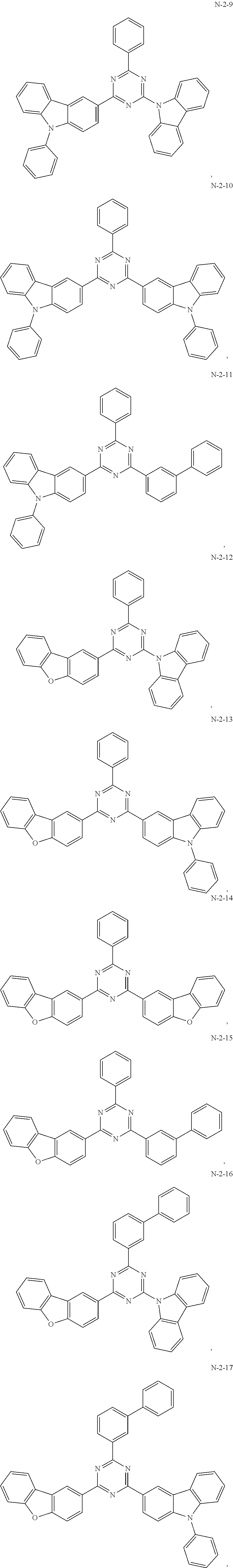 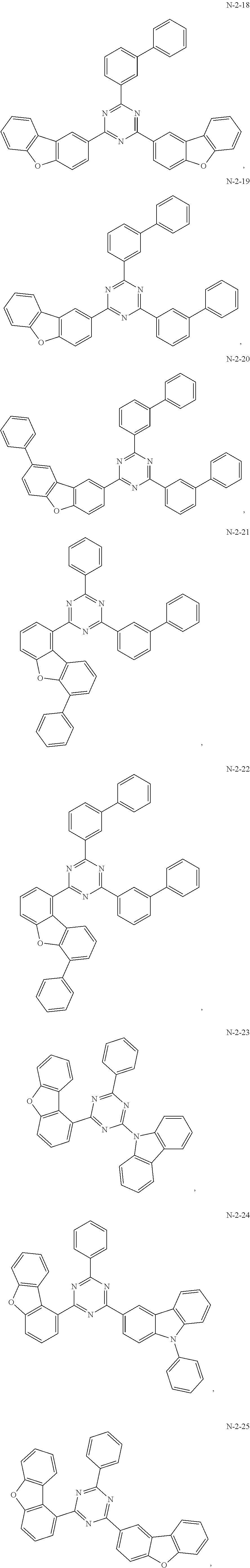 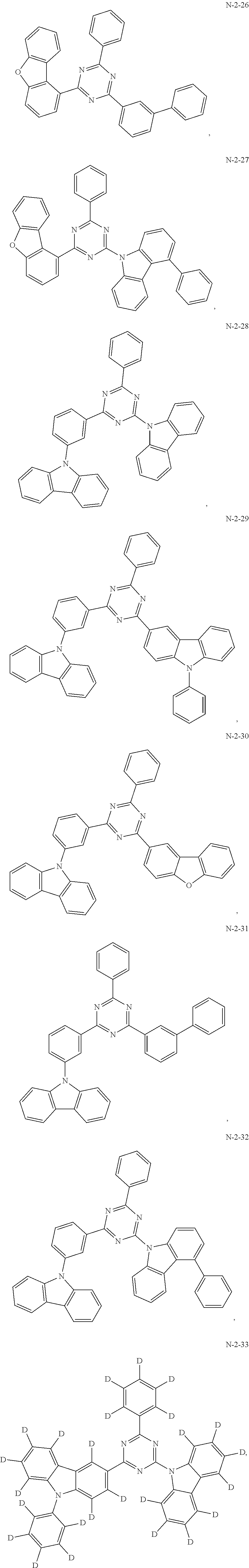 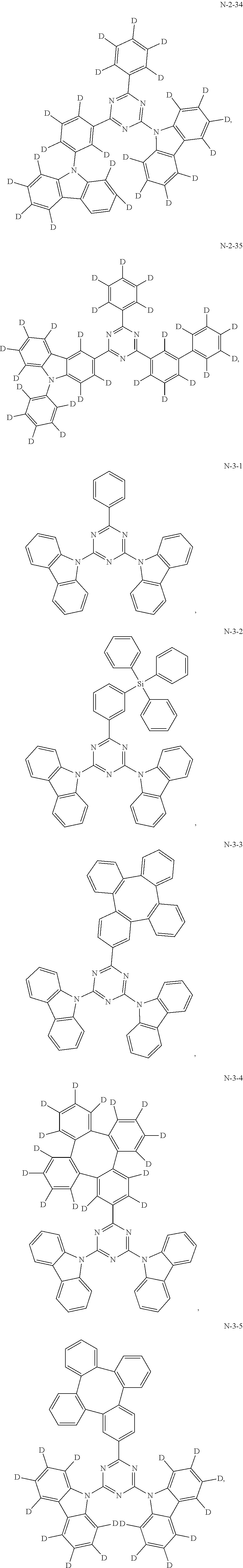 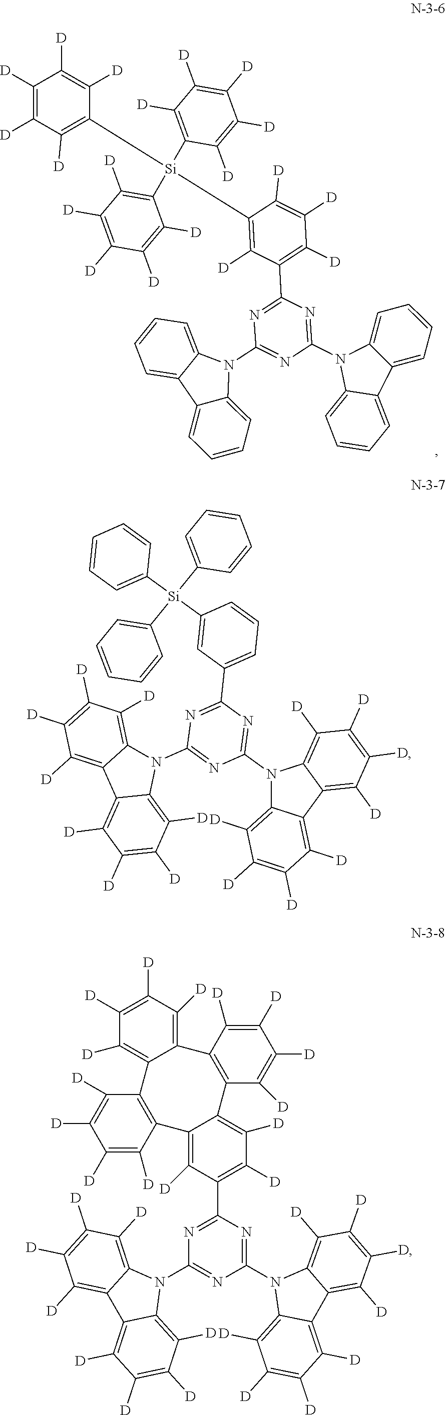 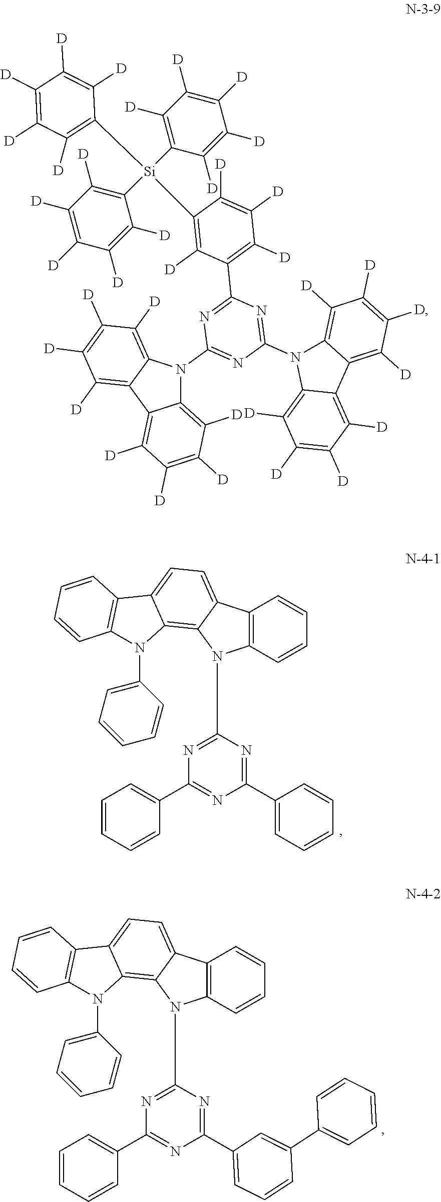 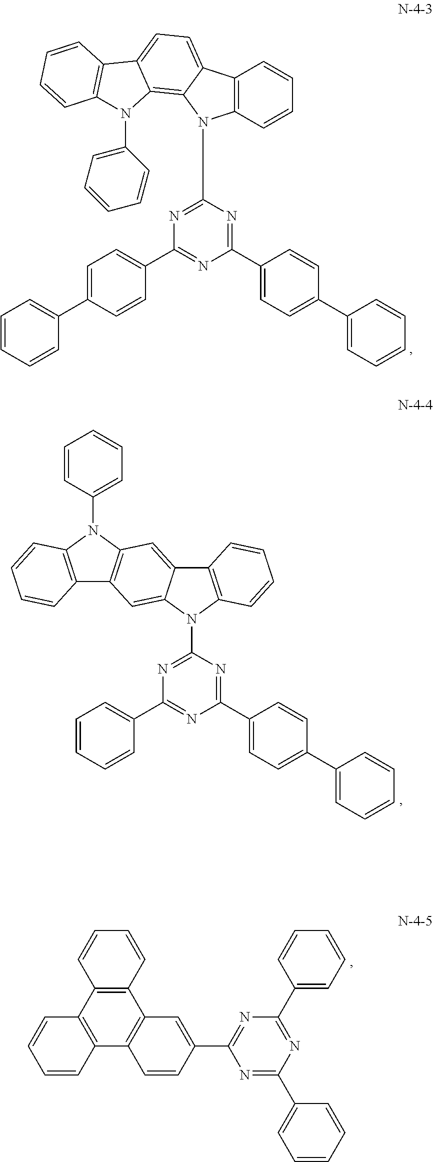 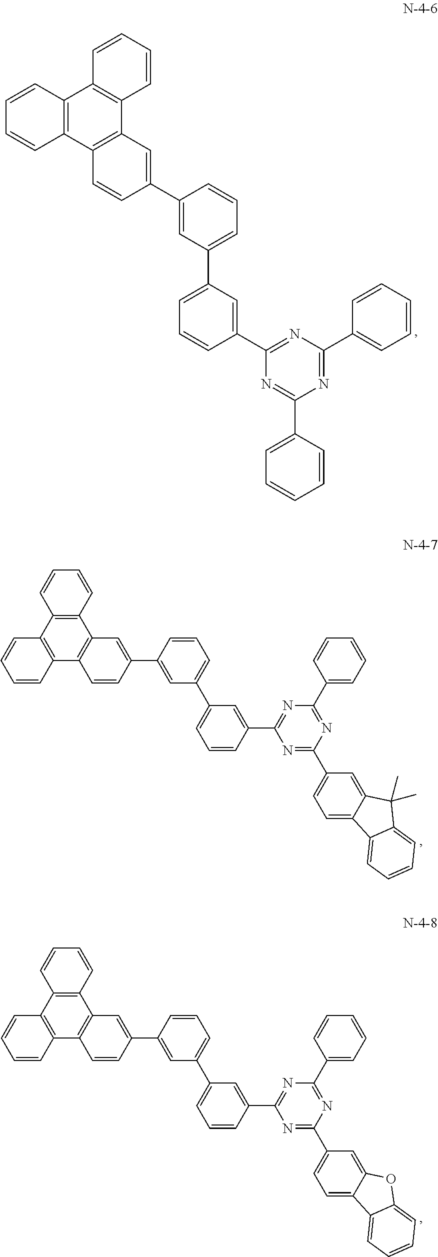 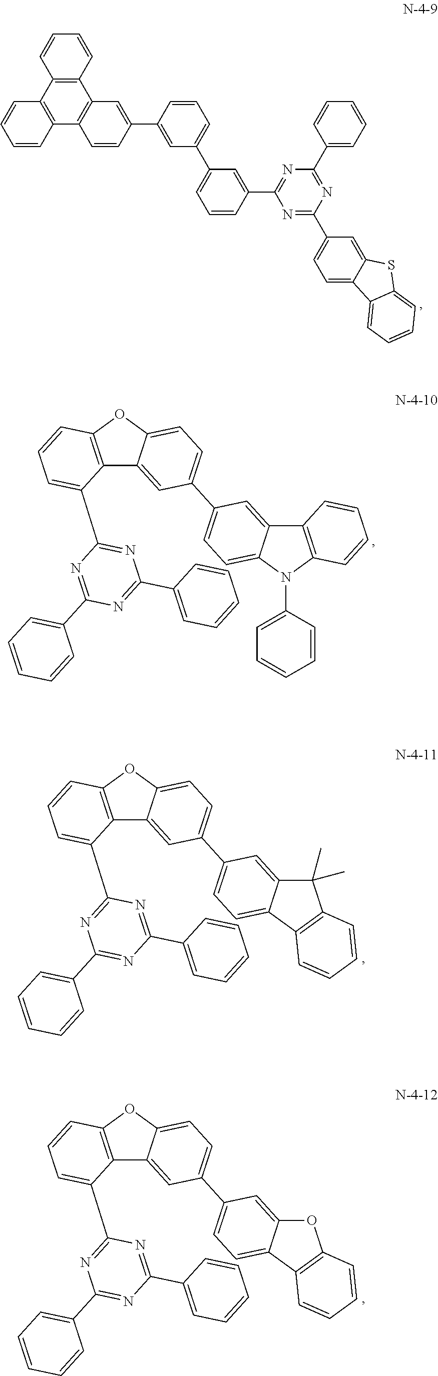 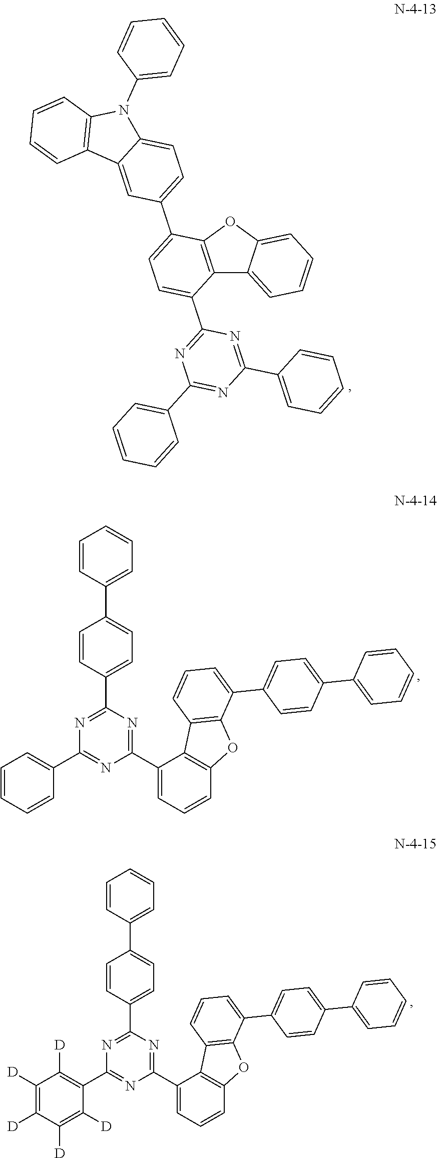 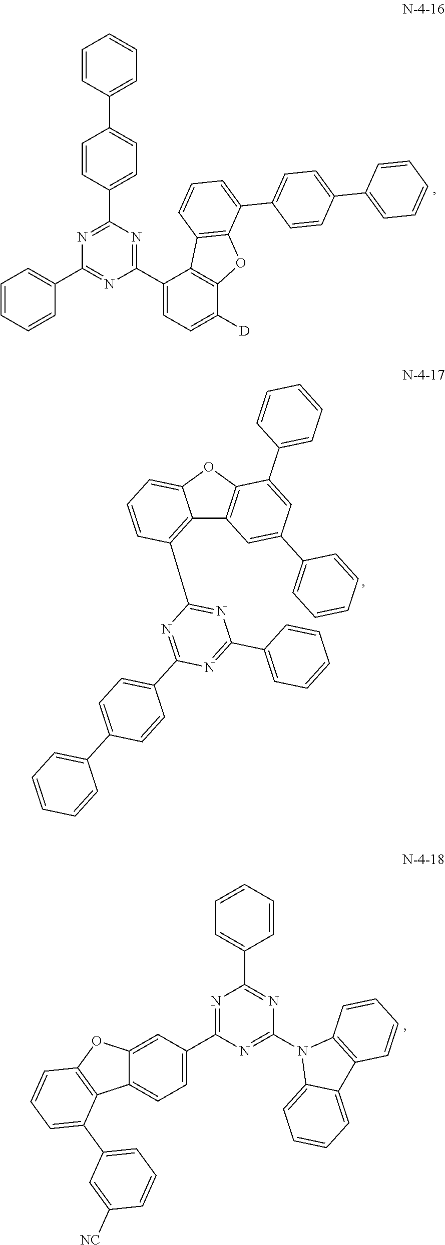 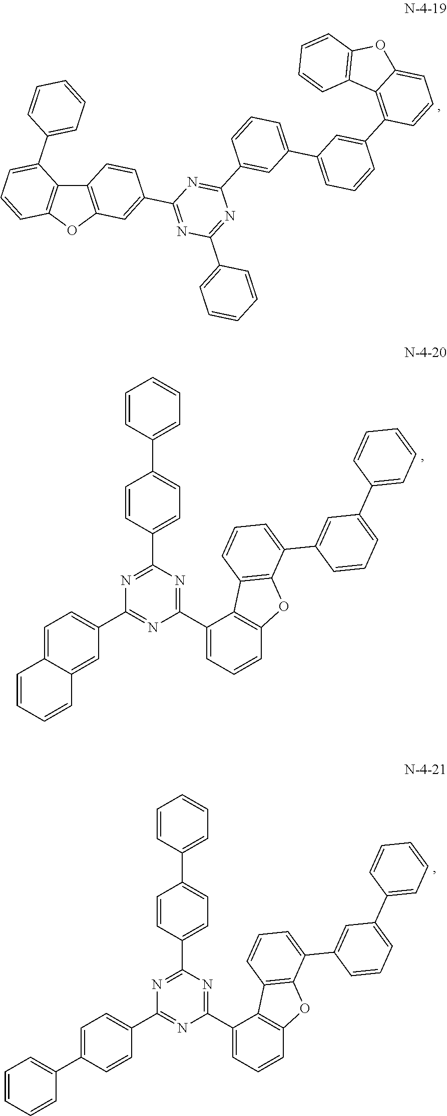 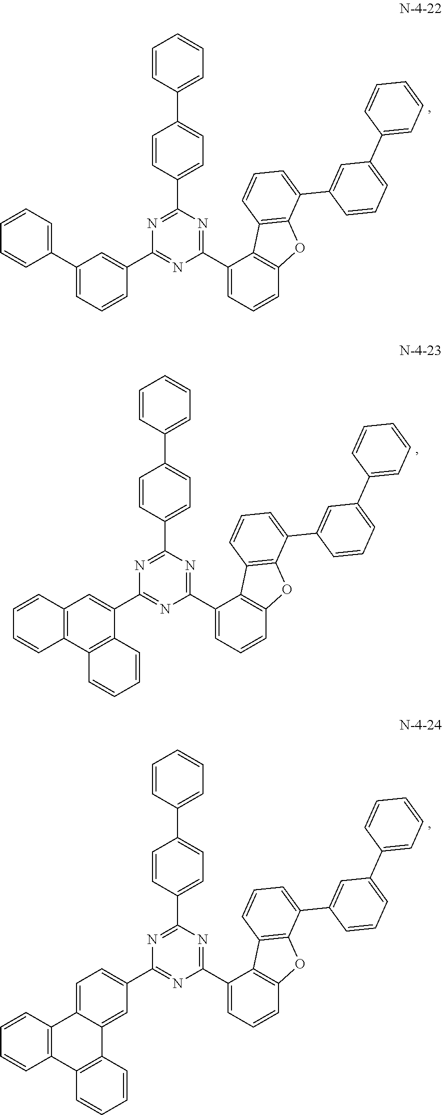 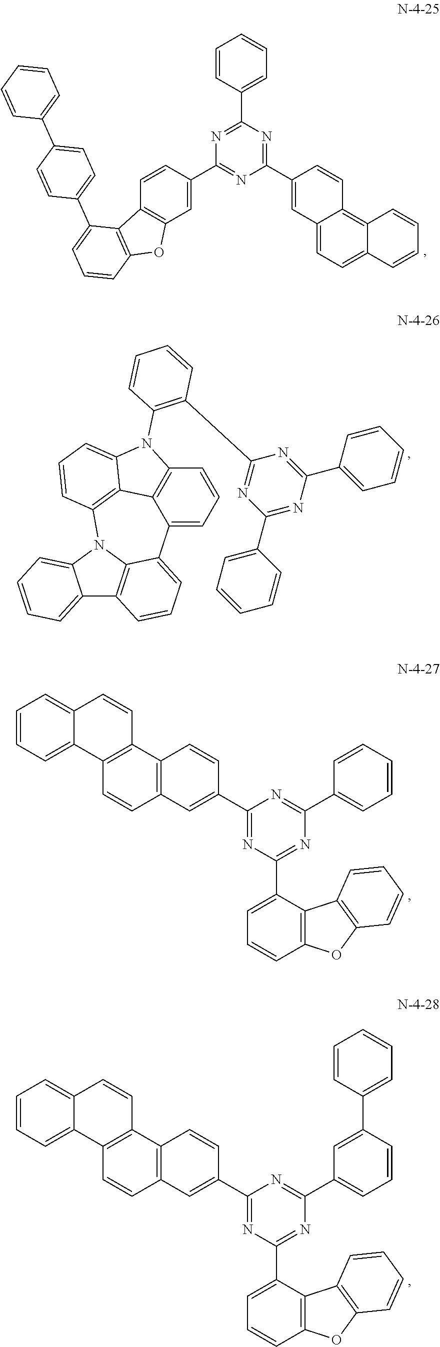 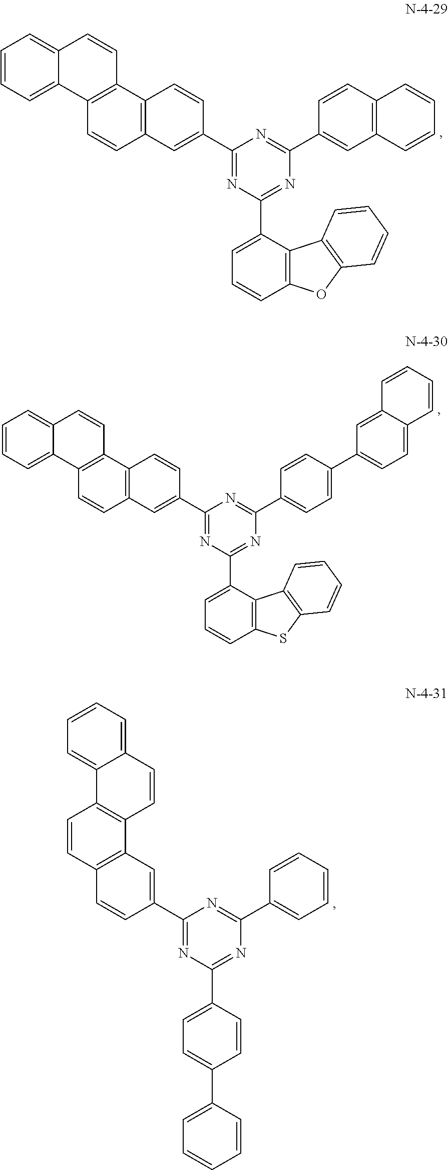 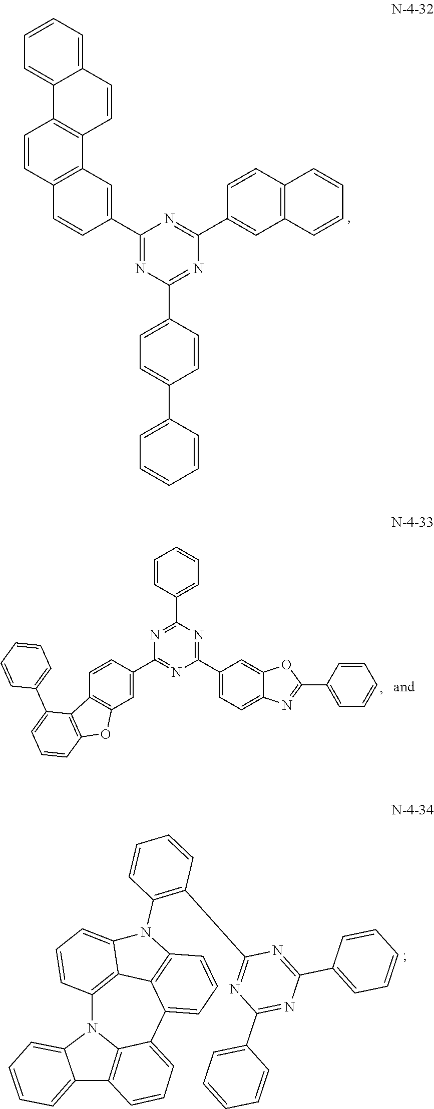 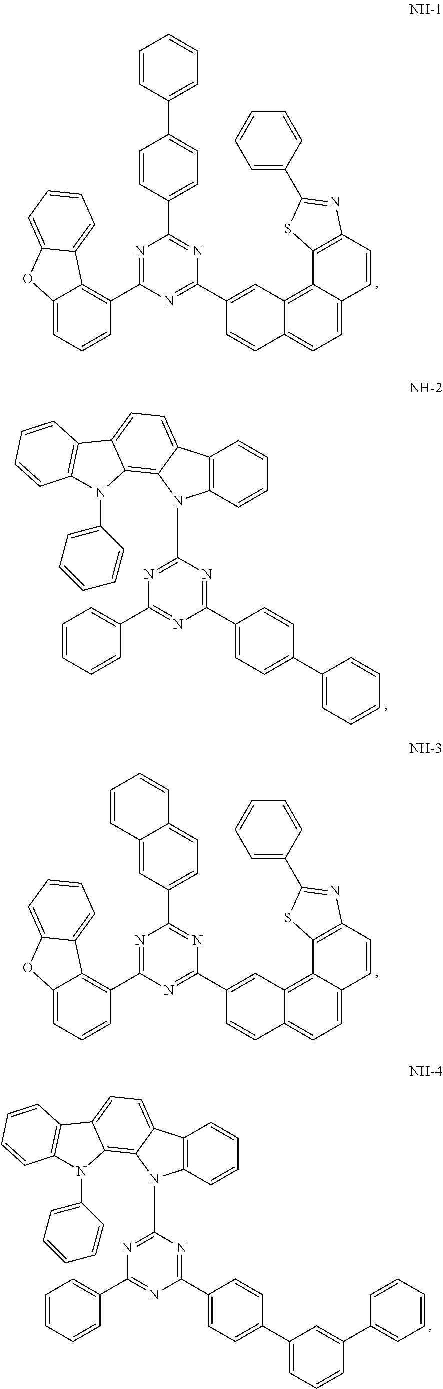 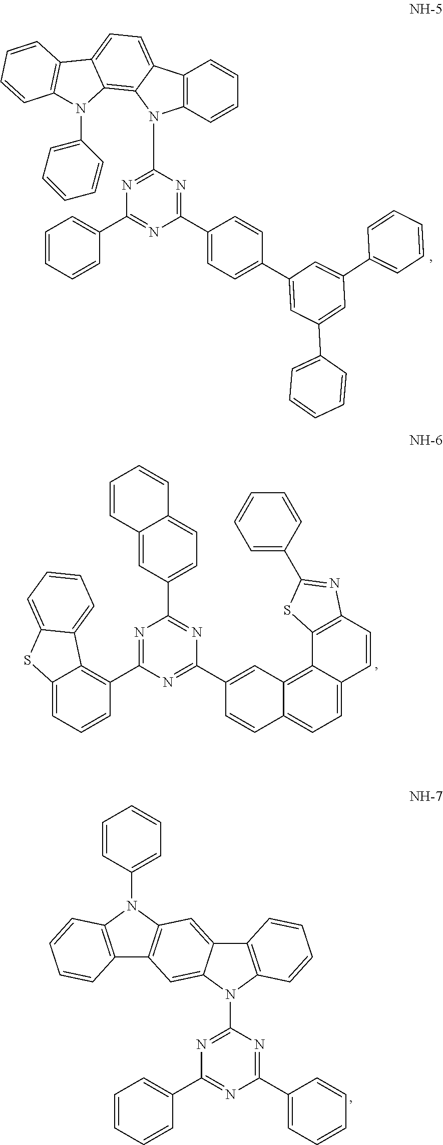 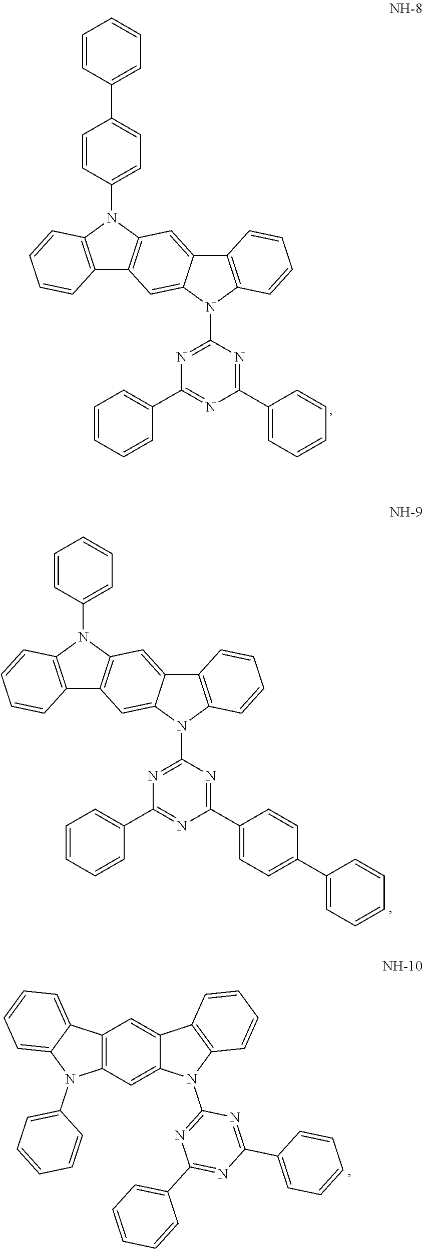 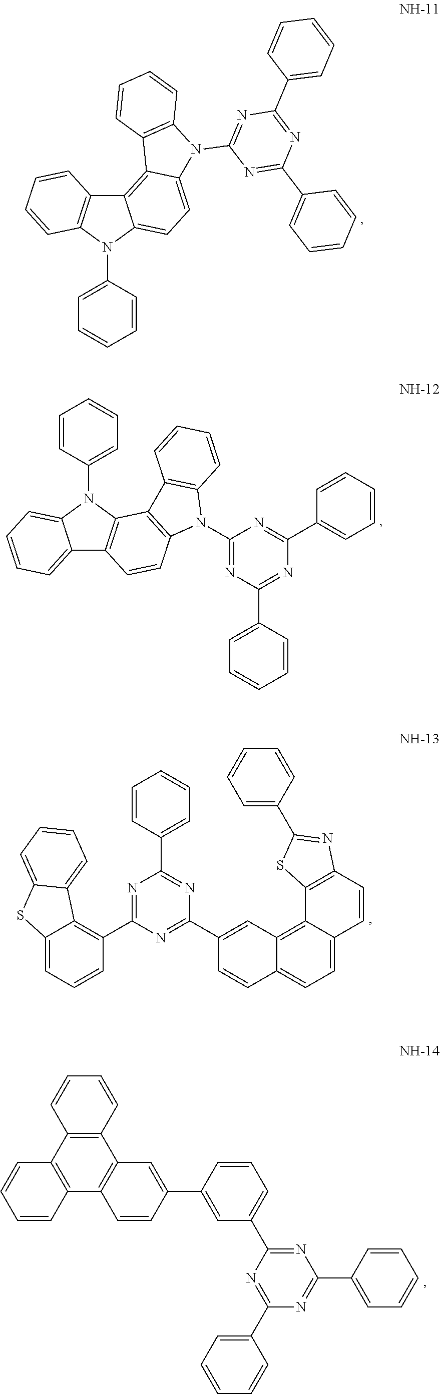 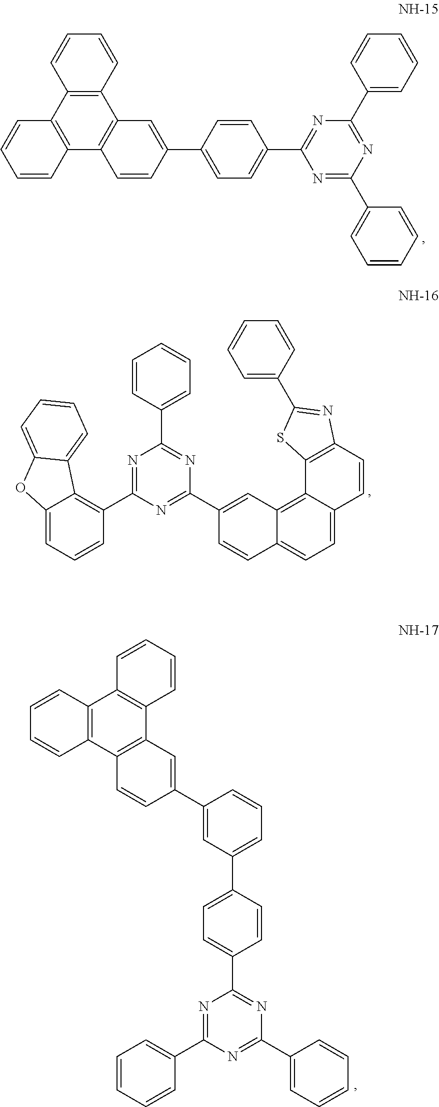 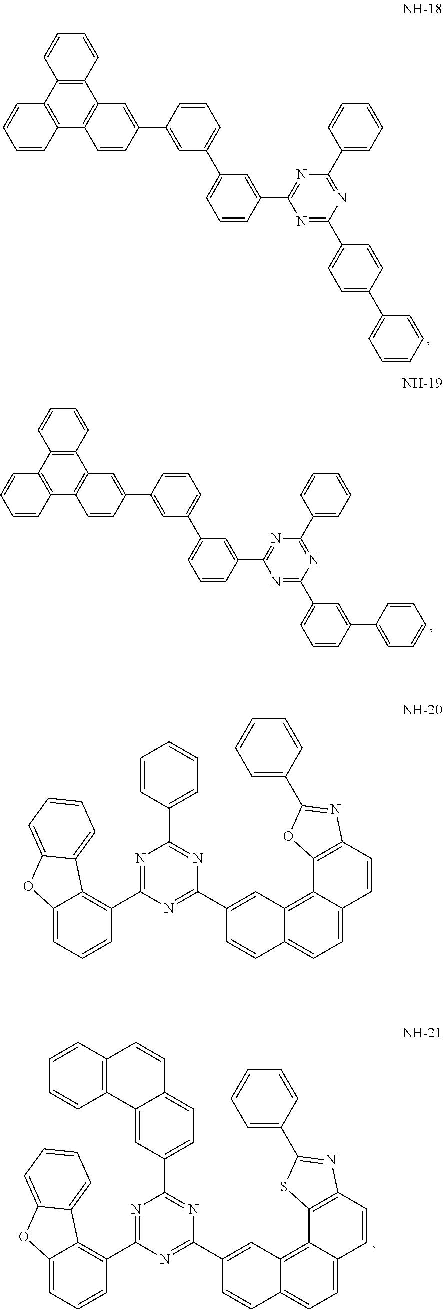 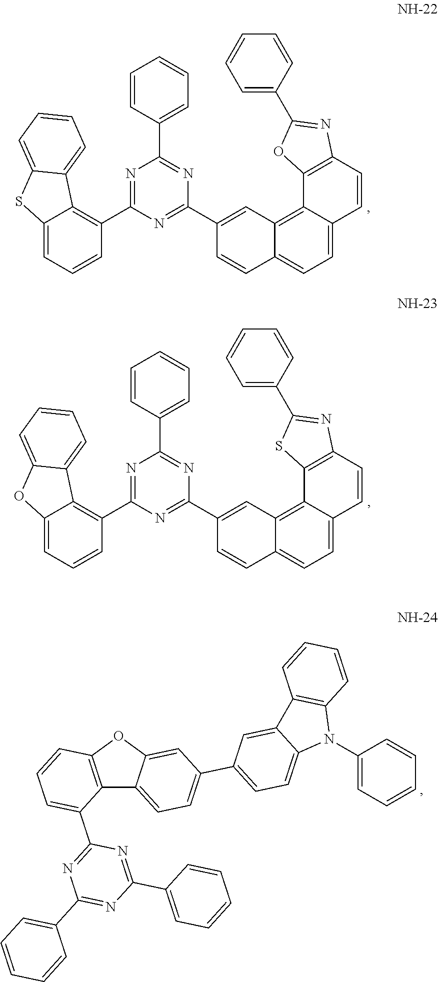 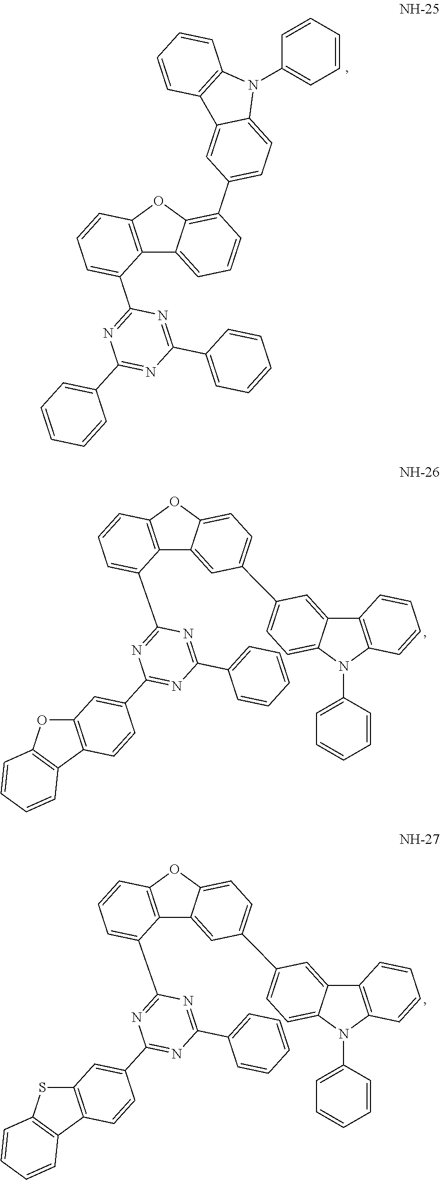 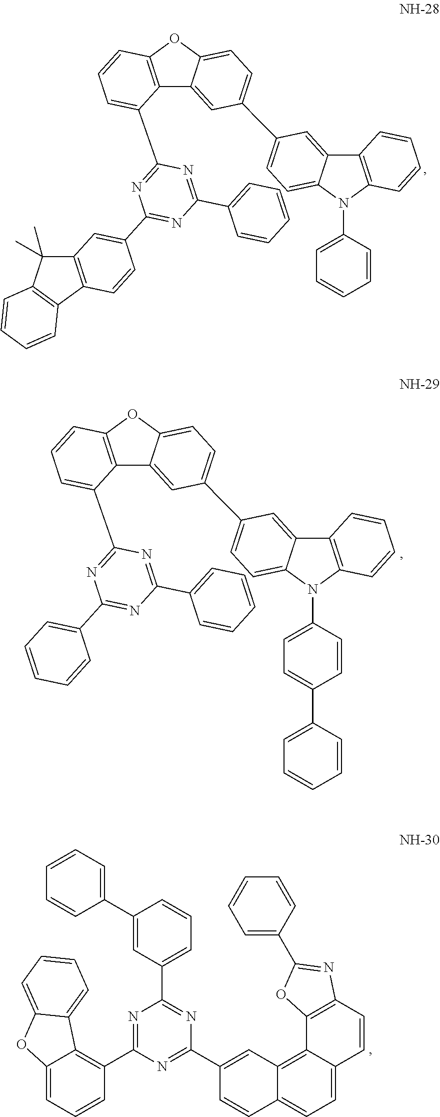 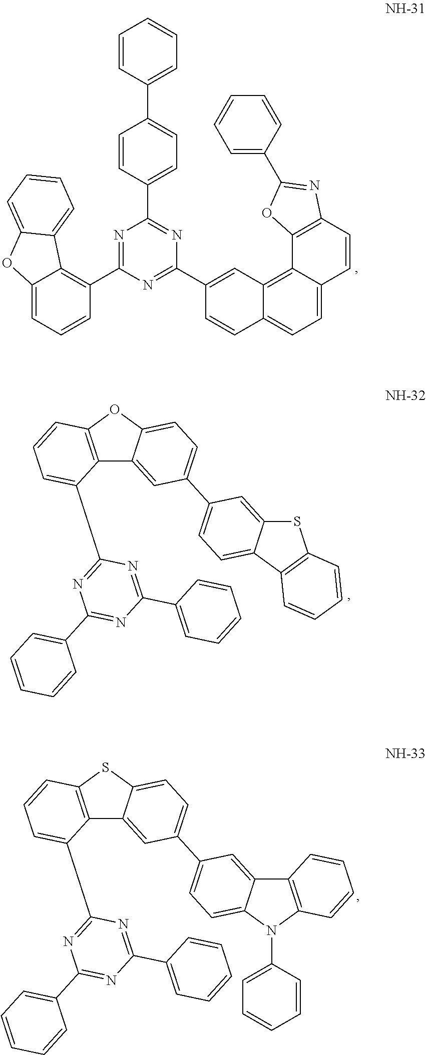 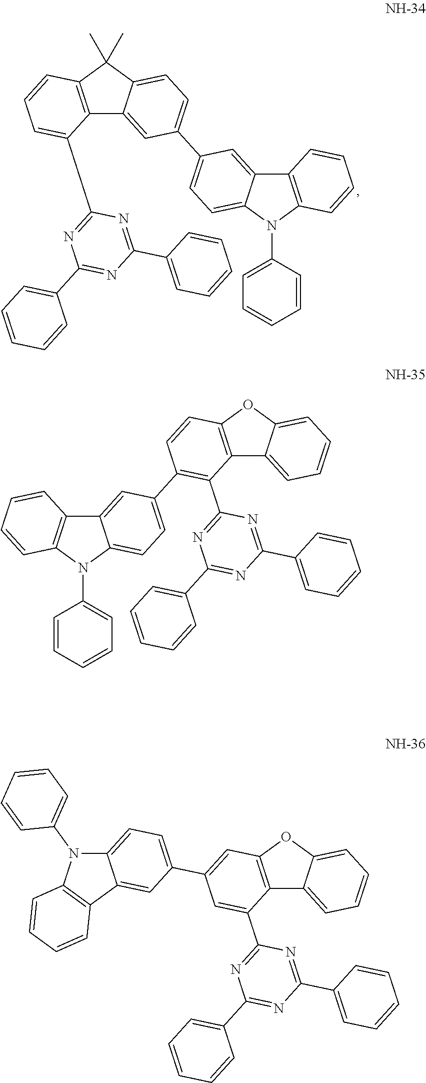 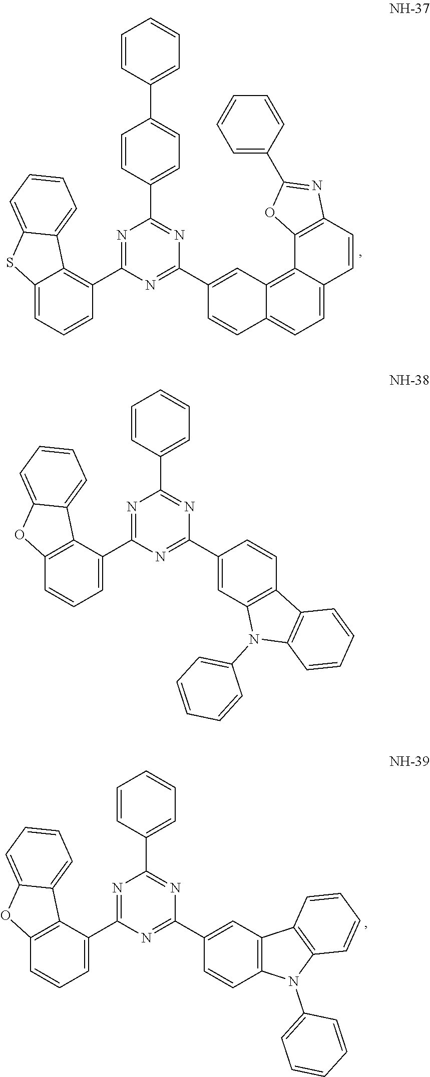 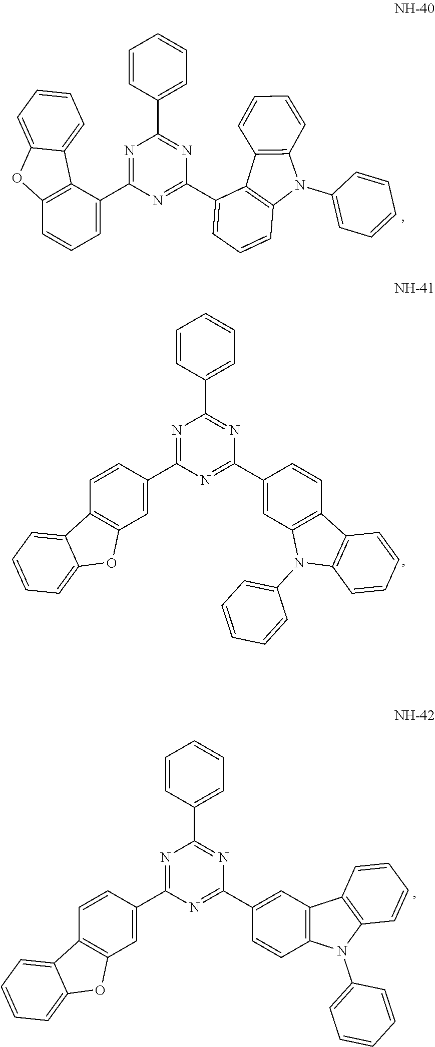 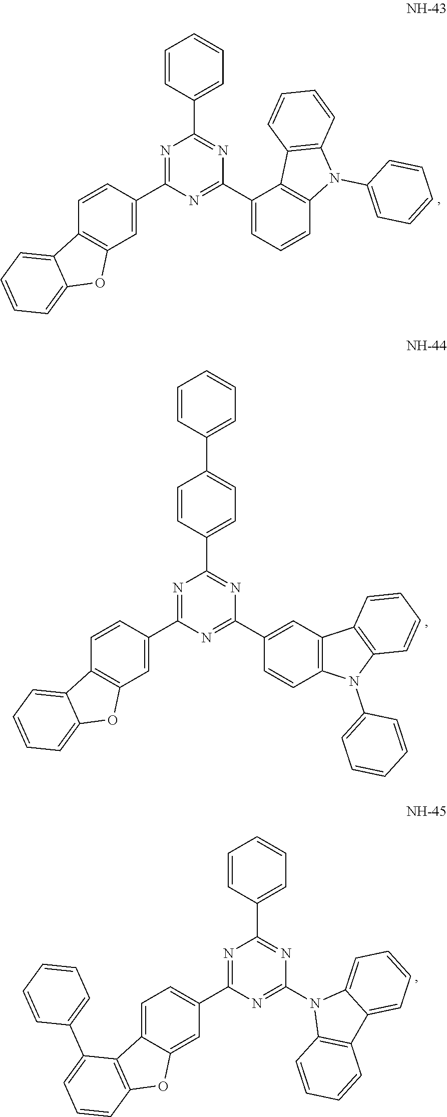 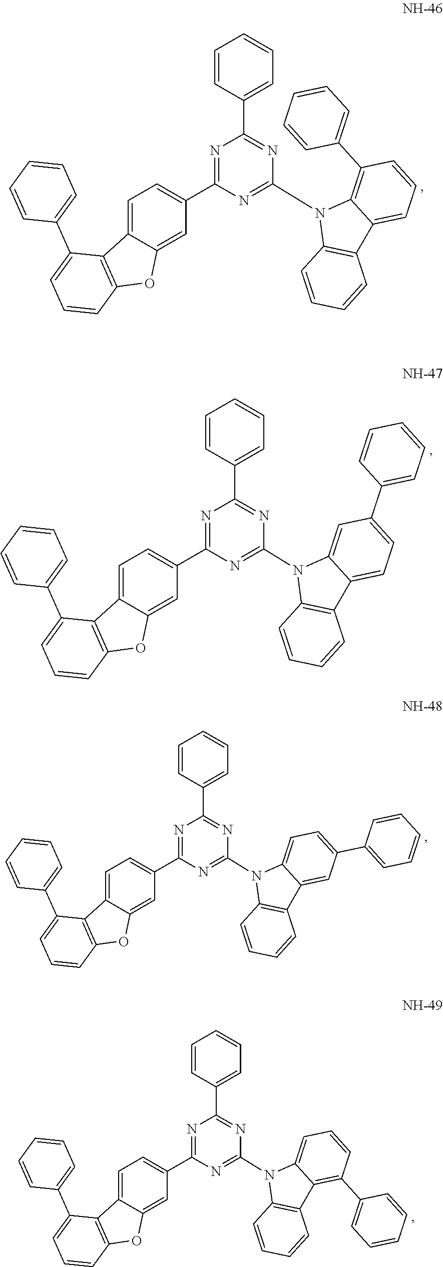 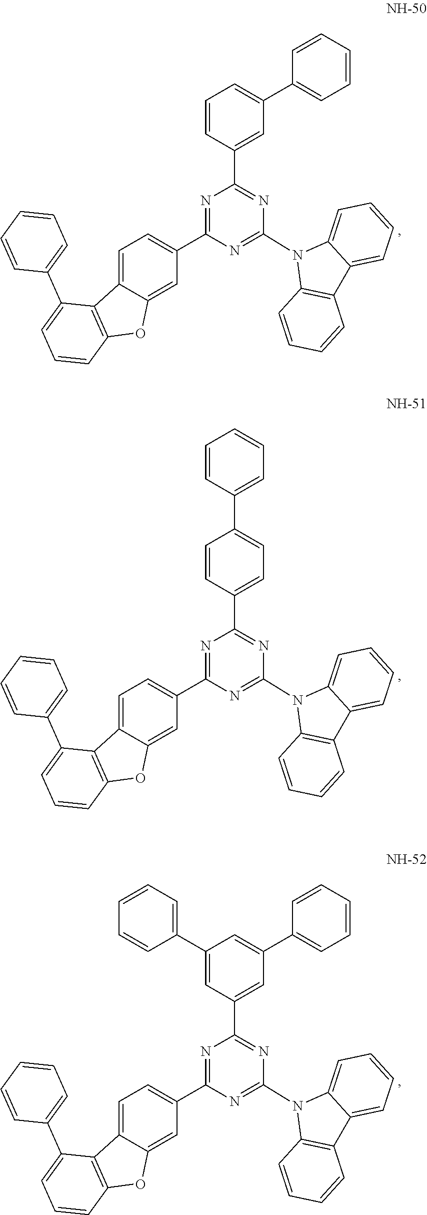 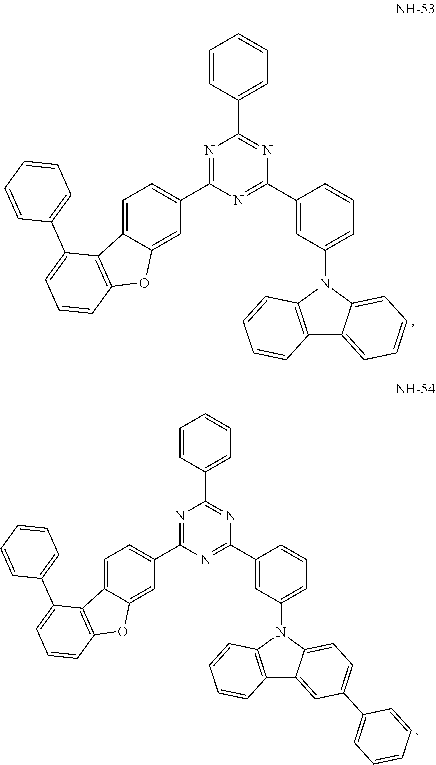 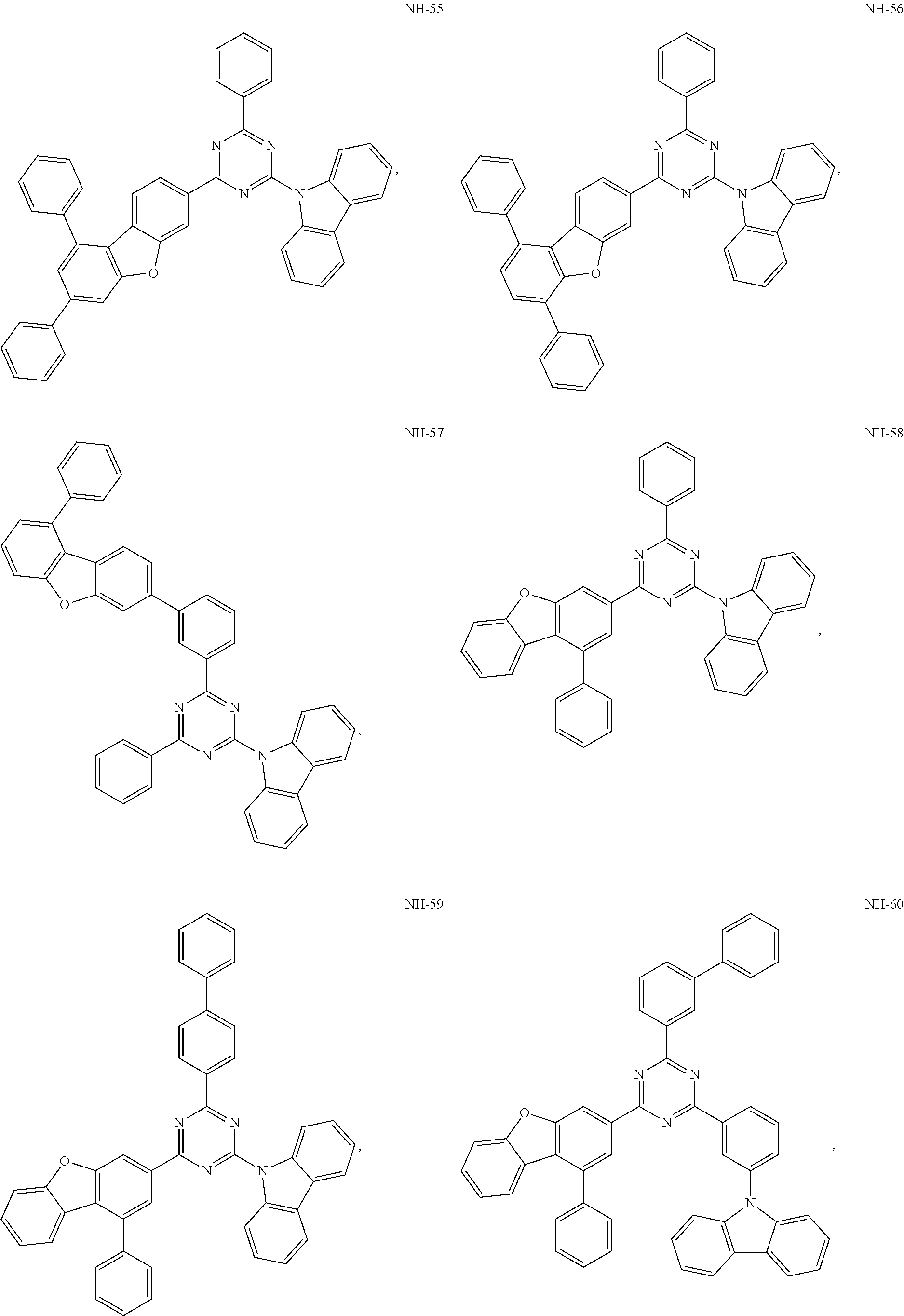 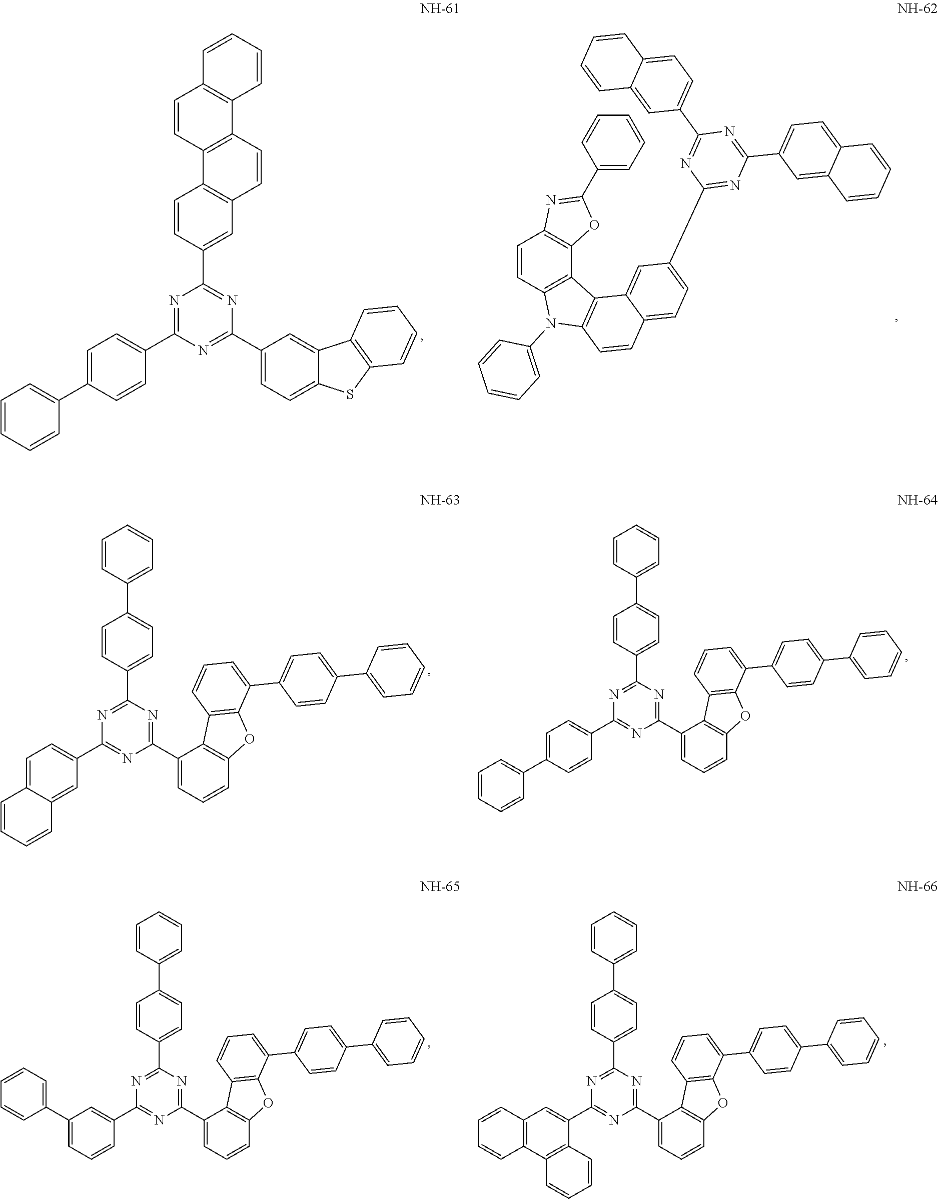 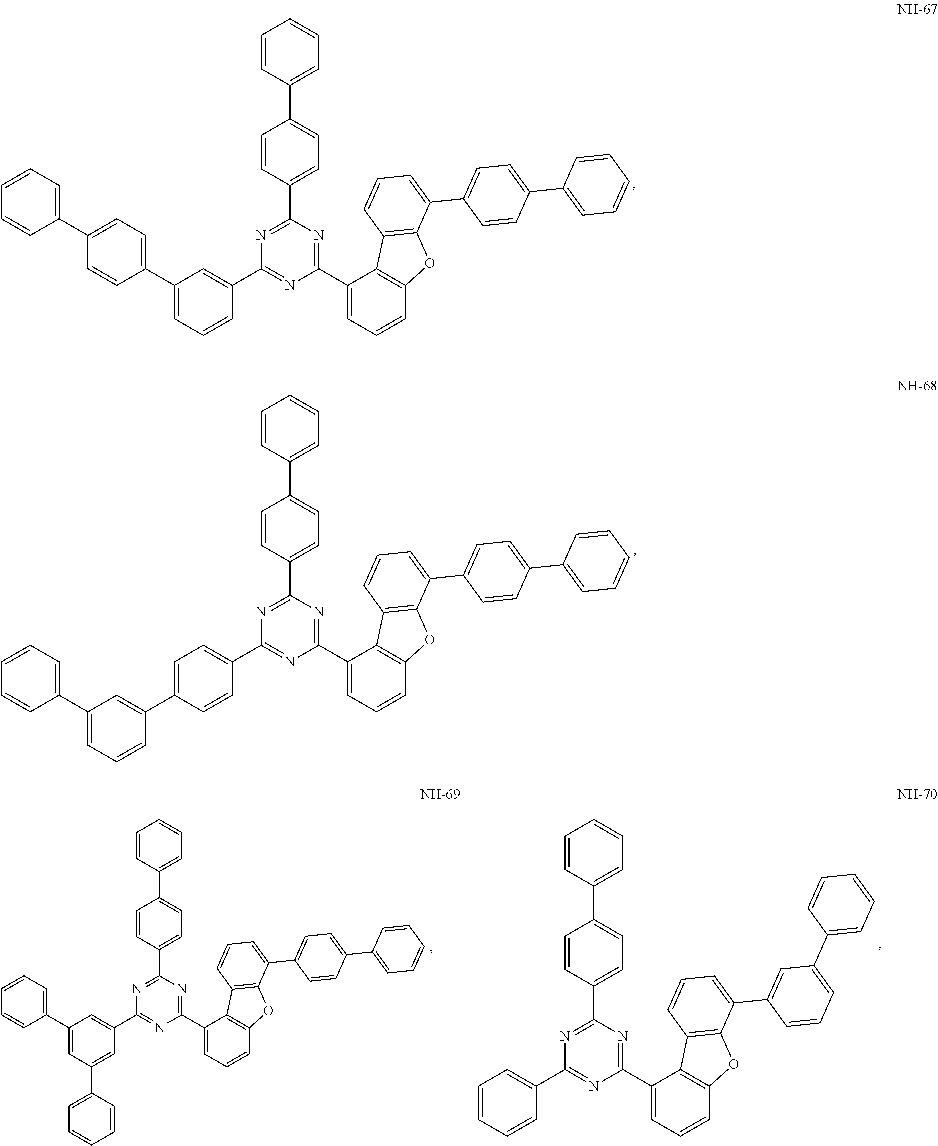 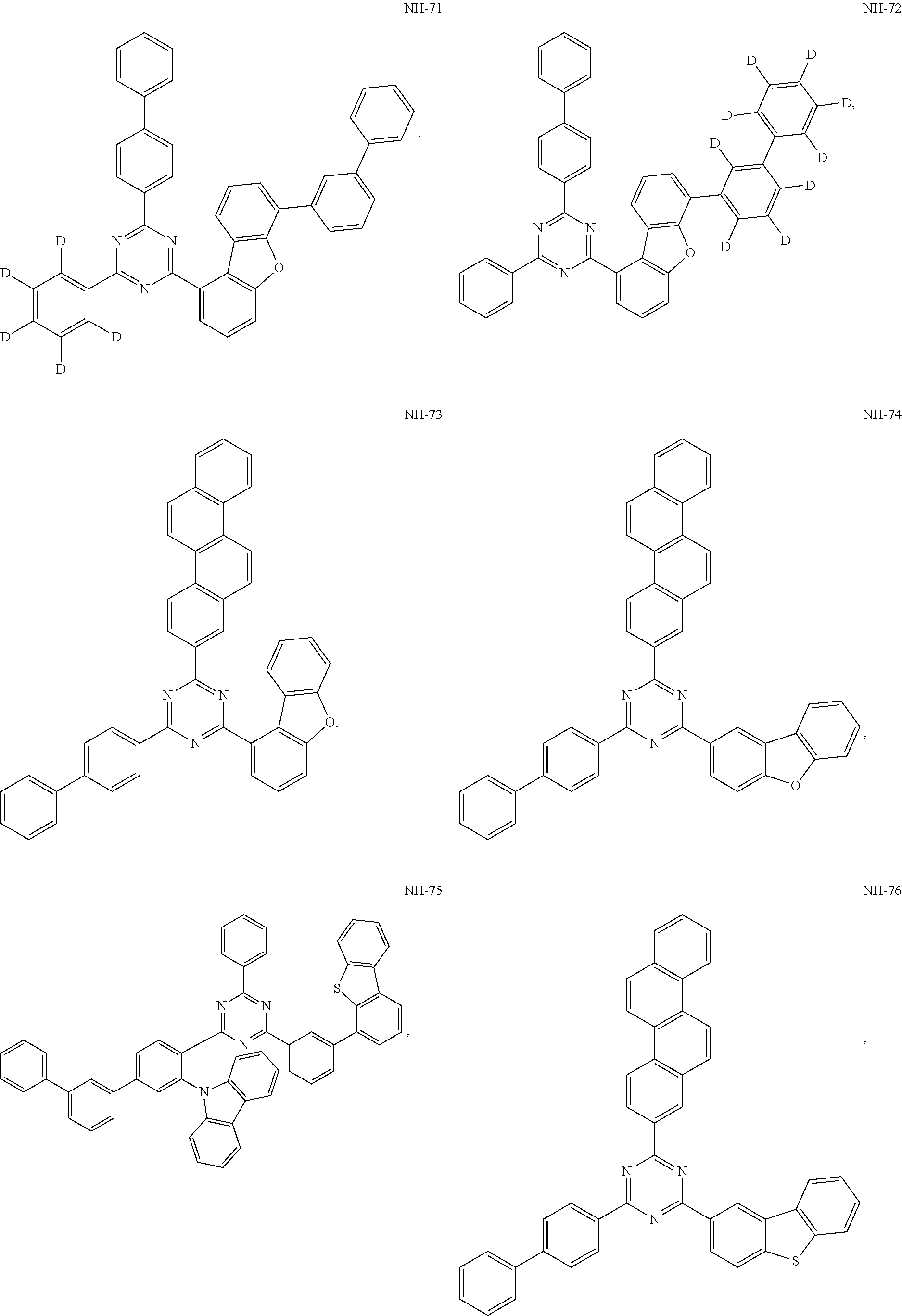 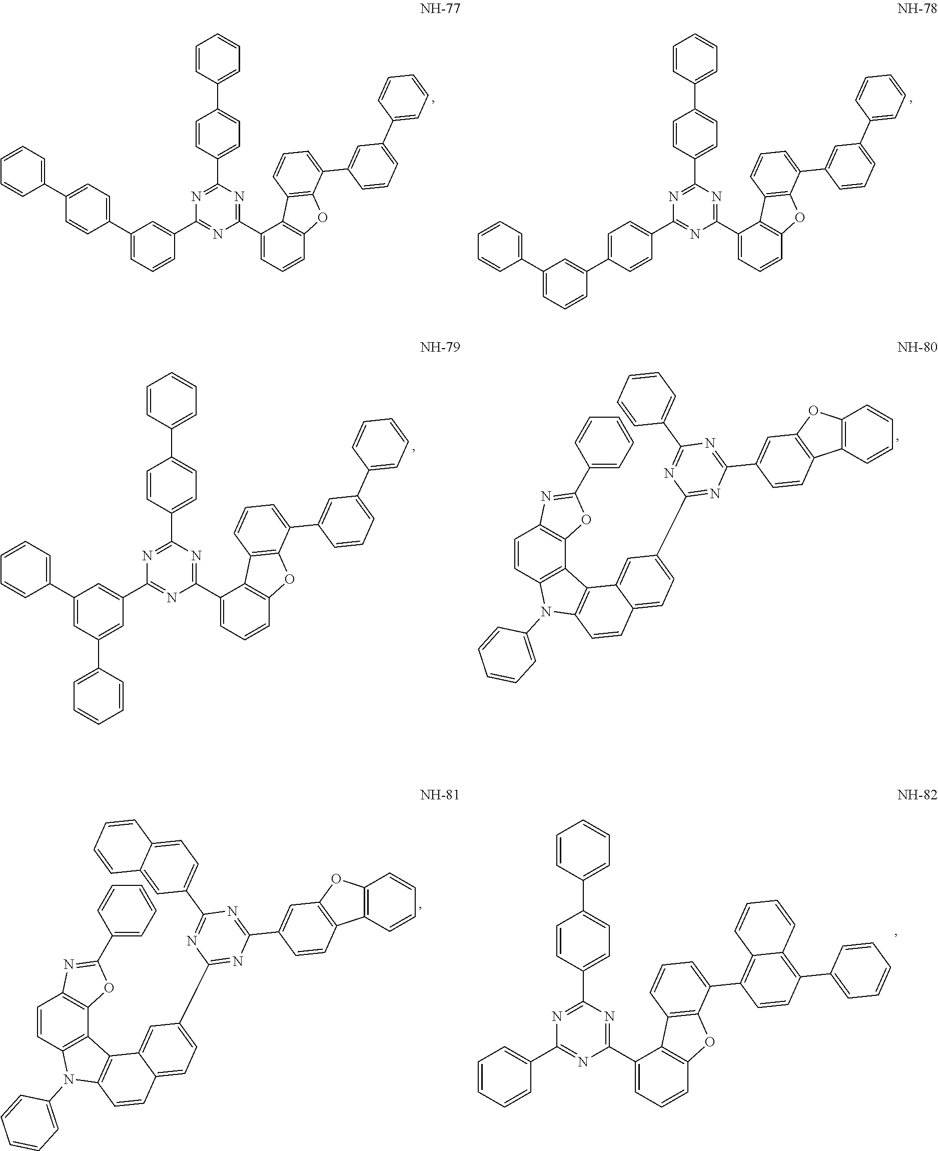 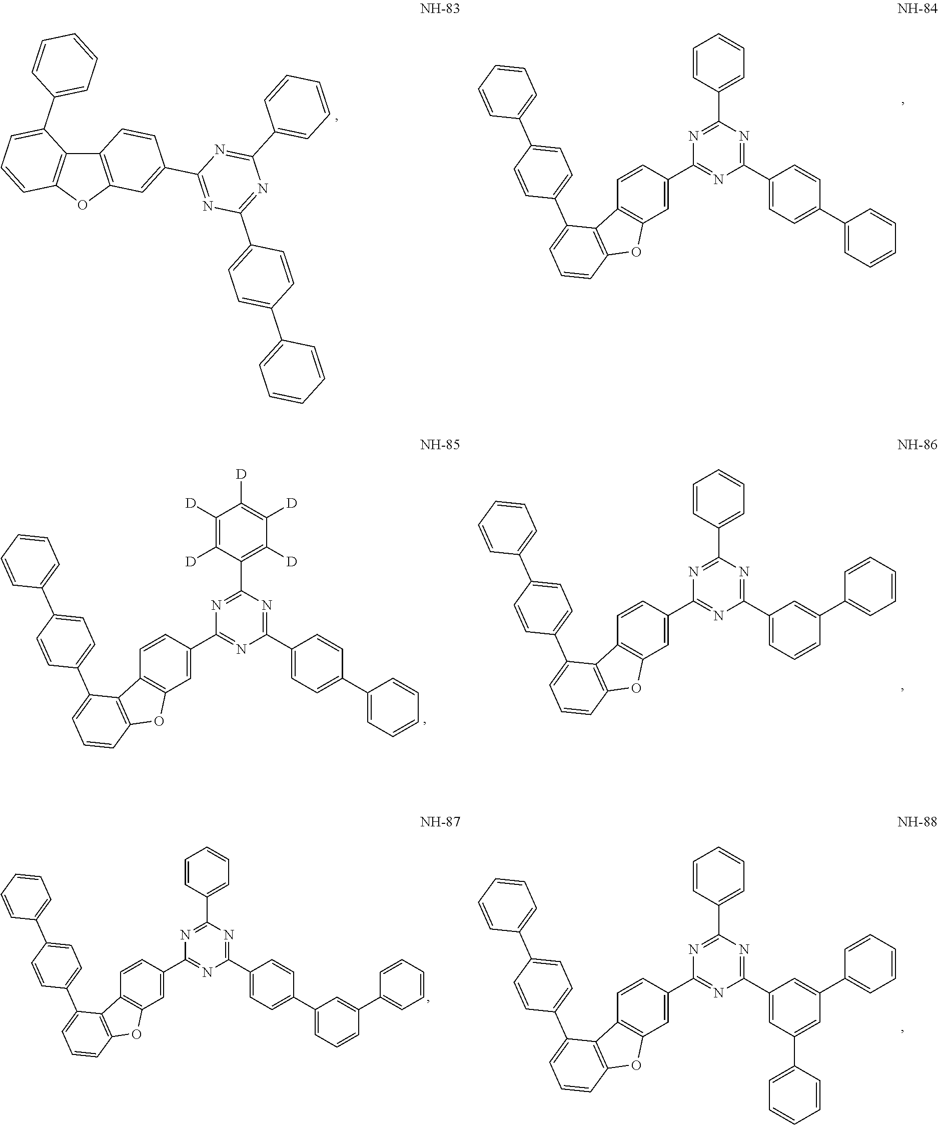 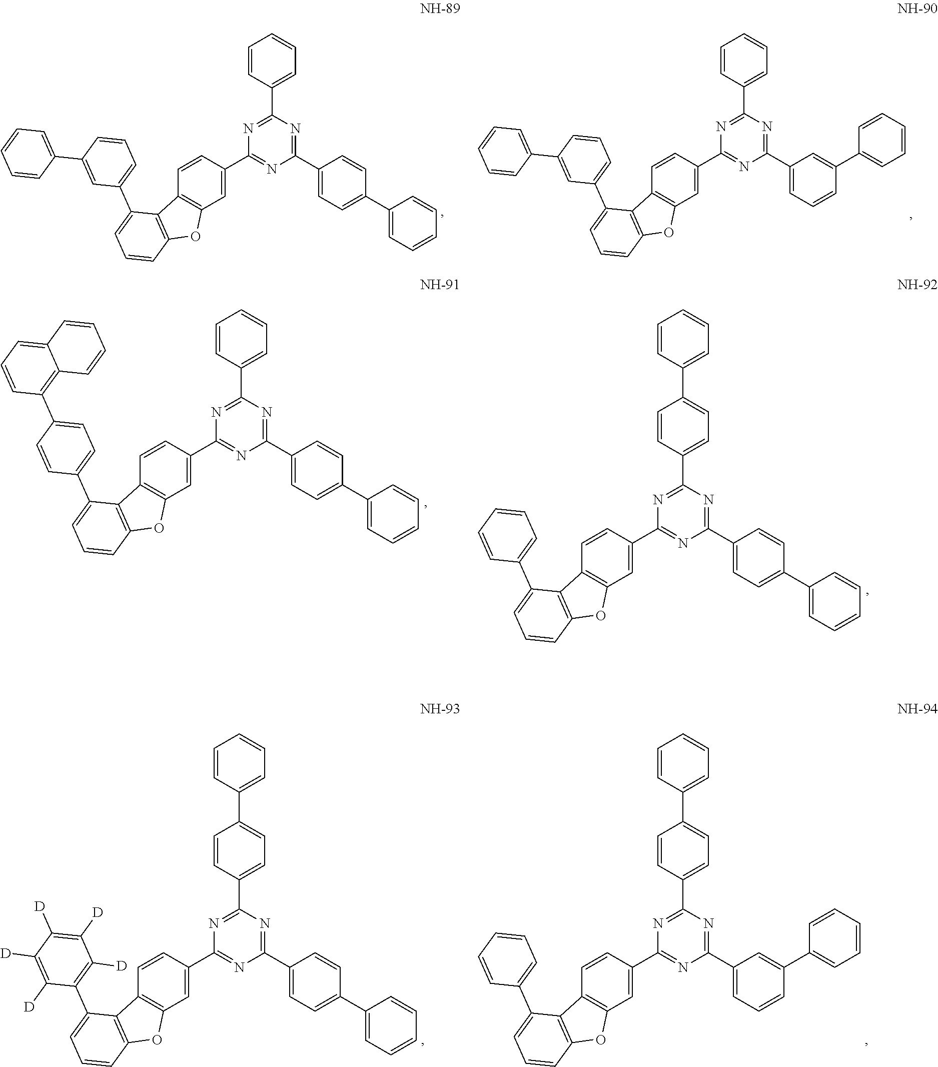 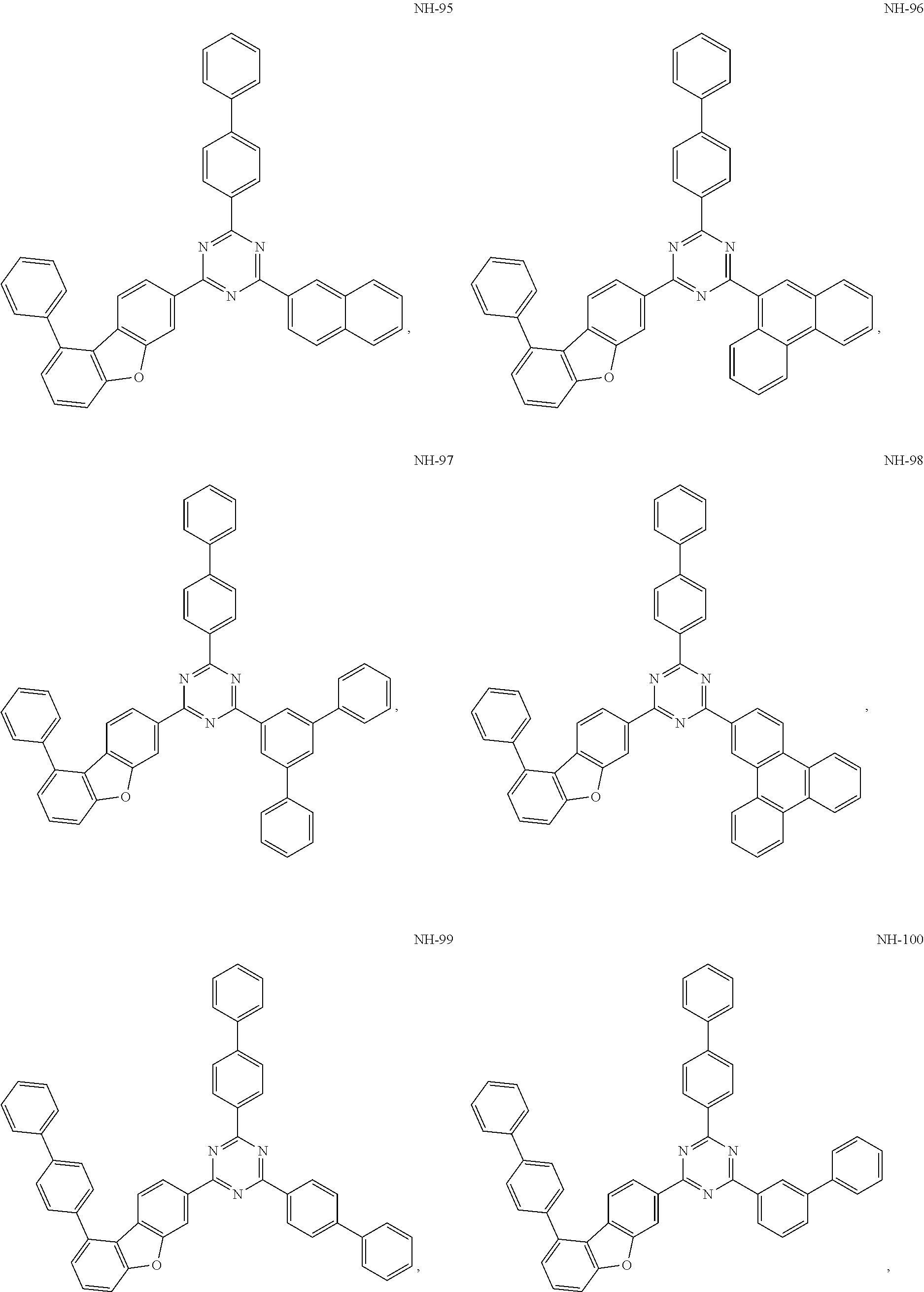 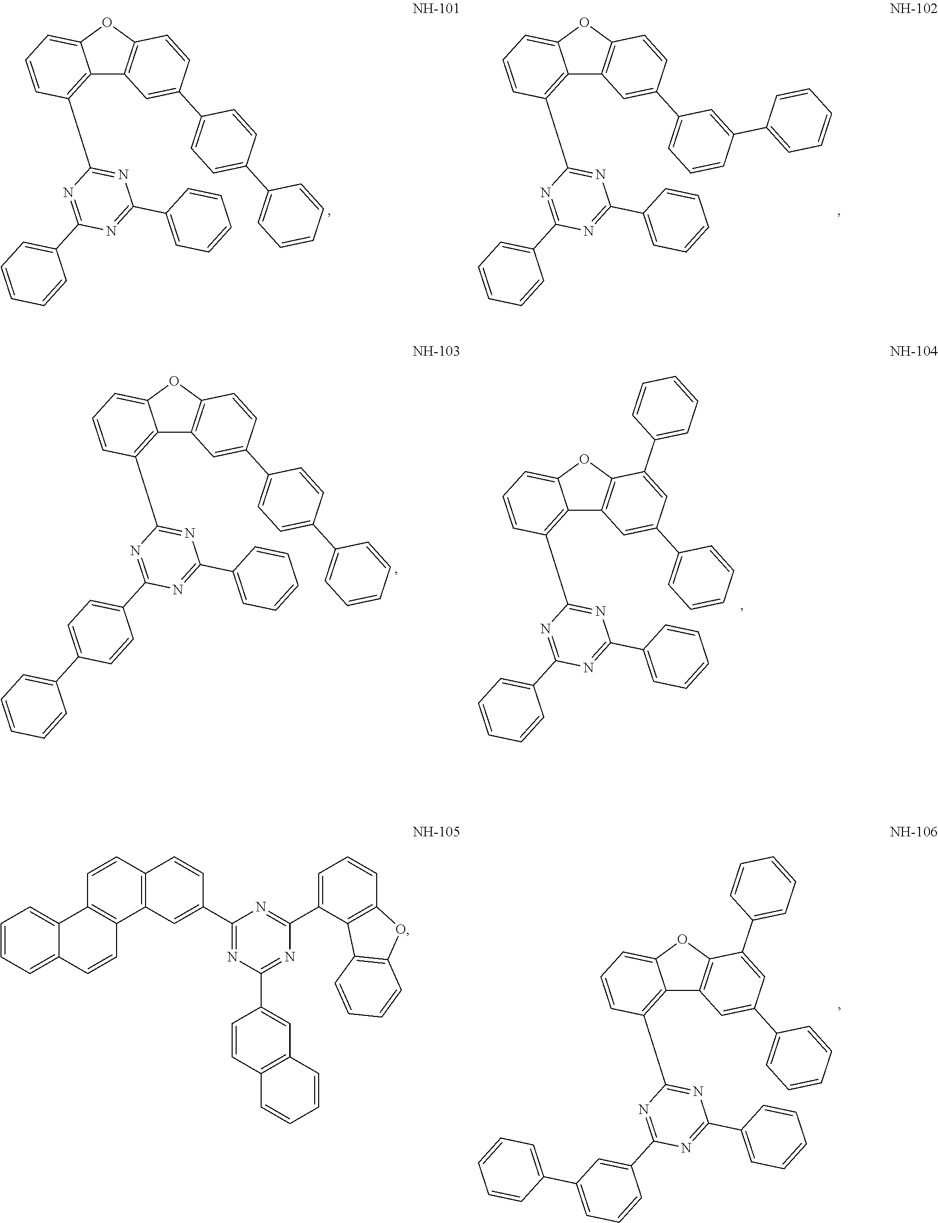 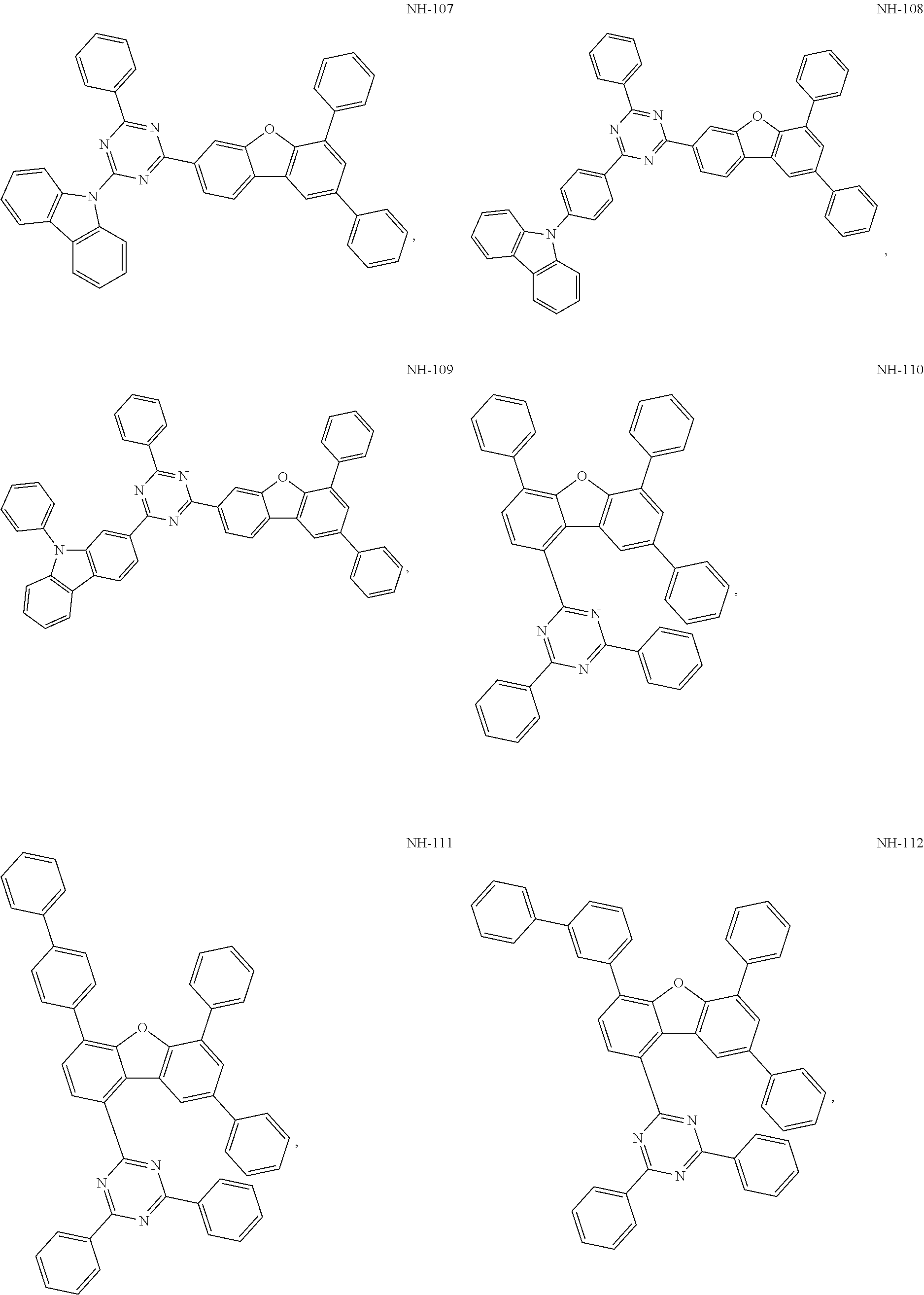 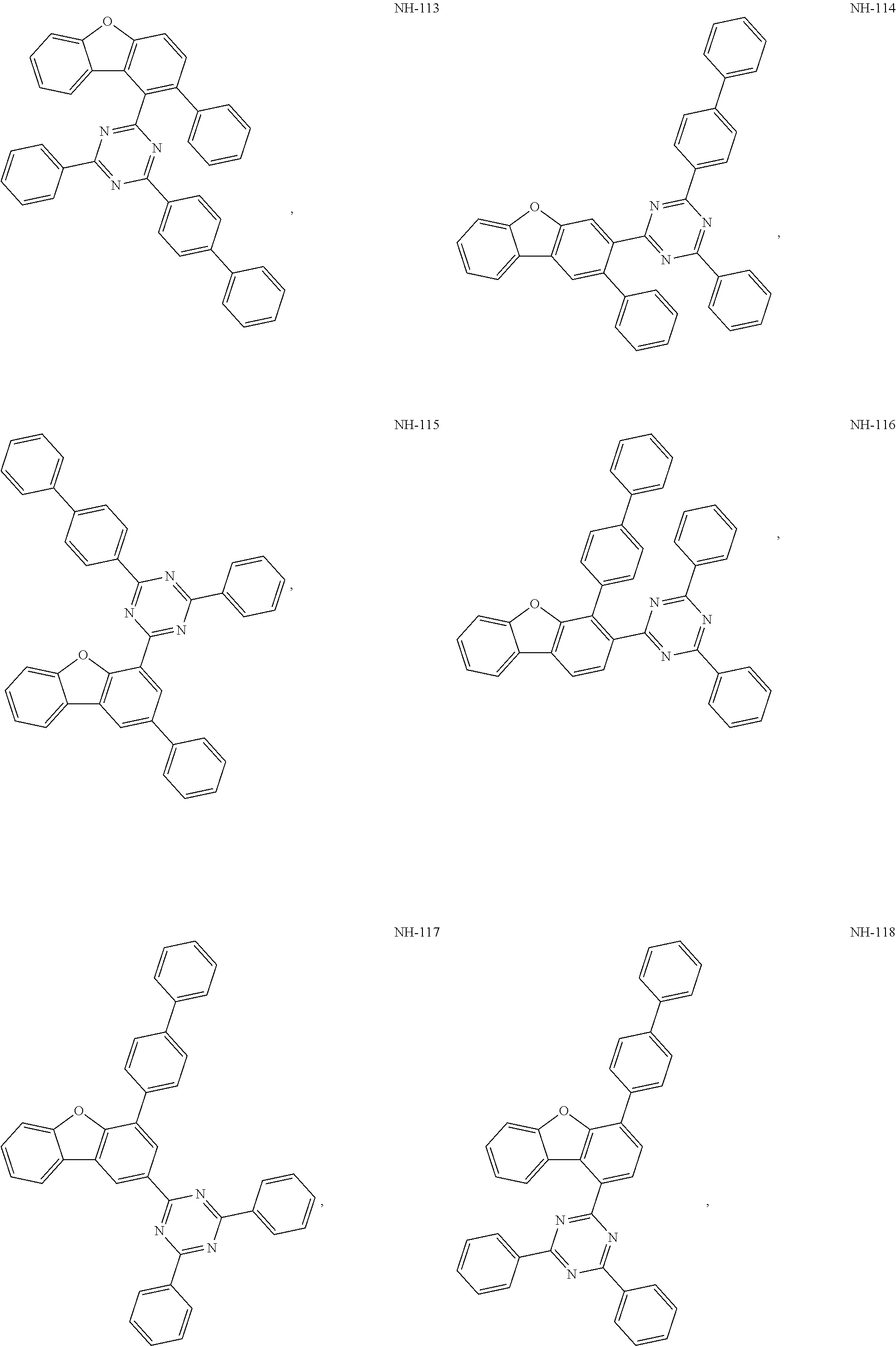 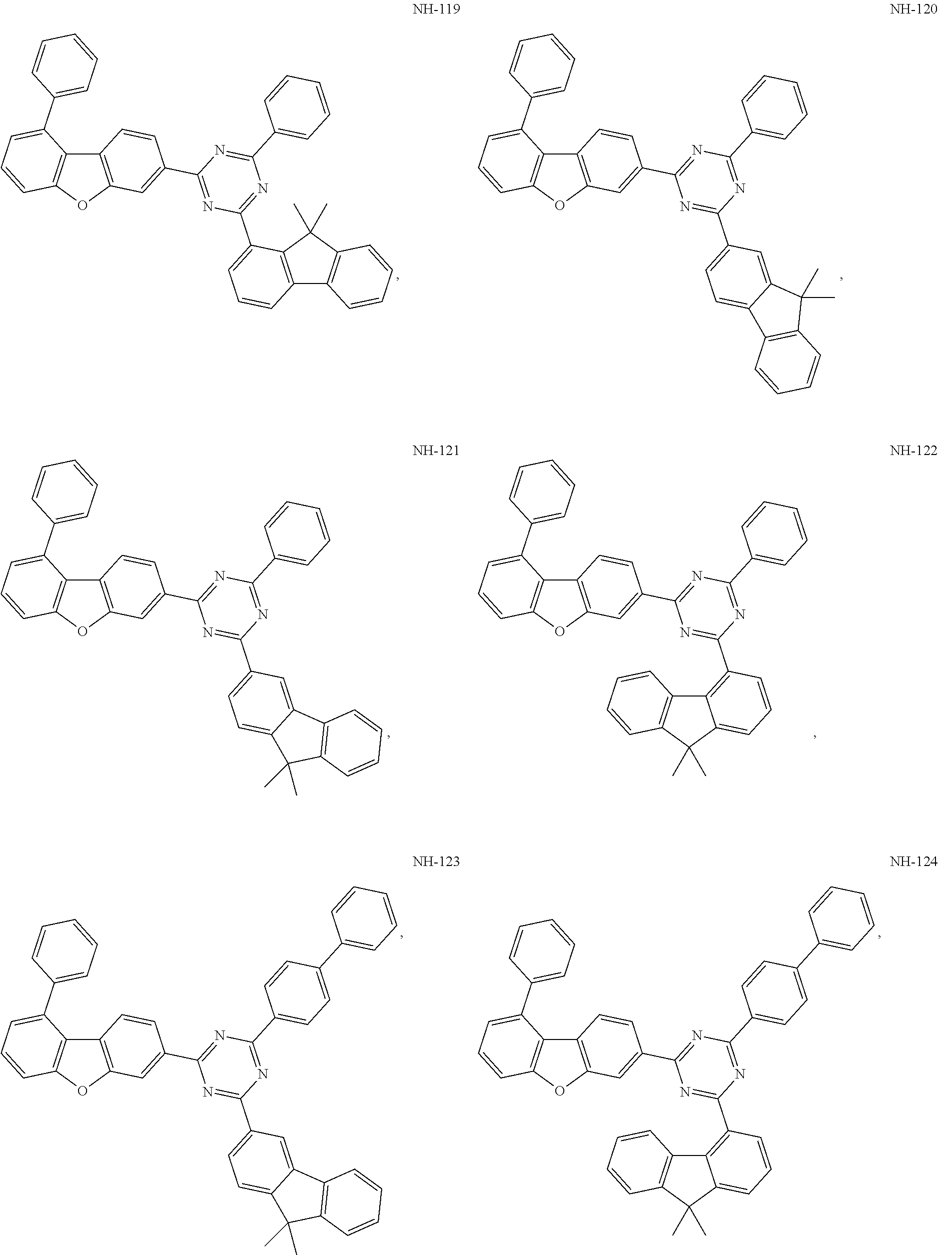 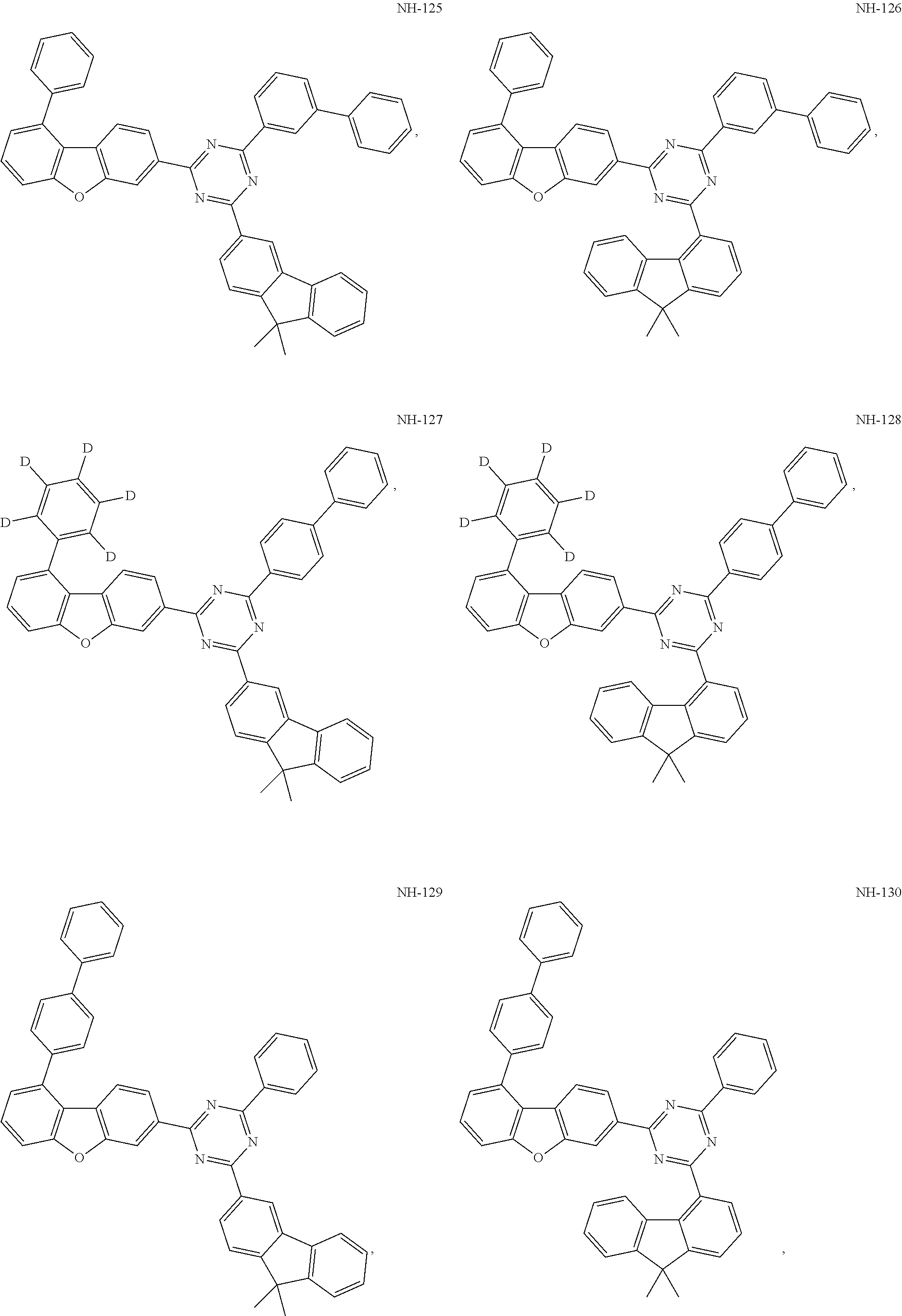 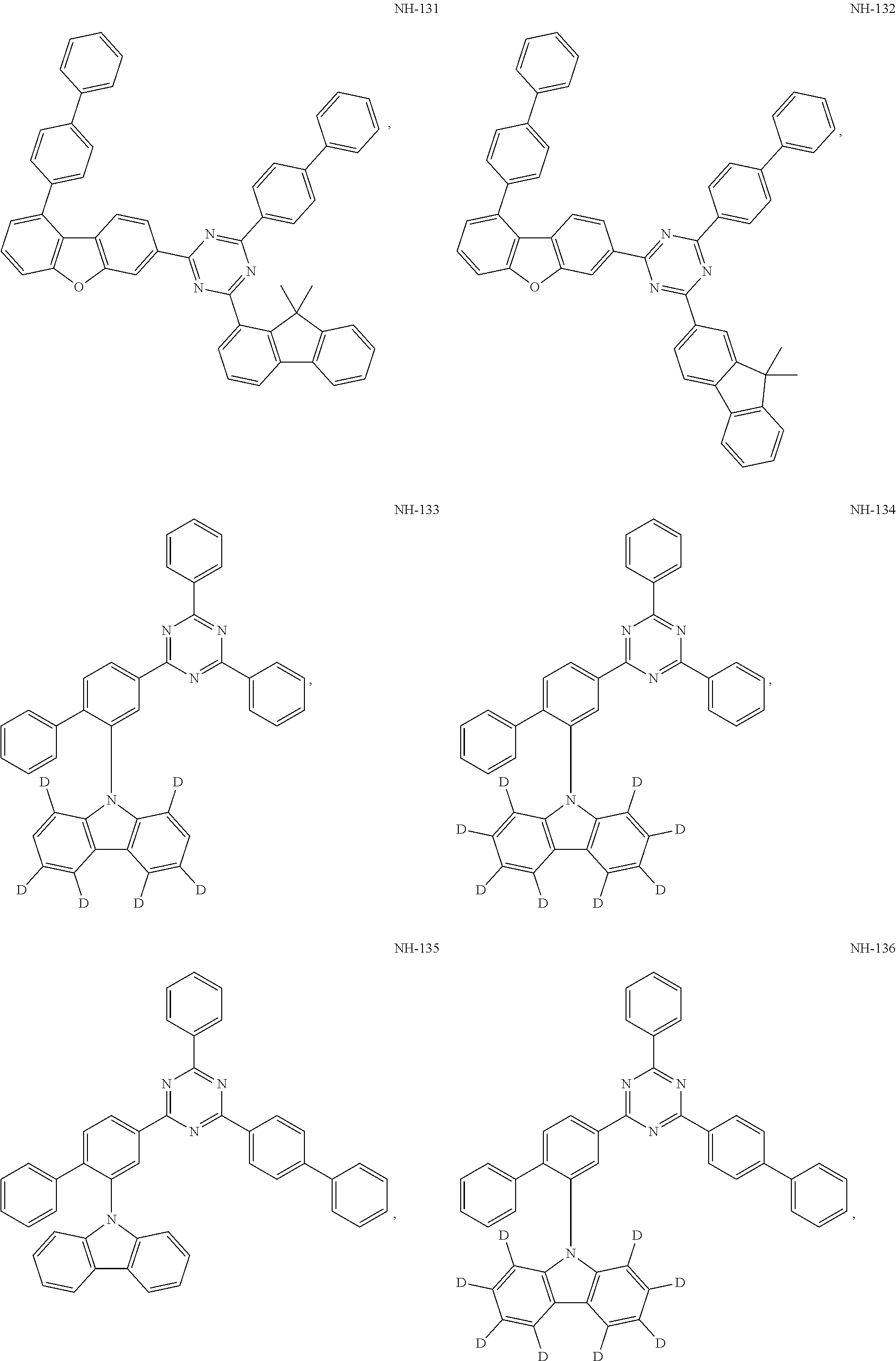 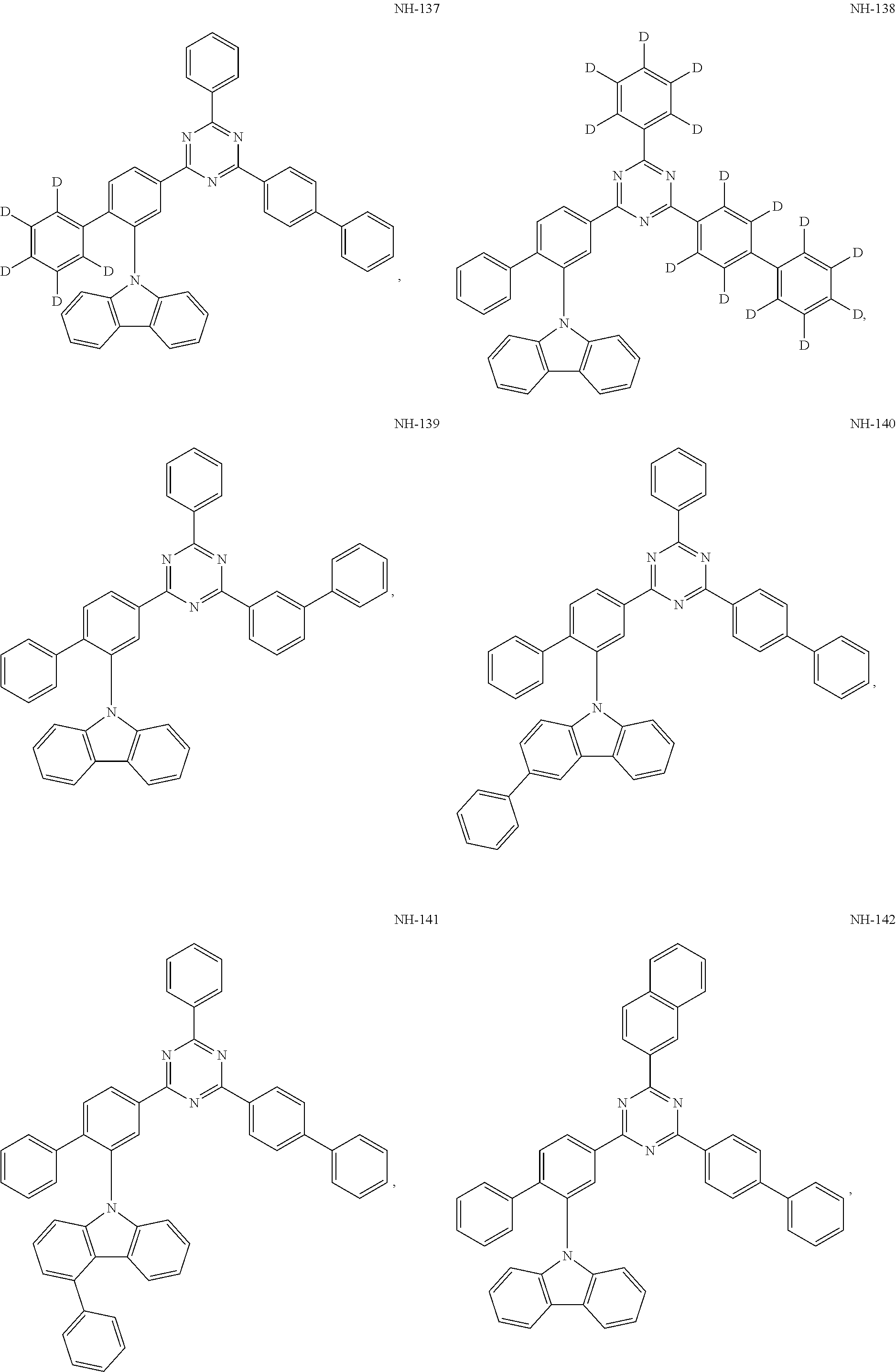 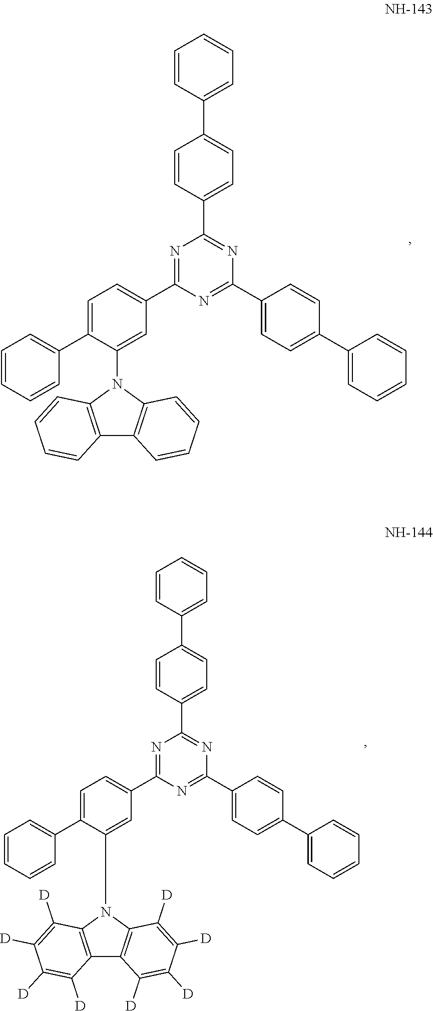 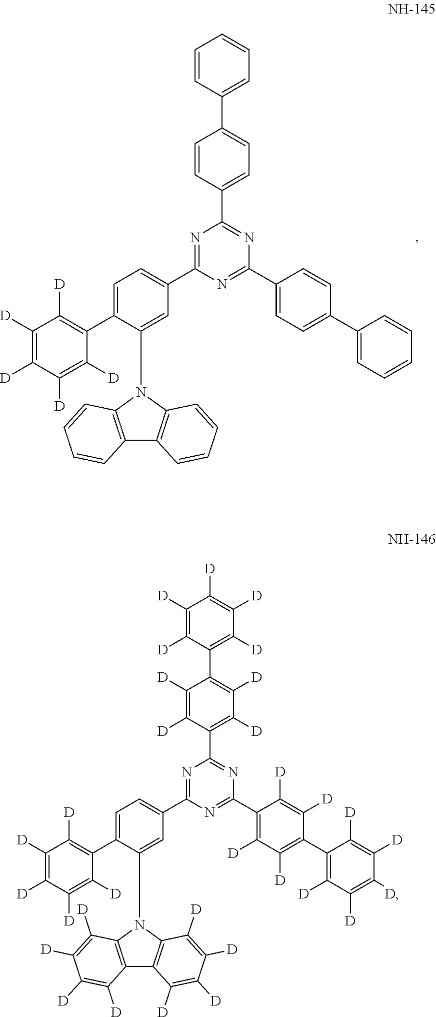 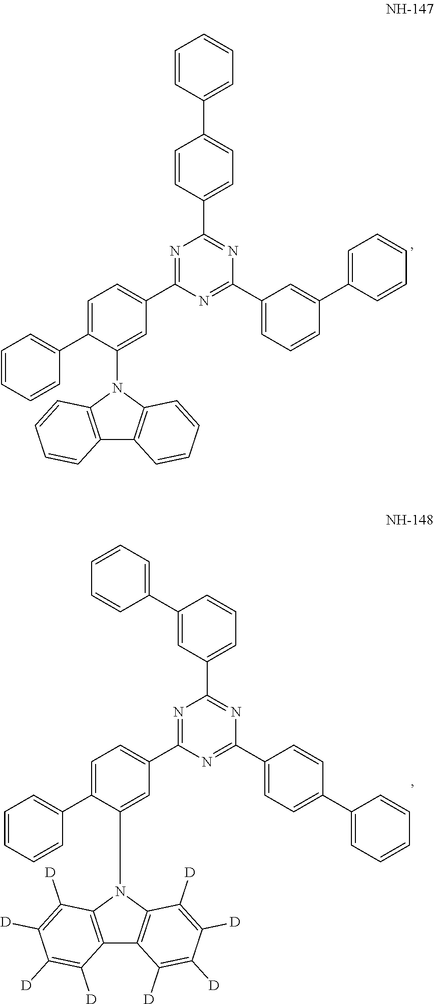 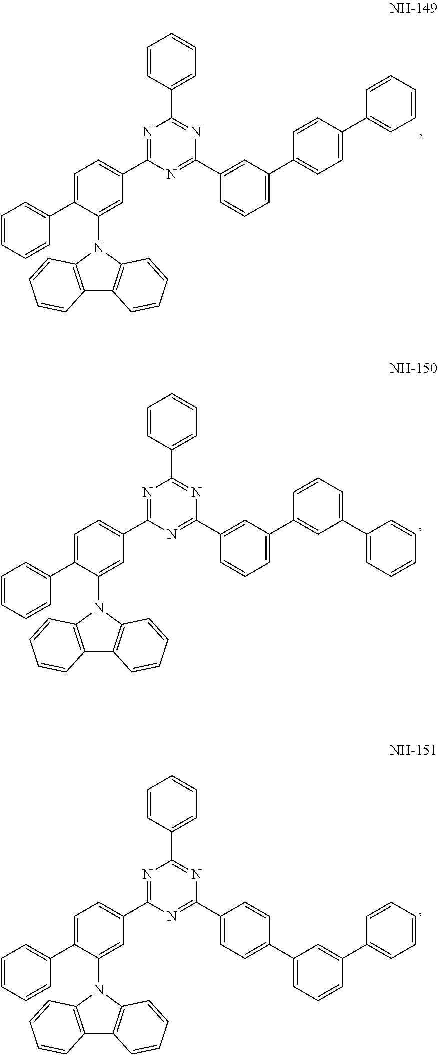 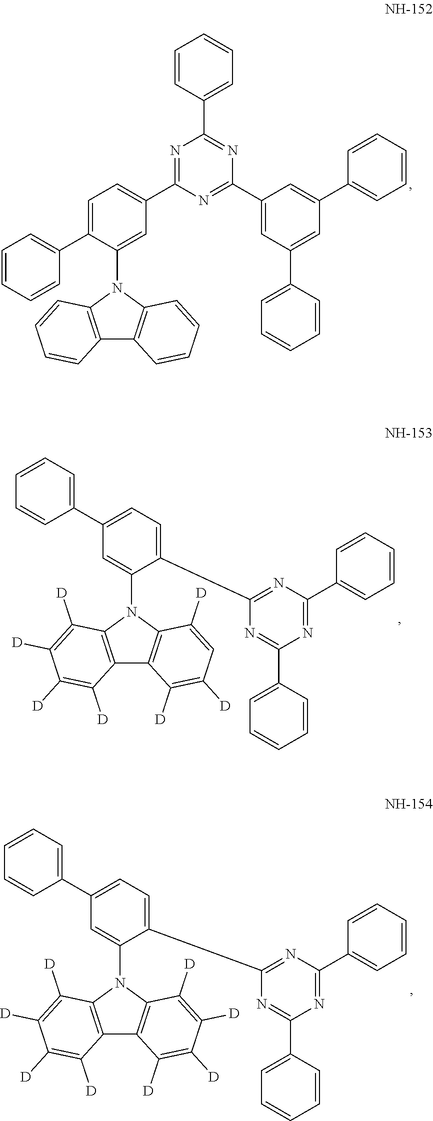 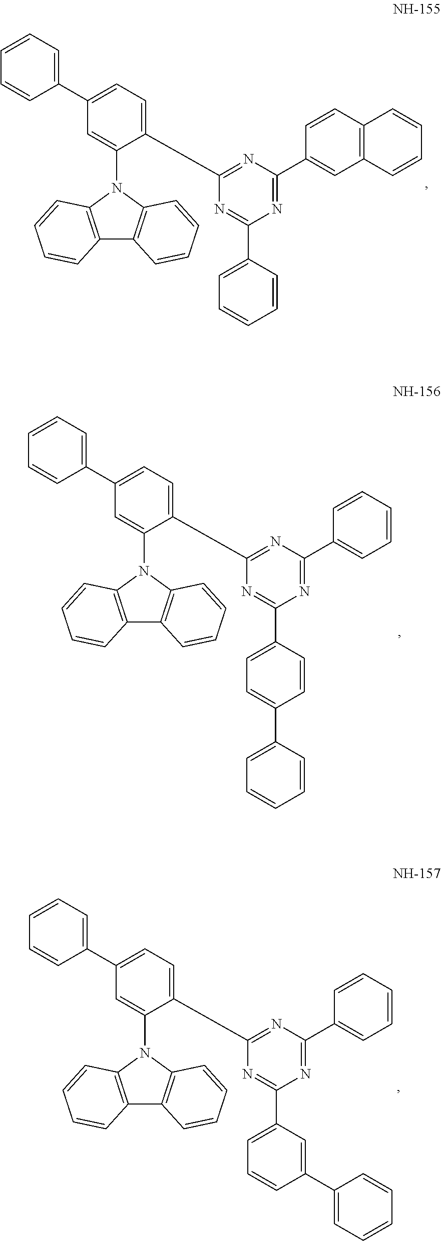 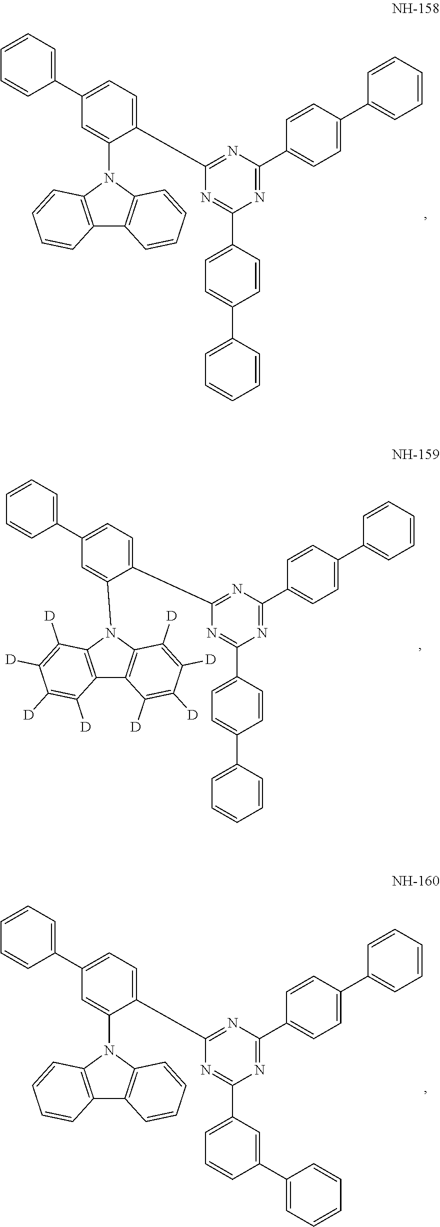 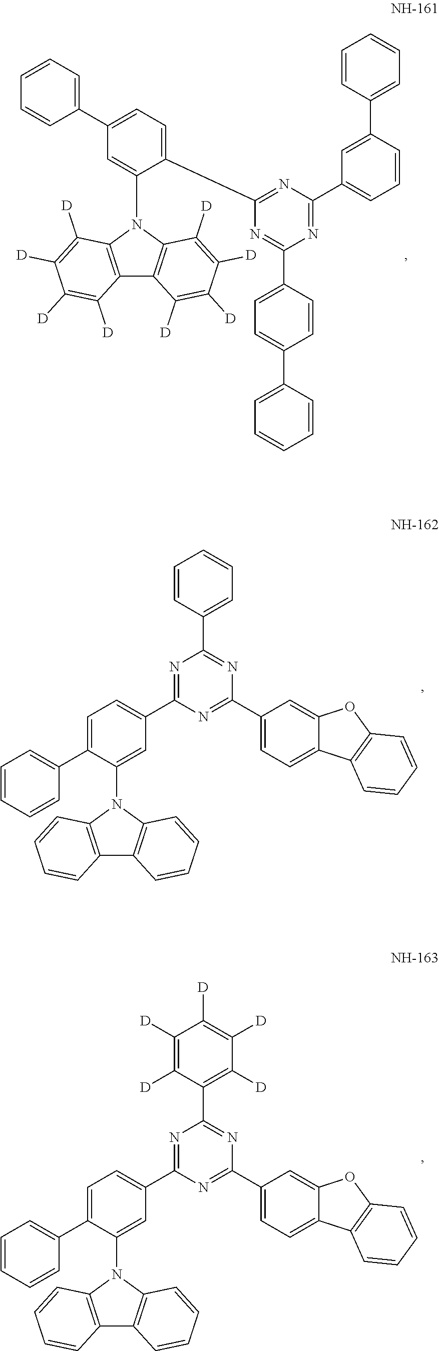 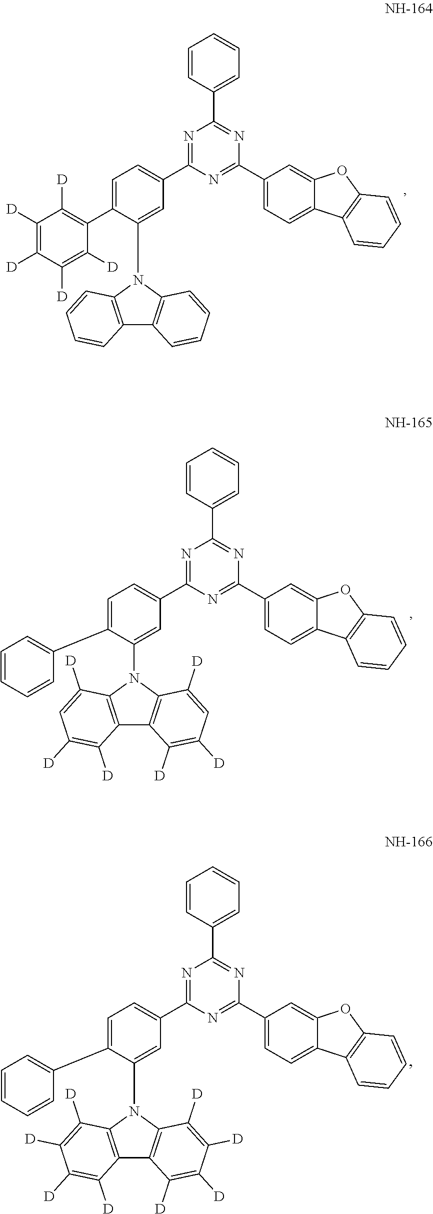 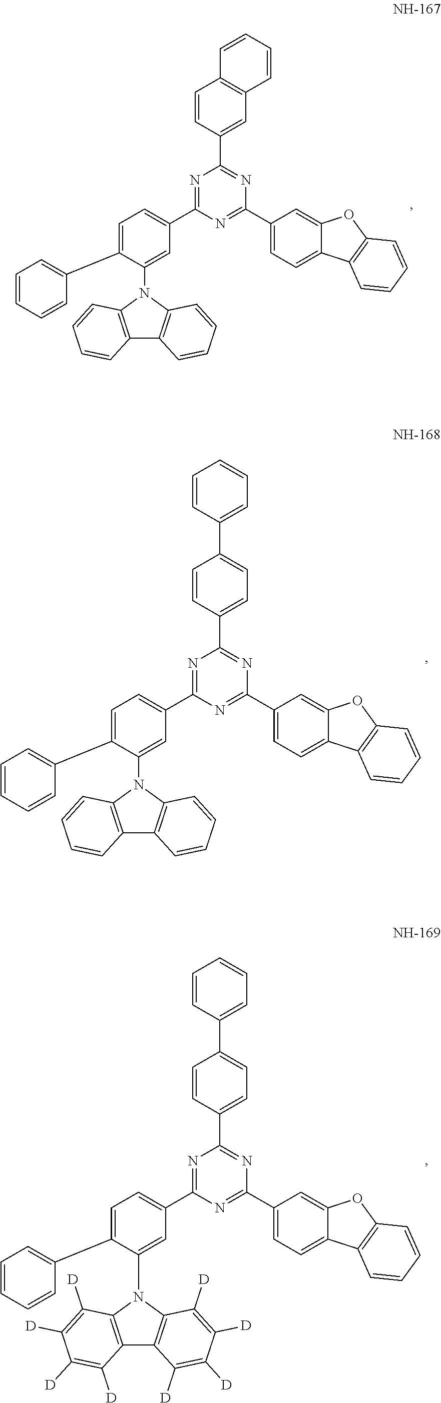 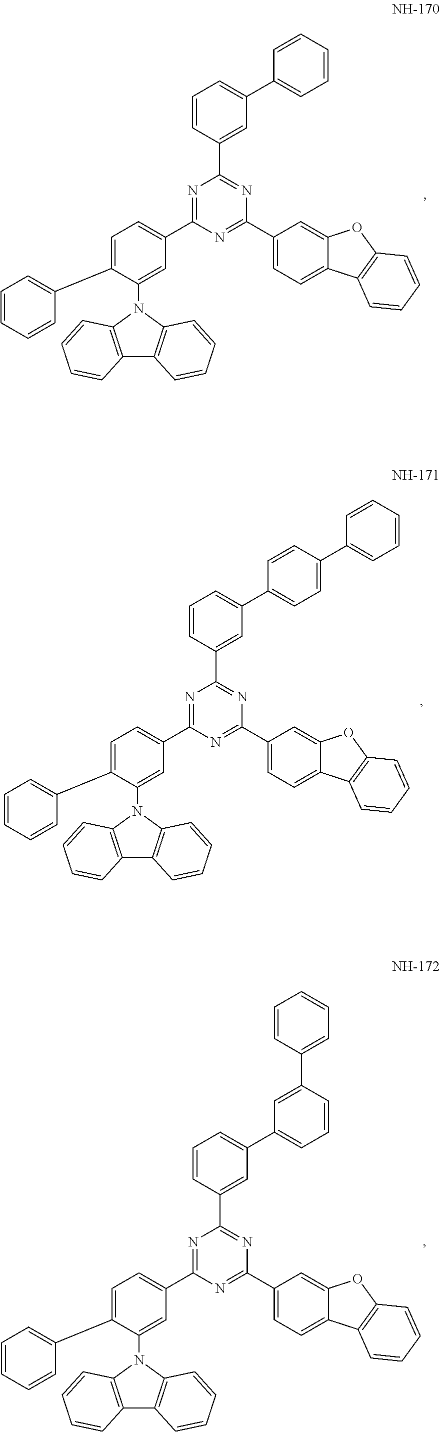 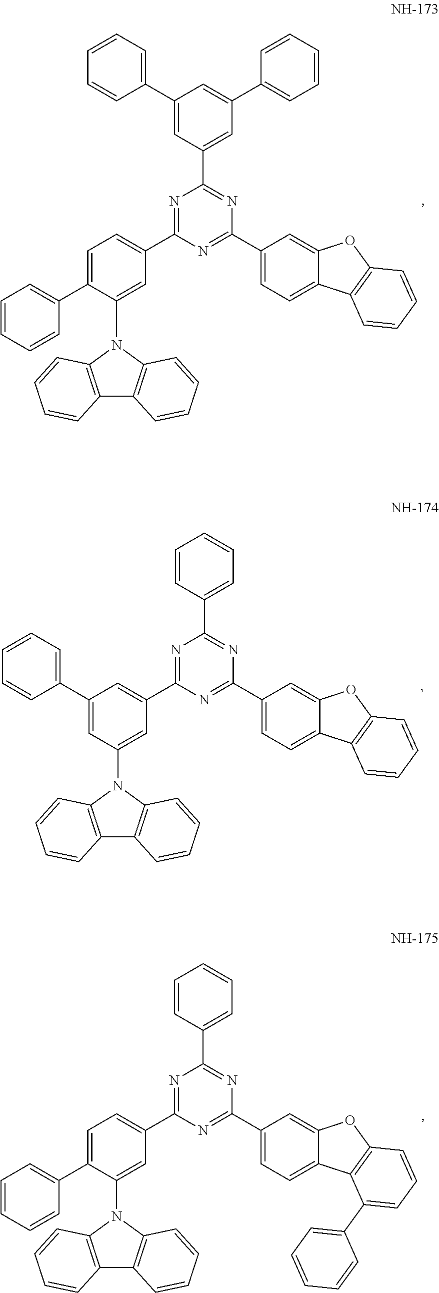 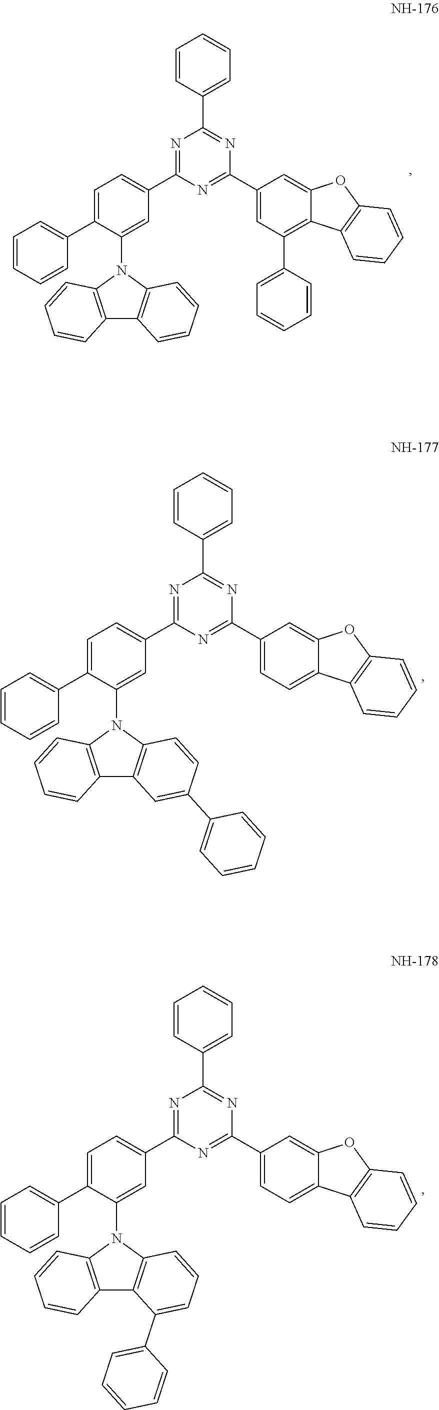 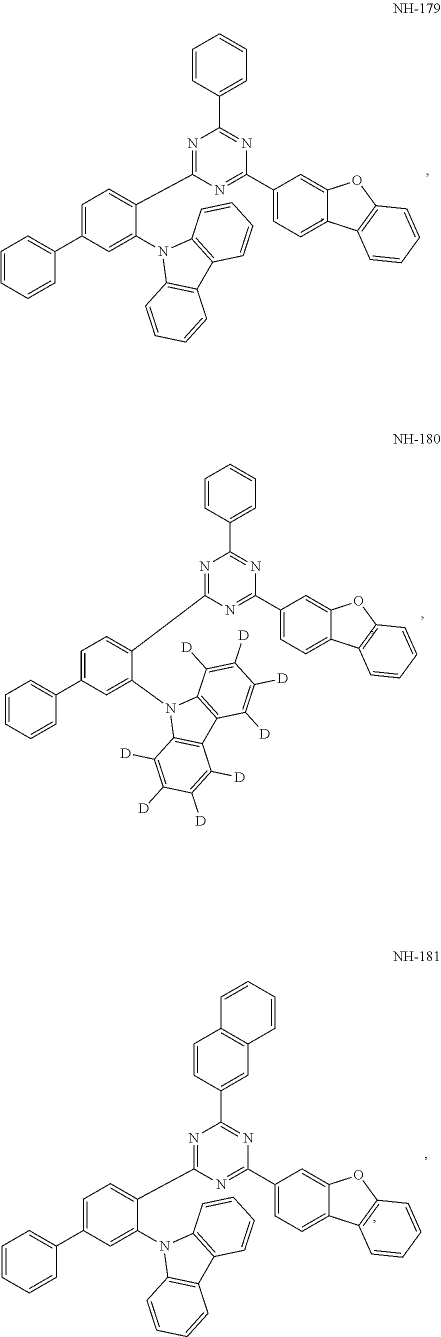 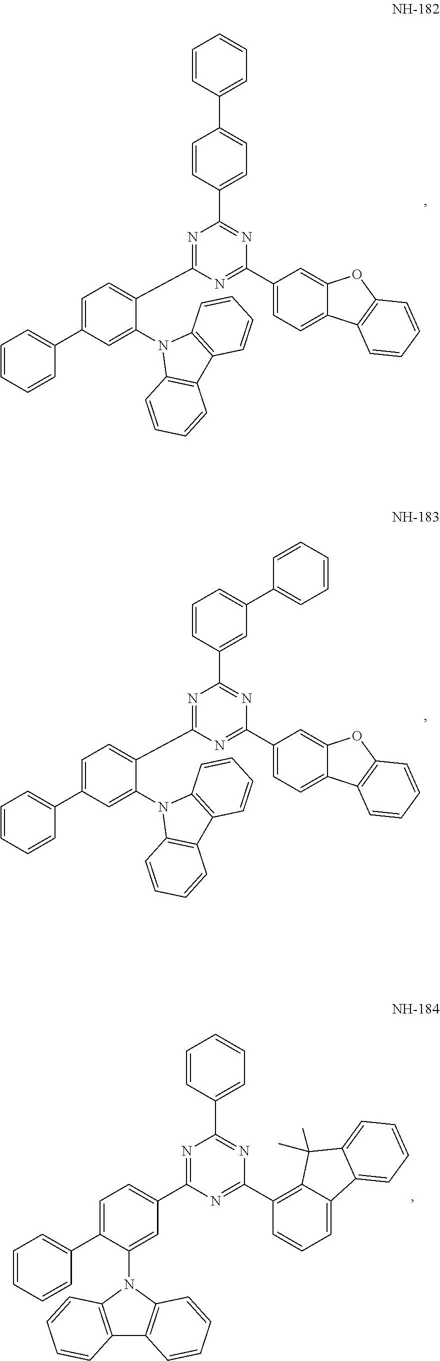 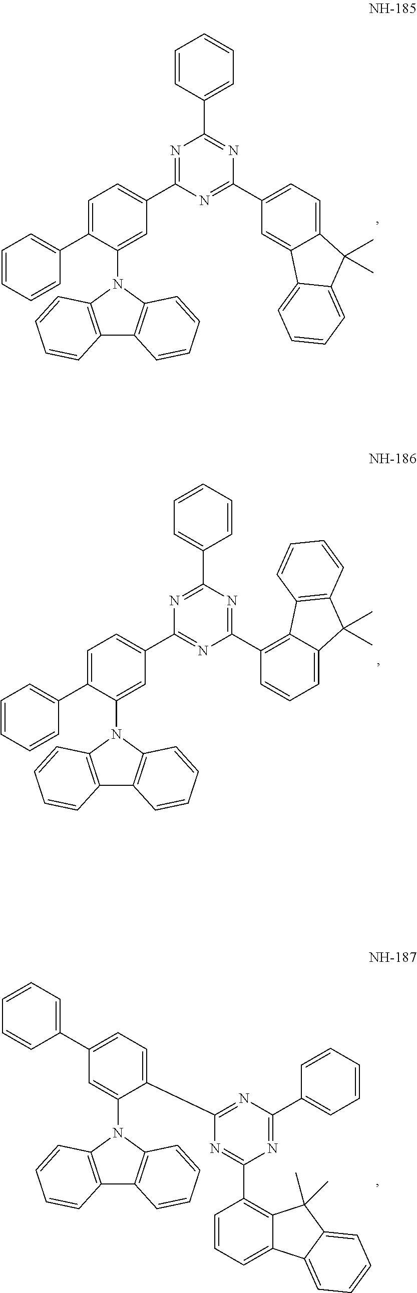 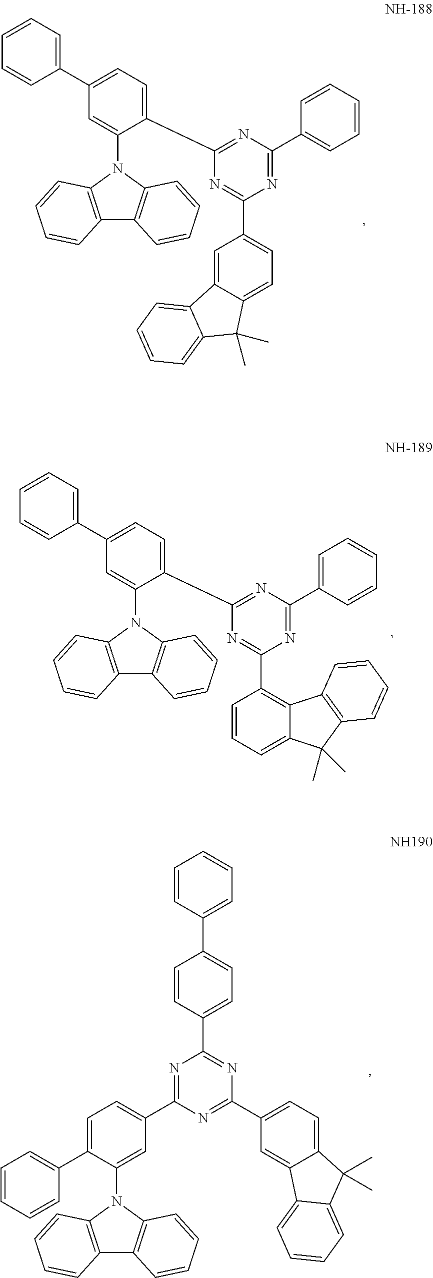 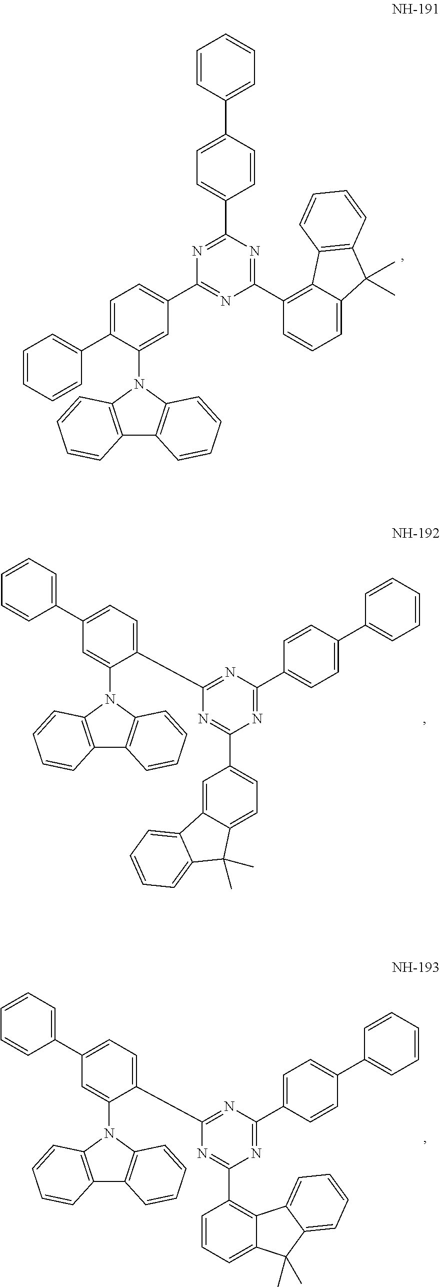 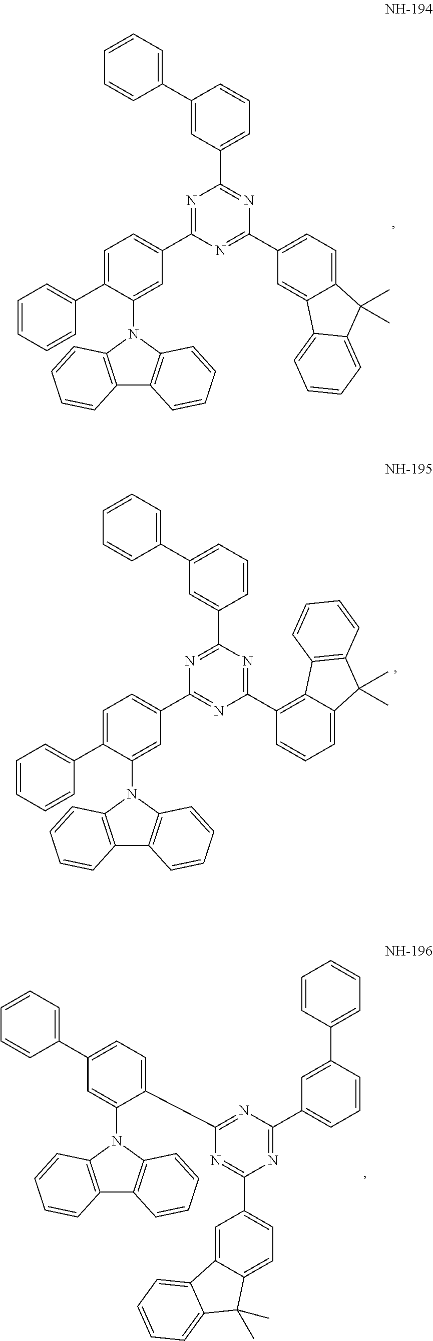 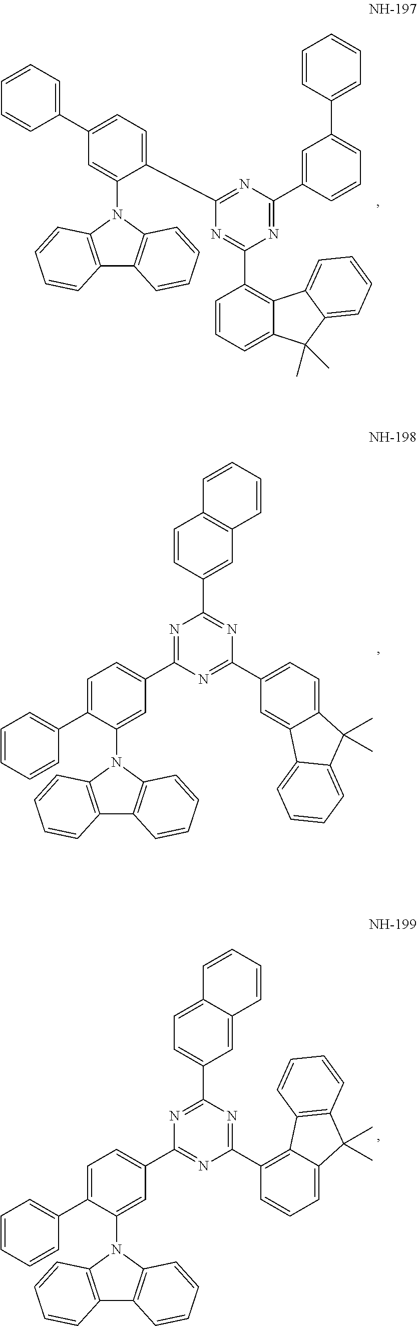 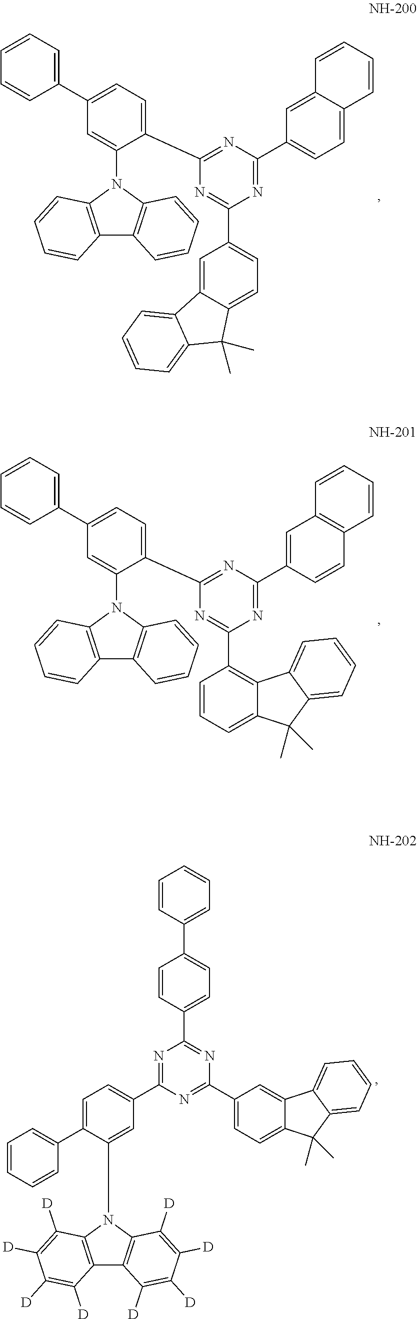 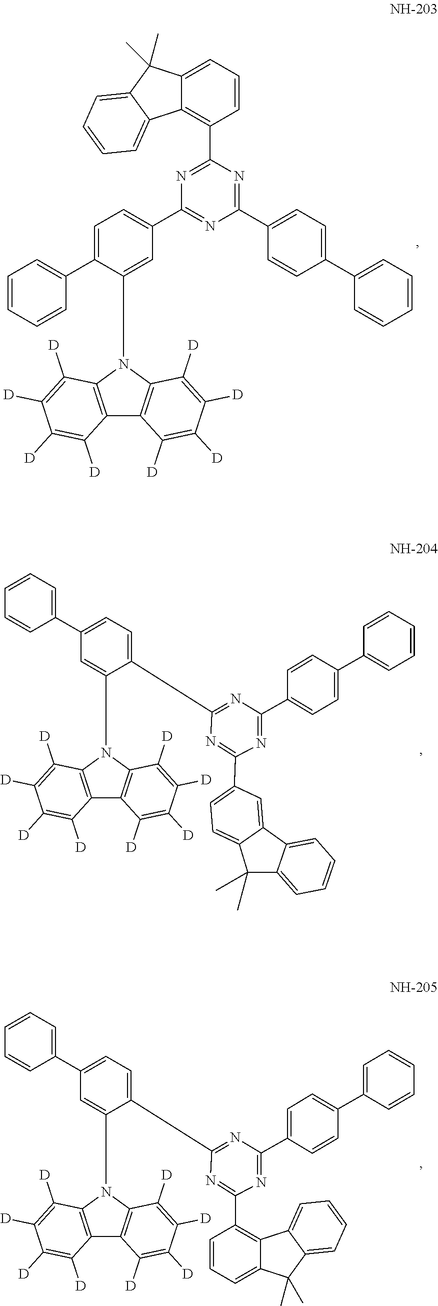 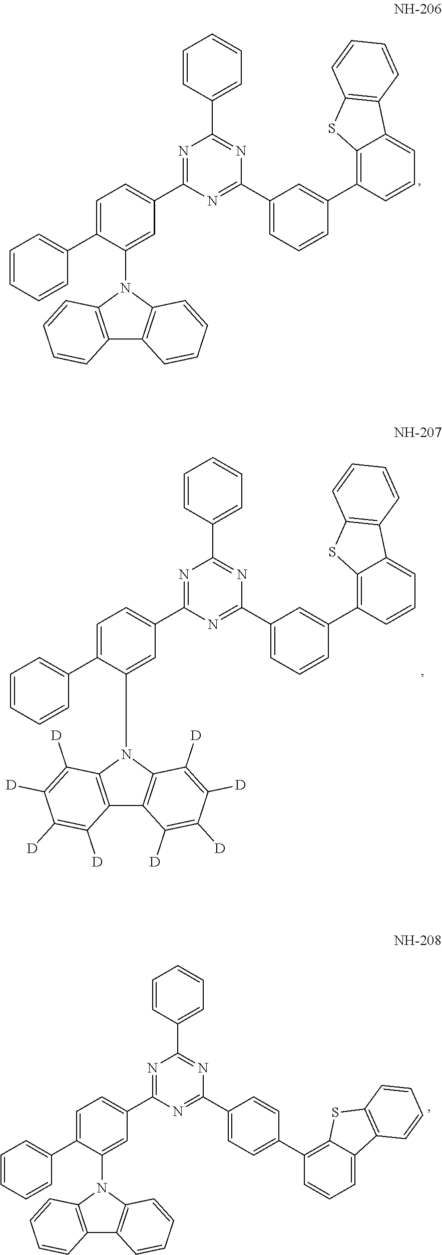 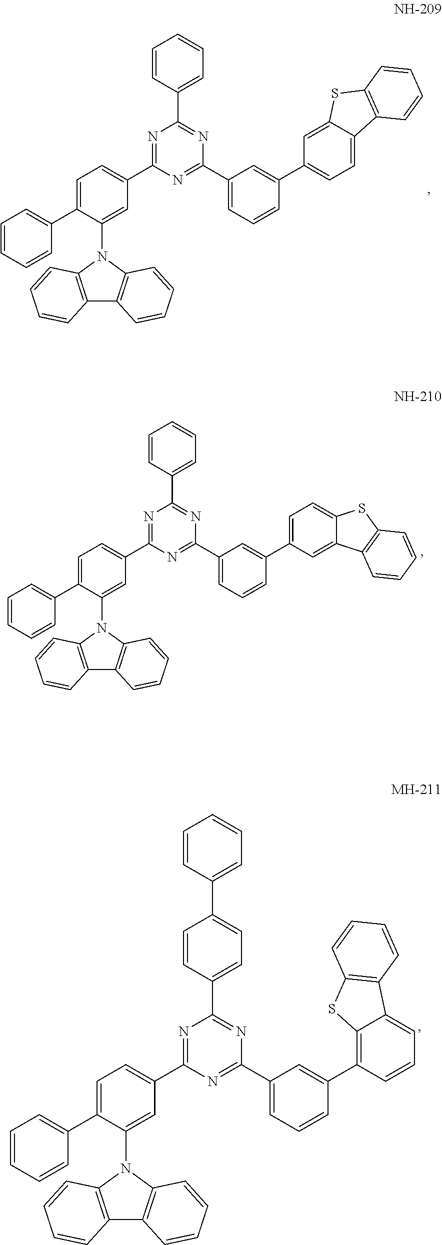 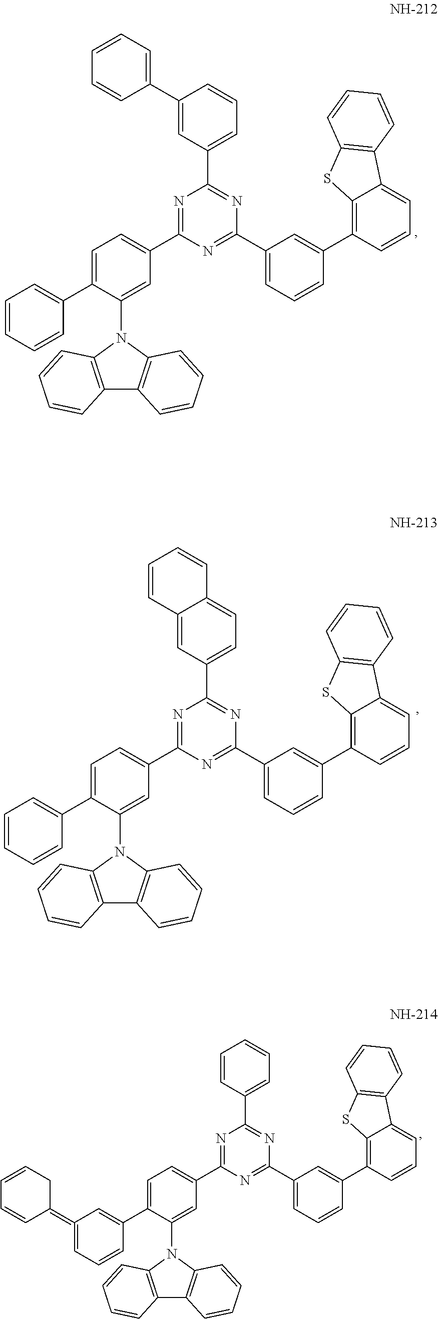 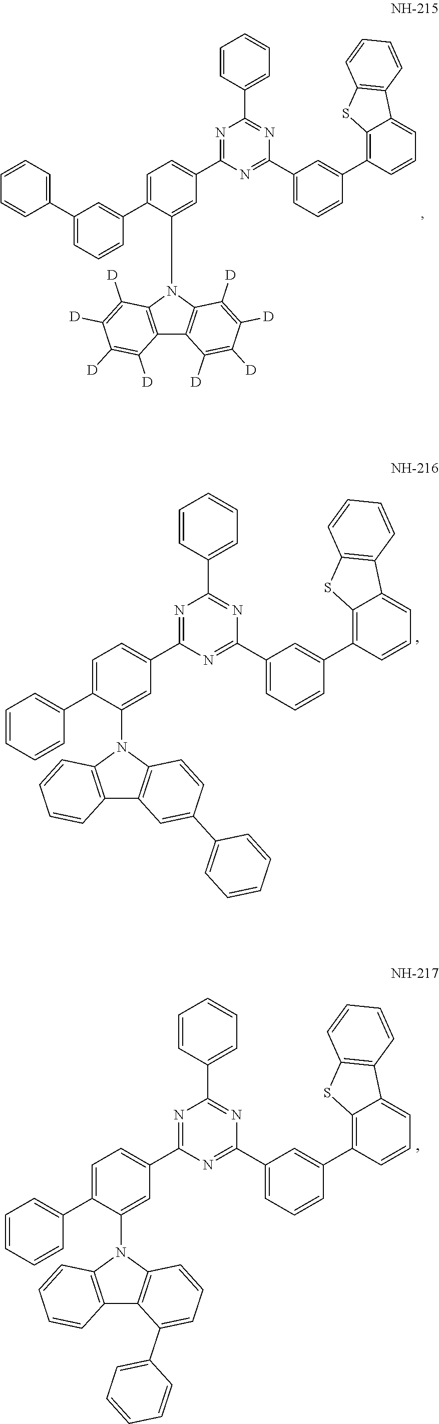 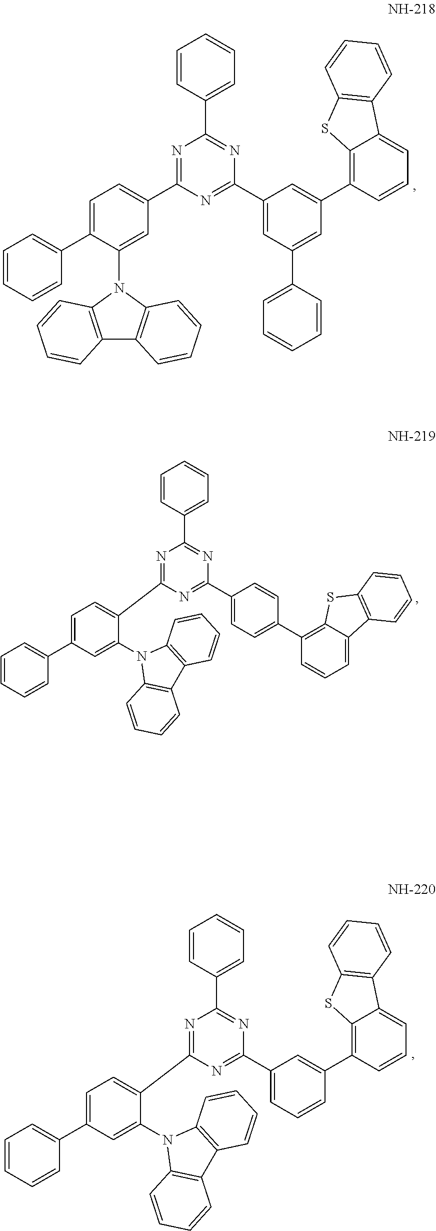 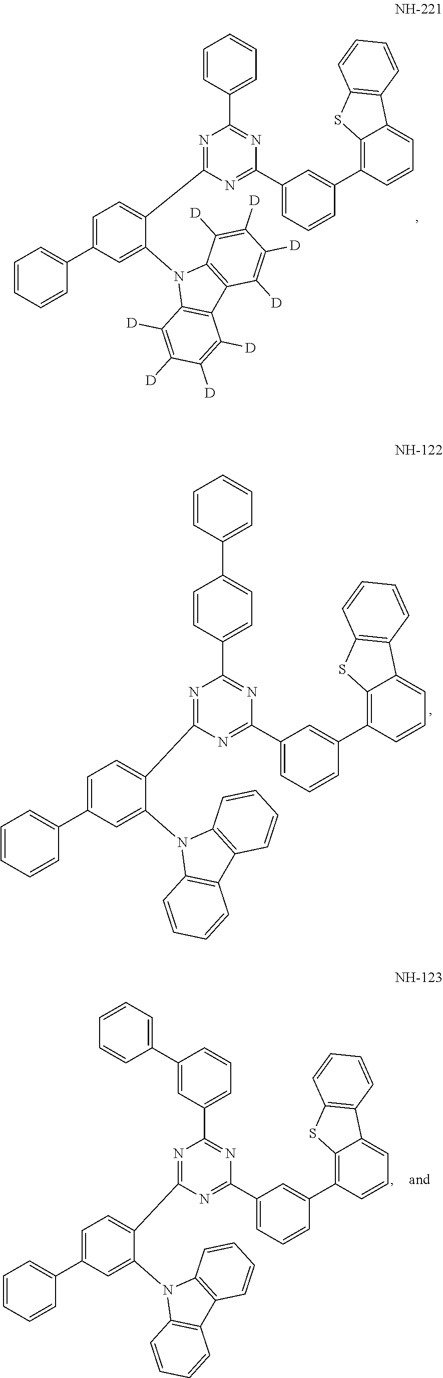 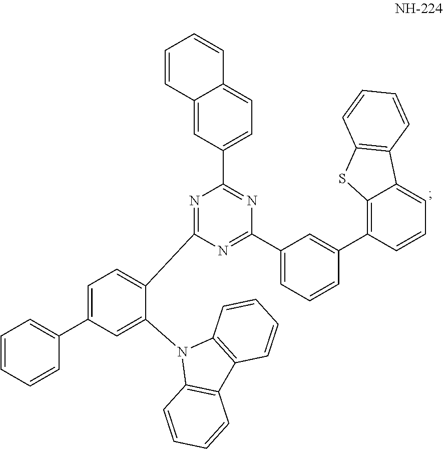
wherein, optionally, hydrogens in the structures of Compound N-1-1 to Compound N-1-53, Compound N-1-58, Compound N-2-1 to Compound N-2-32, Compound N-3-1 to Compound N-3-7, Compound N-4-1 to Compound N-4-34, and Compound NH-1 to Compound NH-224 can be partially or fully substituted with deuterium.

19. The composition of claim 1, wherein the second host compound has a structure represented by Formula 8, Formula 9 or Formula 10: 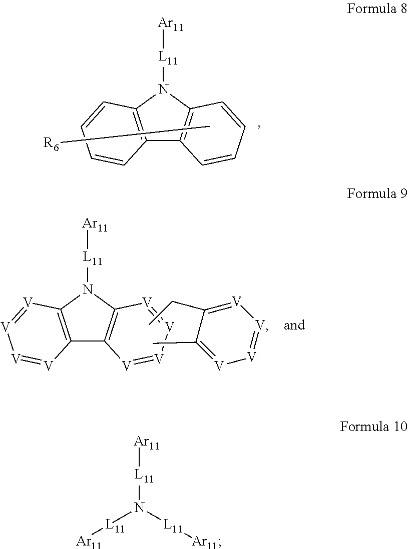
wherein L₁₁ is selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
G′ is, at each occurrence identically or differently, selected from C(R_{g}′)₂, NR_{g}′, O or S;
Vis, at each occurrence identically or differently, selected from C, CR₆ or N;
R₆ represents, at each occurrence identically or differently, mono-substitution, multiple substitutions or non-substitution;
R₆ and R_{g}′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₆ can be optionally joined to form a ring;
preferably, the second host compound has a structure represented by Formula 8-1 or Formula 8-2: 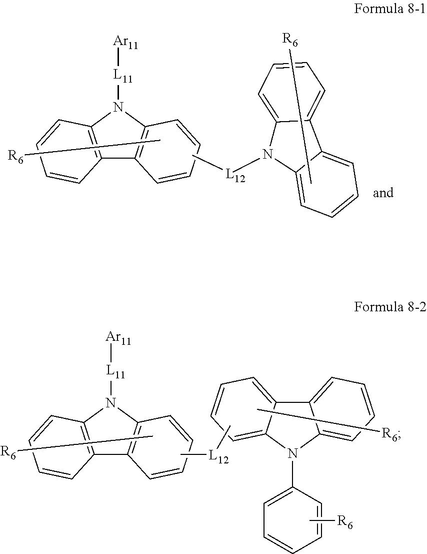
wherein L₁₁ and L₁₂ are selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₆ can be optionally joined to form a ring;
more preferably, the second metal complex is selected from the group consisting of Compound P-1 to Compound P-66 and Compound PH-1 to Compound PH-223: 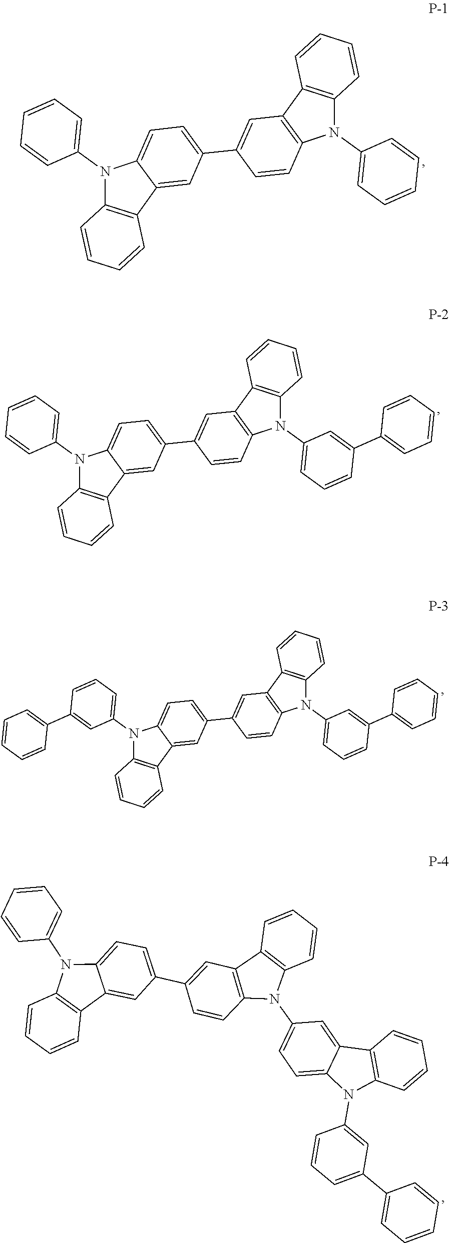 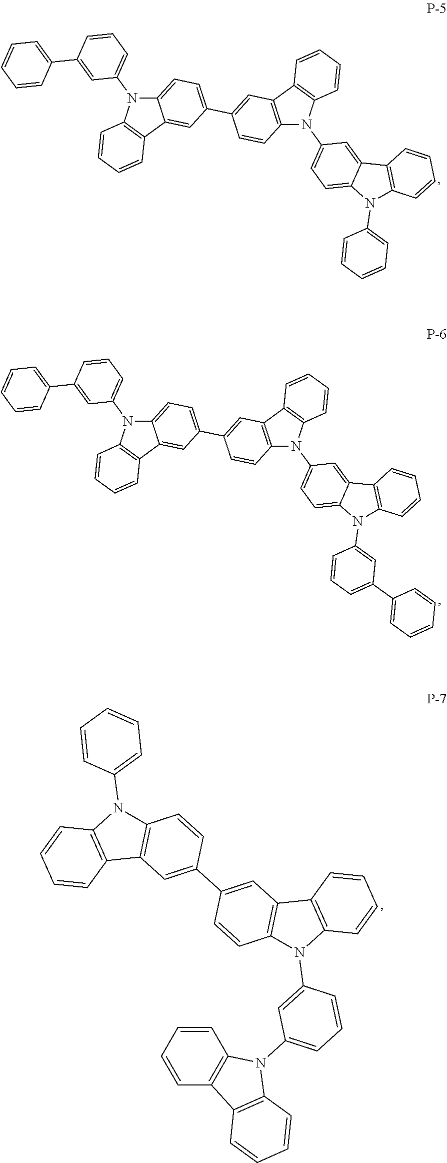 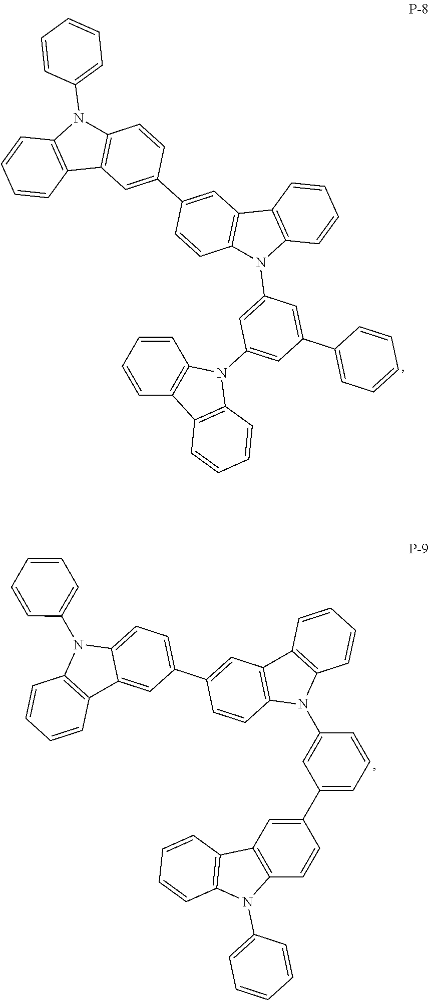 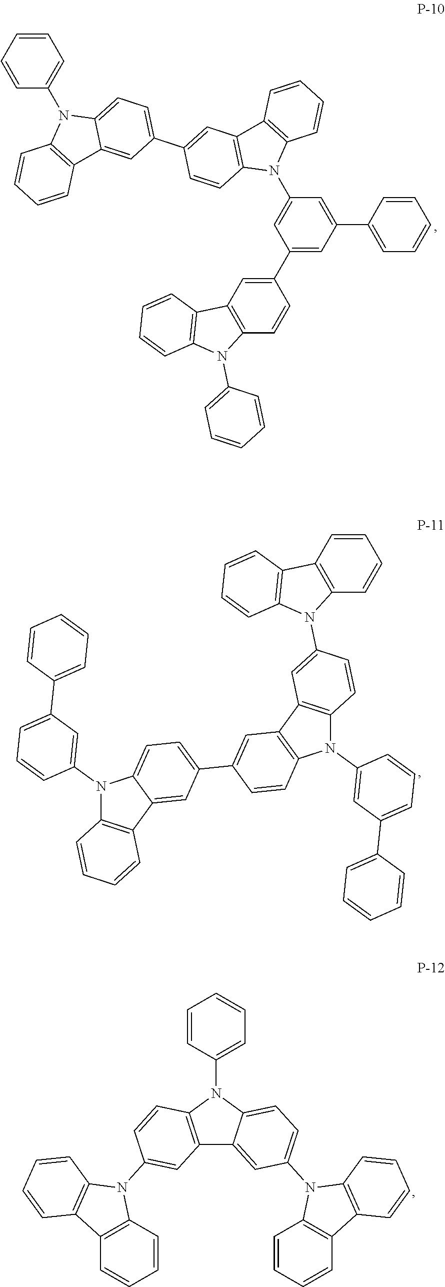 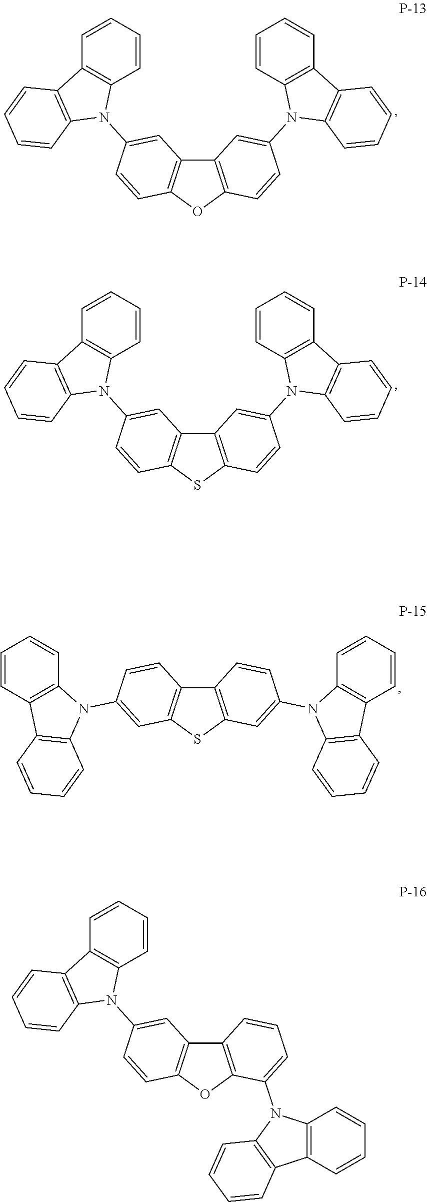 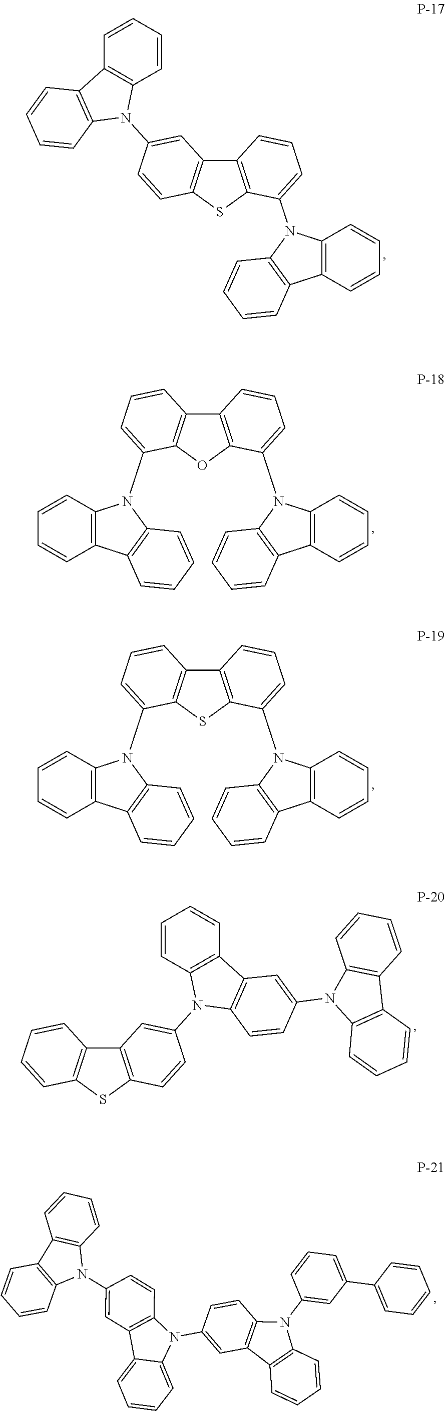 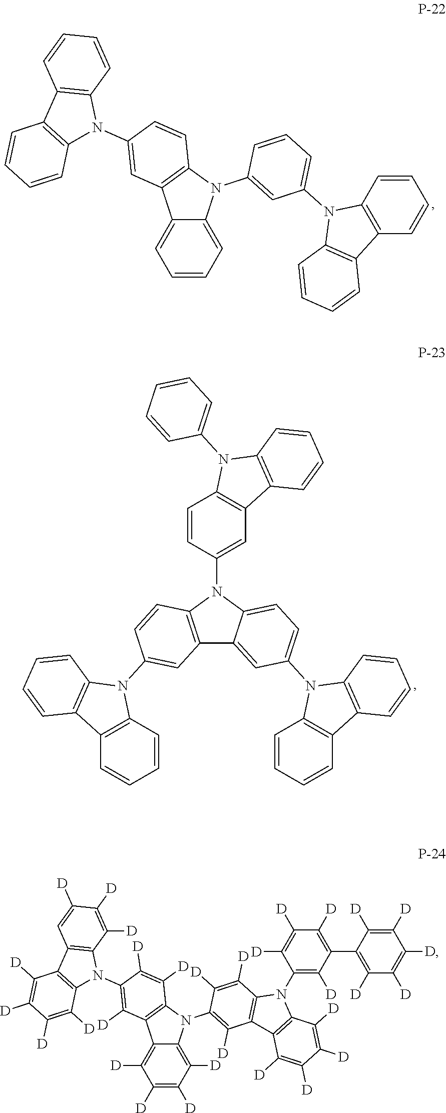 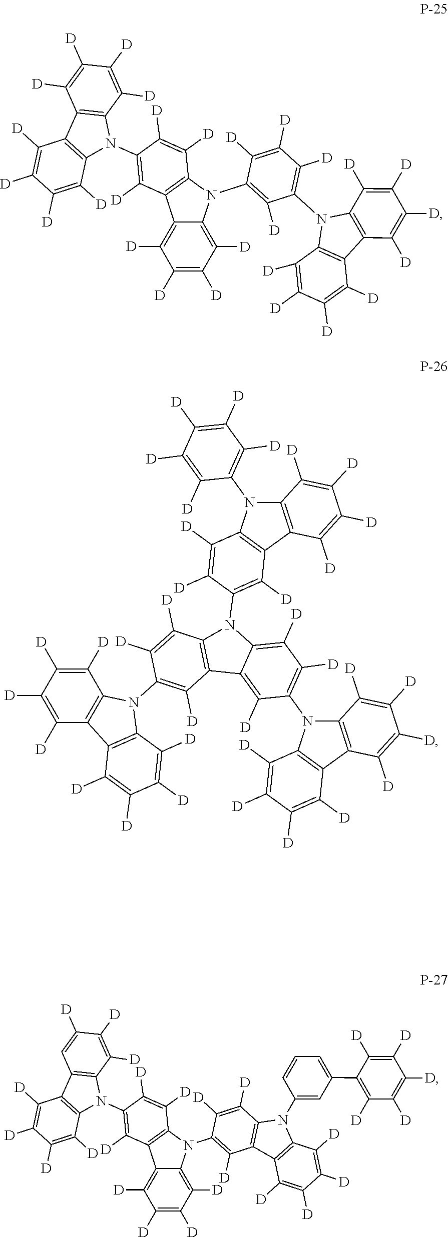 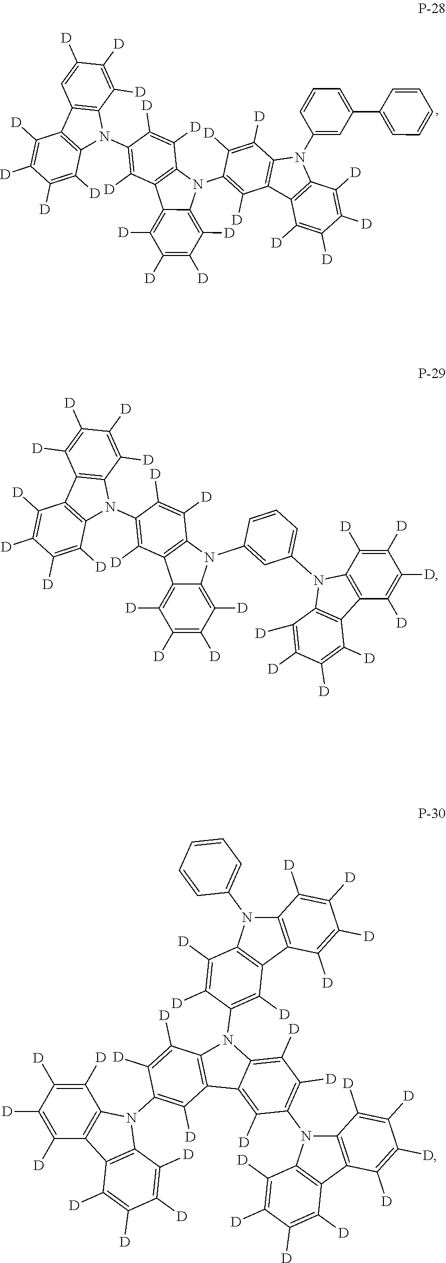 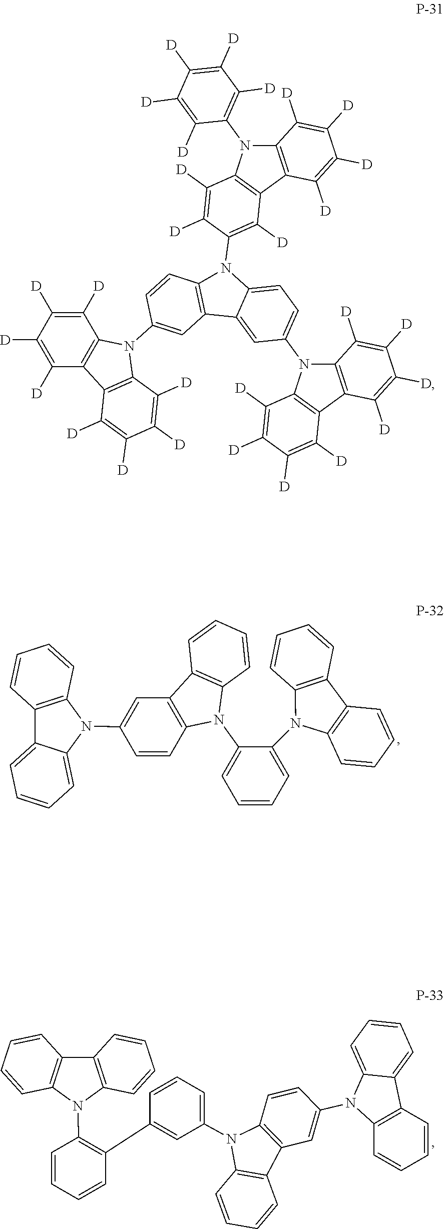 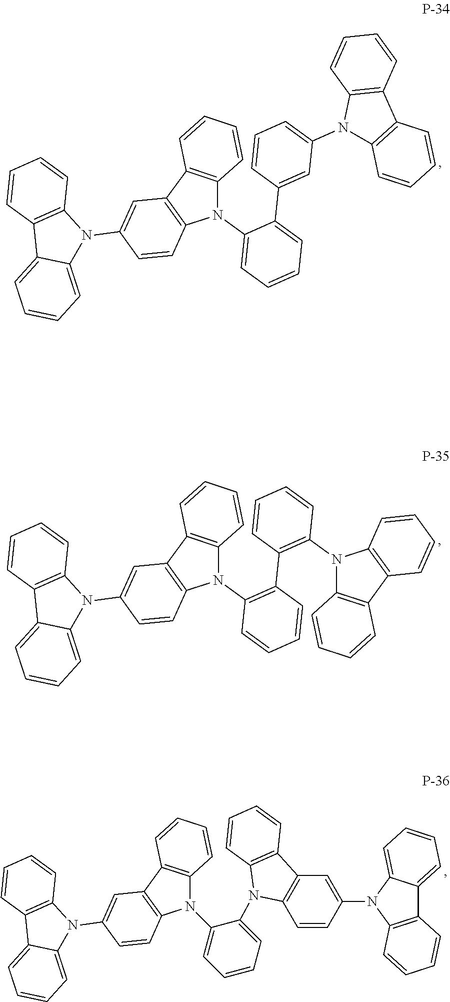 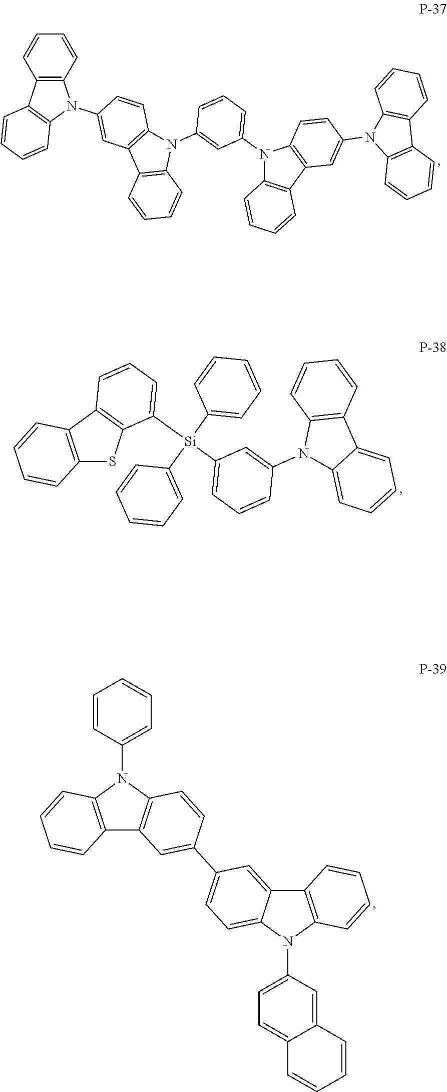 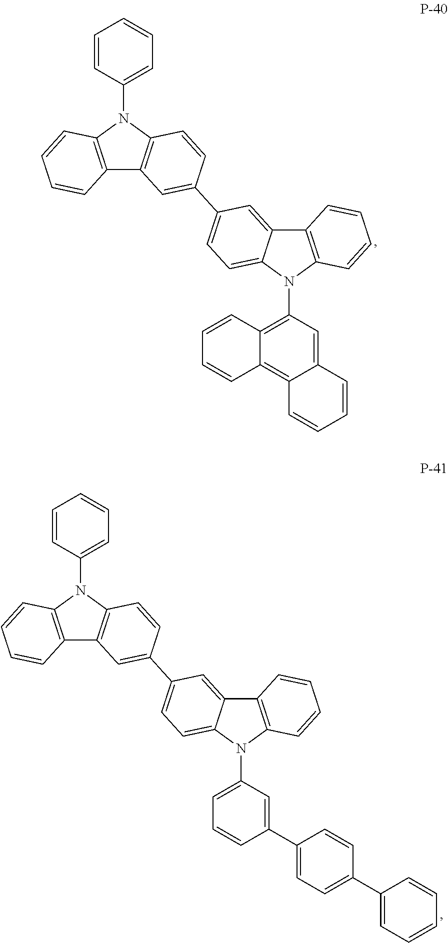 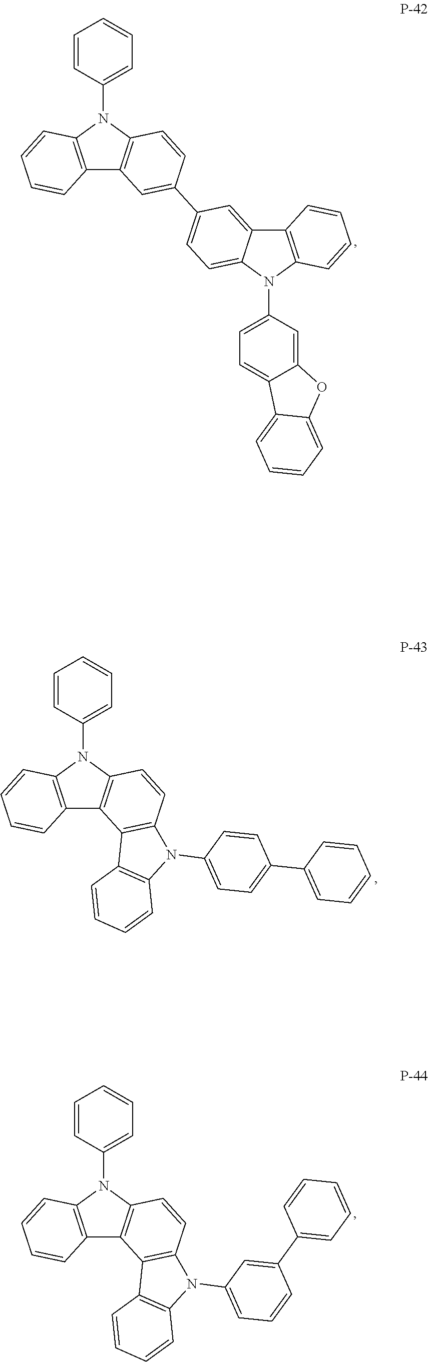 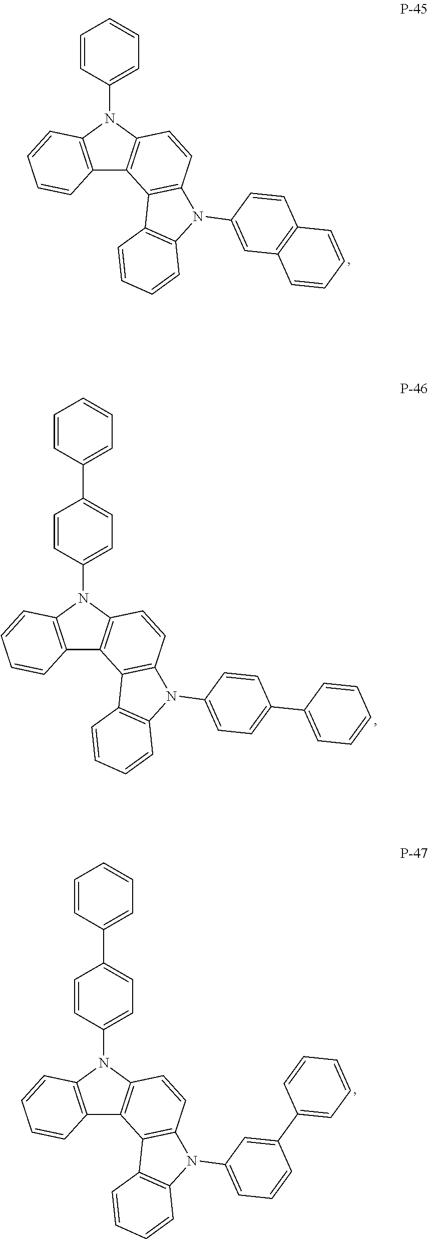 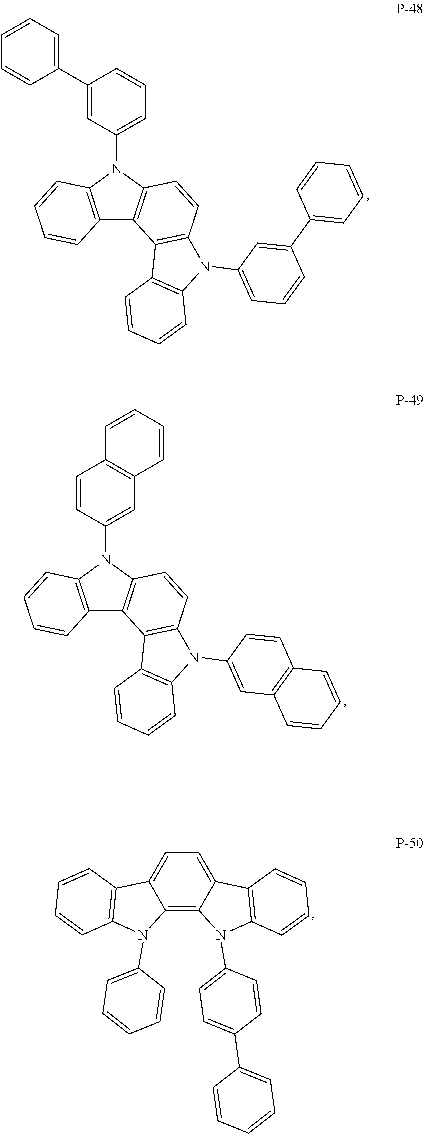 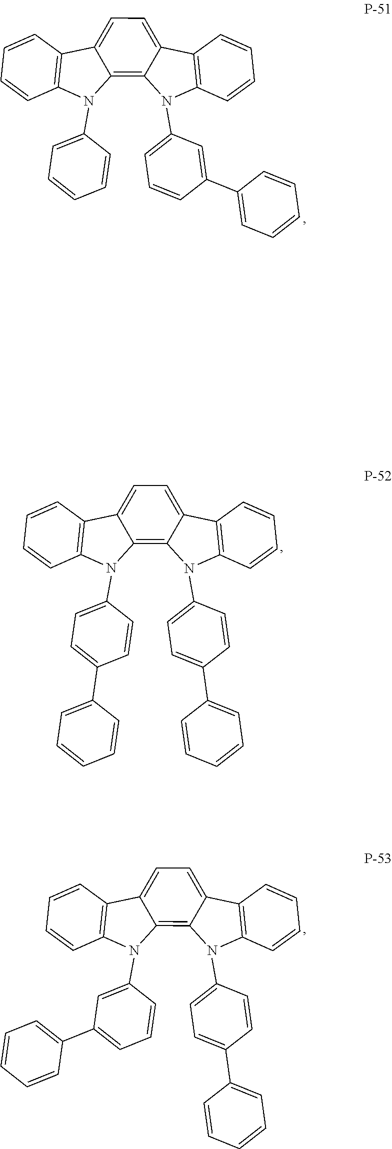 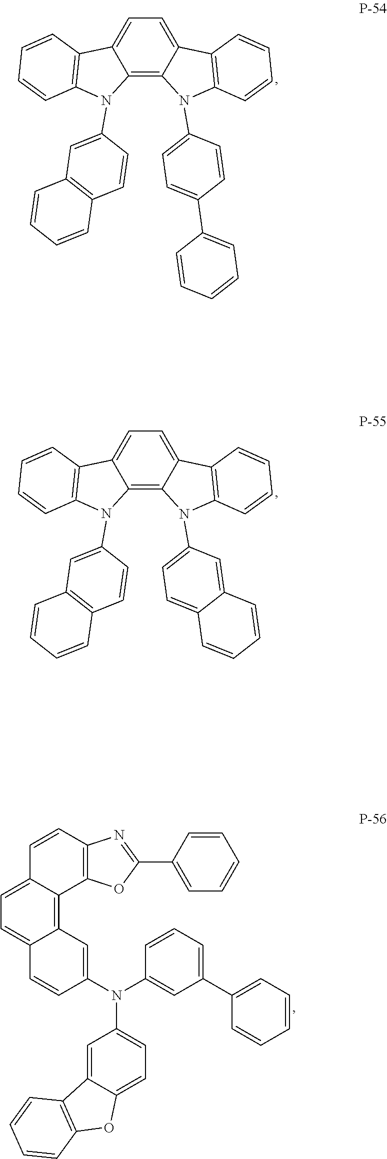 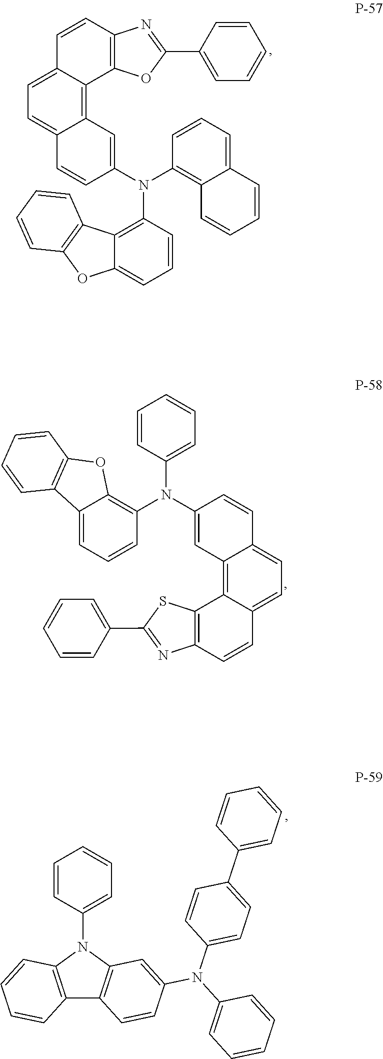 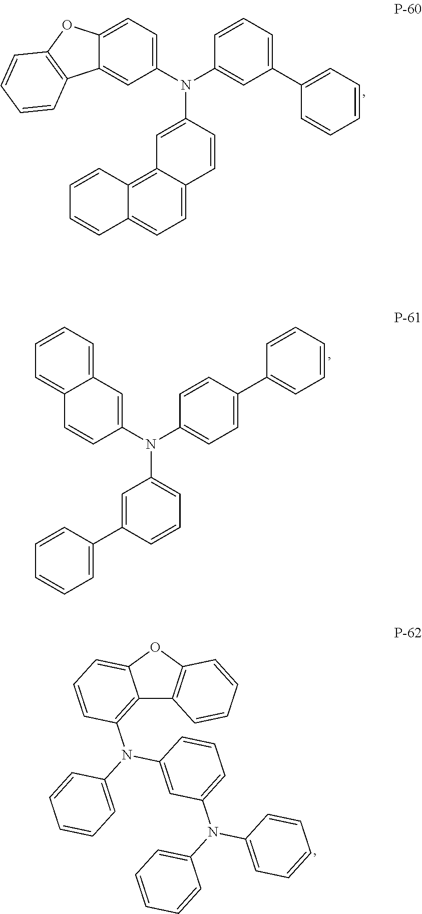 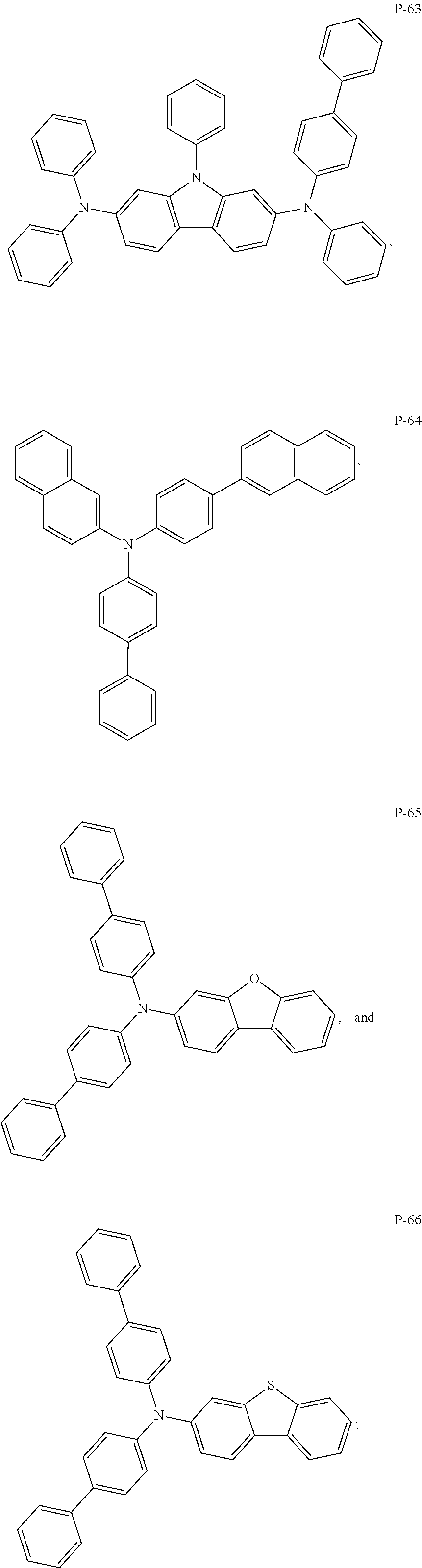 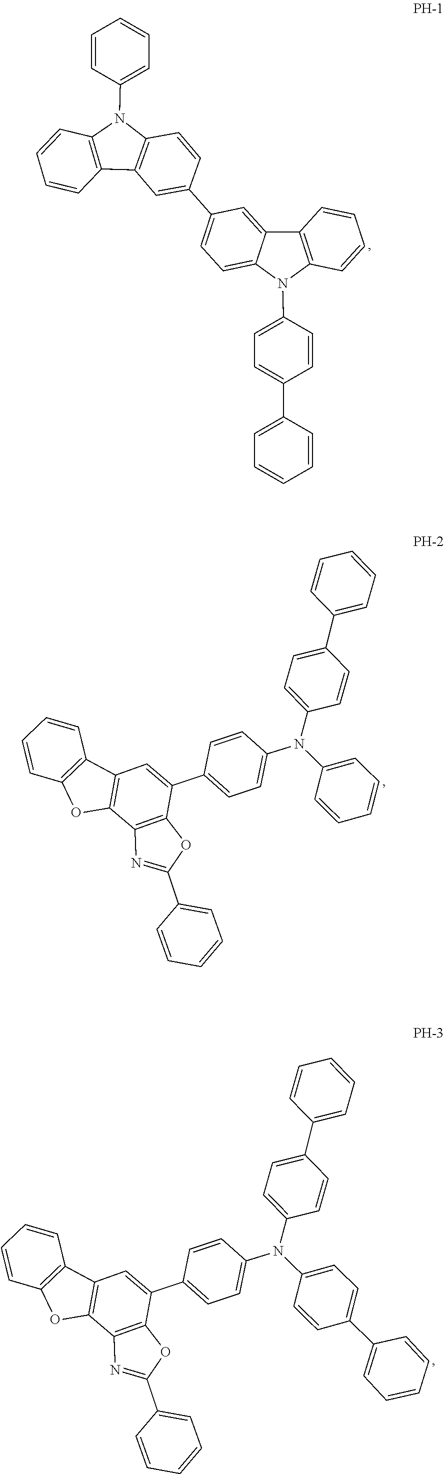 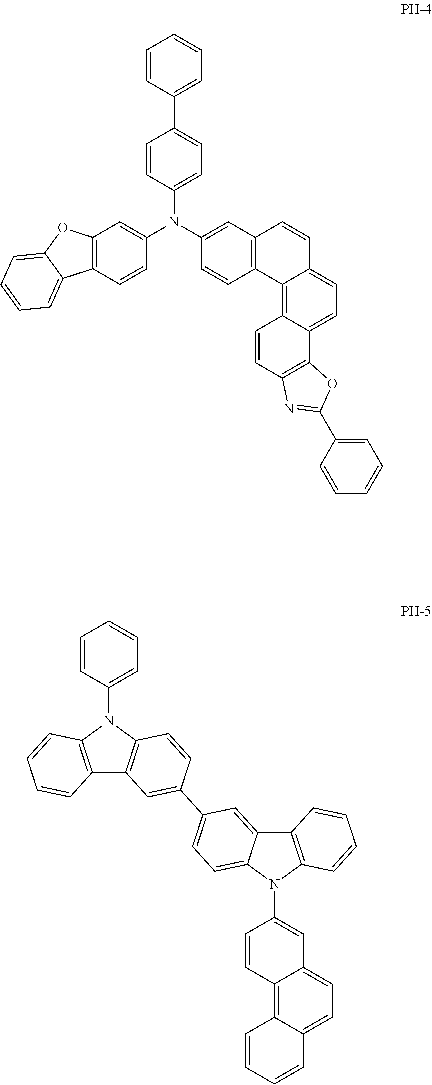 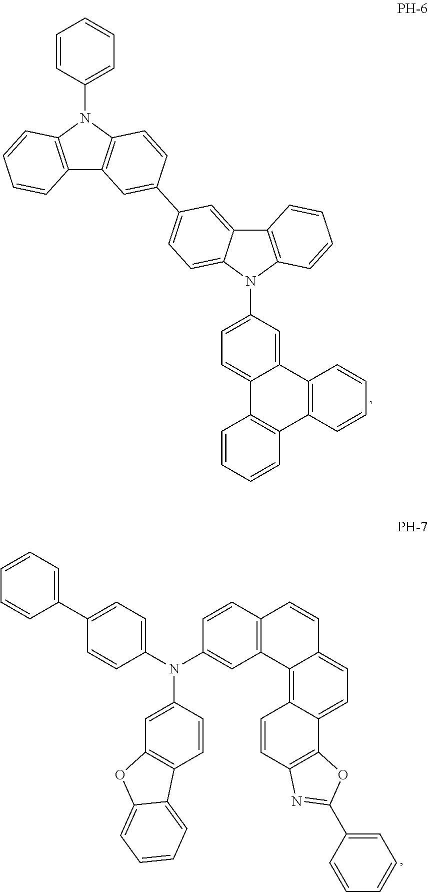 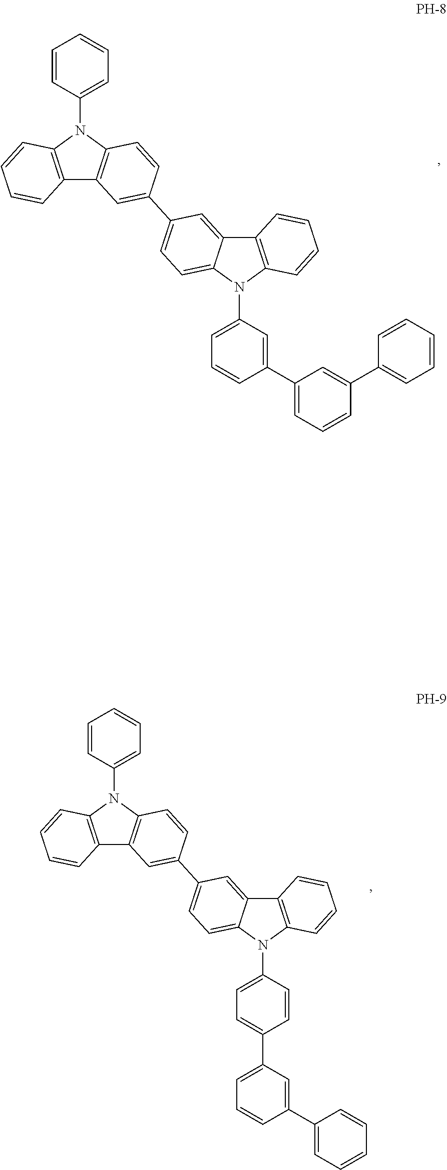 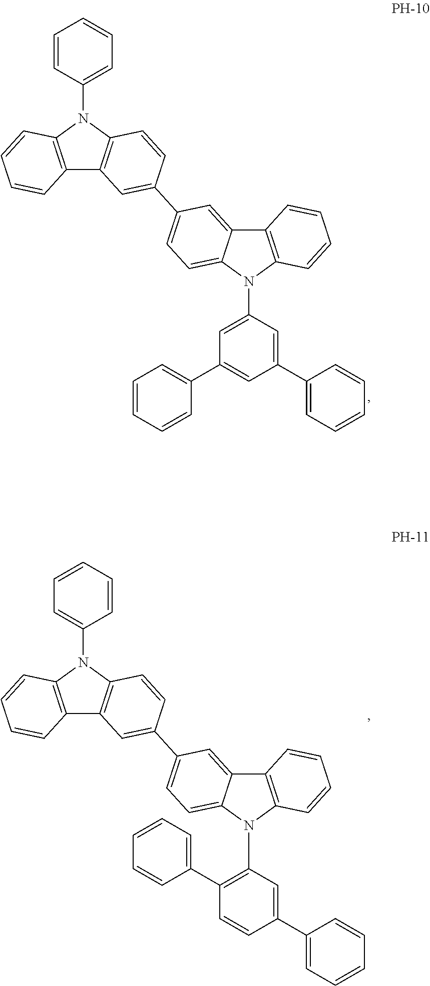 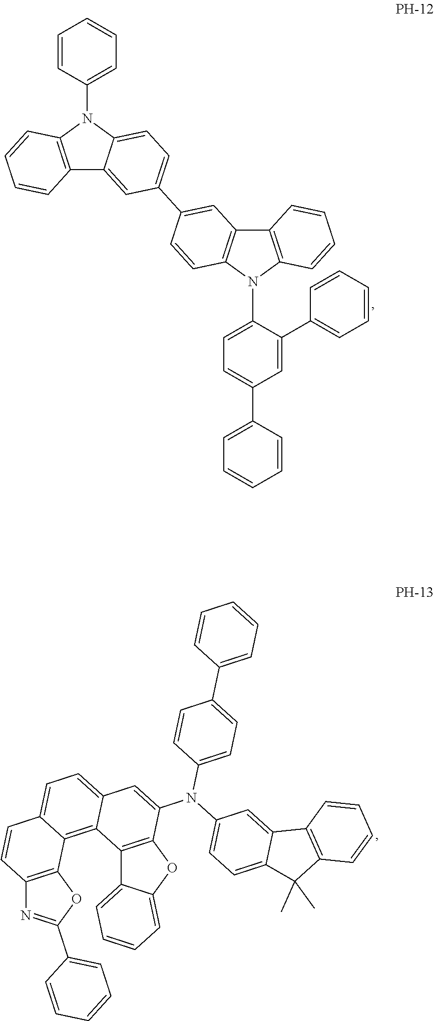 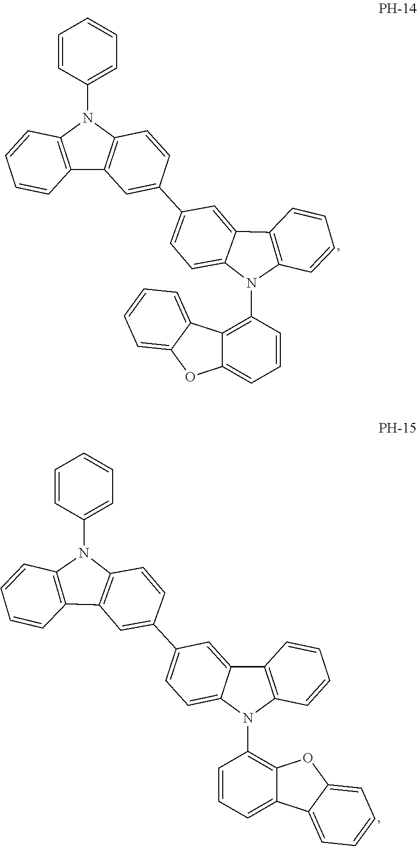 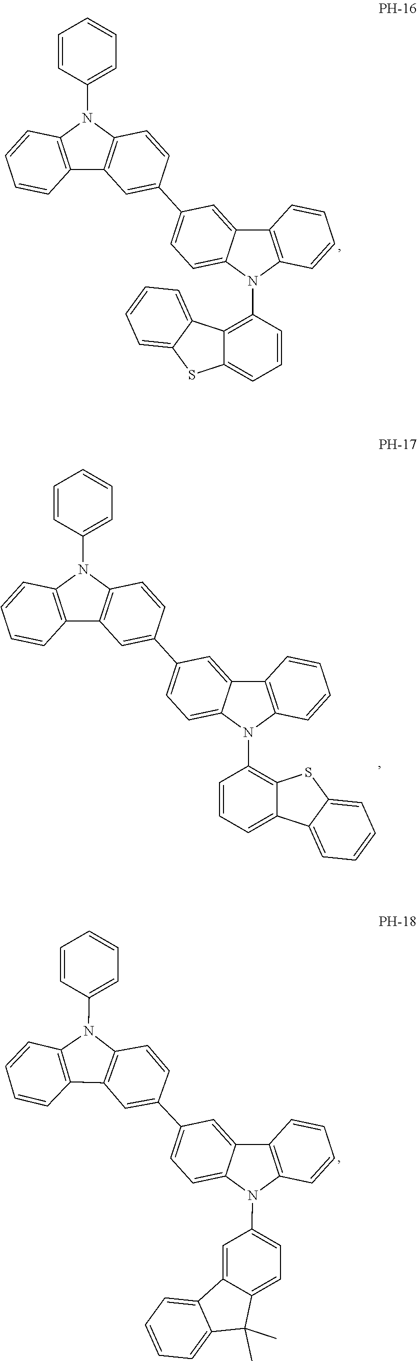 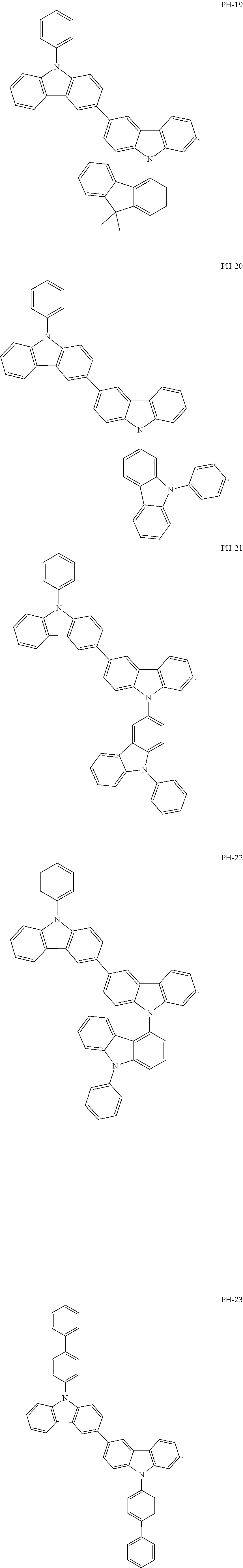 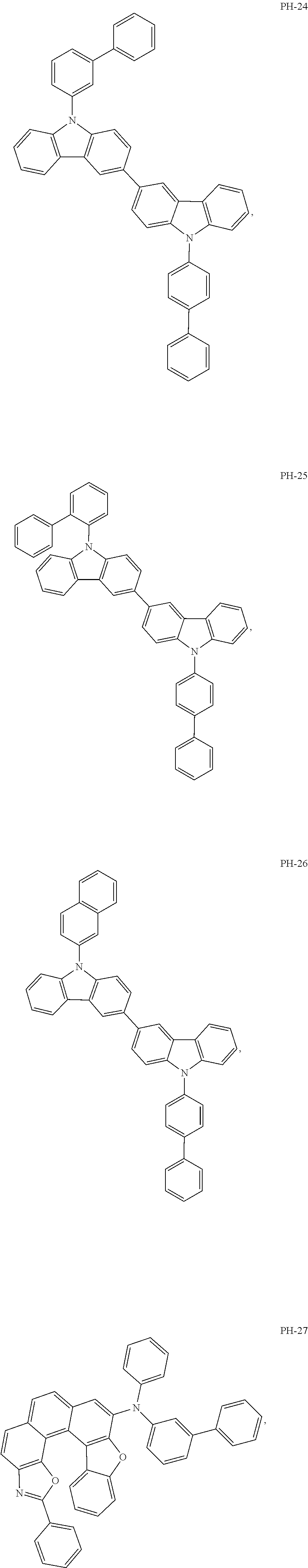 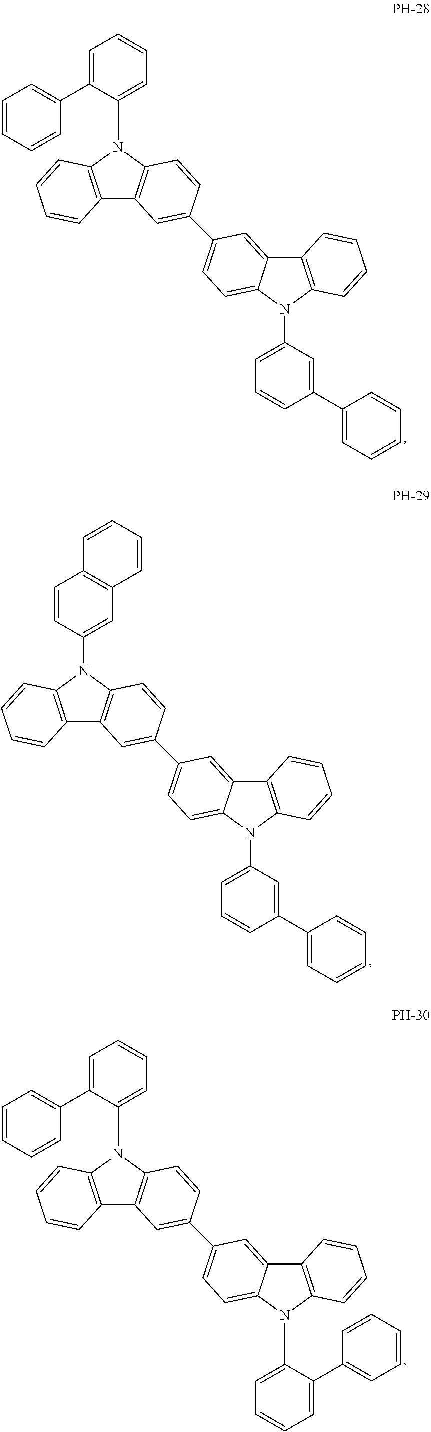 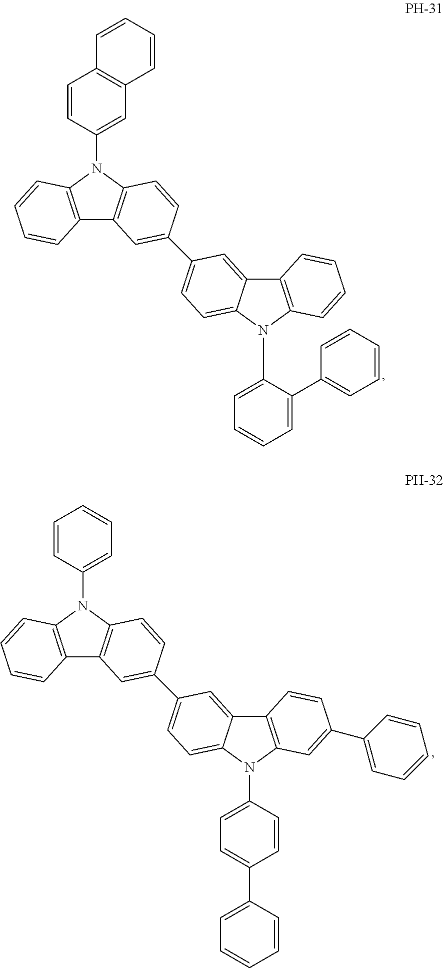 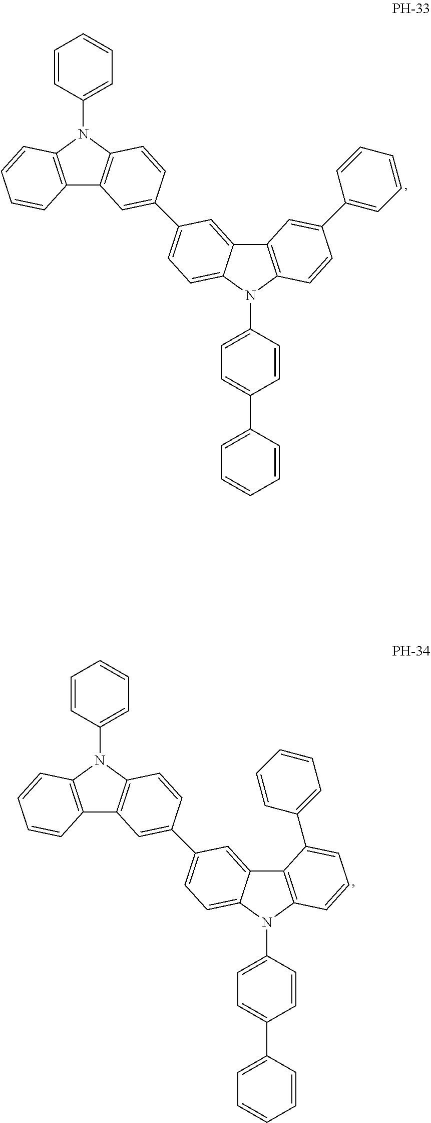 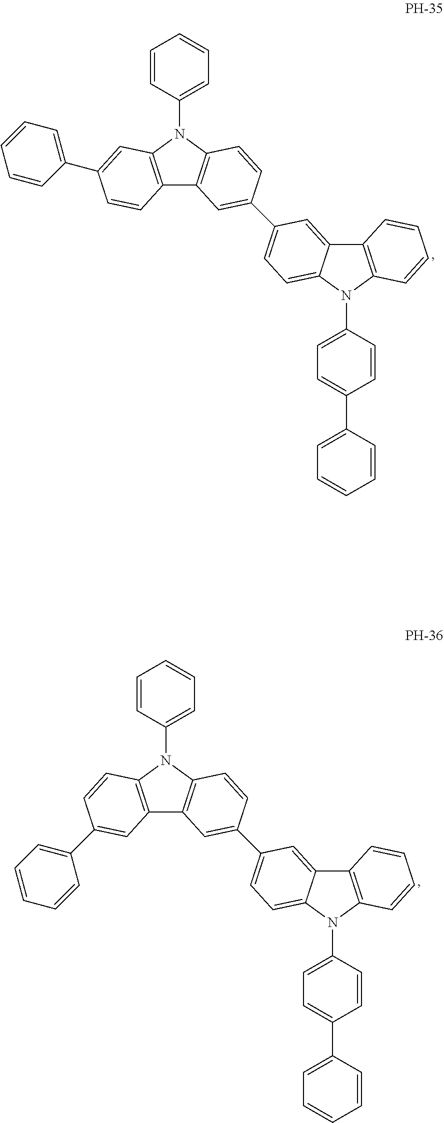 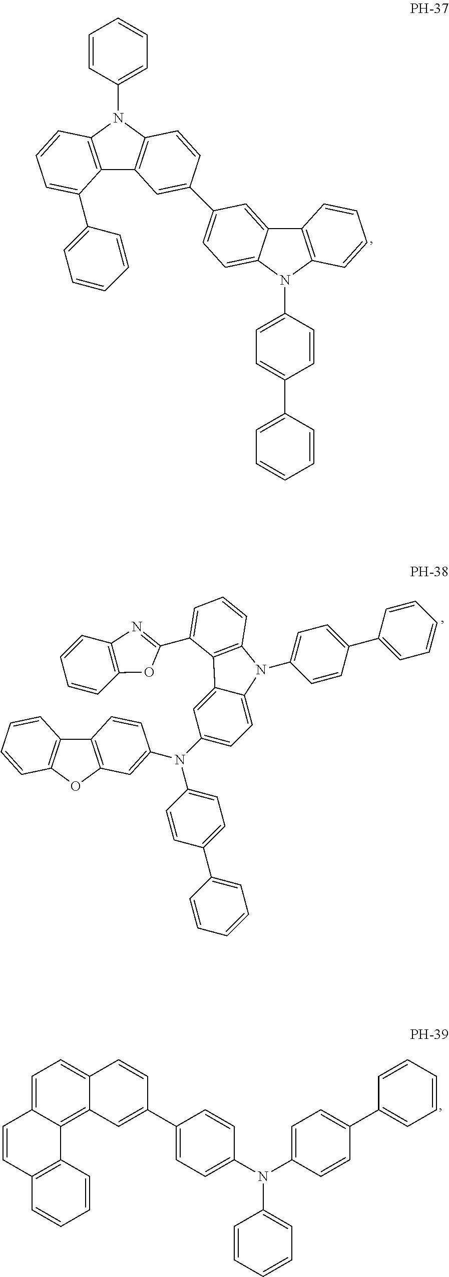 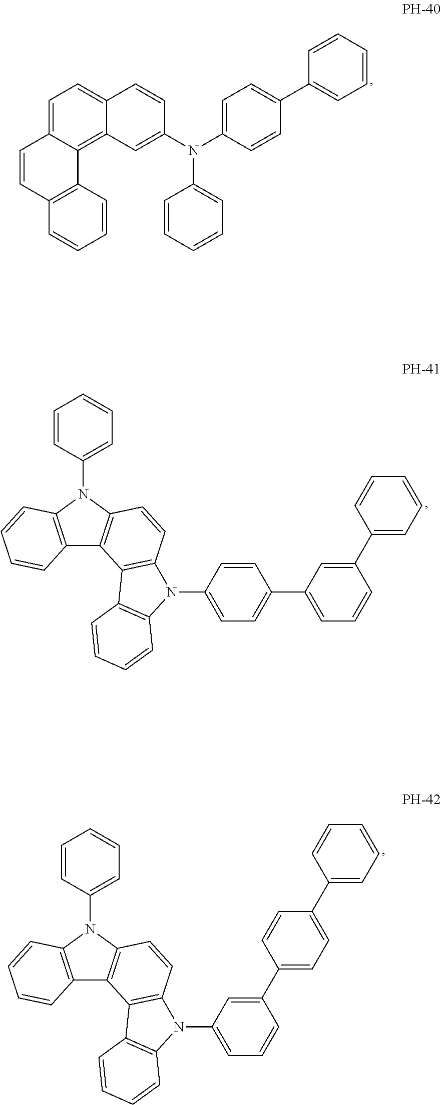 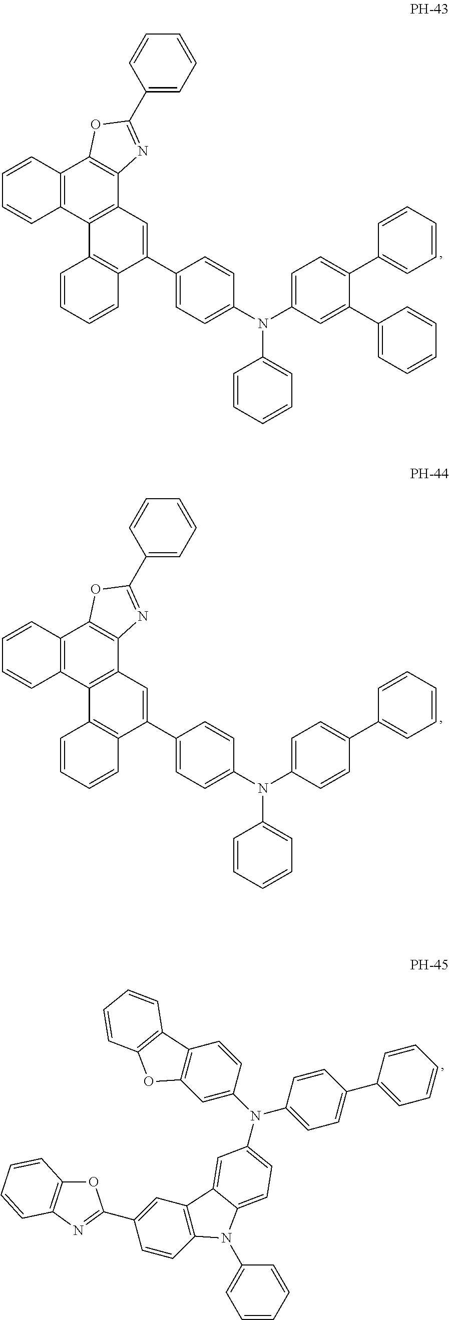 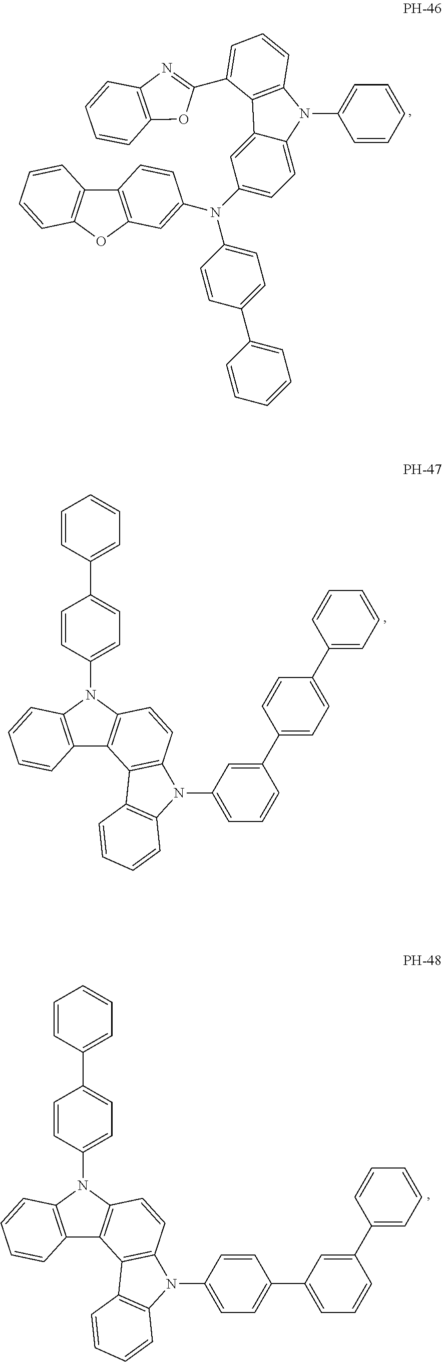 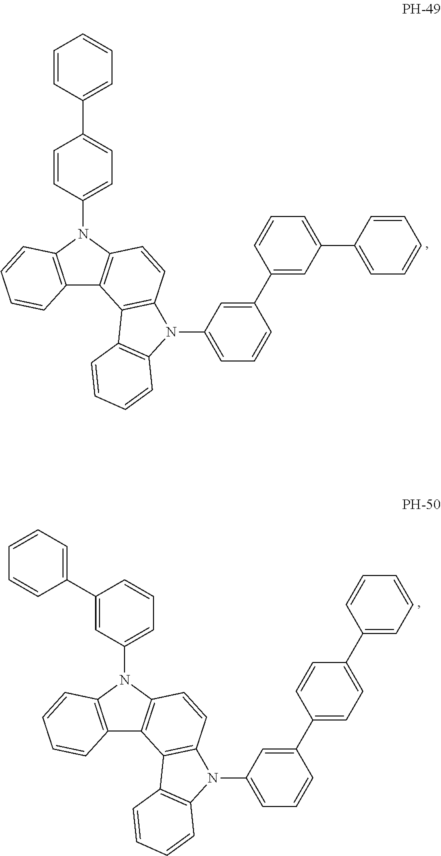 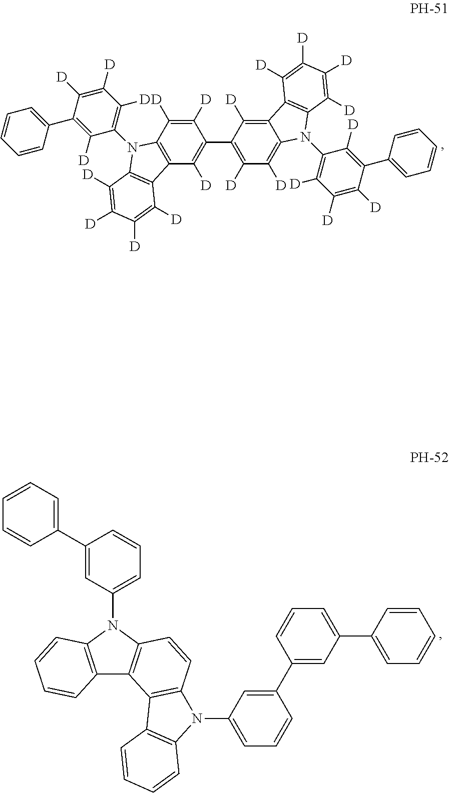 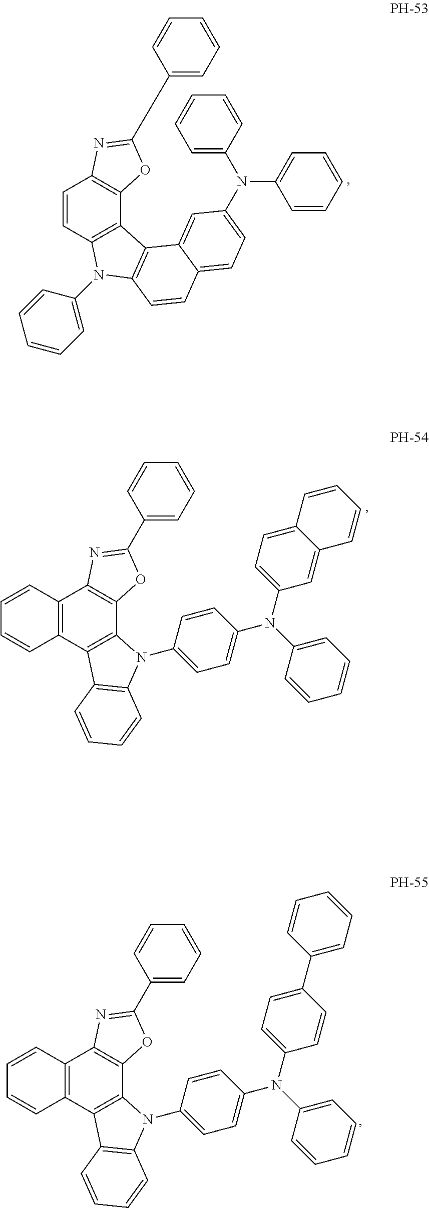 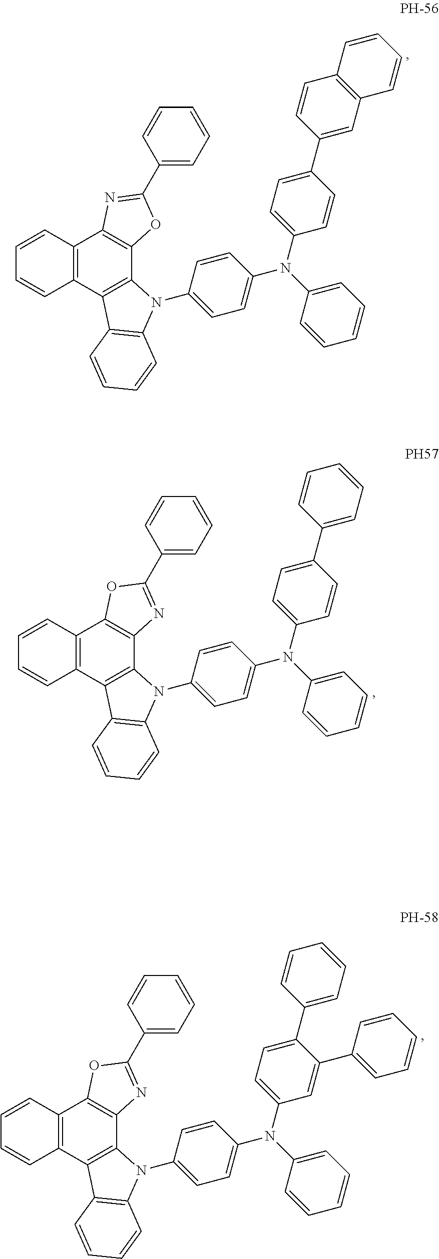 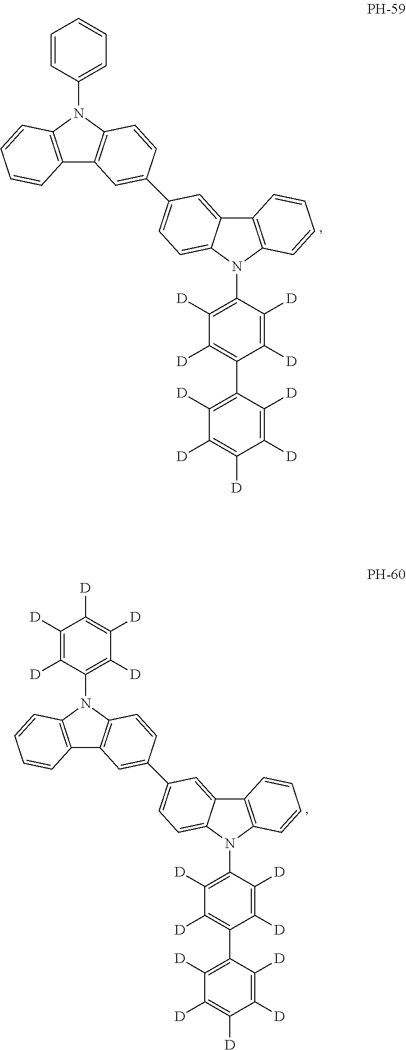 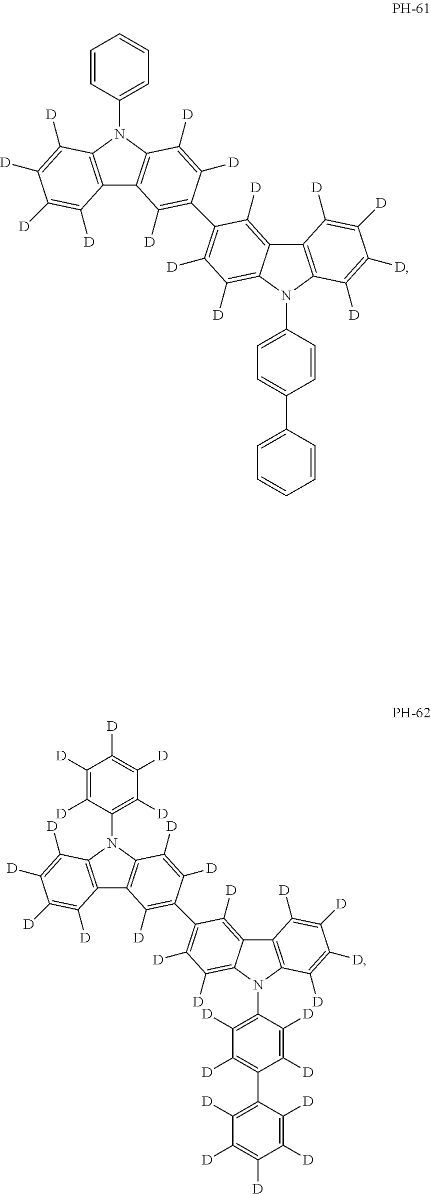 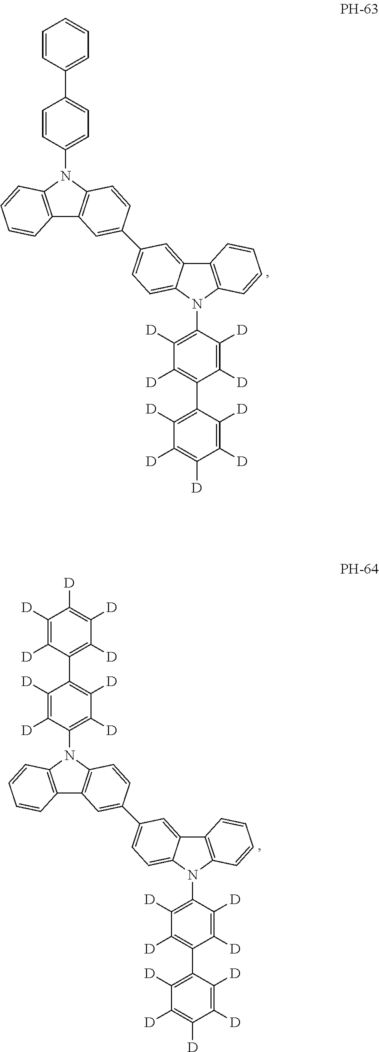 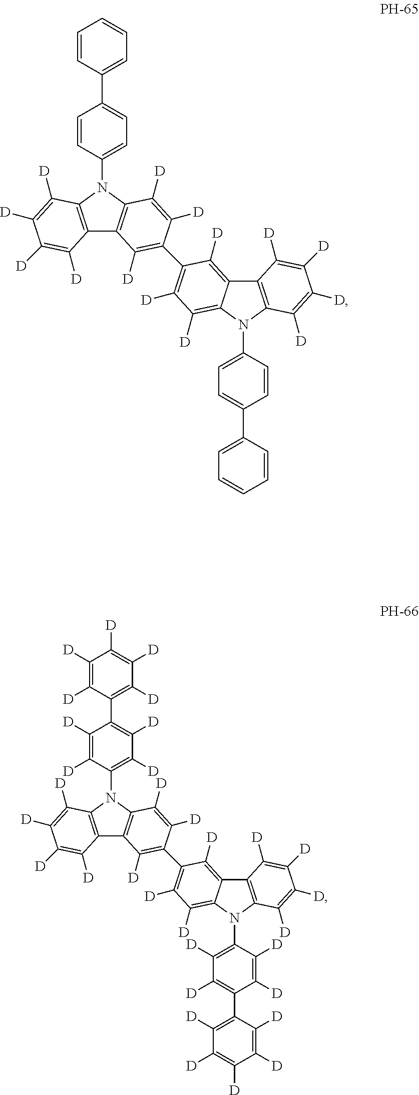 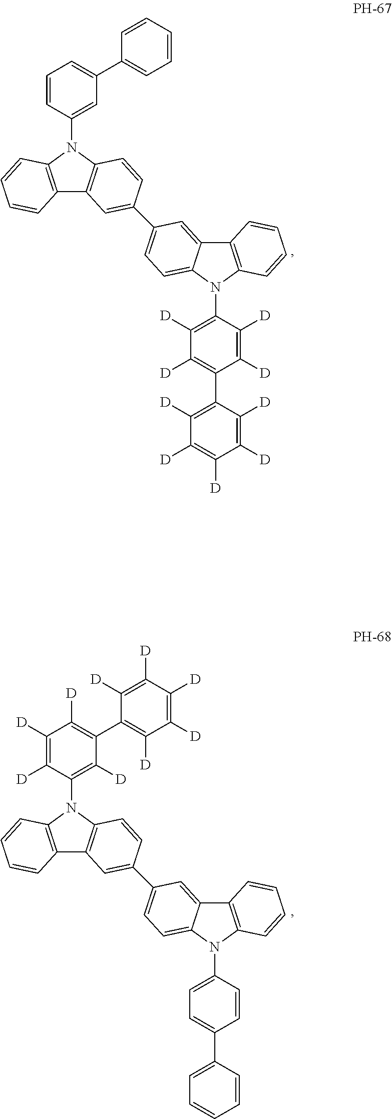 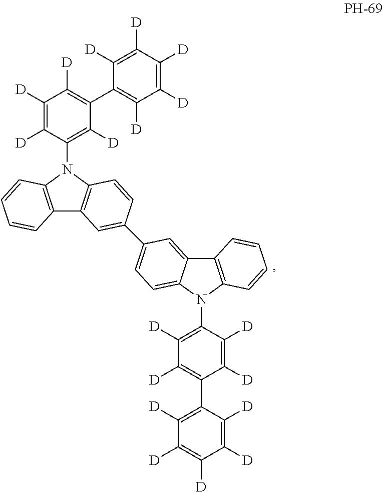 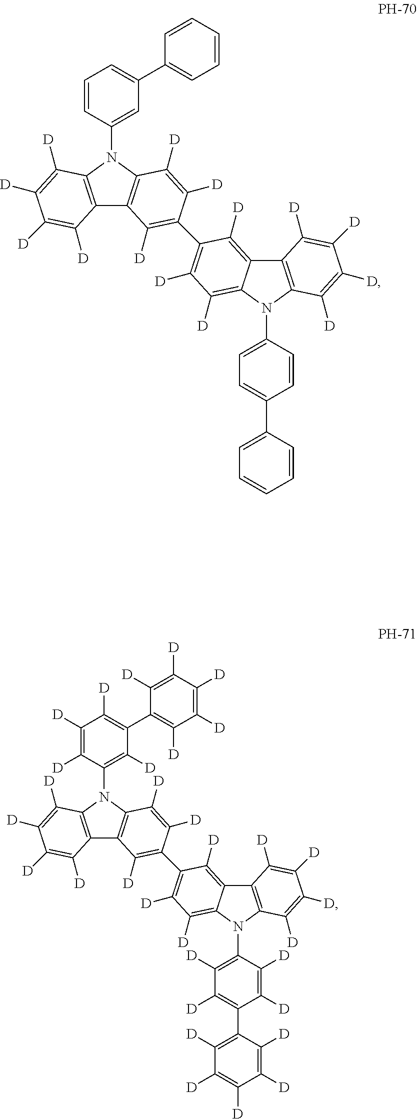 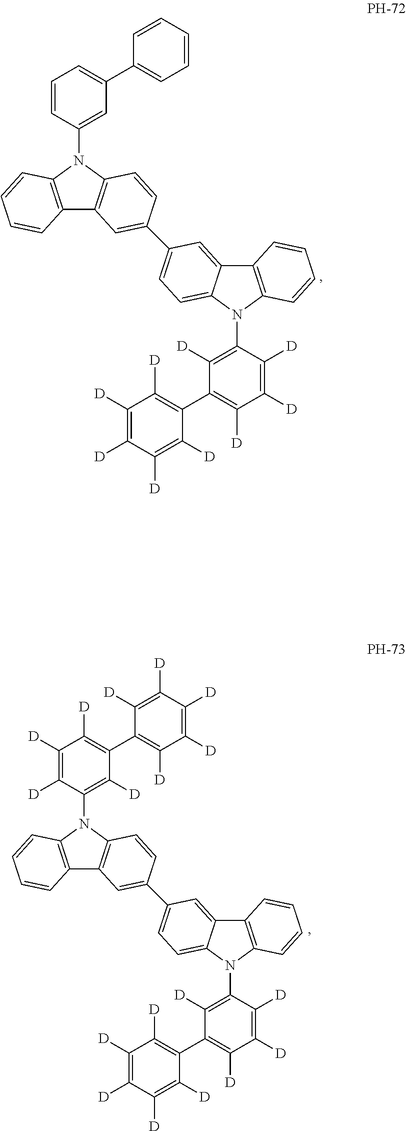 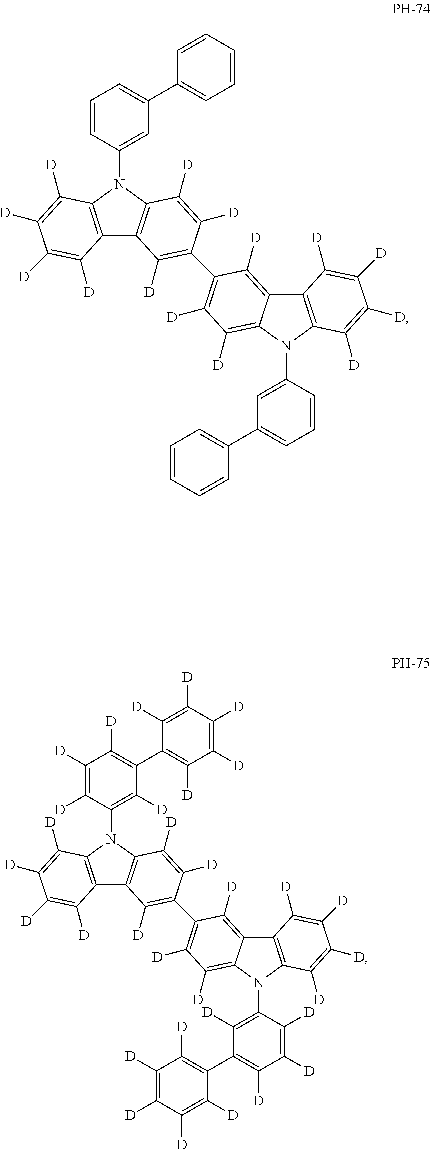 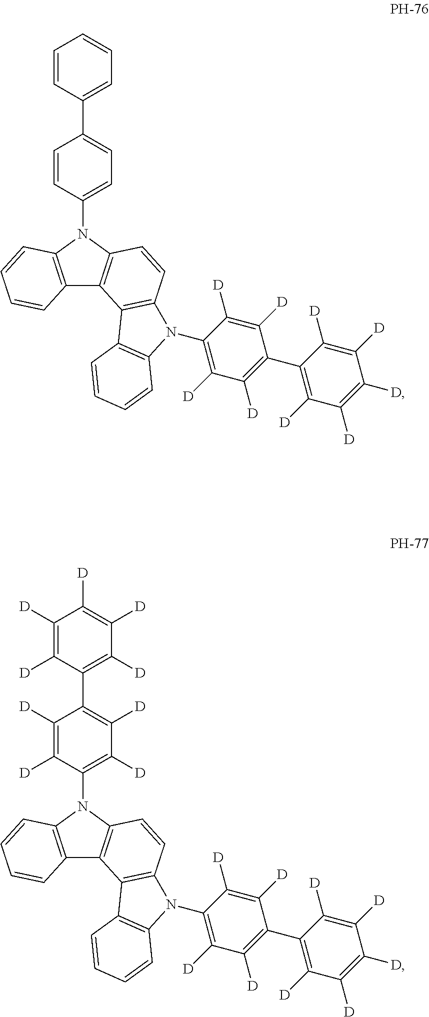 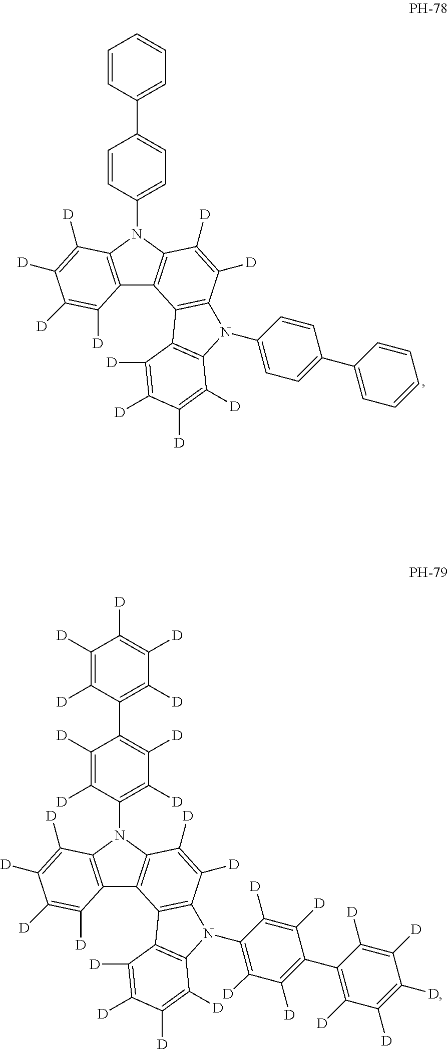 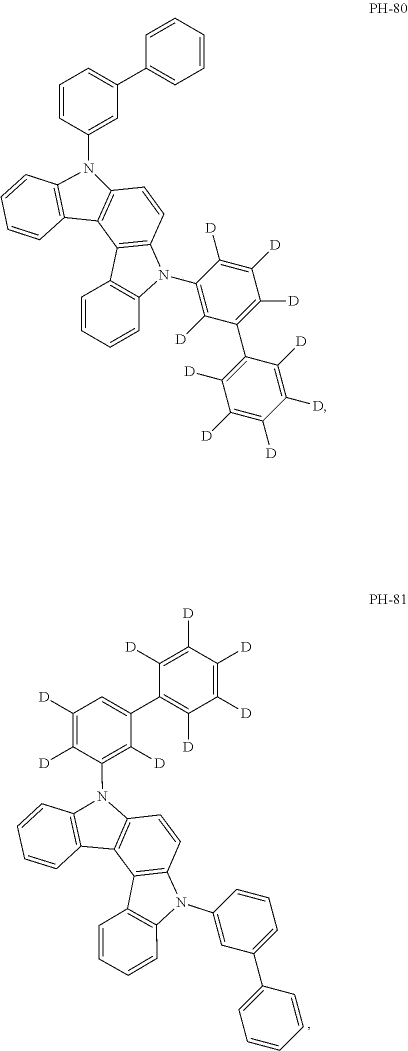 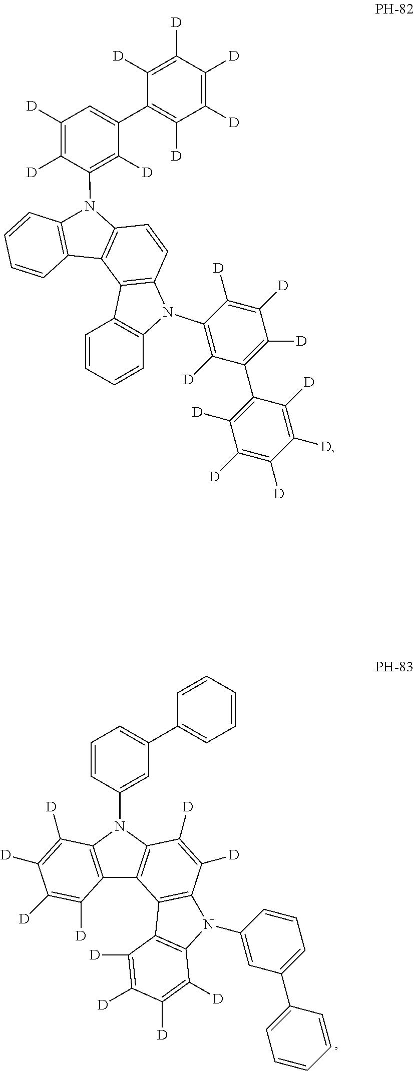 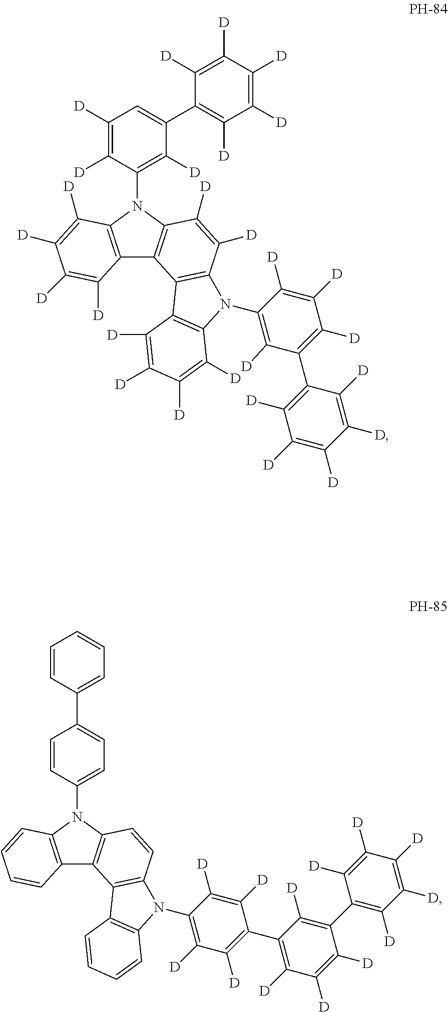 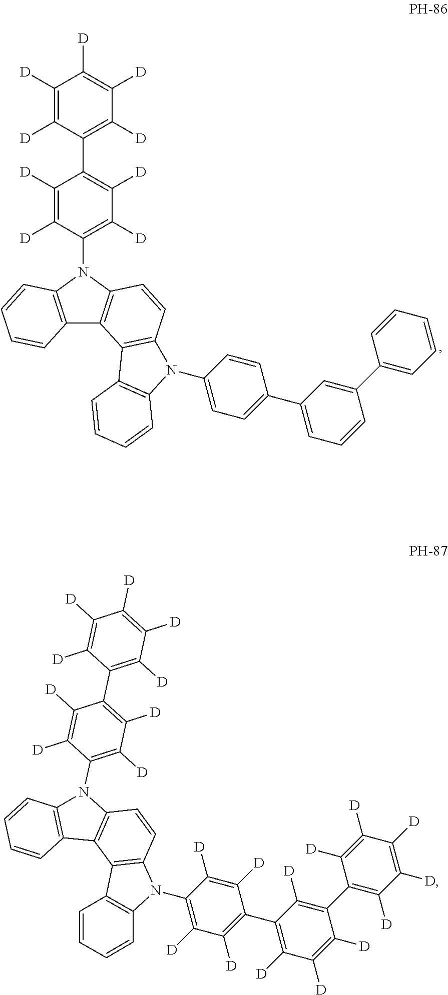 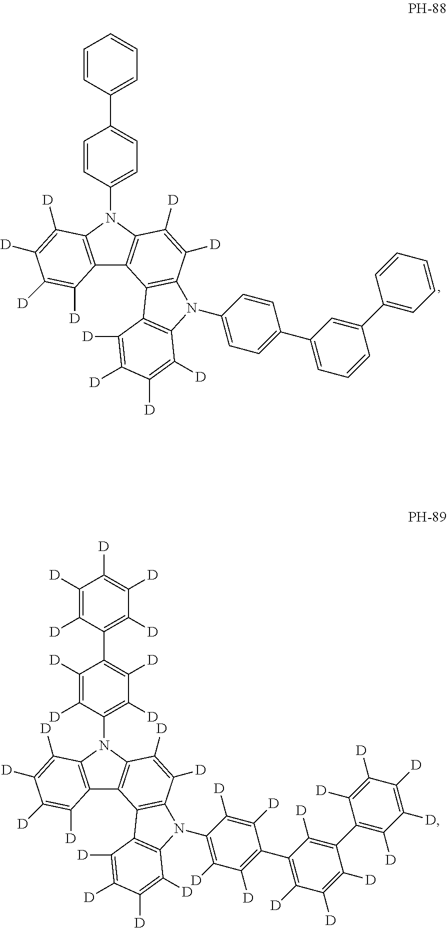 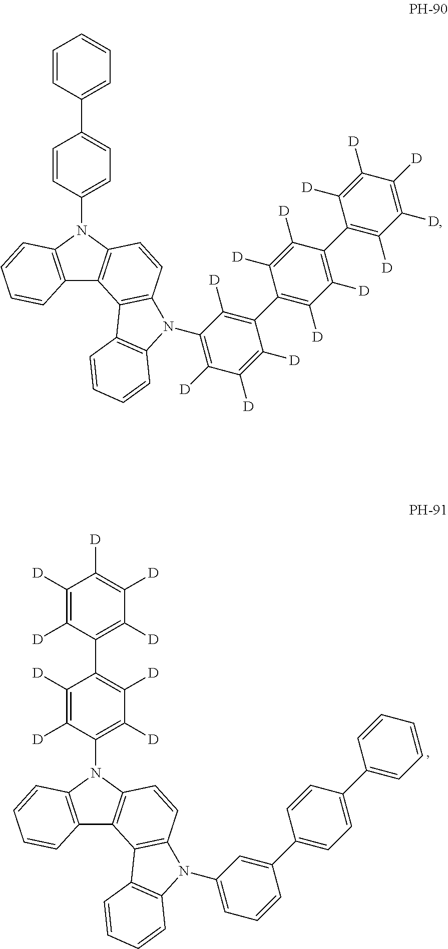 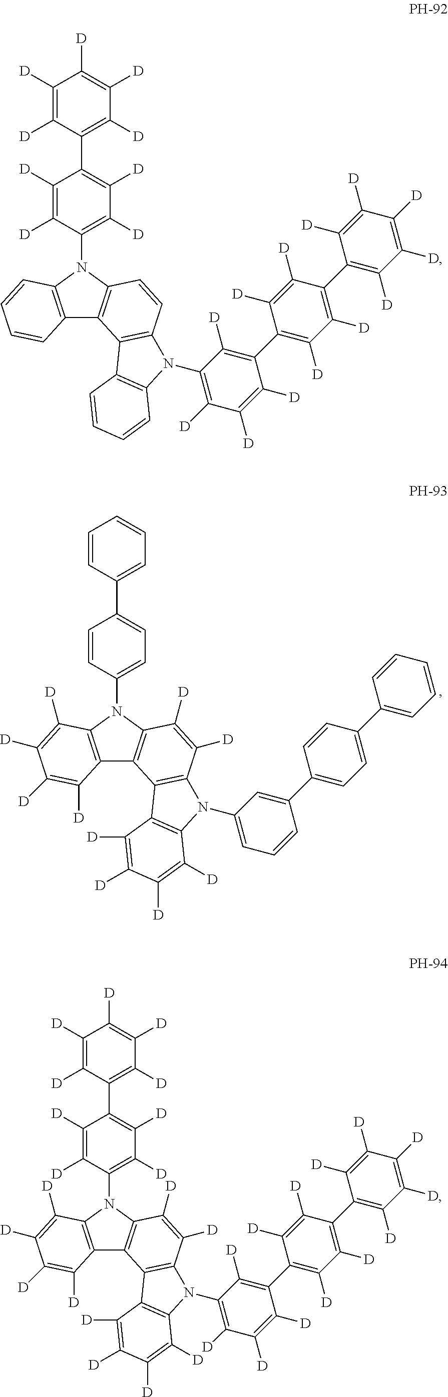 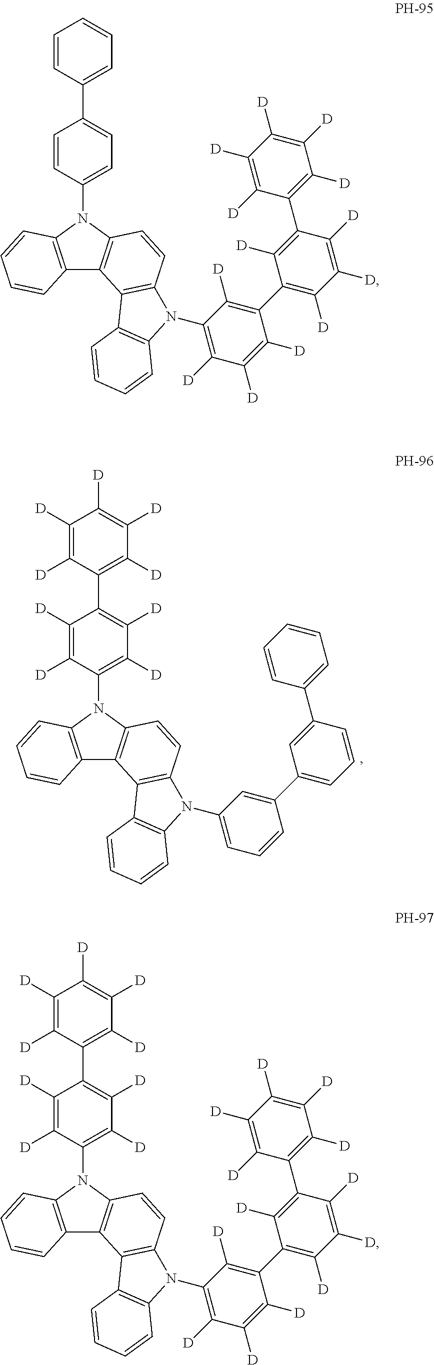 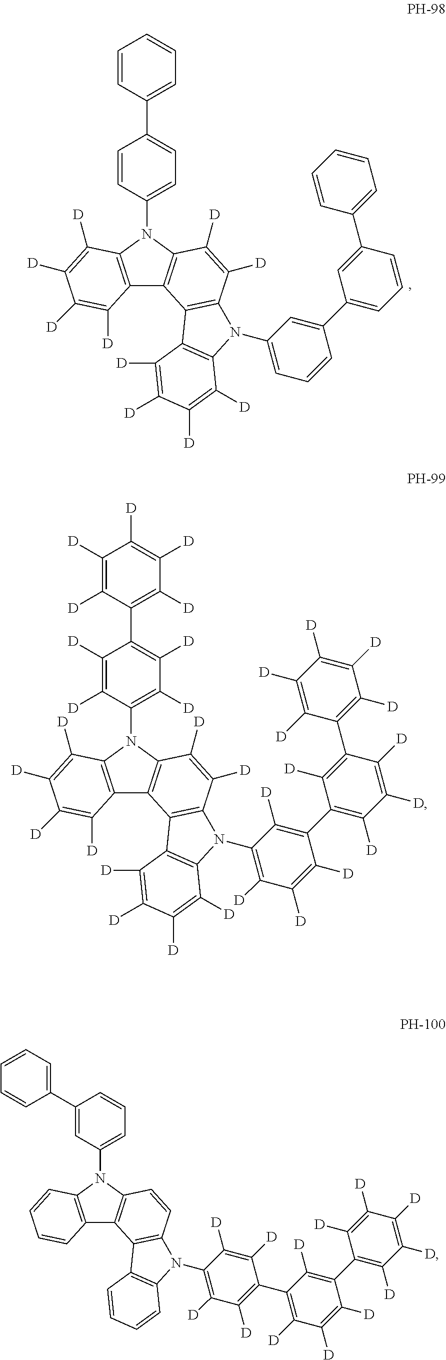 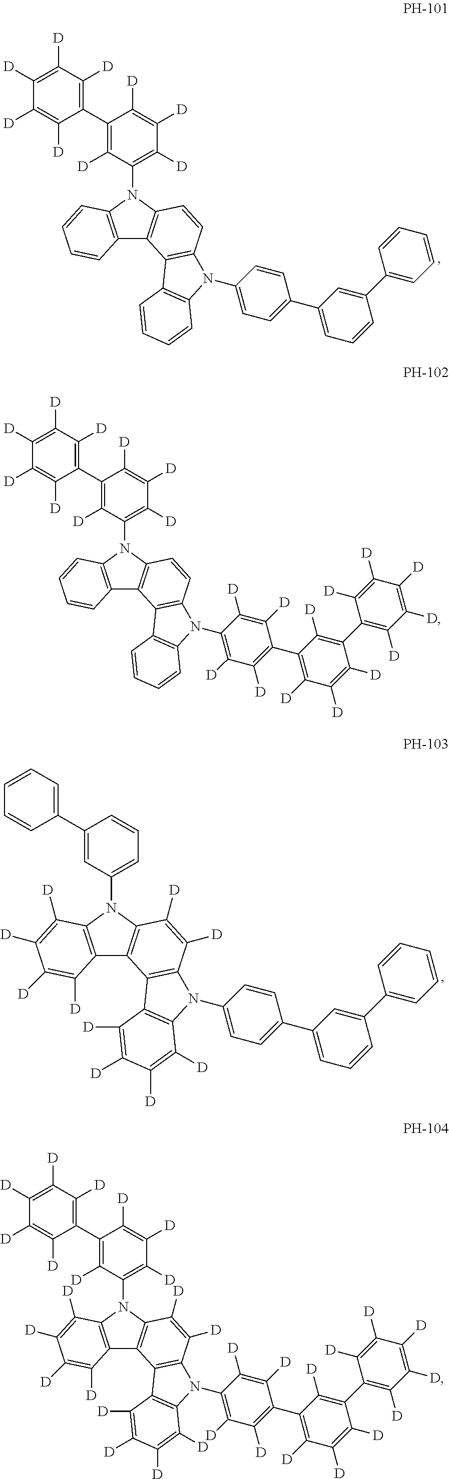 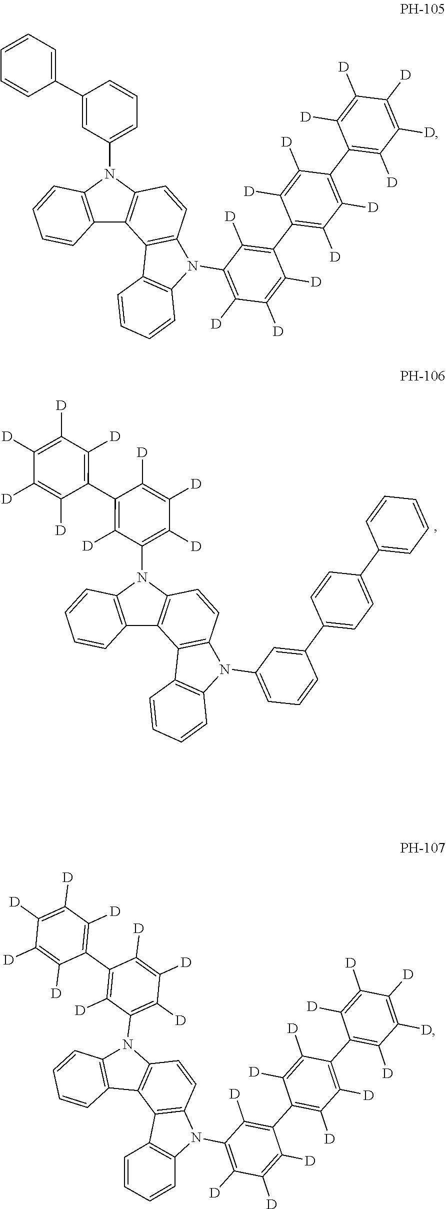 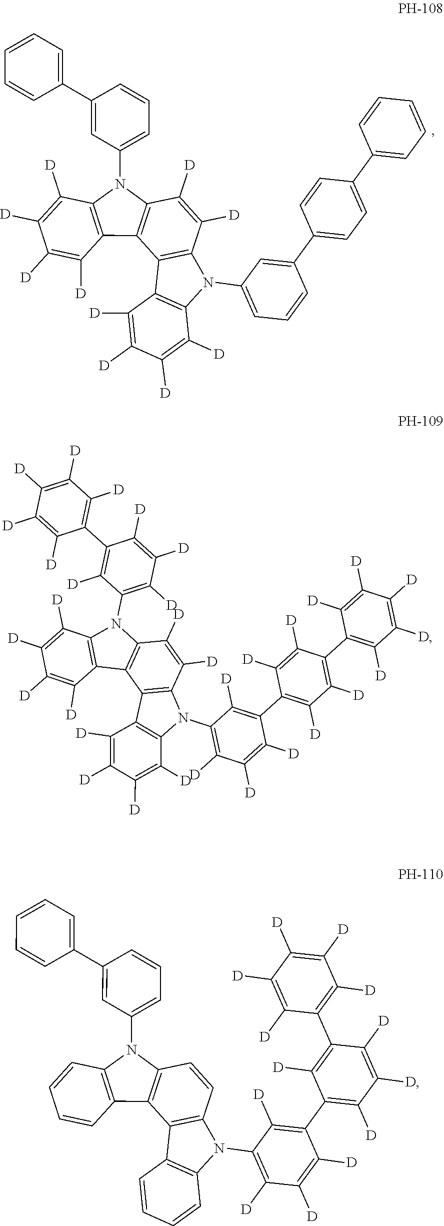 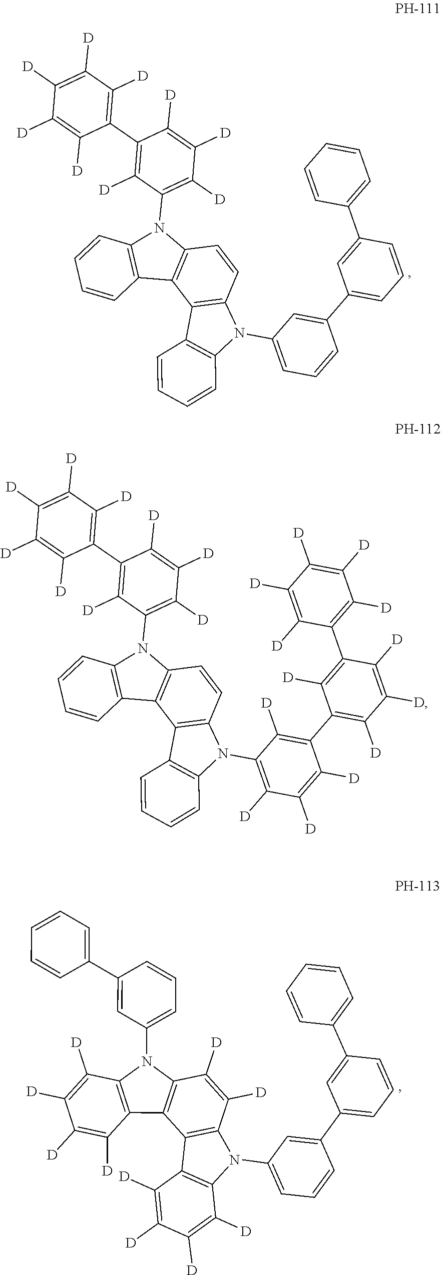 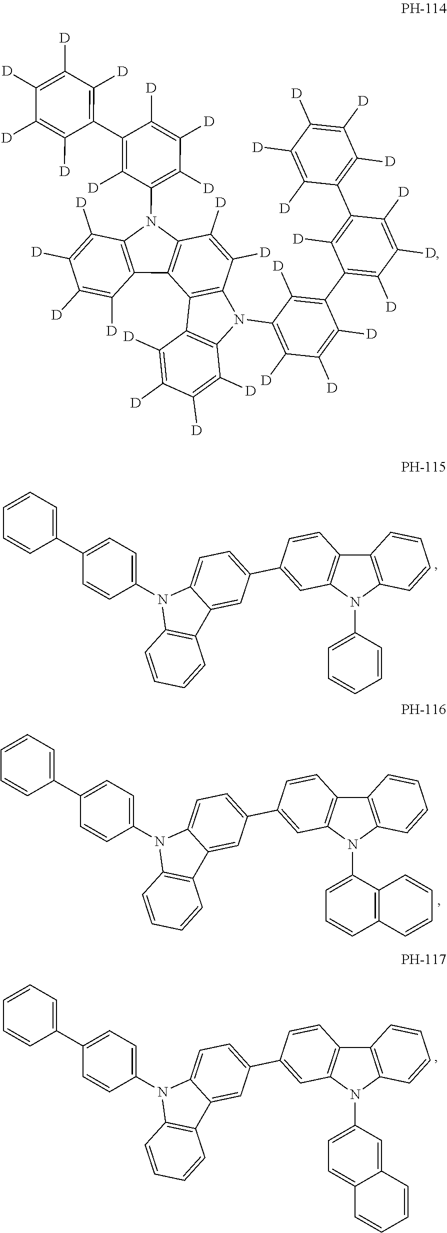 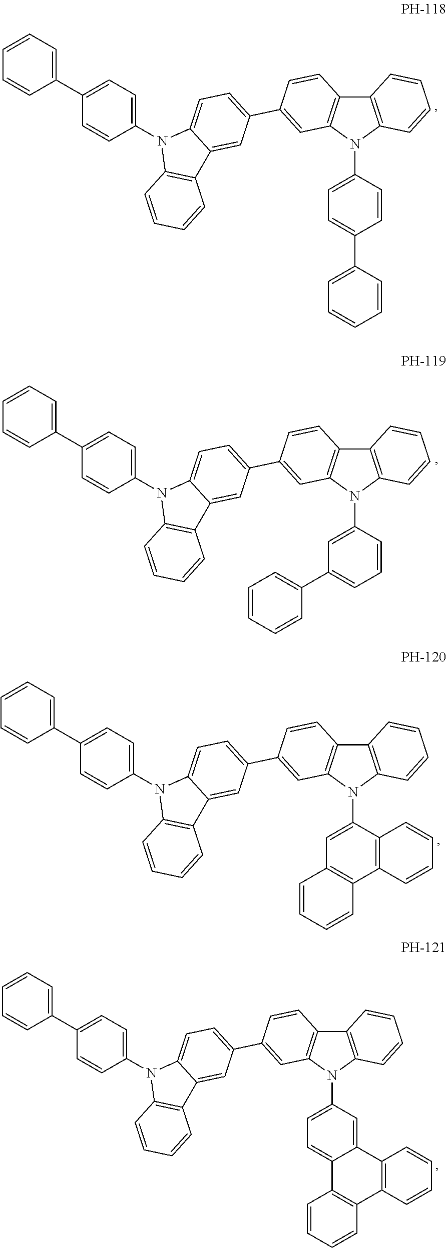 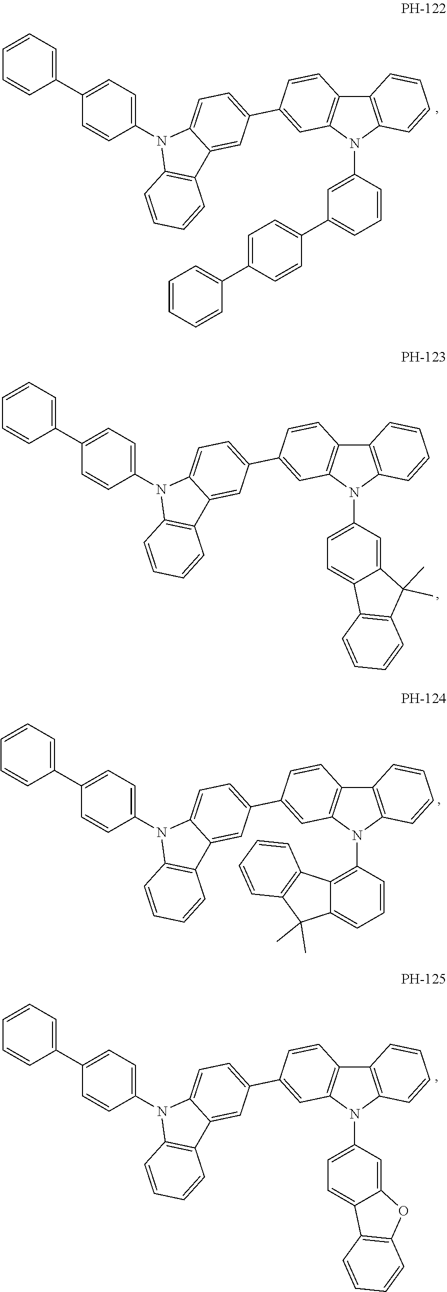 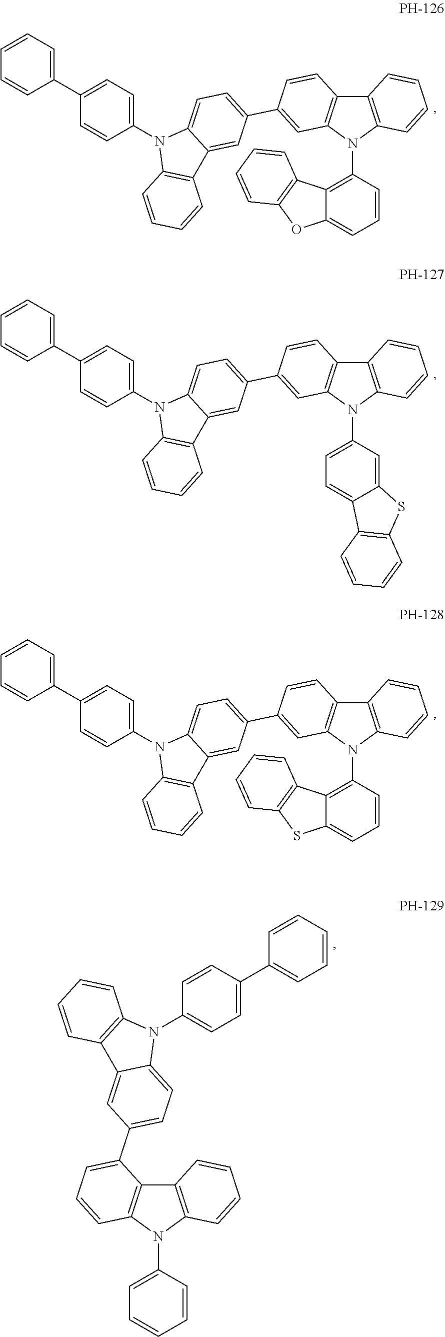 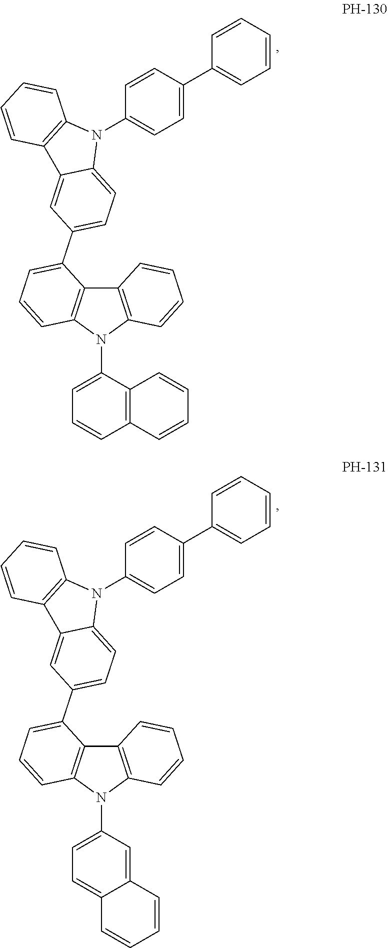 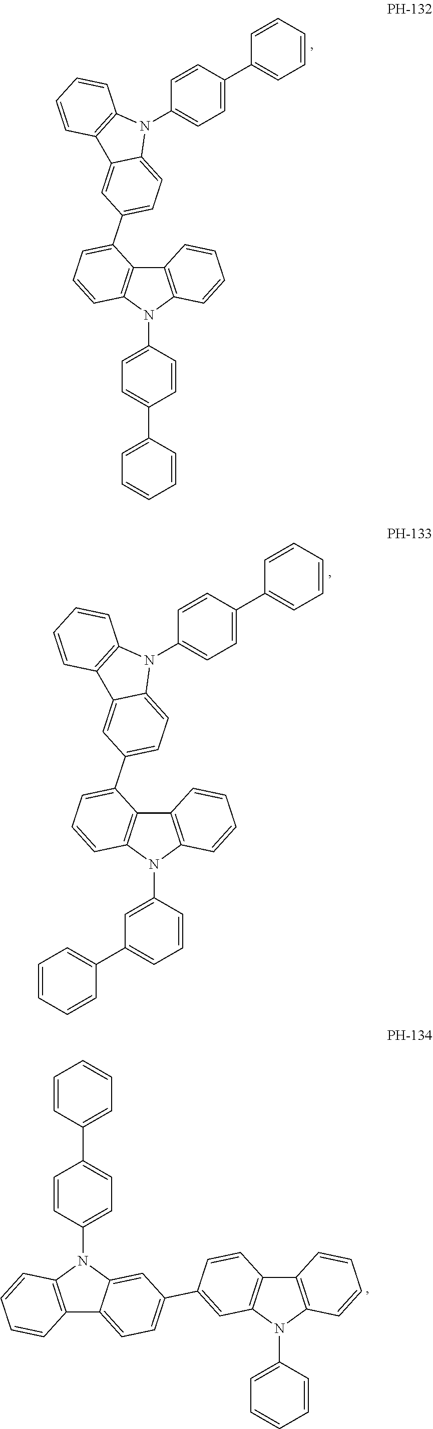 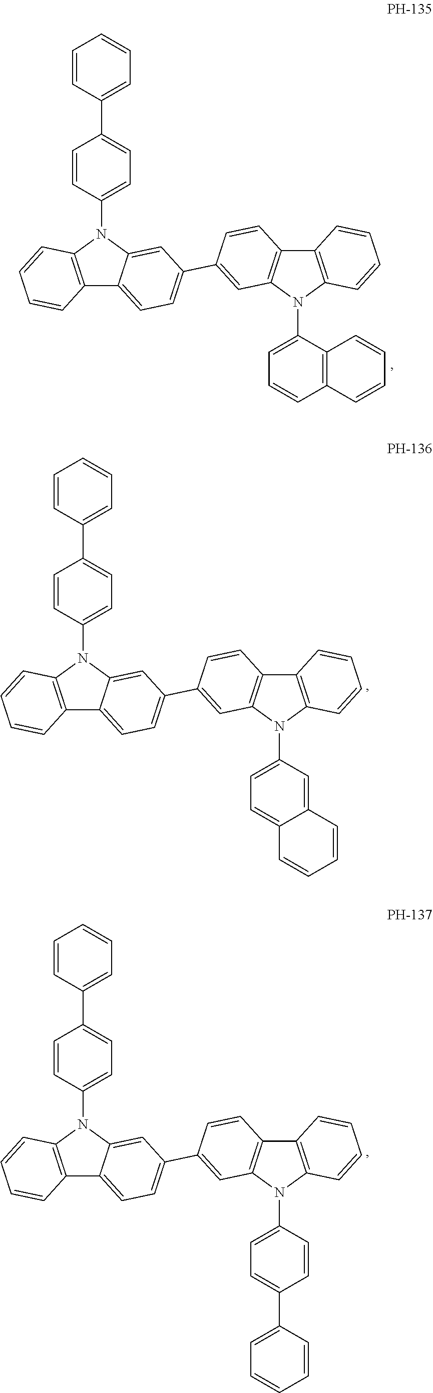 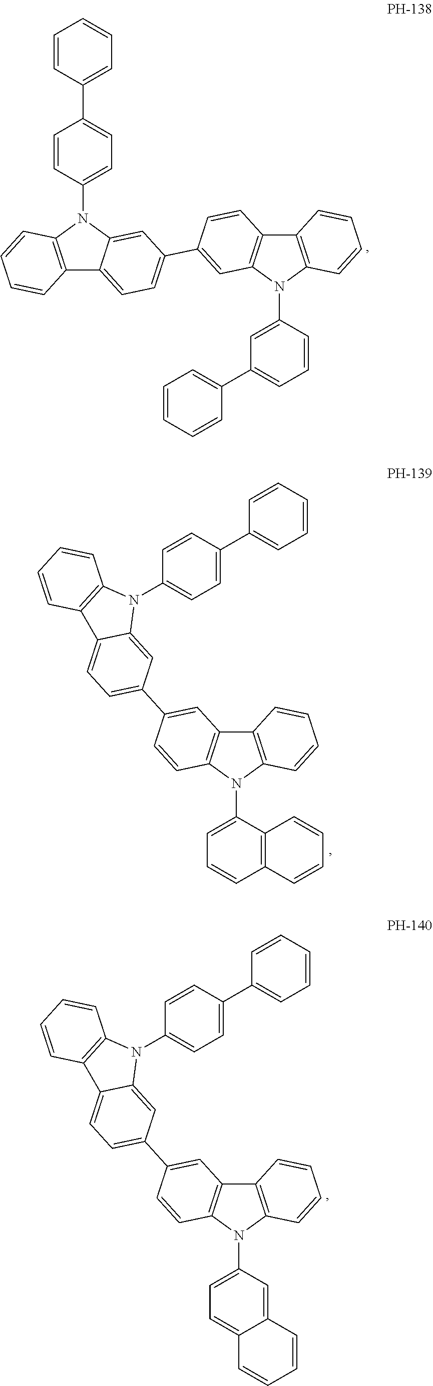 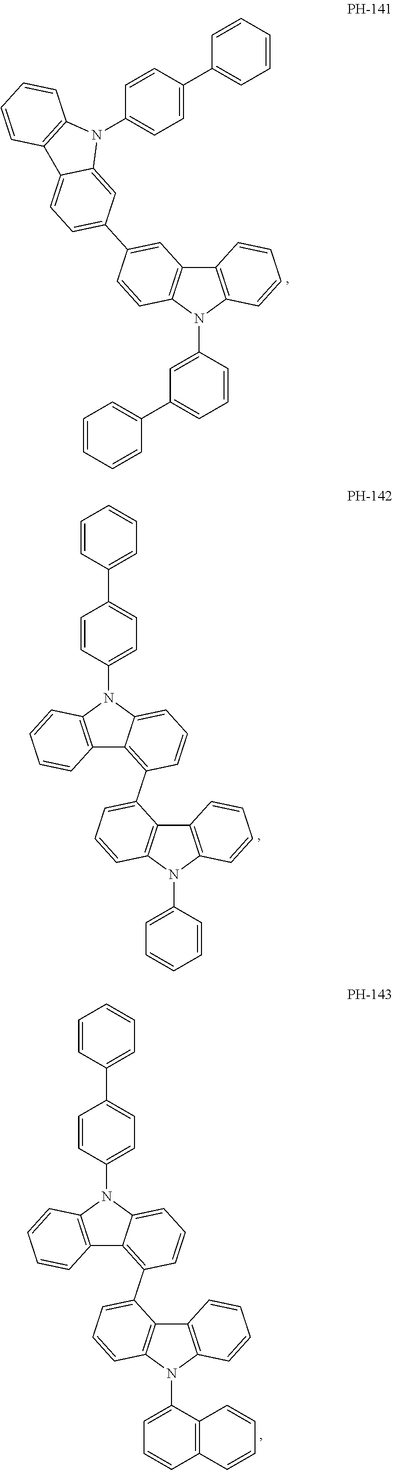 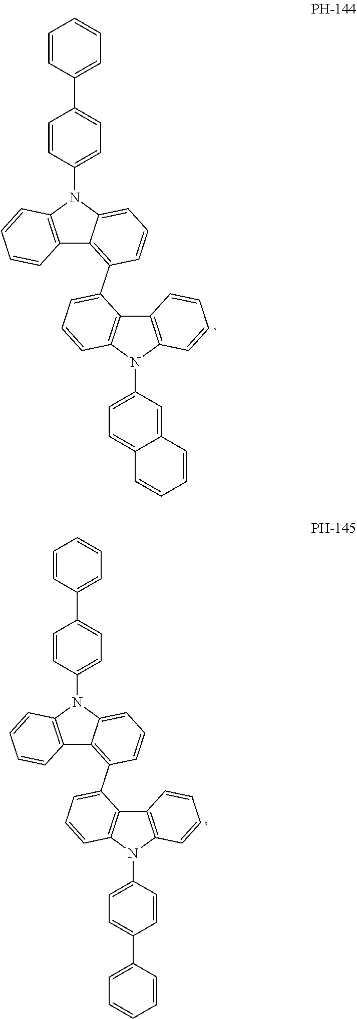 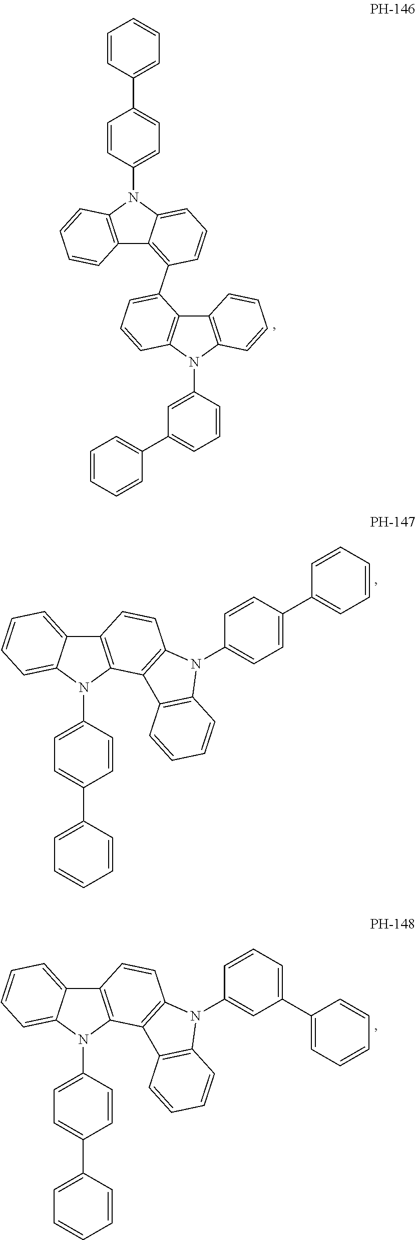 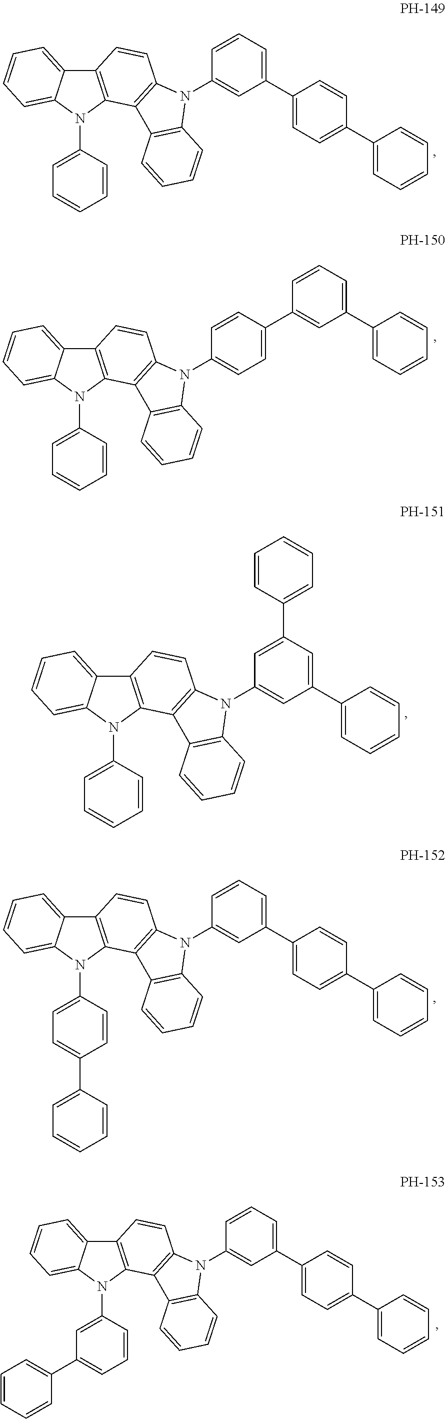 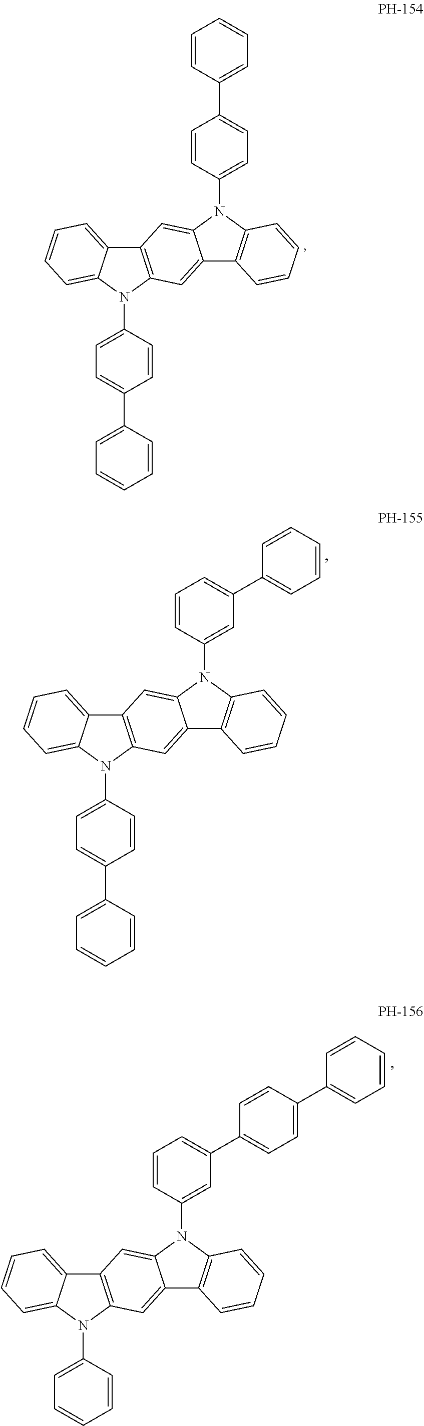 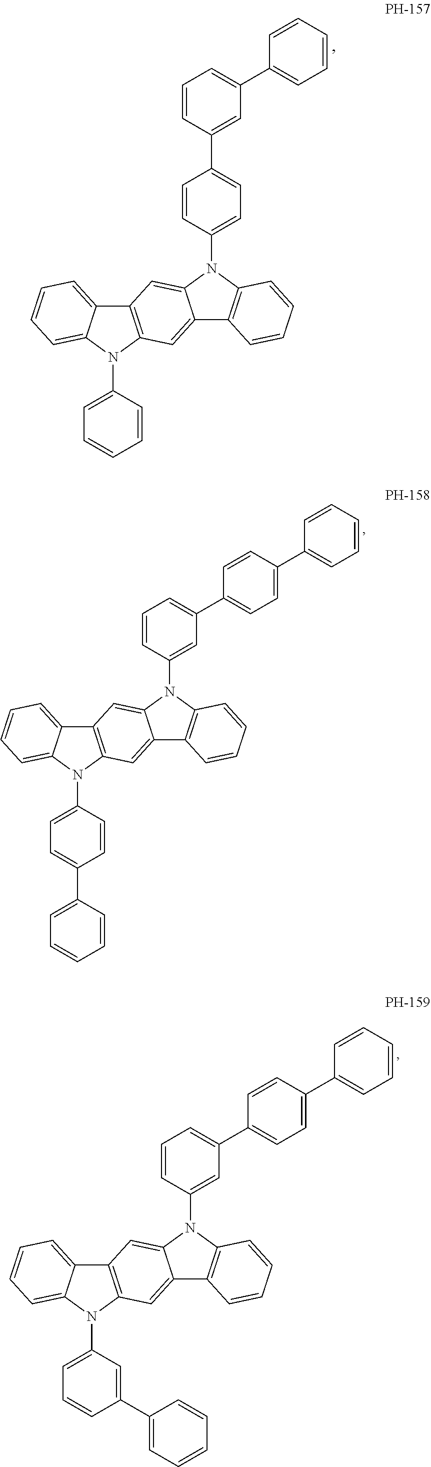 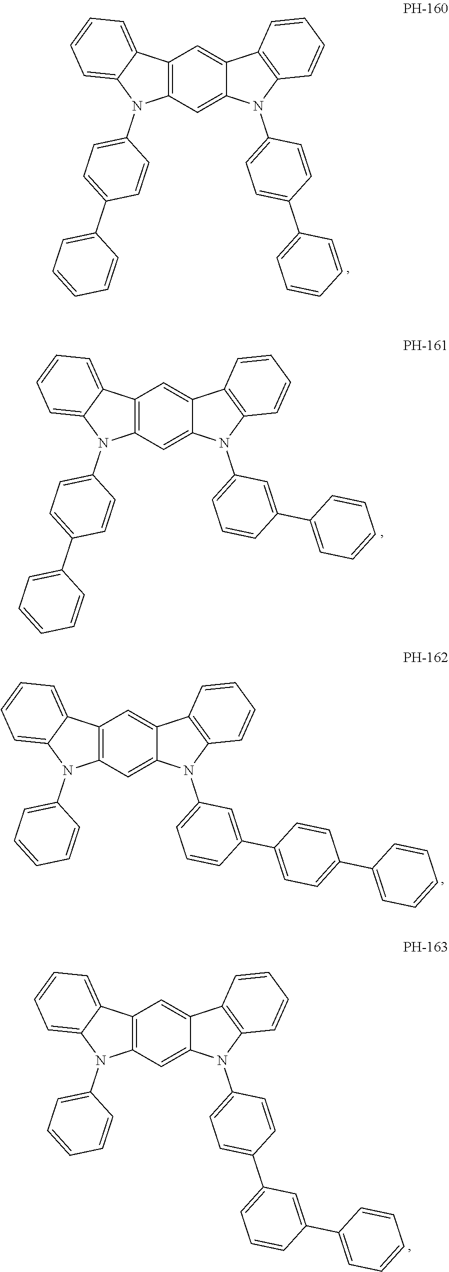 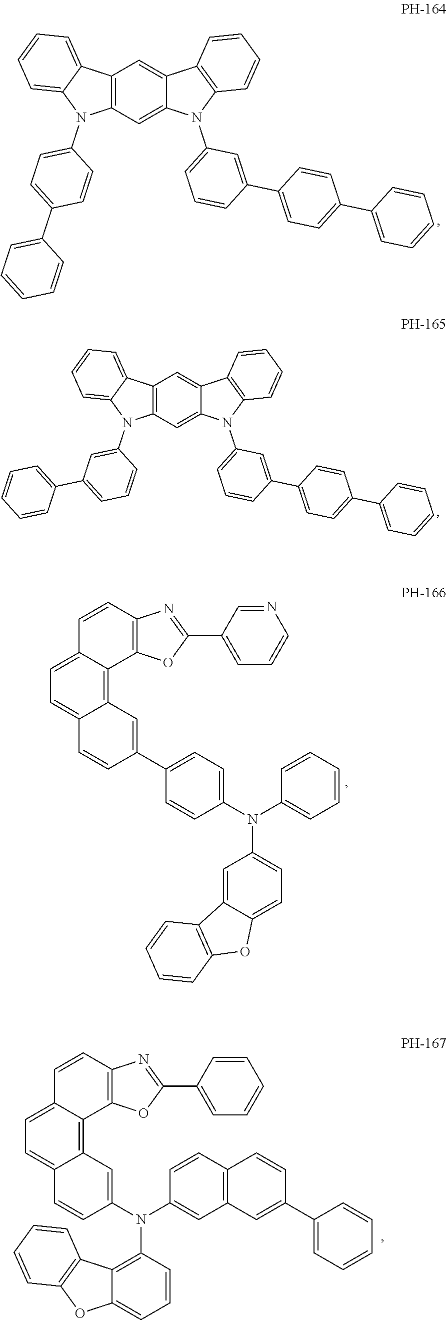 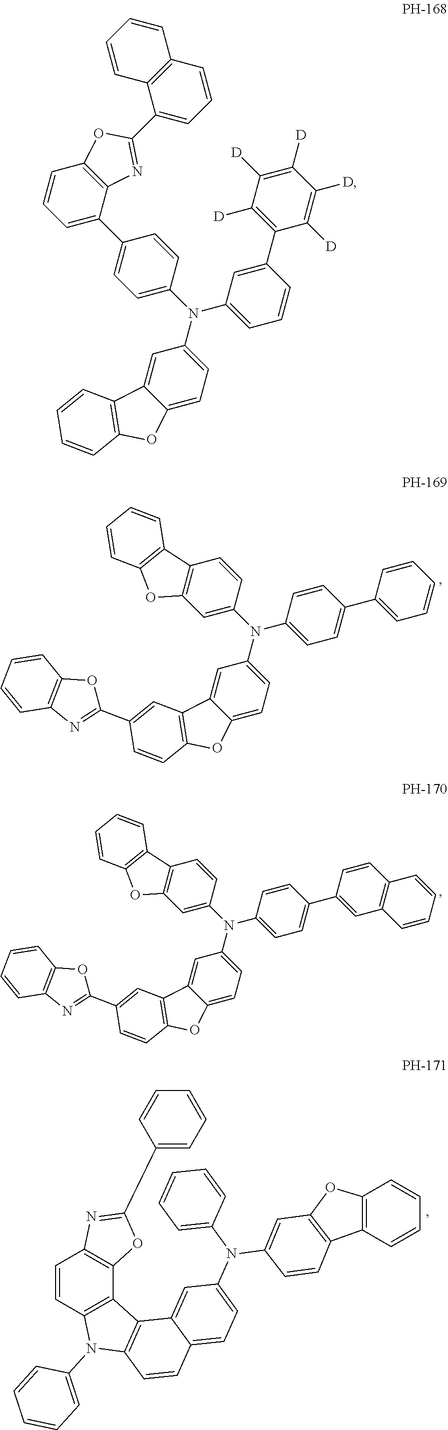 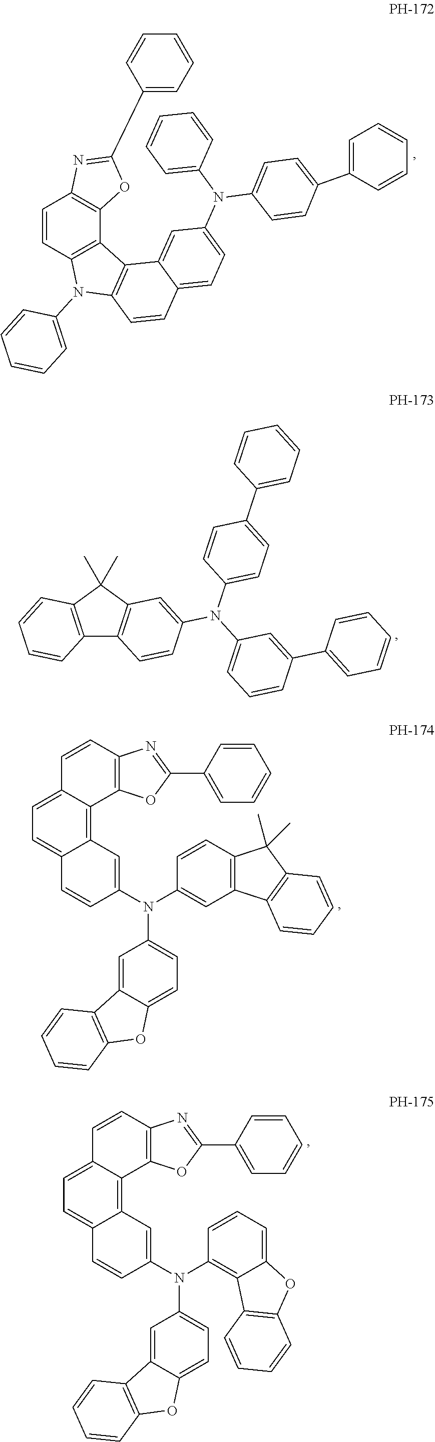 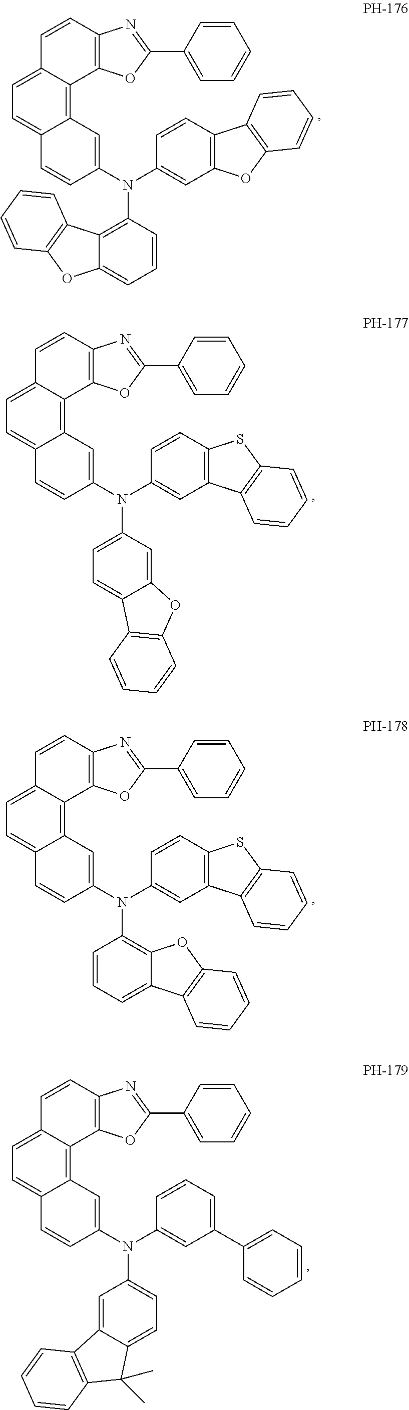 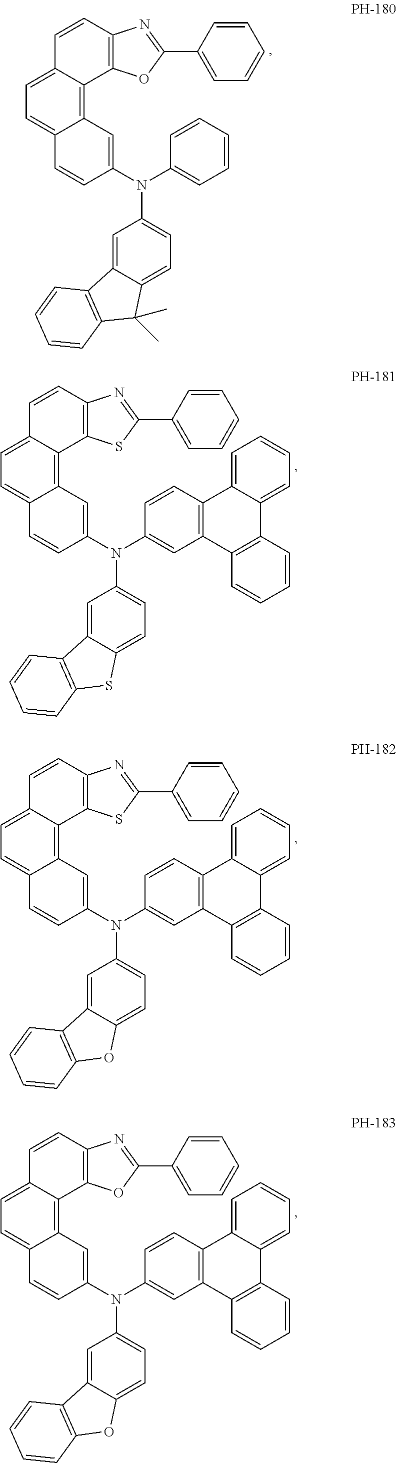 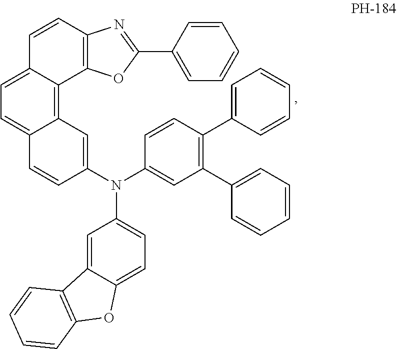 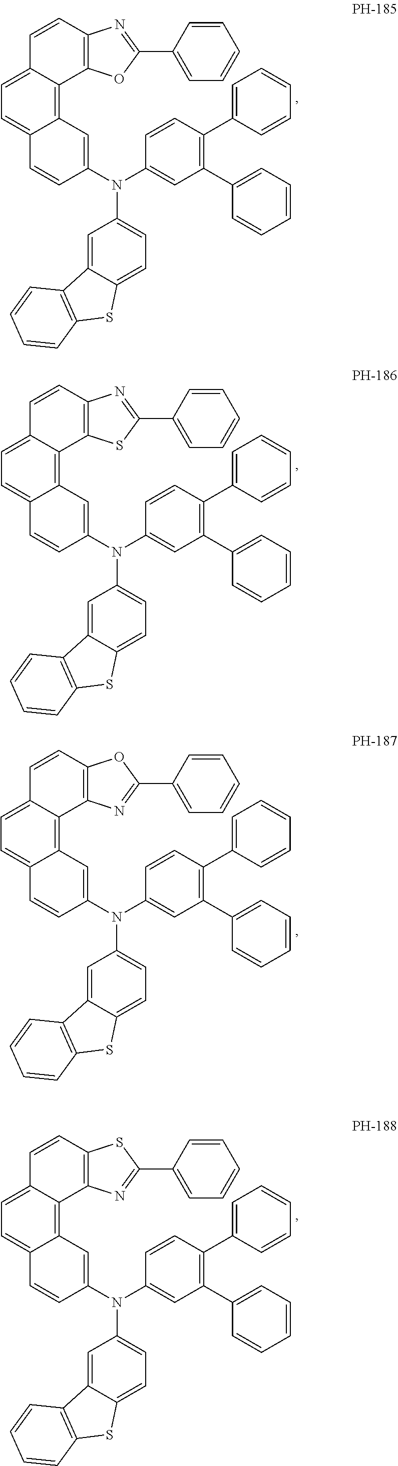 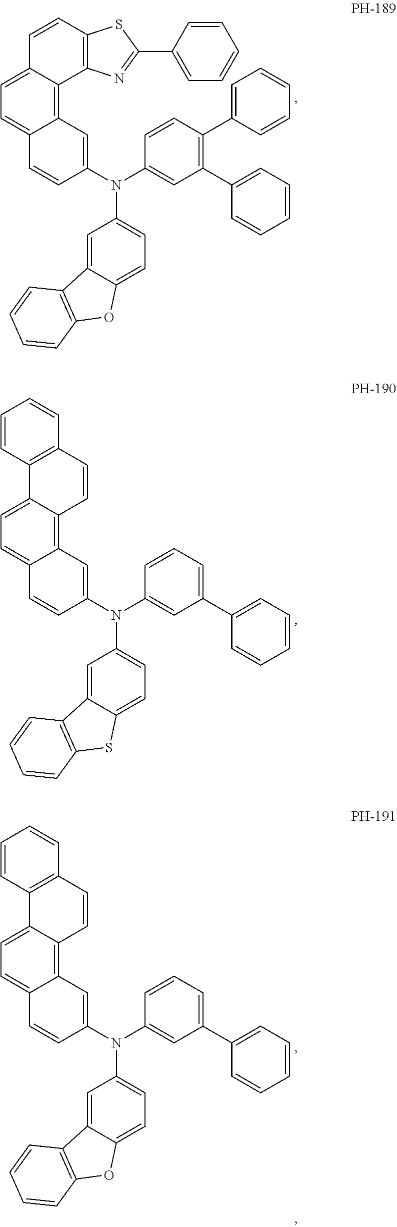 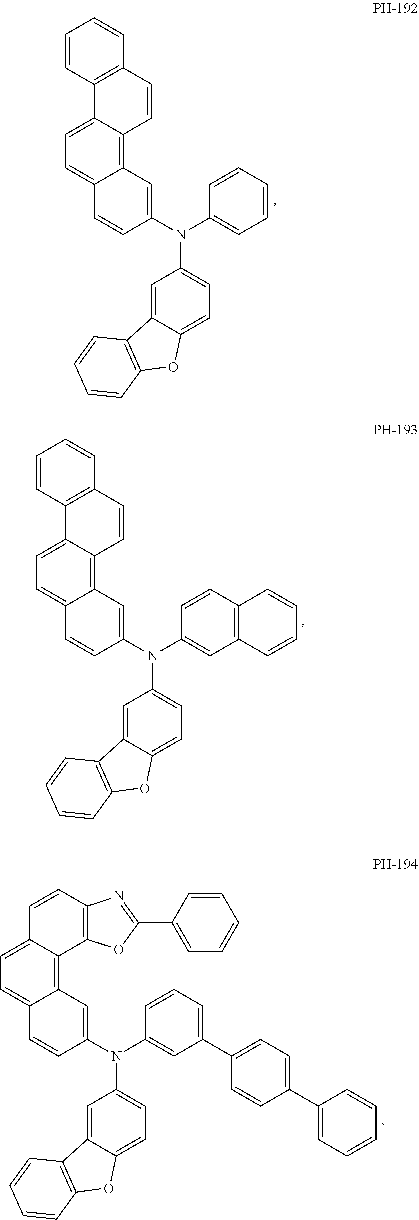 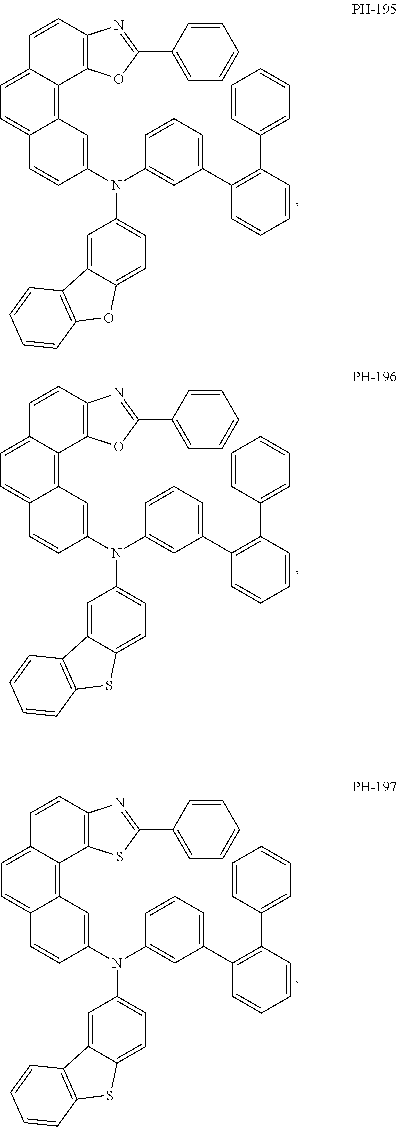 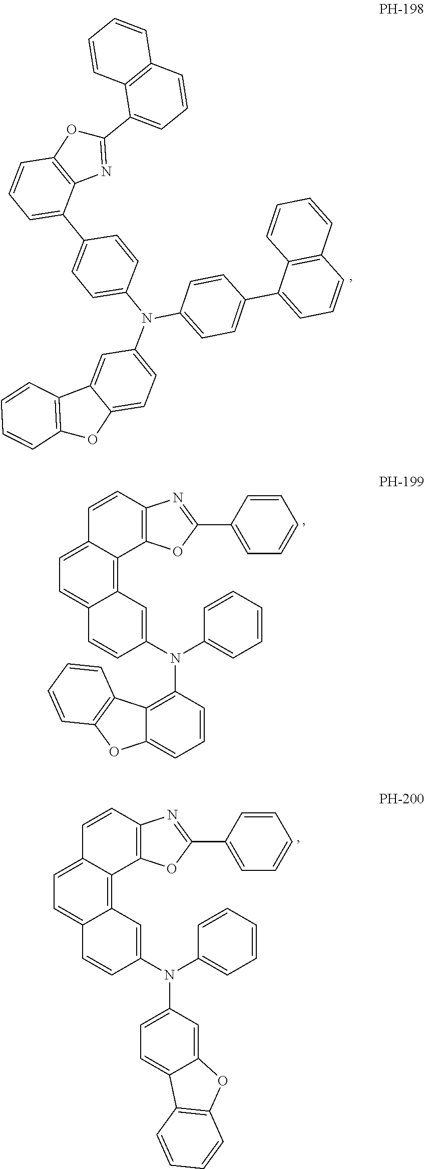 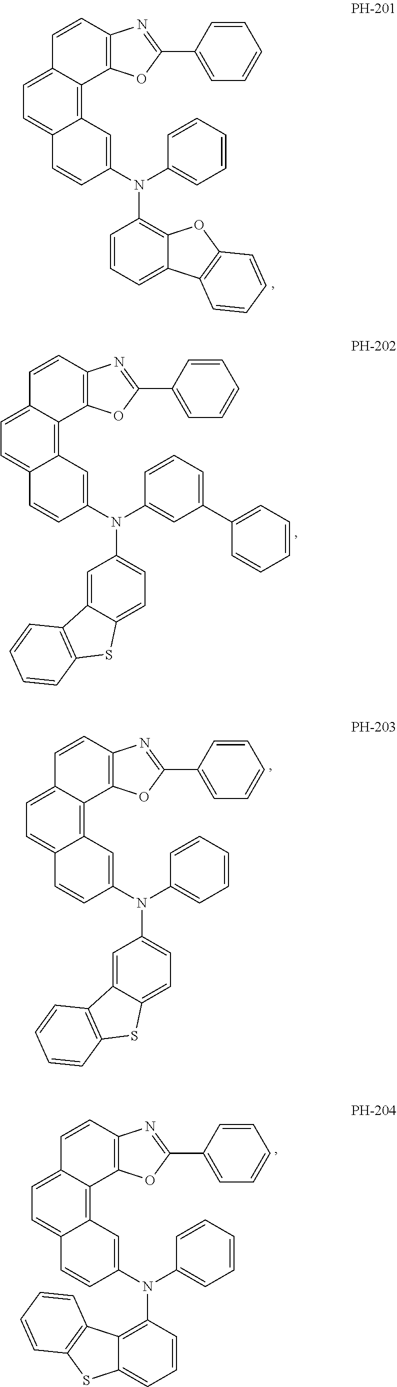 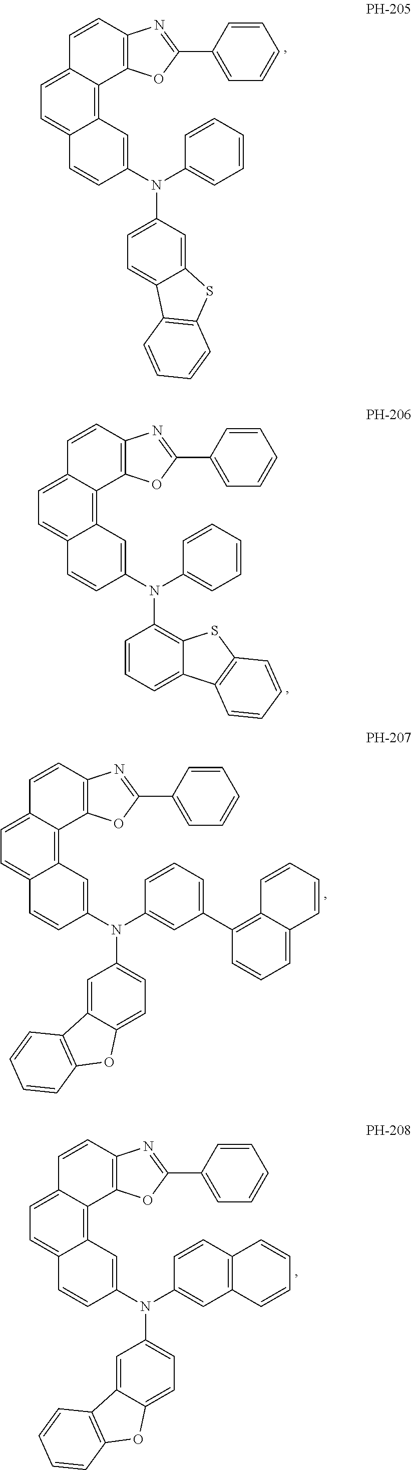 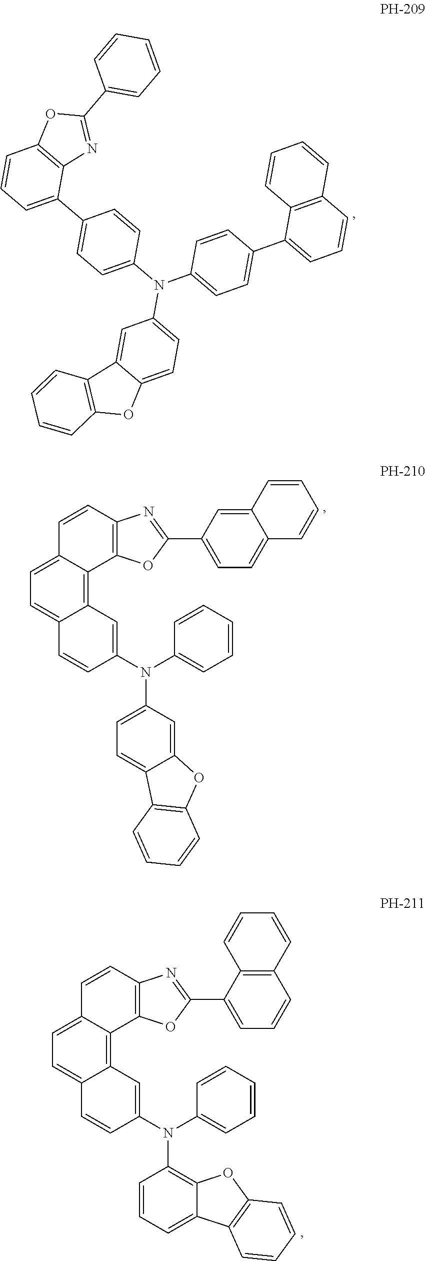 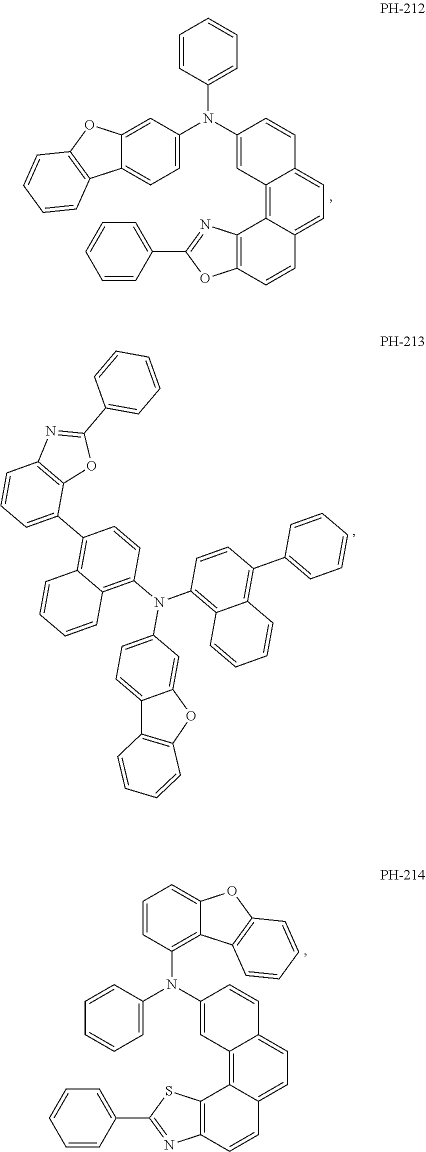 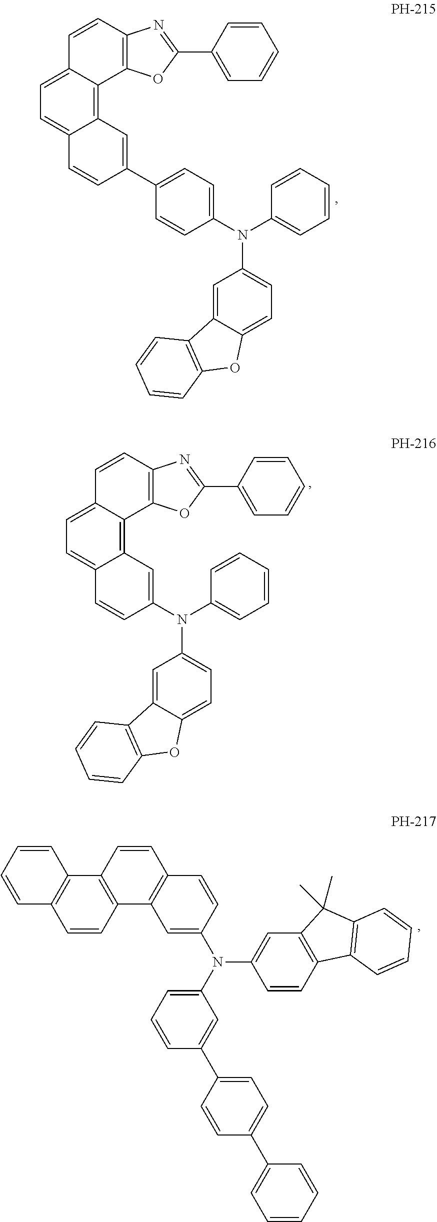 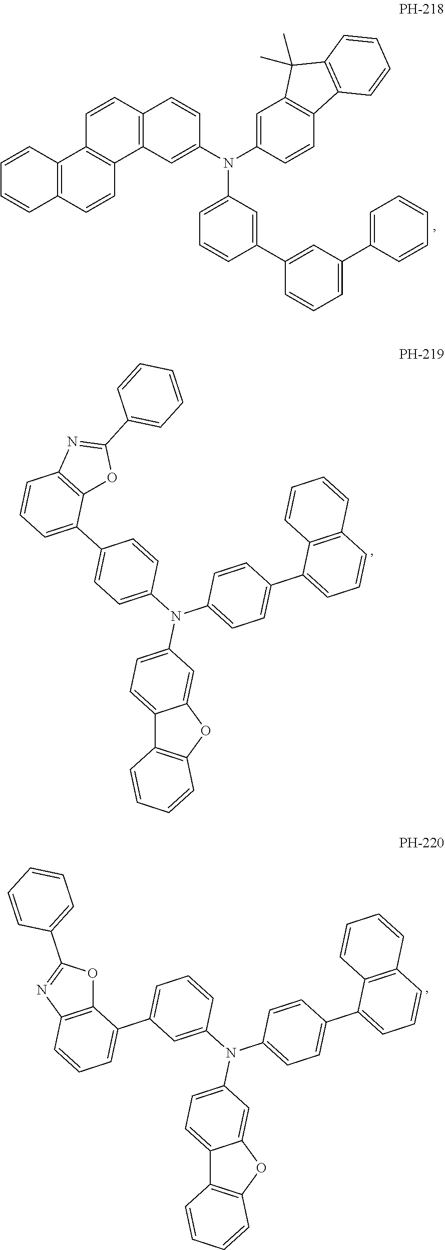 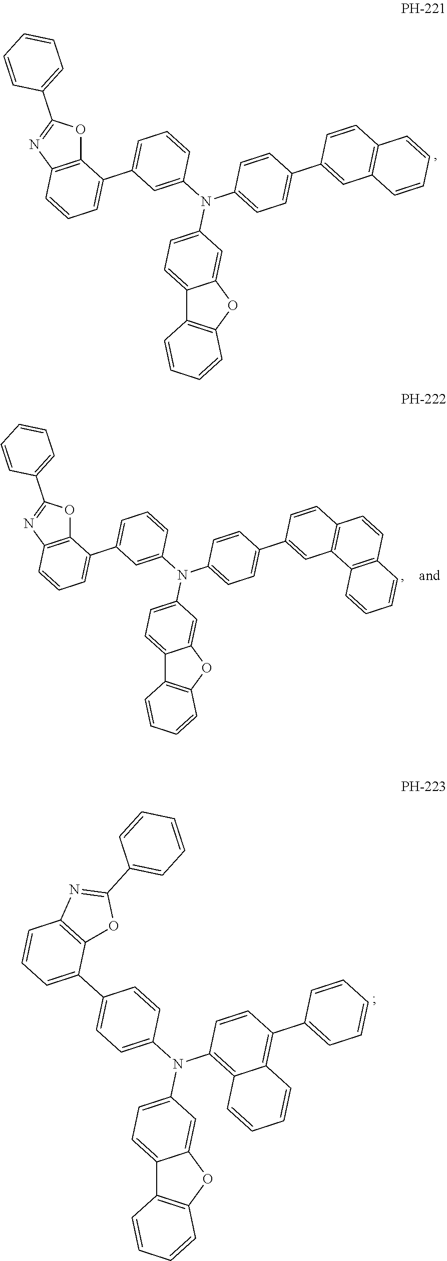
wherein, optionally, hydrogens in the structures of Compound P-1 to Compound P-23, Compound P-27 to Compound P-66, and Compound PH-1 to Compound PH-223 can be partially or fully substituted with deuterium.

20. Use of the composition of claim 1 in an organic electroluminescent device.

21. An organic electroluminescent device, comprising:
an anode,
a cathode, and
an organic layer disposed between the anode and the cathode, wherein the organic layer comprises the composition of claim 1;
the composition comprises a premix and a phosphorescent sensitizer, wherein the premix comprises a first host compound, a second host compound, and a fluorescent compound;
a triplet energy level of the first host compound, a triplet energy level of the second host compound, and a triplet energy level of the phosphorescent sensitizer are higher than a triplet energy level of the fluorescent compound;
the first host compound has an evaporation temperature T1, wherein T1 ranges from 100° C. to 400° C.;
the second host compound has an evaporation temperature T2, wherein T2 ranges from 100° C. to 400° C.;
an absolute value of a difference between T1 and T2 is less than or equal to 20° C.

22. The organic electroluminescent device of claim 21, wherein the organic layer is an emissive layer, the first host compound and the second host compound are host materials, and the fluorescent compound is an emissive material.

23. The organic electroluminescent device of claim 21, wherein the device emits blue light, green light or white light.

24. The organic electroluminescent device of claim 22, wherein weights of the first host compound and the second host compound account for 65% to 98.9% of a total weight of an emissive layer material, a weight of the phosphorescent sensitizer accounts for 1% to 30% of the total weight of the emissive layer material, and a weight of the fluorescent compound accounts for 0.1% to 5% of the total weight of the emissive layer material;
preferably, the weights of the first host compound and the second host compound account for 82% to 94.5% of the total weight of the emissive layer material, the weight of the phosphorescent sensitizer accounts for 5% to 15% of the total weight of the emissive layer material, and the weight of the fluorescent compound accounts for 0.5% to 3% of the total weight of the emissive layer material;
more preferably, the weights of the first host compound and the second host compound account for 86.5% to 91.5% of the total weight of the emissive layer material, the weight of the phosphorescent sensitizer accounts for 8% to 12% of the total weight of the emissive layer material, and the weight of the fluorescent compound accounts for 0.5% to 1.5% of the total weight of the emissive layer material.

25. A preparation method of an organic electroluminescent device, wherein the organic electroluminescent device comprises an anode, a cathode, and an organic layer disposed between the anode and the cathode, the organic layer comprises the composition of claim 1, and the preparation method comprises:
step 1: providing a substrate and disposing the anode thereon;
step 2: pre-mixing a first host compound, a second host compound, and a fluorescent compound to form a premix, and placing the premix in an evaporation source 1 in a high vacuum evaporation tool; placing a phosphorescent sensitizer in an evaporation source 2 in the high vacuum evaporation tool; in the high vacuum evaporation tool with a vacuum degree of 10 6 Torr or lower, co-evaporating the premix in the evaporation source 1 and the phosphorescent sensitizer in the evaporation source 2 at a rate of 0.2 angstroms/second to 2 angstroms/second, and co-evaporating the premix in the evaporation source 1 and the phosphorescent sensitizer in the evaporation source 2 on a surface positioned at a certain distance away from the evaporated premix and the evaporated phosphorescent sensitizer to form the organic layer;
wherein a triplet energy level of the first host compound, a triplet energy level of the second host compound, and a triplet energy level of the phosphorescent sensitizer are higher than a triplet energy level of the fluorescent compound;
the first host compound has an evaporation temperature T1, wherein T1 ranges from 100° C. to 400° C.;
the second host compound has an evaporation temperature T2, wherein T2 ranges from 100° C. to 400° C.;
an absolute value of a difference between T1 and T2 is less than or equal to 20° C.; and
step 3: evaporating the cathode on the organic layer.

26. A premix, comprising a first host compound, a second host compound, and a fluorescent compound;
wherein a triplet energy level of the first host compound and a triplet energy level of the second host compound are higher than a triplet energy level of the fluorescent compound;
the first host compound has an evaporation temperature T1, wherein T1 ranges from 100° C. to 400° C.;
the second host compound has an evaporation temperature T2, wherein T2 ranges from 100° C. to 400° C.;
an absolute value of a difference between T1 and T2 is less than or equal to 20° C.
